(19) United States
(12) Patent Application Publication
(10) Pub. No.: US 2023/0301160 A1
(43) Pub. Date: Sep. 21, 2023

(54) OPTO-ELECTRONIC DEVICE INCLUDING A LOW-INDEX LAYER

(71) Applicant: OTI Lumionics Inc., Mississauga (CA)

(72) Inventors: Qi WANG, Mississauga (CA); Yi-Lu CHANG, Mississauga (CA); Yingjie ZHANG, Mississauga (CA); Zhibin WANG, Mississauga (CA); Michael HELANDER, Mississauga (CA)

(73) Assignee: OTI Lumionics Inc., Mississauga, ON (CA)

(21) Appl. No.: 18/006,383

(22) PCT Filed: Jul. 24, 2021
(86) PCT No.: PCT/IB2021/056685

§ 371 Date: Jan. 20, 2023

Related U.S. Application Data
(60) Provisional application No. 63/181,100, filed on Apr. 28, 2021.
(60) Provisional application No. 63/163,453, filed on Mar. 19, 2021.
(60) Provisional application No. 63/153,834, filed on Feb. 25, 2021.
(60) Provisional application No. 63/141,857, filed on Jan. 26, 2021.
(60) Provisional application No. 63/122,421, filed on Dec. 7, 2020.
(60) Provisional application No. 63/107,393, filed on Oct. 29, 2020.
(60) Provisional application No. 63/090,098, filed on Oct. 9, 2020.
(60) Provisional application No. 63/064,633, filed on Aug. 12, 2020.
(60) Provisional application No. 63/056,499, filed on Jul. 24, 2020.

(51) Int. Cl. H10K 59/80

(52) U.S. Cl. CPC H10K 59/879; H10K 59/12

(57) ABSTRACT

A semiconductor device having a plurality of layers that extend in an interface portion and a non-interface portion of at least one lateral aspect defined by a lateral axis of the device. A low(er)-index layer, that may comprise a low-index material, that has a first refractive index at a wavelength, is disposed on a first layer surface in at least the interface portion. A higher-index layer, that may comprise a high-index material, that has a second refractive index at a wavelength, is disposed on an exposed layer surface of the device, to define an index interface with the low(er)-index layer in the interface portion. The second refractive index exceeds the first refractive index. A quantity of deposited material may be disposed on a second layer surface in the non-interface portion. The higher-index layer may cover the deposited material in the non-interface portion.

### RELATED APPLICATIONS

The present application claims the benefit of priority to: U.S. Provisional Patent Application No. 63/056,499 filed 24 Jul. 2020, U.S. Provisional Patent Application No. 63/064,633 filed 12 Aug. 2020, U.S. Provisional Patent Application No. 63/090,098 filed 9 Oct. 2020, U.S. Provisional Patent Application No. 63/107,393 filed 29 Oct. 2020, U.S. Provisional Patent Application No. 63/153,834 filed 25 Feb. 2021, U.S. Provisional Patent Application No. 63/163,453 filed 19 Mar. 2021, U.S. Provisional Patent Application No. 63/181,100 filed 28 Apr. 2021, U.S. Provisional Patent Application No. 63/122,421 filed 7 Dec. 2020, and U.S. Provisional Patent Application No. 63/141,857 filed 26 Jan. 2021, the contents of each of which are incorporated herein by reference in their entirety.

### TECHNICAL FIELD

The present disclosure relates to layered semiconductor devices and, in particular, to a layered opto-electronic device having an interface between a low(er) (refractive)-index coating and a higher (refractive)-index coating, through which electromagnetic (EM) radiation may pass, whether or not emitted by the device or passing entirely therethrough, including where the low(er)-index layer is anterior, in an optical path of electromagnetic (EM) radiation passing through the interface, relative to the higher-index layer.

### BACKGROUND

In an opto-electronic device such as an organic light emitting diode (OLED), at least one semiconducting layer is disposed between a pair of electrodes, such as an anode and a cathode. The anode and cathode are electrically coupled with a power source and respectively generate holes and electrons that migrate toward each other through the at least one semiconducting layer. When a pair of holes and electrons combine, a photon may be emitted.

OLED display panels may comprise a plurality of (sub-) pixels, each of which has an associated pair of electrodes and at least one semiconducting layer between them. In some non-limiting examples, the (sub-) pixels may be selectively driven by a driving circuit comprising a plurality of thin-film transistor (TFT) structures electrically coupled by conductive metal lines, in some non-limiting examples, within a substrate upon which the electrodes and the at least one semiconducting layer are deposited. Various layers and coatings of such panels are typically formed by vacuum-based deposition processes.

Such display panels may be used, by way of non-limiting example, in electronic devices such as mobile phones.

In some applications, there may be an aim to provide a conductive deposited layer in a pattern for each (sub-) pixel of the panel across either, or both of, a lateral and a cross-sectional aspect thereof, by selective deposition of at least one thin film of the deposited layer to form a device feature, such as, without limitation, an electrode and/or a conductive element electrically coupled therewith, during the OLED manufacturing process.

In some non-limiting applications, there may be an aim to increase the transmission of EM radiation, and/or to reduce absorption of EM radiation, to provide an improved mechanism for along an optical path through at least a portion of the device in at least a wavelength sub-range of the EM spectrum.

### BRIEF DESCRIPTION OF THE DRAWINGS

Examples of the present disclosure will now be described by reference to the following figures, in which identical reference numerals in different figures indicate identical and/or in some non-limiting examples, analogous and/or corresponding elements and in which:

FIG. 1 is a simplified block diagram from a cross-sectional aspect, of an example device, having a low(er)-index layer anterior (in an optical path indicated generally by arrow OC) to a higher-index layer according to an example in the present disclosure;

FIG. 2 is a graph plotting refractive index values as a function of surface tension for a variety of example materials according to an example;

FIG. 3A is a simplified block diagram from a cross-sectional aspect, of an example version of the device of FIG. 1, with a discontinuous layer of at least one particle structure disposed on an exposed layer surface of the low(er)-index layer according to an example in the present disclosure;

FIG. 3B is a simplified block diagram in plan of the device of FIG. 3A;

FIGS. 4A-4B are simplified block diagrams from a cross-sectional aspect, of an example version of the device of FIG. 1, having a plurality of layers in a lateral aspect, formed by selective deposition of the low(er)-index layer in an interface portion of the lateral aspect, followed by deposition of a closed coating of deposited material in a non-interface portion thereof, and by deposition of a higher-index layer thereover, according to an example in the present disclosure;

FIG. 5 is a plot of transmittance as a function of wavelength for various example samples according to an example in the present disclosure;

FIG. 6 is a schematic diagram showing an example process for depositing a patterning coating on an exposed layer surface of an underlying layer, in a first portion of a lateral aspect, in an example version of the device of FIG. 4, according to an example in the present disclosure;

FIG. 7 is a schematic diagram showing an example process for depositing a deposited material in a second portion of the lateral aspect, on an exposed layer surface that comprises the deposited pattern of the patterning coating of FIG. 6;

FIG. 8A is a schematic diagram illustrating an example version of the device of FIG. 4 in a cross-sectional view;

FIG. 8B is a schematic diagram illustrating the device of FIG. 8A in a complementary plan view;

FIG. 8C is a schematic diagram illustrating an example version of the device of FIG. 4 in a cross-sectional view;

FIG. 8D is a schematic diagram illustrating the device of FIG. 8C in a complementary plan view;

FIG. 8E is a schematic diagram illustrating an example of the device of FIG. 4 in a cross-sectional view;

FIG. 8F is a schematic diagram illustrating an example of the device of FIG. 4 in a cross-sectional view;

FIG. 8G is a schematic diagram illustrating an example of the device of FIG. 4 in a cross-sectional view;

FIGS. 9A-9I are schematic diagrams that show various potential behaviours of a patterning coating at a deposition interface with a deposited layer in an example version of the device of FIG. 4, according to various examples in the present disclosure;

FIG. 10 is a block diagram from a cross-sectional aspect, of an example electro-luminescent device according to an example in the present disclosure;

FIG. 11 is a cross-sectional view of the device of FIG. 10;

FIG. 12 is a schematic diagram illustrating, in plan view, an example patterned electrode suitable for use in a version of the device of FIG. 10, according to an example in the present disclosure;

FIG. 13 is a schematic diagram illustrating an example cross-sectional view of the device of FIG. 12 taken along line 13-13;

FIG. 14A is a schematic diagram illustrating, in plan view, a plurality of example patterns of electrodes suitable for use in an example version of the device of FIG. 10, according to an example in the present disclosure;

FIG. 14B is a schematic diagram illustrating an example cross-sectional view, at an intermediate stage, of the device of FIG. 14C taken along line 14B-14B;

FIG. 14C is a schematic diagram illustrating an example cross-sectional view of the device of FIG. 14A taken along line 14C-14C;

FIG. 15 is a schematic diagram illustrating a cross-sectional view of an example version of the device of FIG. 10, having an example patterned auxiliary electrode according to an example in the present disclosure;

FIG. 16 is a schematic diagram illustrating, in plan view an example pattern of an auxiliary electrode overlaying at least one emissive region and at least one non-emissive region according to an example in the present disclosure;

FIG. 17A is a schematic diagram illustrating, in plan view, an example pattern of an example version of the device of FIG. 10, having a plurality of groups of emissive regions in a diamond configuration according to an example in the present disclosure;

FIG. 17B is a schematic diagram illustrating an example cross-sectional view of the device of FIG. 17A taken along line 17B-17B;

FIG. 17C is a schematic diagram illustrating an, example cross-sectional view of the device of FIG. 17A taken along line 17C-17C;

FIG. 18 is a schematic diagram illustrating an example cross-sectional view of an example version of the device of FIG. 11 with additional example deposition steps according to an example in the present disclosure;

FIG. 19 is a schematic diagram illustrating an example cross-sectional view of an example version of the device of FIG. 11 with additional example deposition steps according to an example in the present disclosure;

FIG. 20 is a schematic diagram illustrating an example cross-sectional view of an example version of the device of FIG. 11 with additional example deposition steps according to an example in the present disclosure;

FIG. 21 is a schematic diagram illustrating an example cross-sectional view of an example version of the device of FIG. 11 with additional example deposition steps according to an example in the present disclosure;

FIG. 22A is a schematic diagram illustrating, in plan view, an example of a transparent version of the device of FIG. 10 comprising at least one example pixel region and at least one example light-transmissive region, with at least one auxiliary electrode according to an example in the present disclosure;

FIG. 22B is a schematic diagram illustrating an example cross-sectional view of the device of FIG. 22A taken along line 22B-22B;

FIG. 23A is a schematic diagram illustrating, in plan view, an example of a transparent version of the device of FIG. 10 comprising at least one example pixel region and at least one example light-transmissive region according to an example in the present disclosure;

FIG. 23B is a schematic diagram illustrating an example cross-sectional view of the device of FIG. 23A taken along line 23-23;

FIG. 23C is a schematic diagram illustrating an example cross-sectional view of the device of FIG. 23A taken along line 23-23;

FIG. 24 is a schematic diagram that may show example stages of an example process for manufacturing an example version of the device of FIG. 11 having sub-pixel regions having a second electrode of different thickness according to an example in the present disclosure;

FIG. 25 is a schematic diagram illustrating an example cross-sectional view of an example version of the device of FIG. 10 in which a second electrode is coupled with an auxiliary electrode according to an example in the present disclosure;

FIG. 26 is a schematic diagram illustrating an example cross-sectional view of an example version of the device of FIG. 10 having a partition and a sheltered region, such as a recess, in a non-emissive region thereof according to an example in the present disclosure;

FIGS. 27A-27B are schematic diagrams that show example cross-sectional views of an example version of the device of FIG. 10 having a partition and a sheltered region, such as an aperture, in a non-emissive region, according to various examples in the present disclosure;

FIGS. 28A-28C are schematic diagrams that show example stages of an example process for depositing a deposited layer in a pattern on an exposed layer surface of an example version of the device of FIG. 10, by selective deposition and subsequent removal process, according to an example in the present disclosure;

FIG. 29 is an example energy profile illustrating relative energy states of an adatom absorbed onto a surface according to an example in the present disclosure; and

FIG. 30 is a schematic diagram illustrating the formation of a film nucleus according to an example in the present disclosure.

In the present disclosure, a reference numeral having at least one numeric value (including without limitation, in subscript) and/or lower-case alphabetic character(s) (including without limitation, in lower-case) appended thereto, may be considered to refer to a particular instance, and/or subset thereof, of the element or feature described by the reference numeral. Reference to the reference numeral without reference to the appended value(s) and/or character(s) may, as the context dictates, refer generally to the element(s) or feature(s) described by the reference numeral, and/or to the set of all instances described thereby. Similarly, a reference numeral may have the letter “x’ in the place of a numeric digit. Reference to such reference numeral may, as the context dictates, refer generally to the element(s) or feature(s) described by the reference numeral, where the character “x” is replaced by a numeric digit, and/or to the set of all instances described thereby.

In the present disclosure, for purposes of explanation and not limitation, specific details are set forth to provide a thorough understanding of the present disclosure, including, without limitation, particular architectures, interfaces and/or techniques. In some instances, detailed descriptions of well-known systems, technologies, components, devices, circuits, methods, and applications are omitted to not obscure the description of the present disclosure with unnecessary detail.

Further, it will be appreciated that block diagrams reproduced herein can represent conceptual views of illustrative components embodying the principles of the technology.

Accordingly, the system and method components have been represented where appropriate by conventional symbols in the drawings, showing only those specific details that are pertinent to understanding the examples of the present disclosure, to not obscure the disclosure with details that will be readily apparent to those of ordinary skill in the art having the benefit of the description herein.

Any drawings provided herein may not be drawn to scale and may not be considered to limit the present disclosure in any way.

Any feature or action shown in dashed outline may in some examples be considered as optional.

### SUMMARY

It is an object of the present disclosure to obviate or mitigate at least one disadvantage of the prior art.

The present disclosure discloses a semiconductor device having a plurality of layers that extend in an interface portion and a non-interface portion of at least one lateral aspect defined by a lateral axis of the device. A low(er)-index layer, that may comprise a low-index material, that has a first refractive index at a wavelength, is disposed on a first layer surface in at least the interface portion. A higher-index layer, that may comprise a high-index material, that has a second refractive index at a wavelength, is disposed on an exposed layer surface of the device, to define an index interface with the low(er)-index layer in the interface portion. The second refractive index exceeds the first refractive index. A quantity of deposited material may be disposed on a second layer surface in the non-interface portion. The higher-index layer may cover the deposited material in the non-interface portion.

According to a broad aspect of the present disclosure, there is disclosed a semiconductor device having a plurality of layers and extending in an interface portion and a non-interface portion of at least one lateral aspect defined by a lateral axis thereof, comprising: a low(er)-index layer that has a first refractive index, at a wavelength in a first wavelength range, disposed on a first layer surface in at least the interface portion; and a higher-index layer that has a second refractive index, at a wavelength in a second wavelength range, disposed on a second exposed layer surface of the device, to define an index interface with the low(er)-index layer in the interface portion that exceeds the first refractive index.

In some non-limiting examples, the first wavelength may be selected from at least one of between about: 315-400 nm, 450-460 nm, 510-540 nm, 600-640 nm, 456-624 nm, 425-725 nm, 350-450 nm, 300-450 nm, 300-550 nm, 300-700 nm, 380-740 nm, 750-900 nm, 380-900 nm, and 300-900 nm.

In some non-limiting examples, the first refractive index may vary across the first wavelength range by no more than at least one of about: 0.4, 0.3, 0.2, and 0.1. In some non-limiting examples, the first refractive index may be no more than at least one of about: 1.7, 1., 1.5, 1.45, 1.4, 1.35, 1.3, and 1.25. In some non-limiting examples, the first refractive index may be at least one of between about: 1.2-1.6, 1.2-1.5, 1.25-1.45, and 1.25-1.4.

In some non-limiting examples, the low(er)-index layer comprises a low-index material.

In some non-limiting examples, at least one of the low(er)-index layer and the low-index material may exhibit an extinction coefficient in the first wavelength range that is no more than at least one of about: 0.10, 0.08, 0.05, 0.03, and 0.01.

In some non-limiting examples, at least one of the low(er)-index layer and the low-index material may be substantially transparent.

In some non-limiting examples, at least one of the low(er)-index layer and the low-index material may comprise at least one void therewithin.

In some non-limiting examples, the low-index material may comprise at least one of an organic compound and an organic-inorganic hybrid material.

In some non-limiting examples, the second wavelength range may be selected from at least one of between about: 315-400 nm, 450-460 nm, 510-540 nm, 600-640 nm, 456-624 nm, 425-725 nm, 350-450 nm, 300-450 nm, 300-550 nm, 300-700 nm, 380-740 nm, 750-900 nm, 380-900 nm, and 300-900 nm. In some non-limiting examples, the second wavelength range may be different from the first wavelength range.

In some non-limiting examples, the second refractive index may be at least one of at least about: 1.7, 1.8, and 1.9.

In some non-limiting examples, the second refractive index may exceed the first refractive index by at least one of at least about: 0.3, 0.4, 0.5, 0.7, 1.0, 1.2, 1.3, 1.4, and 1.5.

In some non-limiting examples, a second maximum refractive index corresponding to a maximum value of the second refractive index measured within the second wavelength range may exceed a first maximum refractive index corresponding to a maximum value of the first refractive index measured within the first wavelength range. In some non-limiting examples, the first maximum refractive index may correspond to a first wavelength within the first wavelength range that is different from a second wavelength within the second wavelength range to which the second maximum refractive index corresponds. In some non-limiting examples, the second maximum refractive index may exceed the first maximum refractive index by at least one of at least about: 0.5, 0.7, 1.0, 1.2, 1.3, 1.4, 1.5, and 1.7.

In some non-limiting examples, the higher-index layer may comprise a physical coating selected from at least one of: a capping layer, a barrier coating, an encapsulation layer, a thin film encapsulation layer, and a polarizing layer. In some non-limiting examples, the higher-index layer may comprise an air gap.

In some non-limiting examples, the higher-index layer may comprise a high-index material.

In some non-limiting examples, at least one of the higher-index layer and the high-index material may exhibit an extinction coefficient in the second wavelength range that is no more than at least one of about: 0.1, 0.08, 0.05, 0.03, and 0.01.

In some non-limiting examples, at least one of the higher-index layer and the high-index material may be substantially transparent.

In some non-limiting examples, the high-index material may comprise an organic compound.

In some non-limiting examples, the first layer surface may be of an underlying layer that has a third refractive index at a wavelength in a third wavelength range that exceeds the first refractive index.

In some non-limiting examples, the third wavelength range may be selected from at least one of between about: 315-400 nm, 450-460 nm, 510-540 nm, 600-640 nm, 456-624 nm, 425-725 nm, 350-450 nm, 300-450 nm, 300-550 nm, 300-700 nm, 380-740 nm, 750-900 nm, 380-900 nm, and 300-900 nm. In some non-limiting examples, the third wavelength range may be different from the first wavelength range.

In some non-limiting examples, the third refractive index may be at least one of at least about: 1.7, 1.8, and 1.9.

In some non-limiting examples, the third refractive index may exceed the first refractive index by at least one of at least about: 0.3, 0.4, 0.5, 0.7, 1.0, 1.2, 1.3, 1.4, and 1.5.

In some non-limiting examples, a third maximum refractive index corresponding to a maximum value of the third refractive index measured within the third wavelength range may exceed a first maximum refractive index corresponding to a maximum value of the first refractive index measured within the first wavelength range. In some non-limiting examples, the first maximum refractive index may correspond to a first wavelength within the first wavelength range that is different from a third wavelength within the third wavelength range to which the third maximum refractive index corresponds. In some non-limiting examples, the third maximum refractive index may exceed the first maximum refractive index by at least one of at least about: 0.5, 0.7, 1.0, 1.2, 1.3, 1.4, 1.5, and 1.7.

In some non-limiting examples, the underlying layer may be a semiconducting layer of an opto-electronic device. In some non-limiting examples, the underlying layer may be selected from an electron transport layer and an electron injection layer.

In some non-limiting examples, an average layer thickness of the low(er)-index layer may be no more than an average layer thickness of the higher-index layer. In some non-limiting examples, the average layer thickness of the low(er)-index layer may be no more than at least one of about: 60 nm, 50 nm, 40 nm, 30 nm, 20 nm, 10 nm, 8 nm, and 5 nm. In some non-limiting examples, the average layer thickness of the low(er)-index layer may be at least one of between about: 5-20 nm, and 5-15 nm.

In some non-limiting examples, the low-index material may exhibit a surface energy that is no more than about 25 dynes/cm and the first refractive index may be no more than about 1.45. In some non-limiting examples, the low-index material may exhibit a surface energy that is no more than about 20 dynes/cm and the first refractive index may be no more than about 1.4.

In some non-limiting examples, the device may further comprise a quantity of deposited material disposed on a second layer surface in the non-interface portion.

In some non-limiting examples, the low(er)-index layer may comprise a patterning coating. In some non-limiting examples, an initial sticking probability for forming a closed coating of the deposited material onto a surface of the patterning coating may be substantially less than the initial sticking probability for forming the deposited material onto the first layer surface, such that the patterning coating may be substantially devoid of a closed coating of the deposited material.

In some non-limiting examples, the interface portion may correspond to a first portion of the lateral aspect and the non-interface portion may correspond to a second portion of the lateral aspect where the deposited material forms a closed coating.

In some non-limiting examples, the quantity of deposited material may comprise at least one particle structure comprising a particle material. In some non-limiting examples, the at least one particle structure may form a discontinuous layer between the low(er)-index layer and the higher-index layer. In some non-limiting examples, the deposited material may preclude the definition of the index interface in the non-interface portion. In some non-limiting examples, the higher-index layer may cover the deposited material in the non-interface portion.

In some non-limiting examples, the second layer surface and the first layer surface may be the same.

In some non-limiting examples, the low(er)-index layer may extend into the non-interface portion and the second layer surface may be an exposed layer surface of the low(er)-index layer therein.

In some non-limiting examples, the device may be adapted to permit EM radiation to engage a surface thereof along at an optical path in a first direction that is at an angle to a plane defined by a plurality of the lateral axes of the device. In some non-limiting examples, the EM radiation may be emitted by the device, and the first direction may be a direction at which the EM radiation is extracted from the device. In some non-limiting examples, the EM radiation may be incident on an external surface of the device and transmitted at least partially therethrough, and the first direction may be a direction at which the EM radiation is incident on the device.

In some non-limiting examples, the interface portion may comprise a first emissive region for emitting a first EM signal along an optical path in a first direction at which EM radiation is extracted from the device and that is at an angle to a plane defined by a plurality of the lateral axes of the device.

In some non-limiting examples, the device may further comprise a substrate; and at least one semiconducting layer disposed thereon; wherein: the first emissive region comprises a first electrode and a second electrode, the first electrode is disposed between the substrate and the at least one semiconducting layer, the at least one semiconducting layer is disposed between the first electrode and the second electrode, and the low(er)-index layer is disposed between the second electrode and the higher-index layer.

In some non-limiting examples, the device may further comprise a second emissive region in the non-interface portion for emitting a second EM signal along the optical path further comprising a third electrode and a fourth electrode, wherein: the third electrode is disposed between the substrate and the at least one semiconducting layer, the at least one semiconducting layer is disposed between the third electrode and the fourth electrode, the non-interface portion is substantially devoid of the low(er)-index layer, and the fourth electrode is disposed between the third electrode and the higher-index layer.

### DESCRIPTION

### Layered Device

The present disclosure relates generally to layered semiconductor devices, and more specifically, to opto-electronic devices. An opto-electronic device may generally encompass any device that converts electrical signals into photons and vice versa.

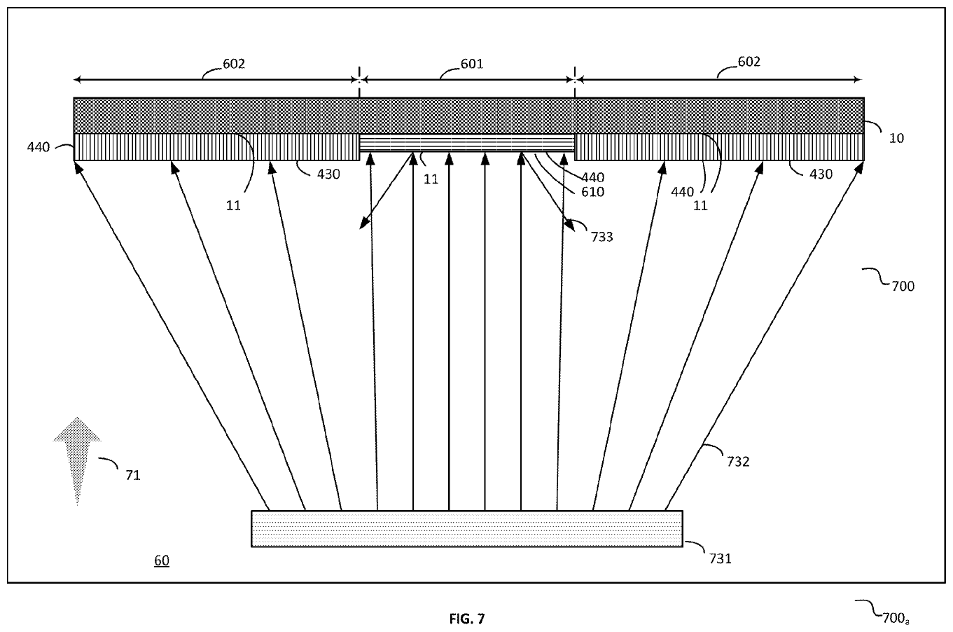

Those having ordinary skill in the relevant art will appreciate that, while the present disclosure is directed to opto-electronic devices, the principles thereof may be applicable to any panel having a plurality of layers, including without limitation, at least one layer of conductive deposited material 731 (FIG. 7), including as a thin film, and in some non-limiting examples, through which electromagnetic (EM) signals may pass, entirely or partially, at an angle relative to a plane of at least one of the layers.

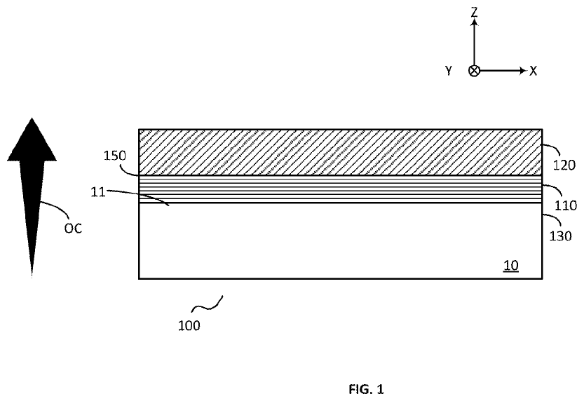

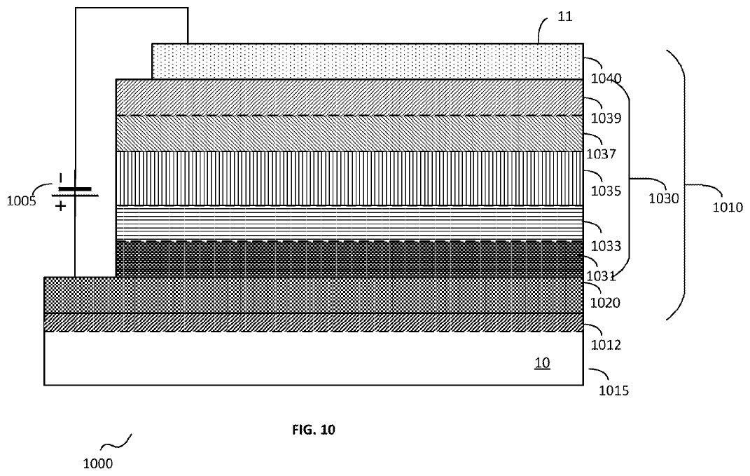

Turning now to FIG. 1, there may be shown a cross-sectional view of an example layered device 100. In some non-limiting examples, as shown in greater detail in FIG. 10, the device 100 may comprise a plurality of layers deposited upon a substrate 10.

A lateral axis, identified as the X-axis, may be shown, together with a longitudinal axis, identified as the Z-axis. A second lateral axis, identified as the Y-axis, may be shown as being substantially transverse to both the X-axis and the Z-axis. At least one of the lateral axes may define a lateral aspect of the device 100. The longitudinal axis may define a transverse aspect of the device 100. Some figures herein may be shown in plan. In such plan view(s), a pair of lateral axes, identified as the X-axis and Y-axis respectively, which in some non-limiting examples may be substantially transverse to one another, are shown. At least one of these lateral axes may define a lateral aspect of the device 100.

The layers of the device 100 may extend in the lateral aspect substantially parallel to a plane defined by the lateral axes. Those having ordinary skill in the relevant art will appreciate that the substantially planar representation shown in FIG. 1 may be, in some non-limiting examples, an abstraction for purposes of illustration. In some non-limiting examples, there may be, across a lateral extent of the device 100, localized substantially planar strata of different thicknesses and dimension, including, in some non-limiting examples, the substantially complete absence of a layer, and/or layer(s) separated by non-planar transition regions (including lateral gaps and even discontinuities).

Thus, while for illustrative purposes, the device 100 may be shown in its cross-sectional aspect as a substantially stratified structure of substantially parallel planar layers, such display panel may illustrate locally, a diverse topography to define features, each of which may substantially exhibit the stratified profile discussed in the cross-sectional aspect.

In some non-limiting examples, the device 100 comprises a first layer 110 and a second layer 120, wherein the first layer 110 is disposed on an exposed layer surface 11 of an underlying layer 130, including without limitation, a substrate 10, of the device 100, and the second layer 120 is disposed on an exposed layer surface 11 of the first layer 110, such that the first layer 110 lies between the underlying layer 130 and the second layer 120.

The exposed layer surface 11 of the first layer 110, upon which the second layer 120 is disposed defines an index interface 150 between the first layer 110 and the second layer 120.

In some non-limiting examples, the first layer 110 comprises a medium that has a low refractive index (low-index material) such that the first layer 110 comprises a low(er)-index layer 110.

In some non-limiting examples, the low(er)-index layer 110, and/or the low-index material, in some non-limiting examples, when deposited as a film, and/or coating in a form, and under similar circumstances to the deposition of the low(er)-index layer 110 within the device 100, may exhibit a first refractive index.

In some non-limiting examples, the first refractive index may be determined and/or measured at a first wavelength range and/or at least one first wavelength thereof. In some non-limiting examples, such first wavelength range may be at least one of between about: 315-400 nm, 450-460 nm, 510-540 nm, 600-640 nm, 456-624 nm, 425-725 nm, 350-450 nm, 300-450 nm, 300-550 nm, 300-700 nm, 380-740 nm, 750-900 nm, 380-900 nm, or 300-900 nm.

In some non-limiting examples, a first maximum refractive index may correspond to a maximum value of the first refractive index measured within such first wavelength range.

In some non-limiting examples, the first refractive index may vary by no more than at least one of about: 0.4, 0.3, 0.2, or 0.1 across such first wavelength range.

In some non-limiting examples, the first refractive index may be no more than at least one of about: 1.7, 1.6, 1.5, 1.45, 1.4, 1.35, 1.3, or 1.25 at such first wavelength range.

In some non-limiting examples, the first refractive index may be at least one of between about: 1.2-1.6, 1.2-1.5, 1.25-1.45, or 1.25-1.4 at such first wavelength range.

In some non-limiting examples, the low(er)-index layer 110, and/or the low-index material, in some non-limiting examples, when deposited as a film, and/or coating in a form, and under similar circumstances to the deposition of the low(er)-index layer 110 within the device 100, may exhibit a first extinction coefficient of no more than at least one of about: 0.1, 0.08, 0.05, 0.03, or 0.01 at such first wavelength range.

In some non-limiting examples, the low(er)-index layer 110, and/or the low-index material, in some non-limiting examples, when deposited as a film, and/or coating in a form, and under similar circumstances to the deposition of the low(er)-index layer 110 within the device 100, may be substantially transparent.

In some non-limiting examples, the low(er)-index layer 110, and/or the low-index material, in some non-limiting examples, when deposited as a film, and/or coating in a form, and under similar circumstances to the deposition of the low(er)-index layer 110 within the device 100, may comprise a substantially porous coating and/or medium that has at least one void formed therewithin. Without wishing to be bound by any particular theory, it may be postulated that the presence of such pores and/or voids may contribute to a reduction in the first refractive index of the low(er)-index layer 110 relative to a layer comprised of a similar medium, but which is substantially devoid of such pores and/or voids. In some non-limiting examples, such substantially porous layer and/or medium may be considered to be at least one of: a microporous layer and/or medium that may contain, by way of non-limiting example, at least one pore and/or void having a diameter that is no more than about 2 nm, a mesoporous layer and/or medium that may contain, by way of non-limiting example, at least one pore and/or void having a diameter of between about 2-50 nm, and a microporous layer and/or medium that may contain, by way of non-limiting example, at least one pore and/or void having a diameter that is at least about 50 nm.

In some non-limiting examples, the low-index material may comprise, and/or be formed by, at least one of an organic compound and an organic-inorganic hybrid material.

In some non-limiting examples, the second layer 120 comprises a medium that has a high refractive index (high-index material) such that the second layer 120 comprises a higher-index layer 120.

In some non-limiting examples, the higher-index layer 120, and/or the high-index material, in some non-limiting examples, when deposited as a film, and/or coating in a form, and under similar circumstances to the deposition of the higher-index layer 120 within the device 100, may exhibit a second refractive index.

In some non-limiting examples, the second refractive index may be determined and/or measured at a second wavelength range and/or at least one second wavelength thereof (second wavelength (range)).

In some non-limiting examples, such second wavelength range may be at least one of between about: 315-400 nm, 450-460 nm, 510-540 nm, 600-640 nm, 456-624 nm, 425-725 nm, 350-450 nm, 300-450 nm, 300-550 nm, 300-700 nm, 380-740 nm, 750-900 nm, 380-900 nm, or 300-900 nm.

In some non-limiting examples, a second maximum refractive index may correspond to a maximum value of the second refractive index measured within such second wavelength range.

In some non-limiting examples, the first maximum refractive index may correspond to a wavelength within the first wavelength range that is different from a wavelength within the second wavelength range to which the second maximum refractive index may correspond.

In some non-limiting examples, the second refractive index may be at least one of at least about: 1.7, 1.8, or 1.9.

The second refractive index in the second wavelength (range) exceeds the first refractive index in the first wavelength (range).

In the present disclosure, the medium of which the low(er)-index layer 110 may be formed may be considered a low-index material provided that it has a first refractive index that is exceeded by the second refractive index of the medium of which the higher-index layer 120 may be formed (high-index material), even if the first refractive index of the medium of which the low(er)-index layer 110 may be formed may not necessarily be considered to be low in comparison with the refractive index of other material(s) that may be employed in a typical opto-electronic device.

In some non-limiting examples, the second wavelength (range) may be the same and/or different from the first wavelength (range).

In some non-limiting examples, the second refractive index in the second wavelength (range) may exceed the first refractive index in the first wavelength (range) by at least one of at least about: 0.3, 0.4, 0.5, 0.7, 1.0, 1.2, 1.3, 1.4, or 1.5.

In some non-limiting examples, the second maximum refractive index may exceed the first maximum refractive index by at least one of at least about: 0.5, 0.7, 1.0, 1.2, 1.3, 1.4, 1.5, or 1.7.

In some non-limiting examples, the higher-index layer 120, and/or the high-index material, in some non-limiting examples, when deposited as a film, and/or coating in a form, and under similar circumstances to the deposition of the higher-index layer 120 within the device 100, may exhibit a second extinction coefficient of no more than at least one of about: 0.1, 0.08, 0.05, 0.03, or 0.01 at such second wavelength (range).

Although not shown, in some non-limiting examples, the exposed layer surface 11 of the low(er)-index layer 110 may be provided at the index interface 150, with an air gap, whether during, or subsequent to, manufacture, and/or in operation, where the low(er)-index layer 110 has a first refractive index that may be lower than that of air (which may be considered to have a refractive index that is typically slightly above 1.0) such that the air gap may be considered to be the second layer 120, and indeed, the higher-index layer 120.

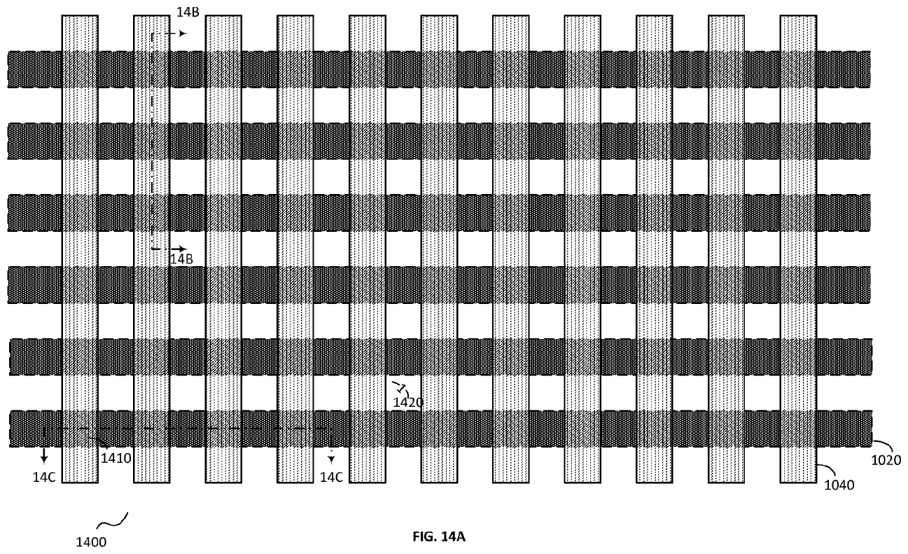

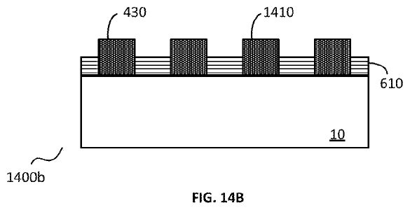

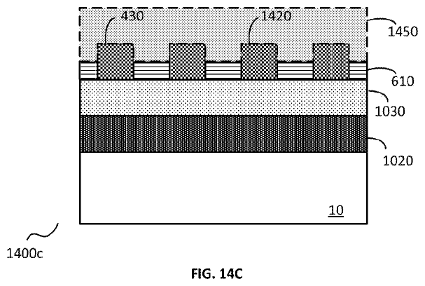

In some non-limiting examples, the second layer 120 is a physical coating, including without limitation, capping layer (CPL) (or other barrier coating or encapsulation layer 1450 (FIG. 14C) such as a TFE layer and/or a polarizing layer) of the device 100.

In some non-limiting examples, the higher-index layer 120, and/or the high-index material, in some non-limiting examples, when deposited as a film, and/or coating in a form, and under similar circumstances to the deposition of the higher-index layer 120 within the device 100, may be substantially transparent.

In some non-limiting examples, the high-index material may comprise, and/or be formed by, an organic compound.

In some non-limiting examples, the device 100 is configured to substantially permit EM radiation to engage a surface of the device 100 along an optical path in at least a first direction indicated by the arrow OC at an angle to a plane of the underlying layer 130 defined by a plurality of the lateral axes. The optical path corresponds to a (first) direction that is at least one of: a direction from which EM radiation, emitted by the device 100, may be extracted therefrom, and a direction at which EM radiation is incident on an exposed layer surface 11 of the device 100, and propagated at least partially therethrough, including without limitation, where the EM radiation is incident on an exposed layer surface of the substrate 10, opposite to that on which the various layers and/or coatings have been deposited, and transmitted at least partially through the substrate 10 and the various layers and/or coatings.

Those having ordinary skill in the relevant art will appreciate that there may be a scenario where EM radiation is both emitted by the device 100 and concomitantly, EM radiation is incident on an exposed layer surface 11 of the device 100 and transmitted at least partially therethrough. In such scenario, the direction of the optical path will, unless the context indicates to the contrary, be determined by the direction from which the EM radiation emitted by the device 100 may be extracted. In some non-limiting examples, the EM radiation transmitted entirely through the device 100 may be propagated in the same or a similar direction. Nevertheless, nothing in the present disclosure should be interpreted as limiting the propagation of EM radiation entirely through the device 100 to a direction that is the same or similar to the direction of propagation of EM radiation emitted by the device 100.

In the present disclosure, the propagation of EM radiation temporally in a given direction, including without limitation, as indicated by the arrow OC, gives rise to a directional convention, in which the low(er)-index layer 110 may be said to be “anterior” to, “ahead of”, and/or “before” the higher-index layer 120 in the ((first) direction of propagation of the EM radiation in the) optical path.

In some non-limiting examples, the device 100 may be a top-emission opto-electronic device in which EM radiation (including without limitation, in the form of light and/or photons) is emitted by the device 100 in at least the first direction.

In some non-limiting examples, the device 100 may comprise at least one light-transmissive region in which EM radiation incident on an exposed layer surface 11 of the substrate 10, opposite to that on which the various layers and/or coatings have been deposited, may be transmitted through the substrate 10 and the various layers and/or coatings in at least the first direction.

Those having ordinary skill in the relevant art will appreciate that the use of a CPL by itself to promote outcoupling of light emitted by an opto-electronic device so as to enhance its external quantum efficiency (EQE) may be well known.

Those having ordinary skill in the relevant art may reasonably expect that inclusion of a low(er)-index layer 110 anterior to the higher-index layer 120 in the optical path, may, in some non-limiting examples, create an index interface 150 between such low(er)-index layer 110 and the higher-index layer 120, that might cause EM radiation to be reflected back therefrom towards the underlying layer 130, resulting in a reduced fraction of EM radiation that may be extracted from such a device 100.

However, it has now been found, somewhat surprisingly, that arranging the low(er)-index layer 110 having a first refractive index that is lower than a second refractive index of the higher-index layer 120, to be anterior to such higher-index layer 120 in the optical path, such that it lies between the underlying layer 130 and the higher-index layer 120, may, in some non-limiting examples, exhibit enhanced outcoupling of EM radiation relative to an equivalent device that lacks such a low(er)-index layer 110 between the underlying layer 130 and the higher-index layer 120 and thus, may increase a fraction of EM radiation that may be extracted from the device 100, at least in some non-limiting examples.

In some non-limiting examples, the underlying layer 130 comprises a medium that has a high refractive index (high-index underlying material) such that the underlying layer 130 comprises a higher-index underlying layer 130.

In some non-limiting examples, the higher-index underlying layer 130, and/or the high-index underlying material, in some non-limiting examples, when deposited as a film, and/or coating in a form, and under similar circumstances to the deposition of the higher-index underlying layer 130 within the device 100, may exhibit a third refractive index.

In some non-limiting examples, the third refractive index may be determined and/or measured at a third wavelength range and/or at least one third wavelength thereof (third wavelength (range)).

In some non-limiting examples, such third wavelength range may be at least one of between about: 315-400 nm, 450-460 nm, 510-540 nm, 600-640 nm, 456-624 nm, 425-725 nm, 350-450 nm, 300-450 nm, 300-550 nm, 300-700 nm, 380-740 nm, 750-900 nm, 380-900 nm, or 300-900 nm.

In some non-limiting examples, a third maximum refractive index may correspond to a maximum value of the third refractive index measured within such third wavelength range.

In some non-limiting examples, the first maximum refractive index may correspond to a wavelength within the first wavelength range that is different from a wavelength within the third wavelength range to which the third maximum refractive index may correspond.

In some non-limiting examples, the third refractive index may be at least one of at least about: 1.7, 1.8, or 1.9.

In some non-limiting examples, the third refractive index in the third wavelength (range) may exceed the first refractive index in the first wavelength (range), such that in some non-limiting examples, the low(er)-index layer 110 may lie between two layers comprising a higher-index material, namely, the higher-index underlying layer 130 and the higher-index layer 120.

By way of non-limiting example, the underlying layer 130 may comprise one of the at least one semiconducting layers 1030 (FIG. 10) of an organic stack of an opto-electronic device, including without limitation, an organic light-emitting diode (OLED). In some non-limiting examples, the underlying layer 130 may comprise one of the top-most semiconducting layers 1030, including without limitation, an electron transport layer (ETL) 1037 and/or an electron injection layer (EIL) 1039. Typically, ETL 1037 and/or EIL 1039 materials tend to have a relatively high refractive index.

Without wishing to be bound by any particular theory, it may be postulated that arranging a thin low(er)-index layer 110 comprising a low-index material having a first refractive index that is lower than a (second) refractive index of the higher-index layer 120 and/or a third refractive index of the underlying layer 130 may enhance transmission of EM radiation passing through the device 100, relative to devices in which no such low(er)-index layer 110 is present.

In some non-limiting examples, an average layer thickness of the low(er)-index layer 110 may be no more than an average layer thickness of the higher-index layer 120.

In some non-limiting examples, an average layer thickness of the low(er)-index layer 110 may be no more than at least one of about: 60 nm, 50 nm, 40 nm, 30 nm, 20 nm, 10 nm, 8 nm, or 5 nm.

Without wishing to be bound by any particular theory, it may be postulated that reducing an average layer thickness of the low(er)-index layer 110, including without limitation, to at least one of between about: 5-20 nm, or 5-15 nm, may, in some non-limiting examples, result in an increased fraction of extraction of EM radiation while mitigating a likelihood of adversely affecting performance of the device 100 and/or a process of manufacturing same, because of the presence, in the device 100, of such low(er)-index layer 110.

Without wishing to be bound by any particular theory, it has now been found, somewhat surprisingly, that materials exhibiting relatively low surface tension, in particular those containing, and/or formed by, an organic material, may, in some non-limiting examples, exhibit a relatively low refractive index. This may be seen in the table below, which sets out a surface tension and a refractive index obtained for various example materials:

TABLE 1
Surface Tension and Refractive index for Various Materials

| | Surface Tension | |
|---|---|---|
| Material | (dynes/cm) | Refractive Index |
| Tetradecafluorohexane | 12.23 | 1.252 |
| Perfluoro(methylcyclohexane) | 15.1 | 1.285 |
| Hexane | 18 | 1.375 |
| Octamethylcyclotetrasiloxane | 18.2 | 1.396 |
| Perfluorodecalin | 19.41 | 1.31 |
| Heptane | 19.5 | 1.3855 |
| Octane | 21 | 1.3951 |
| Nonane | 21.7 | 1.405 |
| Ethanol | 22.39 | 1.361 |
| Decane | 23.2 | 1.411 |
| Undecane | 23.5 | 1.417 |
| Dodecane | 24.2 | 1.421 |
| Tetradecane | 25.1 | 1.429 |
| Acetone | 25.2 | 1.36 |
| Hexadecane | 26 | 1.434 |
| Benzene | 28.88 | 1.501 |
| O-Xylene | 29.3 | 1.505 |
| Carbon Disulfide | 35.3 | 1.628 |
| Methyl salicylate | 38.71 | 1.536 |
| Lepidine | 43.2 | 1.62 |
| 1-Bromonaphthalene | 43.7 | 1.657 |
| Diiodomethane | 50.8 | 1.741 |
| Formamide | 58.3 | 1.449 |
| Glycerol | 63 | 1.4729 |
| Water | 72.8 | 1.333 |

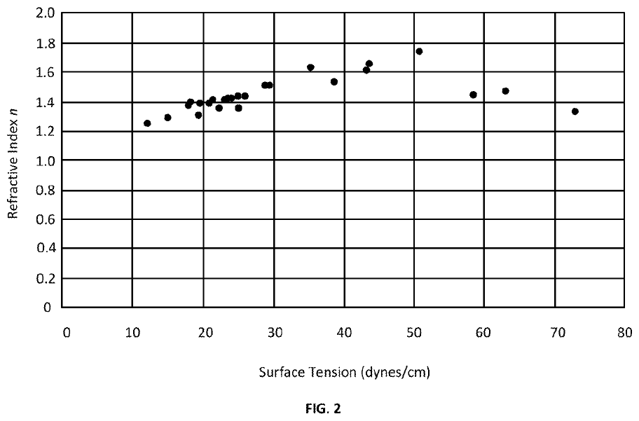

FIG. 2 is a plot of the refractive index as a function of surface tension for the example materials set out in Table 1 above.

Based on the foregoing, it may be postulated that materials that exhibit relatively low surface energy may be suitable to act as a low-index material. In some non-limiting examples, the low(er)-index layer 110 may comprise a low-index material exhibiting a surface energy that is no more than about 25 dynes/cm and a first refractive index that may be no more than about 1.45.

In some non-limiting examples, the low(er)-index layer 110 may comprise a low-index material exhibiting a surface energy that is no more than about 20 dynes/cm and a first refractive index of no more than about 1.4.

As shown in FIG. 1, the device 100 may comprise a substrate 10 on which various coatings and/or layers may be deposited. At some point, the low(er)-index layer 110 may be disposed on the exposed layer surface 11 of the underlying layer 130, in some non-limiting examples, across at least a part of the lateral aspect thereof. The higher-index layer 120 may be deposited on the exposed layer surface 11 of the device 100, including over the low(er)-index layer 110 to define the index interface 150 therewith.

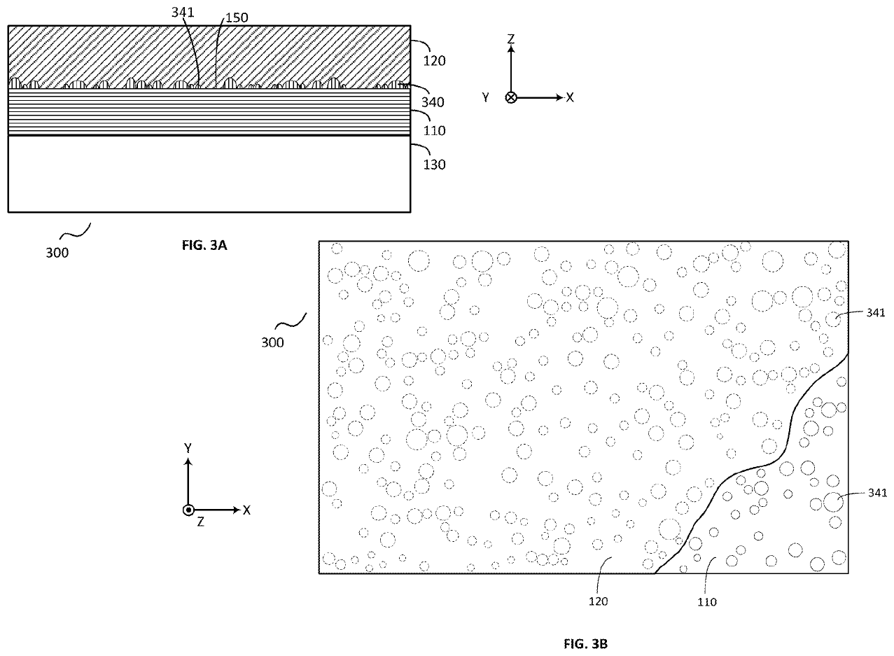

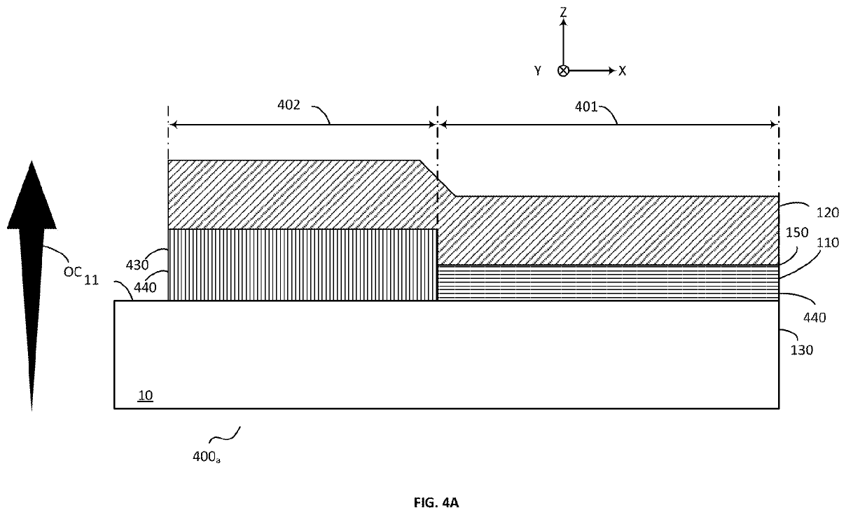

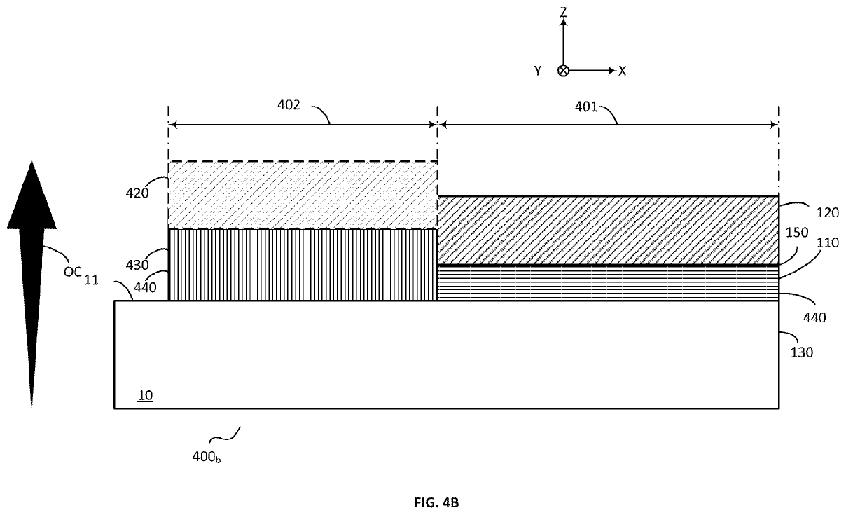

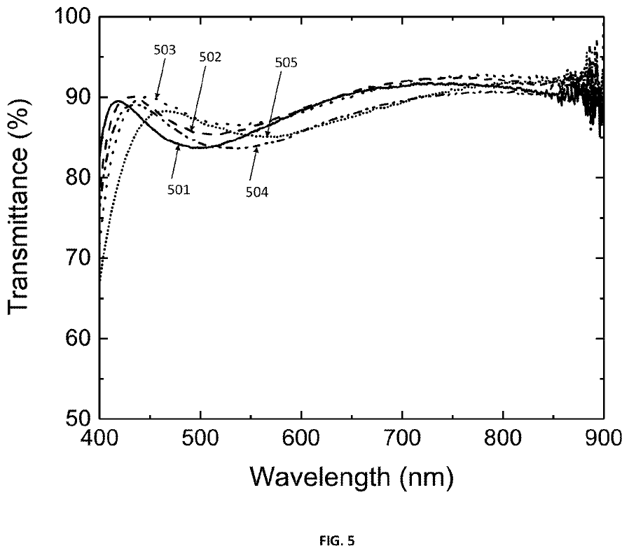

Turning now to FIG. 3A, there is shown a cross-sectional view of a version 300 of the device 100 according to some non-limiting examples, in which a quantity of deposited material 731 (FIG. 7) is deposited on the device 300. In some non-limiting examples, as shown, the deposited material 731 is disposed on an exposed layer surface 11 of the low(er)-index layer 110. In some non-limiting examples, the deposited material 731 is formed as a discontinuous layer 340 that may comprise a plurality of particle structures 341 comprising a particle material. In some non-limiting examples, including without limitation, when the low(er)-index layer 110 functions, as discussed herein, as a patterning coating 610 (FIG. 6) deposited in a first portion 601 (FIG. 6) for selective deposition of a deposited layer 430 (FIG. 4A) in a second portion 602 (FIG. 6) in an open mask and/or mask-free deposition process, such particle structures 341 may be formed by impingement of vapor monomers or a vapor flux 732 (FIG. 7) of the deposited material 731 on an exposed layer surface 11 of the low(er)-index layer 110, which may condense to form the at least one particle structure 341. While, if left unimpeded, further exposure of the discontinuous layer 340 of the at least one particle structure 341 to vapor monomers 732 of the deposited material 731 may potentially lead to eventual formation of a substantially closed coating 440 (FIG. 4A) of the deposited material 731, such growth may continue to be inhibited due to at least one property and/or feature of the low(er)-index layer 110, including without limitation, a low initial sticking probability against deposition of the deposited material 731.

In some non-limiting examples, the higher-index layer 120 may be disposed over the portion(s) of the exposed layer surface 11 of the low(er)-index layer 110 that are not covered by any deposited material 731 to define the index layer 150.

In some non-limiting examples, the higher-index layer 120 may also be disposed over and coat the deposited material 731. Even so, those having ordinary skill in the relevant art will appreciate that in such scenario, the presence of the quantity of deposited material 731, including without limitation, as at least one particle structure 341, between the low(er)-index layer 110 and the higher-index layer 120, may cause the index interface 150 between the low(er)-index layer 110 and the higher-index layer 120 to be (at least locally) disrupted, such that it may be said, in those lateral aspects where such deposited material 731 is situated, that no such index interface 150 exists is formed, and/or is defined.

Thus, a portion of the lateral aspect of the device 300 where there exists an index interface 150 between the low(er)-index layer 110 and the higher-index layer 120 may be denoted as an interface portion 401, while a portion where there is no such index interface 150 because of the (intervening) presence of deposited material 731, whether as a local disruption in the form of at least one particle structure 341, or as a deposited layer 430 forming a closed coating 440 of the deposited material 731, may be denoted as a non-interface portion 402.

Those having ordinary skill in the relevant art will appreciate that typically, a material with a low surface energy may exhibit low intermolecular forces and that such a material may readily crystallize and/or undergo other phase transformation at a lower temperature relative to a material with high intermolecular forces. In at least some applications, a material that readily crystallizes and/or undergoes other phase transformations at relatively low temperatures may, in some non-limiting examples, reduce at least one of a long-term performance, stability, reliability and/or lifetime of a device incorporating such material.

In some non-limiting examples, including without limitation, where the higher-index layer 120 comprises an air gap, the presence of a quantity of deposited material 731, including without limitation, in the form of a discontinuous layer 340, including without limitation, of at least one particle structure 341 may reduce and/or mitigate crystallization of thin film layers, and/or coatings disposed adjacent thereto in the longitudinal aspect, including without limitation, the low(er)-index layer 110 in the surrounding interface portion(s) 401 where there are no such particle structures 341, thereby stabilizing a property of the thin film layers, and/or coatings disposed adjacent thereto, including without limitation, reducing scattering.

FIG. 3B shows the device 300 in a partially cut-away plan view.

As discussed in greater detail herein, under the heading “Particle”, it has been previously reported that, in some non-limiting examples, certain metal nanoparticles (NPs) may absorb and/or scatter EM radiation, including without limitation, photons, in a wavelength range of the EM spectrum, including the visible spectrum or a sub-range thereof. Such optical characteristics may affect, without limitation, at least one of: an absorption spectrum, a refractive index, and/or an extinction spectrum of the EM radiation. In some non-limiting examples, the impact of such metal NPs on such optical characteristics, may to some extent be tuned by varying a number of physical properties of the NPs, including without limitation, a characteristic size, size distribution, shape, surface coverage, configuration, deposited density, dispersity, size, degree of aggregation, and/or property of the media in the vicinity of the NPs. By way of non-limiting example, it has been reported that arranging certain metal NPs proximate to a medium that has a relatively low refractive index, may give rise to blue-shifting of the absorption spectrum of the NPs.

Without wishing to be bound by any particular theory, it may be postulated that a discontinuous layer 340 of such particle structures 341 in the non-interface portion 402 may resemble, if not actually form, such metal NPs, such that such optical characteristics may be controllably tuned, including without limitation, shifting an absorption spectrum, by introducing such discontinuous layer 340 of at least one particle structure 341 on an exposed layer surface 11 of the low(er)-index layer 110, as shown, such that it does not substantially overlap with a wavelength range of EM radiation being emitted by, and/or transmitted through, the device 300.

In some non-limiting examples, a peak absorption wavelength of the discontinuous layer 340 may be no more than a peak wavelength of the EM radiation being emitted by, and/or transmitted through, the device 300. In some non-limiting examples, the discontinuous layer 340 may exhibit a peak absorption at a wavelength that is no more than at least one of about: 470 nm, 460 nm, 455 nm, 450 nm, 445 nm, 440 nm, 430 nm, 420 nm, or 400 nm.

In some non-limiting examples, the at least one particle structure may have a characteristic size that is no more than about 200 nm. In some non-limiting examples, the at least one particle structure 340 may have a characteristic size of at least one of between about: 1-200 nm, 1-160 nm, 1-100 nm, 1-50 nm, or 1-30 nm.

In some non-limiting examples, the higher-index layer 120 may substantially coat the exposed layer surface 11 of the deposited material 731 in the non-interface portion 402 and also coats part(s) of the exposed layer surface 11 of the low(er)-index layer 110 in the interface portion 401, including without limitation, where uncovered by gaps between the at least one particle structures 341 of the deposited material 731 that define the non-interface portion(s) 402 of the device 300.

Turning now to FIG. 4A, there is shown a simplified block diagram from a cross-sectional aspect of an example version 400a of the device 100. In some non-limiting examples, a lateral aspect of an exposed layer surface 11 of the device 400a may comprise an interface portion 401 and a non-interface portion 402. In some non-limiting examples, the interface portion 401 may comprise that part of the exposed layer surface 11 of the underlying layer 130 of the device 300 that lies beyond the non-interface portion 402.

The low(er)-index layer 110 may be deposited on an exposed layer surface 11 of the underlying layer 130 in the interface portion 401.

In some non-limiting examples, in the interface portion 401, the low(er)-index layer 110 comprising a low-index material, may be selectively deposited as a closed coating 440 on the exposed layer surface 11 of an underlying layer 130, including without limitation, a substrate 10, of the device 400.

A quantity of deposited material 731, in some non-limiting examples, as a closed coating 440 of a deposited layer 430, may be deposited on an exposed layer surface 11 of an underlying layer 130, including without limitation, a substrate 10, of the device 400, only in the non-interface portion 402.

In some non-limiting examples, the low(er)-index layer 110 may be deposited at least in the interface portion 401 prior to the deposition of the deposited material 731 in the non-interface portion 402. Indeed, in some non-limiting examples, the low(er)-index layer 110 may also be deposited in the second portion 602 such that the low(er)-index layer 110 may be the underlying layer 130 in the non-interface portion 402 upon which the deposited material 731 may be deposited.

In some non-limiting examples, the low(er)-index layer 110 may be, act as, and/or comprise a patterning coating 610, comprising a patterning material 611 (FIG. 6) to substantially inhibit deposition of the deposited material 731 thereon as discussed herein. In some non-limiting examples, in the non-interface portion 402, a deposited layer 430, comprising a quantity of deposited material 731, may be disposed (in some non-limiting examples, in an open mask and/or mask-free deposition process, by using the low(er)-index layer 110 as a patterning coating 610) as a closed coating 440 on an exposed layer surface 11 of an underlying layer 130, including without limitation, the substrate 10. In some non-limiting examples, the exposed layer surface 11 of such underlying layer 130 may be substantially devoid of a closed coating 440 of the low-index material.

In some non-limiting examples, it may be postulated that materials that exhibit relatively low surface energy may be suitable to act as such a patterning material 611.

In some non-limiting examples, the higher-index layer 120 may be deposited on the exposed layer surface 11 of the device 400, so as to form the index interface 150 with the low(er)-index layer 110 in the interface portion 401, while being deposited on an exposed layer surface 11 of the deposited material 731 in the non-interface portion 402, including without limitation, as a closed coating of the deposited layer 430, and/or as a discontinuous layer 340 of at least one particle structure 341.

In some non-limiting examples, such as is shown in FIG. 4B, the higher-index layer 120 may be disposed substantially only in the interface portion 401, on the exposed layer surface 11 of the low(er)-index layer 110. In some non-limiting examples, another CPL 420 may be disposed to coat the exposed layer surface 11 of the deposited material 731 in the non-interface portion 402, especially if the deposited material 731 is formed as a deposited layer 430 in a closed coating 440. In some non-limiting examples, such other CPL 420 may exhibit at least one property that differs from the properties of the higher-index layer 120, including without limitation, the refractive index exhibited thereby.

A series of samples were fabricated by depositing, in vacuo, an approximately 50 nm thick layer of various example materials over respective glass substrates. The refractive index, and the extinction coefficient, of the coating formed by each example material was determined using an ellipsometer. The refractive index and extinction coefficient for each example material, determined at a wavelength of 578 nm, is summarized in Table 2 below:

TABLE 2

| Material | Refractive index | Extinction coefficient |
|---|---|---|
| Liq | 1.633 | 0 |
| Comparative Material A | 1.774 | 0 |
| Example Material A | 1.299 | 0 |
| Example Material B | 1.290 | 0 |

In Table 2, Comparative Material A is included as a comparative example of an organic material that may be used as the high-index material.

Example Material A and Example Material B are non-limiting examples of low-index media that each exhibit optical properties of the low(er)-index layer 110, including without limitation, a refractive index of no more than about 1.3 and substantially no more than that of a high-index material, such as Comparative Example A, and an extinction coefficient of about 0 at a wavelength range in the visible spectrum.

Liq is included as a comparative example of an organic material used in some known OLED structures, that exhibits a relatively high refractive index relative to those of Example Material A and Example Material B.

### Example 2

A series of samples were fabricated by depositing at least one semiconducting layer 1030 as an example stack on a glass substrate, in vacuo, and depositing thereon, in vacuo, in sequence, at least one of a low(er)-index layer 110 and a higher-index layer 120.

The example stack in each sample was formed by depositing, in sequence, various semiconducting layers 1030 typically present in an opto-electronic device including without limitation, an OLED. Specifically, in Example 2, the stack in each sample was formed by HIL/HTL/EBL/HBL/ETL/EIL layers, so as to mimic a non-limiting example of a frontplane layer 1010 of an OLED device 1000.

Table 3 summarizes the layers and/or coatings and/or their associated average layer thickness in the longitudinal aspect deposited on the example stack, in each sample:

TABLE 3

| Sample | Sample Configuration |
|---|---|
| Comparative Sample 1 | Organic Stack/CPL (50 nm) |
| Example Sample 1 | Organic Stack/Low-Index |
| | Coating (5 nm)/CPL (50 nm) |
| Example Sample 2 | Organic Stack/Low-Index |
| | Coating (15 nm)/CPL 50 nm) |
| Comparative Sample 2 | Organic Stack/CPL (65 nm) |
| Example Sample 3 | Organic Stack/Low-Index |
| | Coating (15 nm)/CPL (65 nm) |

As set out in Table 3, Example Samples 1, 2, and 3 were fabricated to have both a low(er)-index layer 110 and a higher-index layer 120, albeit of varying average layer thicknesses, while Comparative Samples 1 and 2 were fabricated such that the average layer thickness of the higher-index layer 120 was comparable to Example Samples 1 and 3 respectively. However, in both Comparative Samples, the low(er)-index layer 110 was omitted.

In each sample, the low(er)-index layer 110 was formed of Example Material A, and the higher-index layer 120 was formed of Comparative Material A.

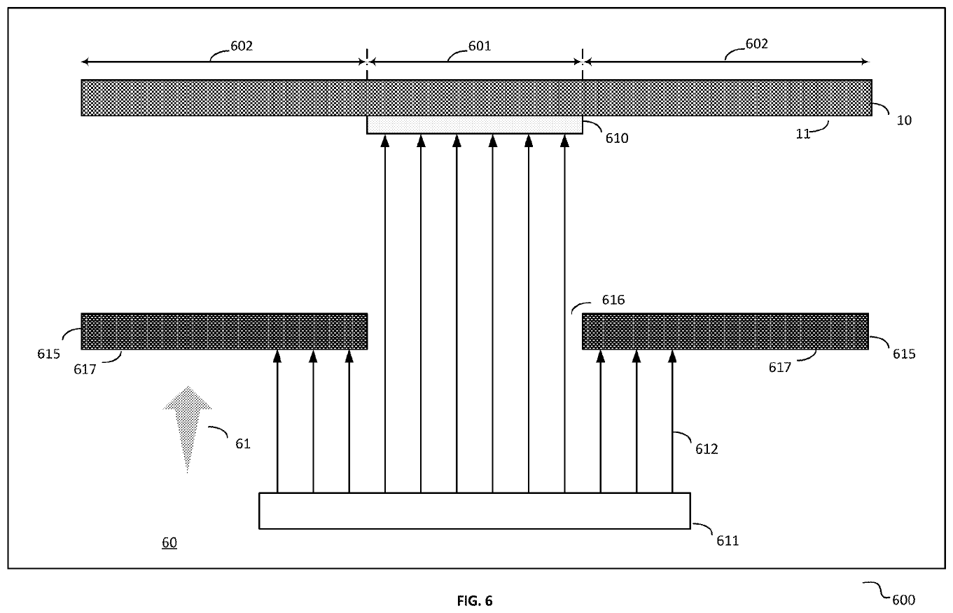

FIG. 5 is a plot of transmittance as a function of wavelength for measured data points using the example samples of Example 2. The transmittance for each sample was determined by measuring a fraction of EM radiation transmitted entirely through each sample upon directing light from an external source toward the sample.

As may be seen from FIG. 5, it was found, somewhat surprisingly, that the transmittance measured for Comparative Sample 1 was generally lower across the visible spectrum relative to the transmittance 502 measured for Example Sample 1. By way of non-limiting example, the transmittance 502 measured for Example Sample 1 may be substantially higher than the transmittance 501 measured for Comparative Sample 1, at wavelengths between about 450-600 nm.

It was also found, somewhat surprisingly, that the transmittance 503 measured for Example Sample 2 may, at least at some wavelengths, exceed the transmittance 502 measured for Example Sample 1, even though an average layer thickness of the low(er)-index layer 110 of Example Sample 2 is substantially thicker than that of Example Sample 1.

Further, by comparing the transmittance 504 measured for Comparative Sample 2 to the transmittance 505 measured for Example Sample 3, it may be observed that the presence of the low(er)-index layer 110 results in a transmittance across the visible spectrum that is at least as much as the transmittance of a comparable sample that is devoid of such low(er)-index layer 110. By way of non-limiting example, the transmittance 505 measured for Example Sample 3 may be substantially higher than the transmittance measured for Comparative Sample 2, at wavelengths between about 450-600 nm.

### Patterning Coating

In some non-limiting examples, a patterning coating 610, including without limitation, in some non-limiting examples, the low(er)-index layer 110, may be deposited in a first portion 601 of the lateral aspect of the device 400. In some non-limiting examples, the patterning coating 610 may comprise a patterning material 611. In some non-limiting examples, the patterning coating 610 may comprise a closed coating 440 of the patterning material 611.

The patterning coating 610 may provide an exposed layer surface 11 with a relatively low initial sticking probability (in some non-limiting examples, under the conditions identified in the dual QCM technique described by Walker et al.) against the deposition of deposited material 731, which, in some non-limiting examples, may be substantially no more than the initial sticking probability against the deposition of the deposited material 731 of the exposed layer surface 11 of the underlying layer 130 of the device 400, upon which the patterning coating 610 has been deposited.

Because of the low initial sticking probability of the patterning coating 610, and/or the patterning material 611, in some non-limiting examples, when deposited as a film, and/or coating in a form, and under similar circumstances to the deposition of the patterning coating 610 within the device 400, against the deposition of the deposited material 731, the first portion 601 comprising the patterning coating 610 may be substantially devoid of a closed coating 440 of the deposited material 731.

In some non-limiting examples, the patterning coating 610, and/or the patterning material 611, in some non-limiting examples, when deposited as a film, and/or coating in a form, and under similar circumstances to the deposition of the patterning coating 610 within the device 400, may have an initial sticking probability against the deposition of the deposited material 731, that is no more than at least one of about: 0.9, 0.3, 0.2, 0.15, 0.1, 0.08, 0.05, 0.03, 0.02, 0.01, 0.008, 0.005, 0.003, 0.001, 0.0008, 0.0005, 0.0003, or 0.0001.

In some non-limiting examples, the patterning coating 610, and/or the patterning material 611, in some non-limiting examples, when deposited as a film, and/or coating in a form, and under similar circumstances to the deposition of the patterning coating 610 within the device 400, may have an initial sticking probability against the deposition of silver (Ag), and/or magnesium (Mg) that is no more than at least one of about: 0.9, 0.3, 0.2, 0.15, 0.1, 0.08, 0.05, 0.03, 0.02, 0.01, 0.008, 0.005, 0.003, 0.001, 0.0008, 0.0005, 0.0003, or 0.0001.

In some non-limiting examples, the patterning coating 610, and/or the patterning material 611, in some non-limiting examples, when deposited as a film, and/or coating in a form, and under similar circumstances to the deposition of the patterning coating 610 within the device 400, may have an initial sticking probability against the deposition of a deposited material 731 of at least one of between about: 0.15-0.0001, 0.1-0.0003, 0.08-0.0005, 0.08-0.0008, 0.05-0.001, 0.03-0.0001, 0.03-0.0003, 0.03-0.0005, 0.03-0.0008, 0.03-0.001, 0.03-0.005, 0.03-0.008, 0.03-0.01, 0.02-0.0001, 0.02-0.0003, 0.02-0.0005, 0.02-0.0008, 0.02-0.001, 0.02-0.005, 0.02-0.008, 0.02-0.01, 0.01-0.0001, 0.01-0.0003, 0.01-0.0005, 0.01-0.0008, 0.01-0.001, 0.01-0.005, 0.01-0.008, 0.008-0.0001, 0.008-0.0003, 0.008-0.0005, 0.008-0.0008, 0.008-0.001, 0.008-0.005, 0.005-0.0001, 0.005-0.0003, 0.005-0.0005, 0.005-0.0008, or 0.005-0.001.

In some non-limiting examples, the patterning coating 610, and/or the patterning material 611, in some non-limiting examples, when deposited as a film, and/or coating in a form, and under similar circumstances to the deposition of the patterning coating 610 within the device 400, may have an initial sticking probability against the deposition of a plurality of deposited materials 731 that is no more than a threshold value. In some non-limiting examples, such threshold value may be at least one of about: 0.3, 0.2, 0.18, 0.15, 0.13, 0.1, 0.08, 0.05, 0.03, 0.02, 0.01, 0.008, 0.005, 0.003, or 0.001.

In some non-limiting examples, the patterning coating 610, and/or the patterning material 611, in some non-limiting examples, when deposited as a film, and/or coating in a form, and under similar circumstances to the deposition of the patterning coating 610 within the device 400, may have an initial sticking probability that is no more than such threshold value against the deposition of a plurality of deposited materials 731 selected from at least one of: Ag, Mg, ytterbium (Yb), cadmium (Cd), and zinc (Zn). In some further non-limiting examples, the patterning coating 610 may exhibit an initial sticking probability of or below such threshold value against the deposition of a plurality of deposited materials 731 selected from at least one of: Ag, Mg, and Yb.

In some non-limiting examples, the patterning coating 610, and/or the patterning material 611, in some non-limiting examples, when deposited as a film, and/or coating in a form, and under similar circumstances to the deposition of the patterning coating 610 within the device 400, may exhibit an initial sticking probability against the deposition of a first deposited material 731 of, or below, a first threshold value, and an initial sticking probability against the deposition of a second deposited material 731 of, or below, a second threshold value. In some non-limiting examples, the first deposited material 731 may be Ag, and the second deposited material 731 may be Mg. In some other non-limiting examples, the first deposited material 731 may be Ag, and the second deposited material 731 may be Yb. In some other non-limiting examples, the first deposited material 731 may be Yb, and the second deposited material 731 may be Mg. In some non-limiting examples, the first threshold value may exceed the second threshold value.

In some non-limiting examples, the patterning coating 610, and/or the patterning material 611, in some non-limiting examples, when deposited as a film, and/or coating in a form, and under circumstances similar to the deposition of the patterning coating 610 within the device 400 may have a transmittance for EM radiation of at least a threshold transmittance value, after being subjected to a vapor flux 732 of the deposited material 731, including without limitation, Ag.

In some non-limiting examples, such transmittance may be measured after exposing the exposed layer surface 11 of the patterning coating 610 and/or the patterning material 611, formed as a thin film, to a vapor flux 732 of the deposited material 731, including without limitation, Ag under typical conditions that may be used for depositing an electrode of an opto-electronic device, which by way of non-limiting example, may be a cathode of an OLED device.

In some non-limiting examples, the conditions for subjecting the exposed layer surface 11 to the vapor flux 732 of the deposited material 731, including without limitation, Ag, may be as follows: (i) vacuum pressure of about 10⁻⁴ Torr or 10⁻⁵ Torr; (ii) the vapor flux 732 of the deposited material 731, including without limitation, Ag being substantially consistent with a reference deposition rate of about 1 angstrom (A)/sec, which by way of non-limiting example, may be monitored and/or measured using a QCM; and (iii) the exposed layer surface 11 being subjected to the vapor flux 732 of the deposited material 731, including without limitation, Ag until a reference average layer thickness of about 15 nm is reached, and upon such reference average layer thickness being attained, the exposed layer surface 11 not being further subjected to the vapor flux 732 of the deposited material 731, including without limitation, Ag.

In some non-limiting examples, the exposed layer surface 11 being subjected to the vapor flux 732 of the deposited material 731, including without limitation, Ag may be substantially at room temperature (e.g. about 25° C.). In some non-limiting examples, the exposed layer surface 11 being subjected to the vapor flux 732 of the deposited material 731, including without limitation, Ag may be positioned about 65 cm away from an evaporation source by which the deposited material 731, including without limitation, Ag, is evaporated.

In some non-limiting examples, the threshold transmittance value may be measured at a wavelength in the visible spectrum. By way of non-limiting examples, the threshold transmittance value may be measured at a wavelength of about 460 nm. In some non-limiting examples, the threshold transmittance value may be expressed as a percentage of incident EM power that may be transmitted through a sample. In some non-limiting examples, the threshold transmittance value may be at least one of at least about: 60%, 65%, 70%, 75%, 80%, 85%, or 90%.

In some non-limiting examples, there may be a positive correlation between the initial sticking probability of the patterning coating 610, and/or the patterning material 611, in some non-limiting examples, when deposited as a film, and/or coating in a form, and under circumstances similar to the deposition of the patterning coating 610 within the device 400, against the deposition of the deposited material 731 and an average layer thickness of the deposited material 731 thereon.

It would be appreciated by a person having ordinary skill in the relevant art that high transmittance may generally indicate an absence of a closed coating 440 of the deposited material 731, which by way of non-limiting example, may be Ag. On the other hand, low transmittance may generally indicate presence of a closed coating 440 of the deposited material 731, including without limitation, Ag, Mg, and/or Yb, since metallic thin films, particularly when formed as a closed coating 400, may exhibit a high degree of absorption of EM radiation.

It may be further postulated that exposed layer surfaces 11 exhibiting low initial sticking probability with respect to the deposited material 731, including without limitation, Ag, Mg, and/or Yb, may exhibit high transmittance. On the other hand, exposed layer surfaces 11 exhibiting high sticking probability with respect to the deposited material 731, including without limitation, Ag, Mg, and/or Yb, may exhibit low transmittance.

A series of samples was fabricated to measure the transmittance of a example material, as well as to visually observe whether or not a closed coating 440 of Ag was formed on the exposed layer surface 11 of such example material. Each sample was prepared by depositing, on a glass substrate, an approximately 50 nm thick coating of an example material, then subjecting the exposed layer surface 11 of the coating to a vapor flux of Ag at a rate of about 1 Å/sec until a reference layer thickness of about 15 nm was reached. Each sample was then visually analyzed and the transmittance through each sample was measured.

The molecular structures of the example materials used in the samples herein are set out below:

TABLE 4

| Material | Molecular Structure/Name |
|---|---|
| HT211 | 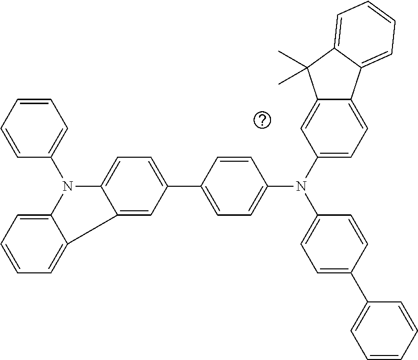 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21] |
| HT01 | 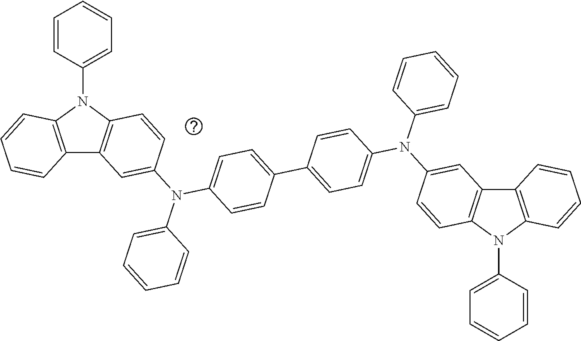 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1] |
| TAZ | 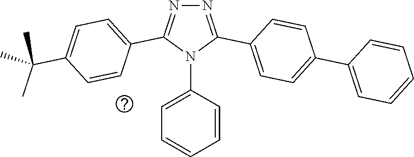 |
| BAlq | 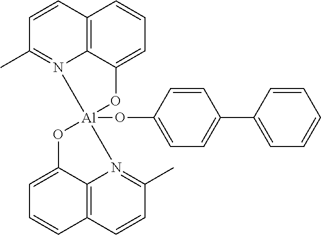 |
| Liq | 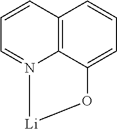 |
| Example Material 1 | 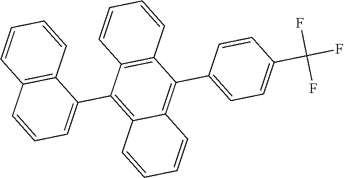 [SMILES: FC(F)(F)c1ccc(-c2c3ccccc3c(-c3cccc4ccccc34)c3ccccc23)cc1] |
| Example Material 2 | 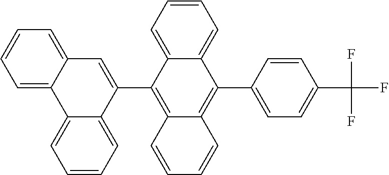 [SMILES: FC(F)(F)c1ccc(-c2c3ccccc3c(-c3cc4ccccc4c4ccccc34)c3ccccc23)cc1] |
| Example Material 3 | 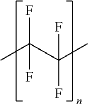 |
| Example Material 4 | 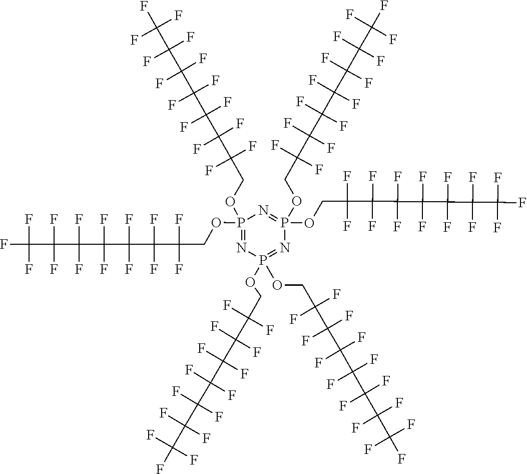 |
| Example Material 5 | 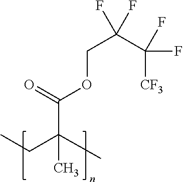 |
| Example Material 6 | 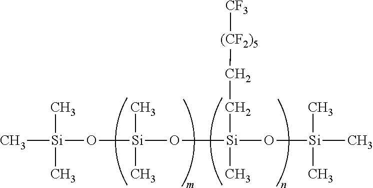 |
| Example Material 7 | 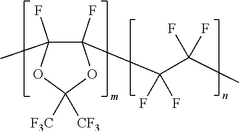 |
| Example Material 8 | 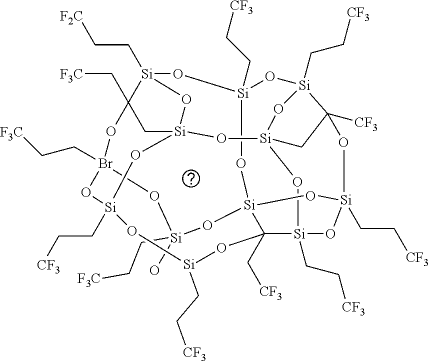 |
| Example Material 9 | 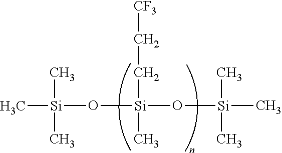 |

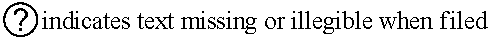

The samples in which a substantially closed coating 440 of Ag had formed were visually identified, and the presence of such coating in these samples was further confirmed by measurement of transmittance therethrough, which showed transmittance of no more than about 50% at a wavelength of about 460 nm.

The samples in which no closed coating 440 of Ag had formed were also identified, and the absence of such coating in these samples was further confirmed by measurement of transmittance therethrough, which showed transmittance in excess of about 70% at a wavelength of about 460 nm.

The results are summarized below:

TABLE 5

| Material | Closed Coating of Ag? |
|---|---|
| HT211 | Present |
| HT01 | Present |
| TAZ | Present |
| Balq | Present |
| Liq | Present |
| Example Material 1 | Present |
| Example Material 2 | Present |
| Example Material 3 | Not Present |
| Example Material 4 | Not Present |
| Example Material 5 | Not Present |
| Example Material 6 | Not Present |
| Example Material 7 | Not Present |
| Example Material 8 | Not Present |
| Example Material 9 | Not Present |

Based on the foregoing, it was found that the materials used in the first 7 samples in Tables 4 and 5 (HT211 to Example Material 2) may be less suitable for inhibiting the deposition of the deposited material 731 thereon, including without limitation, Ag, and/or Ag-containing materials.

On the other hand, it was found that Example Material 3 to Example Material 9 may be suitable, at least in some non-limiting applications, to act as a patterning coating 610 for inhibiting the deposition of the deposited material 731 thereon, including without limitation, Ag, and/or Ag-containing materials.

In some non-limiting examples, the patterning coating 610, and/or the patterning material 611, in some non-limiting examples, when deposited as a film, and/or coating in a form, and under circumstances similar to the deposition of the patterning coating within the device 400, may have a surface energy of no more than at least one of about: 24 dynes/cm, 22 dynes/cm, 20 dynes/cm, 18 dynes/cm, 16 dynes/cm, 15 dynes/cm, 13 dynes/cm, 12 dynes/cm, or 11 dynes/cm.

In some non-limiting examples, the surface energy may be at least one of at least about: 6 dynes/cm, 7 dynes/cm, or 8 dynes/cm.

In some non-limiting examples, the surface energy may be at least one of between about: 10-20 dynes/cm, or 13-19 dynes/cm.

In some non-limiting examples, the critical surface tension of a surface may be determined according to the Zisman method, as further detailed in W. A. Zisman, Advances in Chemistry 43 (1964), pp. 1-51.

By way of non-limiting example, a series of samples was fabricated to measure the critical surface tension of the surfaces formed by the various materials. The results of the measurement are summarized below:

TABLE 6

| Material | Critical Surface Tension (dynes/cm) |
|---|---|
| HT211 | 25.6 |
| HT01 | >24 |
| TAZ | 22.4 |
| BAlq | 25.9 |
| Liq | 24 |
| Example Material 1 | 26.3 |
| Example Material 2 | 24.8 |
| Example Material 3 | 19 |
| Example Material 4 | 7.6 |
| Example Material 5 | 15.9 |
| Example Material 6 | <20 |
| Example Material 7 | 13.1 |
| Example Material 8 | 20 |
| Example Material 9 | 18.9 |

Based on the foregoing measurement of the critical surface tension and the previous observation regarding the presence of absence of a substantially closed coating 440 of Ag, it was found that materials that form low surface energy surfaces when deposited as a coating, which by way of non-limiting examples, may be those having a critical surface tension of at least one of between about: 13-20 dynes/cm, or 13-19 dynes/cm, may be suitable for forming the patterning coating 610 to inhibit deposition of a deposited material 731 thereon, including without limitation, Ag, and/or Ag-containing materials.

Without wishing to be bound by any particular theory, it may be postulated that materials that form a surface having a surface energy lower than, by way of non-limiting example, about 13 dynes/cm, may be less suitable as a patterning material 611 in certain application, as such materials may exhibit relatively poor adhesion to layer(s) surrounding such materials, exhibit a low melting point, and/or exhibit a low sublimation temperature.

In some non-limiting examples, the patterning coating 610, and/or the patterning material 611, in some non-limiting examples, when deposited as a film, and/or coating in a form, and under circumstances similar to the deposition of the patterning coating 610 within the device 400, may have a low refractive index.

In some non-limiting examples, the patterning coating 610, and/or the patterning material 611, in some non-limiting examples, when deposited as a film, and/or coating in a form, and under circumstances similar to the deposition of the patterning coating 610 within the device 400, may have a refractive index for EM radiation at a wavelength of 550 nm that may be no more than at least one of about: 1.55, 1.5, 1.45, 1.43, 1.4, 1.39, 1.37, 1.35, 1.32, or 1.3.

Without wishing to be bound by any particular theory, it has been observed that providing the patterning coating 610 having a low refractive index may, at least in some device 400, enhance transmission of external EM radiation through the second portion 602 thereof. By way of non-limiting example, devices 400 including an air gap therein, which may be arranged near or adjacent to the patterning coating 610, may exhibit a higher transmittance when the patterning coating 610 has a low refractive index relative to a similarly configured device in which such low-index patterning coating 610 was not provided.

By way of non-limiting example, a series of samples was fabricated to measure the refractive index at a wavelength of 550 nm for the coatings formed by some of the various example materials. The results of the measurement are summarized below:

TABLE 7

| Material | Refractive Index |
|---|---|
| HT211 | 1.76 |
| HT01 | 1.80 |
| TAZ | 1.69 |
| BAlq | 1.69 |
| Liq | 1.64 |
| Example Material 2 | 1.72 |
| Example Material 3 | 1.37 |
| Example Material 5 | 1.38 |
| Example Material 7 | 1.3 |

Based on the foregoing measurement of refractive index in Table 7, and the previous observation regarding the presence or absence of a substantially closed coating 440 of Ag, it was found that materials that form a low refractive index coating, which by way of non-limiting example, may be those having a refractive index of no more than at least one of about: 1.4 or 1.38, may be suitable for forming the patterning coating 610 to inhibit deposition of a deposited material 731 thereon, including without limitation, Ag, and/or an Ag-containing materials.

In some non-limiting examples, the patterning coating 610, and/or the patterning material 611, in some non-limiting examples, when deposited as a film, and/or coating in a form, and under circumstances similar to the deposition of the patterning coating 610 within the device 400, may have an extinction coefficient that may be no more than about 0.01 for photons at a wavelength that is at least one of at least about: 600 nm, 500 nm, 460 nm, 420 nm, or 410 nm.

In some non-limiting examples, the patterning coating 610, and/or the patterning coating material 611, in some non-limiting examples, when deposited as a film, and/or coating in a form, and under circumstances similar to the deposition of the patterning coating 610 within the device 400, may not substantially attenuate EM radiation passing therethrough, in at least the visible spectrum.

In some non-limiting examples, the patterning coating 610, and/or the patterning material 611, when deposited as a film, and/or coating in a form, and under circumstances similar to the deposition of the patterning coating 610 within the device 400, may not substantially attenuate EM radiation passing therethrough, in at least the IR spectrum and/or the NIR spectrum.

In some non-limiting examples, the patterning coating 610, and/or the patterning coating 611, in some non-limiting examples, when deposited as a film, and/or coating in a form, and under circumstances similar to the deposition of the patterning coating 610 within the device 400, may have an extinction coefficient that may be at least one of at least about: 0.05, 0.1, 0.2, or 0.5 for EM radiation at a wavelength shorter than at least one of at least about: 400 nm, 390 nm, 380 nm, or 370 nm. In this way, the patterning coating 610, and/or the patterning material 611, when deposited as a film, and/or coating in a form, and under circumstances similar to the deposition of the patterning coating 610 within the device 400, may absorb EM radiation in the UVA spectrum incident upon the device 400, thereby reducing a likelihood that EM radiation in the UVA spectrum may impart undesirable effects in terms of device performance, device stability, device reliability, and/or device lifetime.

In some non-limiting examples, the patterning coating 610, and/or the patterning material 611, in some non-limiting examples, when deposited as a film, and/or coating in a form, and under circumstances similar to the deposition of the patterning coating 610 within the device 400, may have a glass transition temperature that is no more than at least one of about: 300° C., 150° C., 130° C., 30° C., 0° C., −30° C., or −50° C.

In some non-limiting examples, the patterning material may have a sublimation temperature of at least one of between about: 100-320° C., 120-300° C., 140-280° C., or 150-250° C. In some non-limiting examples, such sublimation temperature may allow the patterning material 611 to be readily deposited as a coating using PVD.

The sublimation temperature of a material may be determined using various methods apparent to those having ordinary skill in the relevant art, including without limitation, by heating the material under high vacuum in a crucible and by determining a temperature that may be attained to:
observe commencement of the deposition of the material onto a surface on a QCM mounted a fixed distance from the crucible;
observe a specific deposition rate, by way of non-limiting example, 0.1 Å/sec, onto a surface on a QCM mounted a fixed distance from the crucible; and/or
reach a threshold vapor pressure of the material, by way of non-limiting example, about 10⁻⁴ or 10⁻⁵ Torr.

In some non-limiting examples, the sublimation temperature of a material may be determined by heating the material in an evaporation source under a high vacuum environment, by way of non-limiting example, about 10⁻⁴ Torr, and by determining a temperature that may be attained to cause the material to evaporate, thus generating a vapor flux sufficient to cause deposition of the material, by way of non-limiting example, at a deposition rate of about 0.1 Å/sec onto a surface on a QCM mounted a fixed distance from the source.

In some non-limiting examples, the QCM may be mounted about 65 cm away from the crucible for the purpose of determining the sublimation temperature.

In some non-limiting examples, the patterning coating 610, and/or the patterning material 611, may comprise a fluorine (F) atom and/or a silicon (Si) atom. By way of non-limiting example, the patterning material 611 for forming the patterning coating 610 may be a compound that includes F and/or Si.

In some non-limiting examples, the patterning coating 611 may include a compound that comprises F. In some non-limiting examples, the patterning coating 611 may include a compound that comprises F and a carbon (C) atom. In some non-limiting examples, the patterning coating 611 may include a compound that comprises F and C in an atomic ratio corresponding to a quotient of F/C of at least one of at least about: 1, 1.5, or 2. In some non-limiting examples, an atomic ratio of F to C may be determined by counting all of the F atoms present in the compound structure, and for C atoms, counting solely the spa hybridized C atoms present in the compound structure. In some non-limiting examples, the patterning coating 611 may include a compound that comprises, as part of its molecular sub-structure, a moiety containing F and C in an atomic ratio corresponding to a quotient of F/C of at least about: 1, 1.5, or 2.

In some non-limiting examples, the compound of the patterning coating 611 may be an organic-inorganic hybrid material.

In some non-limiting examples, the patterning coating 611 may be, or comprise, an oligomer.

In some non-limiting examples, the patterning coating 611 may be, or comprise, a compound having a molecular structure containing a backbone and at least one functional group bonded to the backbone. In some non-limiting examples, the backbone may be an inorganic moiety, and the at least one functional group may be an organic moiety.

In some non-limiting examples, such compound may have a molecular structure containing a siloxane group. In some non-limiting examples, the siloxane group may be a linear, branched, or cyclic siloxane group. In some non-limiting examples, the backbone may be, or comprise, a siloxane group. In some non-limiting examples, the backbone may be, or comprise, a siloxane group and at least one functional group containing F. In some non-limiting examples, the at least one functional group containing F may be a fluoroalkyl group. Non-limiting examples of such compound include fluoro-siloxanes. Non-limiting examples of such compound are Example Material 6 and Example Material 9.

In some non-limiting examples, the compound may have a molecular structure comprising a silsesquioxane group. In some non-limiting examples, the silsesquioxane group may be a POSS. In some non-limiting examples, the backbone may be, or comprise, a silsesquioxane group. In some non-limiting examples, the backbone may be, or comprise, a silsesquioxane group and at least one functional group comprising F. In some non-limiting examples, the at least one functional group comprising F may be a fluoroalkyl group. Non-limiting examples of such compound include fluoro-silsesquioxane and/or fluoro-POSS. A non-limiting example of such compound is Example Material 8.

In some non-limiting examples, the compound may have a molecular structure comprising a substituted or unsubstituted aryl group, and/or a substituted or unsubstituted heteroaryl group. In some non-limiting examples, the aryl group may be phenyl, or naphthyl. In some non-limiting examples, one or more C atoms of an aryl group may be substituted by a heteroatom, which by way of non-limiting example may be oxygen (O), nitrogen (N), and/or sulfur (S), to derive a heteroaryl group. In some non-limiting examples, the backbone may be, or contain, a substituted or unsubstituted aryl group, and/or a substituted or unsubstituted heteroaryl group. In some non-limiting examples, the backbone may be, or comprise, a substituted or unsubstituted aryl group, and/or a substituted or unsubstituted heteroaryl group and at least one functional group comprising F. In some non-limiting examples, the at least one functional group comprising F may be a fluoroalkyl group.

In some non-limiting examples, the compound may have a molecular structure comprising a substituted or unsubstituted, linear, branched, or cyclic hydrocarbon group. In some non-limiting examples, one or more C atoms of the hydrocarbon group may be substituted by a heteroatom, which by way of non-limiting example may be O, N, and/or S.

In some non-limiting examples, the compound may have a molecular structure comprising a phosphazene group. In some non-limiting examples, the phosphazene group may be a linear, branched, or cyclic phosphazene group. In some non-limiting examples, the backbone may be, or comprise, a phosphazene group. In some non-limiting examples, the backbone may be, or comprise, a phosphazene group and at least one functional group comprising F. In some non-limiting examples, the at least one functional group comprising F may be a fluoroalkyl group. Non-limiting examples of such compound include fluoro-phosphazenes. A non-limiting example of such compound is Example Material 4.

In some non-limiting examples, the compound may be a fluoropolymer. In some non-limiting examples, the compound may be a block copolymer comprising F. In some non-limiting examples, the compound may be an oligomer. In some non-limiting examples, the oligomer may be a fluorooligomer. In some non-limiting examples, the compound may be a block oligomer comprising F. Non-limiting examples, of fluoropolymers and/or fluorooligomers are those having the molecular structure of Example Material 3, Example Material 5, and/or Example Material 7.

In some non-limiting examples, the compound may be a metal complex. In some non-limiting examples, the metal complex may be an organo-metal complex. In some non-limiting examples, the organo-metal complex may comprise F. In some non-limiting examples, the organo-metal complex may comprise at least one ligand comprising F. In some non-limiting examples, the at least one ligand comprising F may be, or comprise, a fluoroalkyl group.

In some non-limiting examples, the patterning material 611 may be, or comprise, an organic-inorganic hybrid material.

In some non-limiting examples, the patterning coating 611 may comprise a plurality of different materials.

In some non-limiting examples, a molecular weight of the compound of the patterning material 611 may be no more than at least one of about: 5,000 g/mol, 4,500 g/mol, 4,000 g/mol, 3,800 g/mol, or 3,500 g/mol.

In some non-limiting examples, the molecular weight of the compound of the patterning material 611 may be at least about: 1,500 g/mol, 1,700 g/mol, 2,000 g/mol, 2,200 g/mol, or 2,500 g/mol.

Without wishing to be bound by any particular theory, it may be postulated that, for compounds that are adapted to form surfaces with relatively low surface energy, there may be an aim, in at least some applications, for the molecular weight of such compounds to be at least one of between about: 1,500-5,000 g/mol, 1,500-4,500 g/mol, 1,700-4,500 g/mol, 2,000-4,000 g/mol, 2,200-4,000 g/mol, or 2,500-3,800 g/mol.

Without wishing to be bound by any particular theory, it may be postulated that such compounds may exhibit at least one property that maybe suitable for forming a coating, and/or layer having: (i) a relatively high melting point, by way of non-limiting example, of at least 100° C., (ii) a relatively low surface energy, and/or (iii) a substantially amorphous structure, when deposited, by way of non-limiting example, using vacuum-based thermal evaporation processes.

In some non-limiting examples, a percentage of the molar weight of such compound that is attributable to the presence of F atoms, may be at least one of between about: 40-90%, 45-85%, 50-80%, 55-75%, or 60-75%. In some non-limiting examples, F atoms may constitute a majority of the molar weight of such compound.

In some non-limiting examples, the patterning coating 610 may be disposed in a pattern that may be defined by at least one region therein that is substantially devoid of a closed coating 440 of the patterning coating 610. In some non-limiting examples, the at least one region may separate the patterning coating 610 into a plurality of discrete fragments thereof. In some non-limiting examples, the plurality of discrete fragments of the patterning coating 610 may be physically spaced apart from one another in the lateral aspect thereof. In some non-limiting examples, the plurality of the discrete fragments of the patterning coating 610 may be arranged in a regular structure, including without limitation, an array or matrix, such that in some non-limiting examples, the discrete fragments of the patterning coating 610 are configured in a repeating pattern.

In some non-limiting examples, at least one of the plurality of the discrete fragments of the patterning coating 610 may each correspond to an emissive region 1610.

In some non-limiting examples, an aperture ratio of the emissive regions 1610 may be no more than at least one of about: 50%, 40%, 30%, or 20%.

In some non-limiting examples, the patterning coating 610 may be formed as a single monolithic coating.

In some non-limiting examples, the patterning coating 610, and/or the patterning material 611, in some non-limiting examples, when deposited as a film, and/or coating in a form, and under similar circumstances to the deposition of the patterning coating 610 within the device 400, may have an extinction coefficient that may be no more than about 0.01 for photons at a wavelength that exceeds at least one of about: 600 nm, 500 nm, 460 nm, 420 nm, or 410 nm.

In some non-limiting examples, the patterning coating 610 may have and/or provide, including without limitation, because of the patterning material 611 used and/or the deposition environment, at least one nucleation site for the deposited material 731.

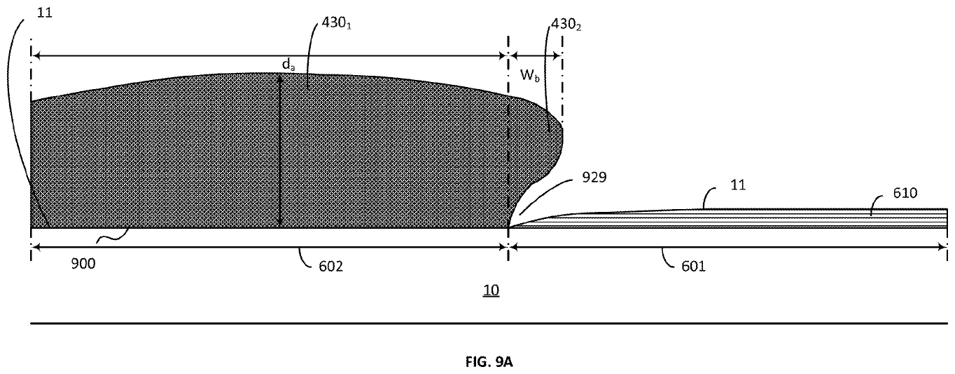

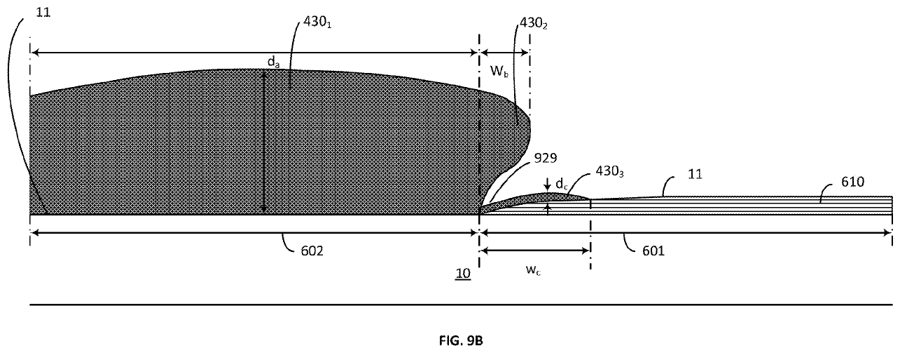

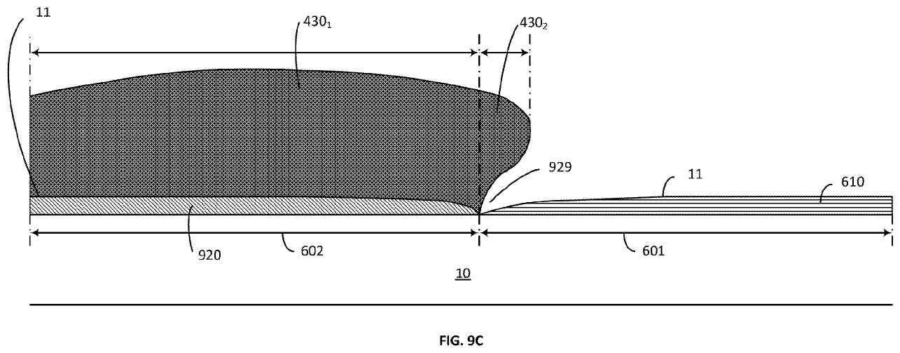

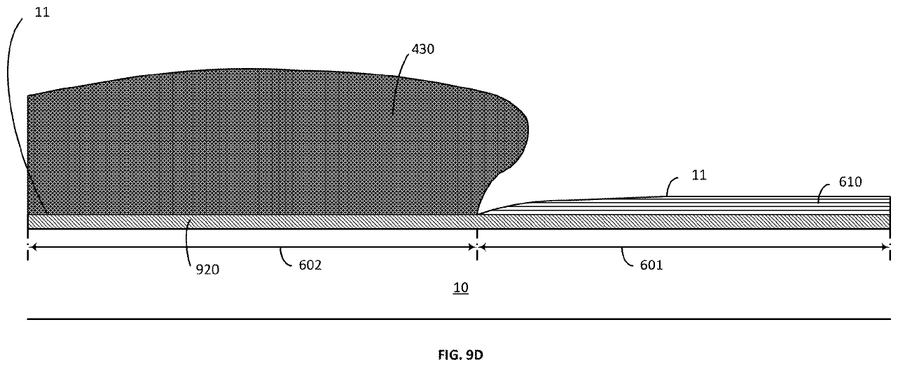

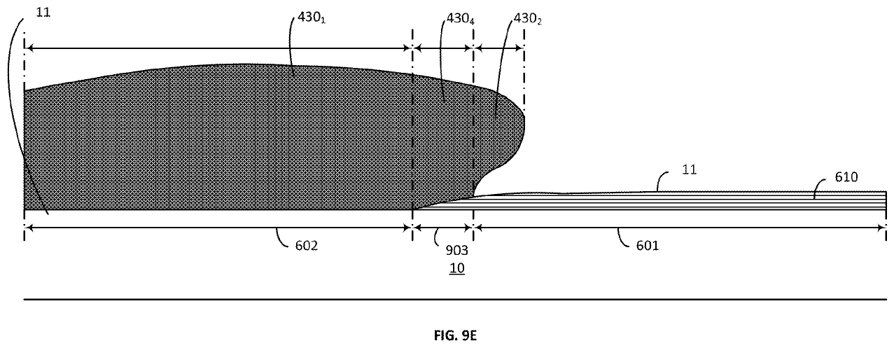

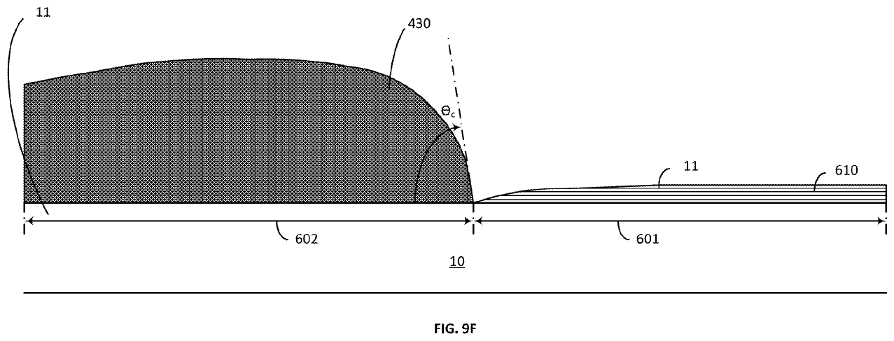

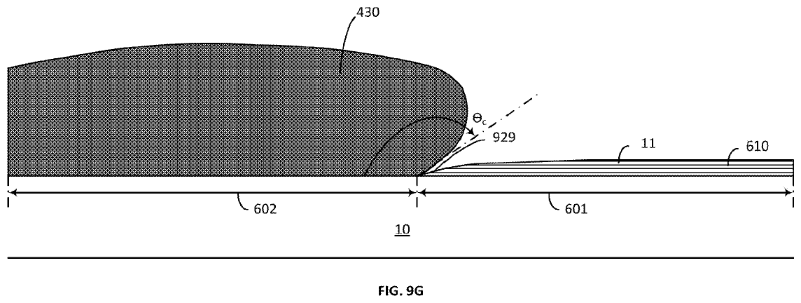

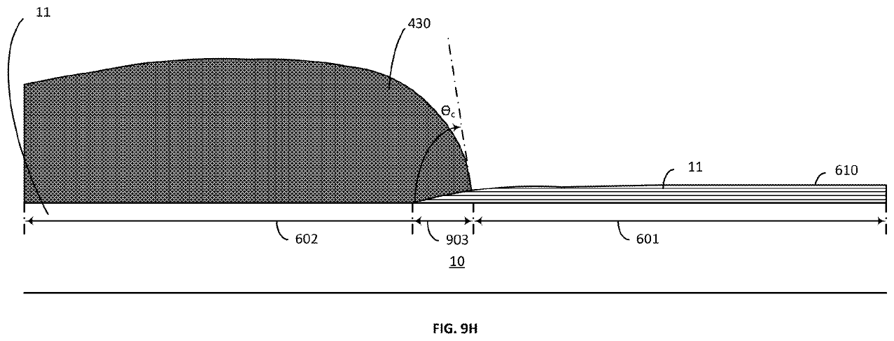

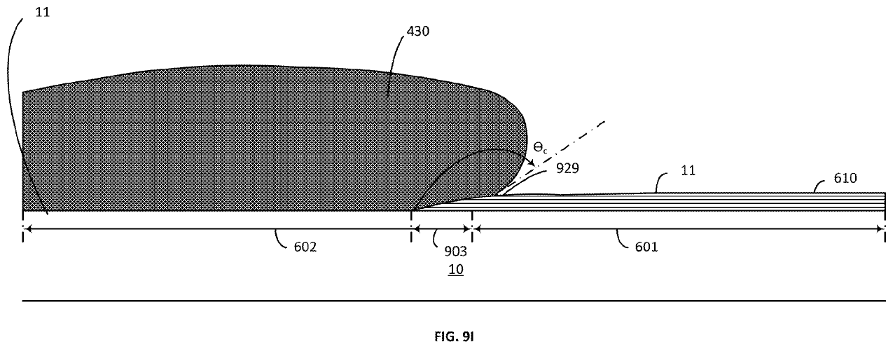

In some non-limiting examples, the patterning coating 610 may be doped, covered, and/or supplemented with another material that may act as a seed or heterogeneity, to act as such a nucleation site for the deposited material 731. In some non-limiting examples, such other material may comprise a nucleation promoting coating (NPC) 920 (FIG. 9C) material. In some non-limiting examples, such other material may comprise an organic material, such as by way of non-limiting example, a polycyclic aromatic compound, and/or a material containing a non-metallic element such as, without limitation, at least one of: O, S, N, or C, whose presence might otherwise be a contaminant in the source material, equipment used for deposition, and/or the vacuum chamber environment. In some non-limiting examples, such other material may be deposited in a layer thickness that is a fraction of a monolayer, to avoid forming a closed coating 440 thereof. Rather, the monomers of such other material will tend to be spaced apart in the lateral aspect so as form discrete nucleation sites for the deposited material.

In some non-limiting examples, the patterning coating 610 may act as an optical coating. In some non-limiting examples, the patterning coating 610 may modify at least one property, and/or characteristic of EM radiation (including without limitation, in the form of photons) emitted by the device 400. In some non-limiting examples, the patterning coating 610 may exhibit a degree of haze, causing emitted EM radiation to be scattered. In some non-limiting examples, the patterning coating 610 may comprise a crystalline material for causing EM radiation transmitted therethrough to be scattered. Such scattering of EM radiation may facilitate enhancement of the outcoupling of EM radiation from the device in some non-limiting examples. In some non-limiting examples, the patterning coating 610 may initially be deposited as a substantially non-crystalline, including without limitation, substantially amorphous, coating, whereupon, after deposition thereof, the patterning coating 610 may become crystallized and thereafter serve as an optical coupling.

### Deposited Layer

In some non-limiting examples, the deposited layer 430 may comprise a deposited material 731.

In some non-limiting examples, the deposited material 731 may comprise an element selected from at least one of: potassium (K), sodium (Na), lithium (Li), barium (Ba), cesium (Cs), Yb, Ag, gold (Au), copper (Cu), aluminum (Al), Mg, Zn, Cd, tin (Sn), or yttrium (Y). In some non-limiting examples, the element may comprise at least one of: K, Na, Li, Ba, Cs, Yb, Ag, Au, Cu, Al, and/or Mg. In some non-limiting examples, the element may comprise at least one of: Cu, Ag, and/or Au. In some non-limiting examples, the element may be Cu. In some non-limiting examples, the element may be Al. In some non-limiting examples, the element may comprise at least one of: Mg, Zn, Cd, or Yb. In some non-limiting examples, the element may comprise at least one of: Mg, Ag, Al, Yb, or Li. In some non-limiting examples, the element may comprise at least one of: Mg, Ag, or Yb. In some non-limiting examples, the element may comprise at least one of: Mg, or Ag. In some non-limiting examples, the element may be Ag.

In some non-limiting examples, the deposited material 731 may be and/or comprise a pure metal. In some non-limiting examples, the deposited material 731 may be at least one of: pure Ag or substantially pure Ag. In some non-limiting examples, the substantially pure Ag may have a purity of at least one of at least about: 95%, 99%, 99.9%, 99.99%, 99.999%, or 99.9995%. In some non-limiting examples, the deposited material 731 may be at least one of: pure Mg or substantially pure Mg. In some non-limiting examples, the substantially pure Mg may have a purity of at least one of at least about: 95%, 99%, 99.9%, 99.99%, 99.999%, or 99.9995%.

In some non-limiting examples, the deposited material 731 may comprise an alloy. In some non-limiting examples, the alloy may be at least one of: an Ag-containing alloy, an Mg-containing alloy, or an AgMg-containing alloy. In some non-limiting examples, the AgMg-containing alloy may have an alloy composition that may range from about 1:10 (Ag:Mg) to about 10:1 by volume.

In some non-limiting examples, the deposited material 731 may comprise other metals in place of, and/or in combination with, Ag. In some non-limiting examples, the deposited material 731 may comprise an alloy of Ag with at least one other metal. In some non-limiting examples, the deposited material 731 may comprise an alloy of Ag with at least one of: Mg, or Yb. In some non-limiting examples, such alloy may be a binary alloy having a composition between about 5-95 vol. % Ag, with the remainder being the other metal. In some non-limiting examples, the deposited material 731 may comprise Ag and Mg. In some non-limiting examples, the deposited material 731 may comprise an Ag:Mg alloy having a composition between about 1:10-10:1 by volume. In some non-limiting examples, the deposited material 731 may comprise Ag and Yb. In some non-limiting examples, the deposited material 731 may comprise a Yb:Ag alloy having a composition between about 1:20-10:1 by volume. In some non-limiting examples, the deposited material 731 may comprise Mg and Yb. In some non-limiting examples, the deposited material 731 may comprise an Mg:Yb alloy. In some non-limiting examples, the deposited material 731 may comprise Ag, Mg, and Yb. In some non-limiting examples, the deposited layer 430 may comprise an Ag:Mg:Yb alloy.

In some non-limiting examples, the deposited layer 430 may comprise at least one additional element. In some non-limiting examples, such additional element may be a non-metallic element. In some non-limiting examples, the non-metallic element may be at least one of: O, S, N, or C. It will be appreciated by those having ordinary skill in the relevant art that, in some non-limiting examples, such additional element(s) may be incorporated into the deposited layer 430 as a contaminant, due to the presence of such additional element(s) in the source material, equipment used for deposition, and/or the vacuum chamber environment. In some non-limiting examples, the concentration of such additional element(s) may be limited to be below a threshold concentration. In some non-limiting examples, such additional element(s) may form a compound together with other element(s) of the deposited layer 430. In some non-limiting examples, a concentration of the non-metallic element in the deposited material 731 may be no more than at least one of about: 1%, 0.1%, 0.01%, 0.001%, 0.0001%, 0.00001%, 0.000001%, or 0.0000001%. In some non-limiting examples, the deposited layer 430 may have a composition in which a combined amount of O and C therein may be no more than at least one of about: 10%, 5%, 1%, 0.1%, 0.01%, 0.001%, 0.0001%, 0.00001%, 0.000001%, or 0.0000001%.

It has now been found, somewhat surprisingly, that reducing a concentration of certain non-metallic elements in the deposited layer 430, particularly in cases wherein the deposited layer 430 may be substantially comprised of metal(s), and/or metal alloy(s), may facilitate selective deposition of the deposited layer 430. Without wishing to be bound by any particular theory, it may be postulated that certain non-metallic elements, such as, by way of non-limiting examples, O, or C, when present in the vapor flux 732 of the deposited layer 430, and/or in the deposition chamber, and/or environment, may be deposited onto the surface of the patterning coating 610 to act as nucleation sites for the metallic element(s) of the deposited layer 430. It may be postulated that reducing a concentration of such non-metallic elements that could act as nucleation sites may facilitate reducing an amount of deposited material 731 deposited on the exposed layer surface 11 of the patterning coating 610.

In some non-limiting examples, the deposited material 731 in the second portion 602 and the underlying layer 130 thereunder may comprise a common metal.

In some non-limiting examples, the deposited layer 430 may comprise a plurality of layers of the deposited material 731. In some non-limiting examples, the deposited material 731 of a first one of the plurality of layers may be different from the deposited material 731 of a second one of the plurality of layers. In some non-limiting examples, the deposited layer 430 may comprise a multilayer coating. In some non-limiting examples, such multilayer coating may be at least one of: Yb/Ag, Yb/Mg, Yb/Mg:Ag, Yb/Yb:Ag, Yb/Ag/Mg, or Yb/Mg/Ag.

In some non-limiting examples, the deposited material 731 may comprise a metal having a bond dissociation energy, of no more than at least one of about: 300 kJ/mol, 200 kJ/mol, 165 kJ/mol, 150 kJ/mol, 100 kJ/mol, 50 kJ/mol, or 20 kJ/mol.

In some non-limiting examples, the deposited material 731 may comprise a metal having an electronegativity that is no more than at least one of about: 1.4, 1.3, or 1.2.

In some non-limiting examples, a sheet resistance of the deposited layer 430 may generally correspond to a sheet resistance of the deposited layer 430, measured or determined in isolation from other components, layers, and/or parts of the device 300. In some non-limiting examples, the deposited layer 430 may be formed as a thin film. Accordingly, in some non-limiting examples, the characteristic sheet resistance for the deposited layer 430 may be determined, and/or calculated based on the composition, thickness, and/or morphology of such thin film. In some non-limiting examples, the sheet resistance may be no more than at least one of about: 10Ω/□, 5Ω/□, 1Ω/□, 0.5Ω/□, 0.2Ω/□, or 0.1Ω/□.

In some non-limiting examples, the deposited layer 430 may be disposed in a pattern that may be defined by at least one region therein that is substantially devoid of a closed coating 440 of the deposited layer 430. In some non-limiting examples, the at least one region may separate the deposited layer 430 into a plurality of discrete fragments thereof. In some non-limiting examples, each discrete fragment of the deposited layer 430 may be a distinct second portion 602. In some non-limiting examples, the plurality of discrete fragments of the deposited layer 430 may be physically spaced apart from one another in the lateral aspect thereof. In some non-limiting examples, at least two of such plurality of discrete fragments of the deposited layer 430 may be electrically coupled. In some non-limiting examples, at least two of such plurality of discrete fragments of the deposited layer 430 may be each electrically coupled with a common conductive layer or coating, including without limitation, the underlying layer 130, to allow the flow of electrical current between them. In some non-limiting examples, at least two of such plurality of discrete fragments of the deposited layer 430 may be electrically insulated from one another.

### Selective Deposition Using Patterning Coatings

FIG. 6 is an example schematic diagram illustrating a non-limiting example of an evaporative deposition process, shown generally at 600, in a chamber 60, for selectively depositing a patterning coating 610 onto a first portion 601 of an exposed layer surface 11 of the underlying layer 130.

In the process 600, a quantity of a patterning material 611 is heated under vacuum, to evaporate, and/or sublime the patterning material 611. In some non-limiting examples, the patterning material 611 may comprise entirely, and/or substantially, a material used to form the patterning coating 610. In some non-limiting examples, such material may comprise an organic material.

An evaporated flux 612 of the patterning material 611 may flow through the chamber 60, including in a direction indicated by arrow 61, toward the exposed layer surface 11. When the evaporated flux 612 is incident on the exposed layer surface 11, the patterning coating 610 may be formed thereon.

In some non-limiting examples, as shown in the figure for the process 600, the patterning coating 610 may be selectively deposited only onto a part, in the example illustrated, the first portion 601, of the exposed layer surface 11, by the interposition, between the evaporated flux 612 and the exposed layer surface 11, of a shadow mask 615, which in some non-limiting examples, may be a fine metal mask (FMM). In some non-limiting examples, such a shadow mask 615 may, in some non-limiting examples, be used to form relatively small features, with a feature size on the order of tens of microns or smaller.

The shadow mask 615 may have at least one aperture 616 extending therethrough such that a part of the evaporated flux 612 passes through the aperture 616 and may be incident on the exposed layer surface 11 to form the patterning coating 610. Where the evaporated flux 612 does not pass through the aperture 616 but is incident on the surface 617 of the shadow mask 615, it is precluded from being disposed on the exposed layer surface 11 to form the patterning coating 610. In some non-limiting examples, the shadow mask 615 may be configured such that the evaporated flux 612 that passes through the aperture 616 may be incident on the first portion 601 but not the second portion 602. The second portion 602 of the exposed layer surface 11 may thus be substantially devoid of the patterning coating 610. In some non-limiting examples (not shown), the patterning material 611 that is incident on the shadow mask 615 may be deposited on the surface 617 thereof.

Accordingly, a patterned surface may be produced upon completion of the deposition of the patterning coating 610.

FIG. 7 is an example schematic diagram illustrating a non-limiting example of a result of an evaporative process, shown generally at 700a, in a chamber 60, for selectively depositing a closed coating 440 of a deposited layer 430 onto the second portion 602 of an exposed layer surface 11 of the underlying layer 130 that is substantially devoid of the patterning coating 610 that was selectively deposited onto the first portion 601, including without limitation, by the evaporative process 600 of FIG. 6.

In some non-limiting examples, the deposited layer 430 may be comprised of a deposited material 731, in some non-limiting examples, comprising at least one metal. It will be appreciated by those having ordinary skill in the relevant art that typically, the vaporization temperature of an organic material is low relative to the vaporization temperature of metals, such as may be employed as a deposited material 731.

Thus, in some non-limiting examples, there may be fewer constraints in employing a shadow mask 615 to selectively deposit a patterning coating 610 in a pattern, relative to directly patterning the deposited layer 430 using such shadow mask 615.

Once the patterning coating 610 has been deposited on the first portion 601 of the exposed layer surface 11 of the underlying layer 130, a closed coating 440 of the deposited material 731 may be deposited, on the second portion 602 of the exposed layer surface 11 that is substantially devoid of the patterning coating 610, as the deposited layer 430.

In the process 700a, a quantity of the deposited material 731 may be heated under vacuum, to evaporate, and/or sublime the deposited material 731. In some non-limiting examples, the deposited material 731 may comprise entirely, and/or substantially, a material used to form the deposited layer 430.

An evaporated flux 732 of the deposited material 731 may be directed inside the chamber 60, including in a direction indicated by arrow 71, toward the exposed layer surface 11 of the first portion 601 and of the second portion 602. When the evaporated flux 732 is incident on the second portion 602 of the exposed layer surface 11, a closed coating 440 of the deposited material 731 may be formed thereon as the deposited layer 430.

In some non-limiting examples, deposition of the deposited material 731 may be performed using an open mask and/or mask-free deposition process.

It will be appreciated by those having ordinary skill in the relevant art that, contrary to that of a shadow mask 615, the feature size of an open mask may be generally comparable to the size of a device 400 being manufactured.

It will be appreciated by those having ordinary skill in the relevant art that, in some non-limiting examples, the use of an open mask may be omitted. In some non-limiting examples, an open mask deposition process described herein may alternatively be conducted without the use of an open mask, such that an entire target exposed layer surface 11 may be exposed.

Indeed, as shown in FIG. 7, the evaporated flux 732 may be incident both on an exposed layer surface 11 of the patterning coating 610 across the first portion 601 as well as the exposed layer surface 11 of the underlying layer 130 across the second portion 602 that is substantially devoid of the patterning coating 610.

Since the exposed layer surface 11 of the patterning coating 610 in the first portion 601 may exhibit a relatively low initial sticking probability against the deposition of the deposited material 731 relative to the exposed layer surface 11 of the underlying layer 130 in the second portion 602, the deposited layer 430 may be selectively deposited substantially only on the exposed layer surface 11, of the underlying layer 130 in the second portion 602, that is substantially devoid of the patterning coating 610. By contrast, the evaporated flux 732 incident on the exposed layer surface 11 of the patterning coating 610 across the first portion 601 may tend to not be deposited (as shown 733), and the exposed layer surface 11 of the patterning coating 610 across the first portion 601 may be substantially devoid of a closed coating 440 of the deposited layer 430.

In some non-limiting examples, an initial deposition rate, of the evaporated flux 732 on the exposed layer surface 11 of the underlying layer 130 in the second portion 602, may exceed at least one of about: 200 times, 550 times, 900 times, 1,000 times, 1,500 times, 1,900 times, or 2,000 times an initial deposition rate of the evaporated flux 732 on the exposed layer surface 11 of the patterning coating 610 in the first portion 601.

Thus, the combination of the selective deposition of a patterning coating 610 in FIG. 6 using a shadow mask 615 and the open mask and/or mask-free deposition of the deposited material 731 may result in a version 700, of the device 400 shown in FIG. 4.

After selective deposition of the patterning coating 610 across the first portion 601, a closed coating 440 of the deposited material 731 may be deposited over the device 700 as the deposited layer 430, in some non-limiting examples, using an open mask and/or a mask-free deposition process, but may remain substantially only within the second portion 602, which is substantially devoid of the patterning coating 610.

The patterning coating 610 may provide, within the first portion 601, an exposed layer surface 11 with a relatively low initial sticking probability S₀, against the deposition of the deposited material 731, that is substantially no more than the initial sticking probability, against the deposition of the deposited material 731, of the exposed layer surface 11 of the underlying material of the device 700 within the second portion 602.

Thus, the first portion 601 may be substantially devoid of a closed coating 440 of the deposited material 731.

While the present disclosure contemplates the patterned deposition of the patterning coating 610 by an evaporative deposition process, involving a shadow mask 615, those having ordinary skill in the relevant art will appreciate that, in some non-limiting examples, this may be achieved by any suitable deposition process, including without limitation, a micro-contact printing process.

While the present disclosure contemplates the patterning coating 610 being a nucleation inhibiting coating (NIC), those having ordinary skill in the relevant art will appreciate that, in some non-limiting examples, the patterning coating 610 may be an NPC 920. In such examples, the portion (such as, without limitation, the first portion 601) in which the NPC 920 has been deposited may, in some non-limiting examples, have a closed coating 440 of the deposited material 731, while the other portion (such as, without limitation, the second portion 602) may be substantially devoid of a closed coating 440 of the deposited material 731.

In some non-limiting examples, an average layer thickness of the patterning coating 610 and of the deposited layer 430 deposited thereafter may be varied according to a variety of parameters, including without limitation, a given application and given performance characteristics. In some non-limiting examples, the average layer thickness of the patterning coating 610 may be comparable to, and/or substantially no more than an average layer thickness of the deposited layer 430 deposited thereafter. Use of a relatively thin patterning coating 610 to achieve selective patterning of a deposited layer 430 may be suitable to provide flexible devices 400. In some non-limiting examples, a relatively thin patterning coating 610 may provide a relatively planar surface on which a barrier coating or other thin film encapsulation (TFE) layer 1450, may be deposited. In some non-limiting examples, providing such a relatively planar surface for application of such barrier coating 1450 may increase adhesion thereof to such surface.

### Edge Effects

Patterning Coating Transition Region

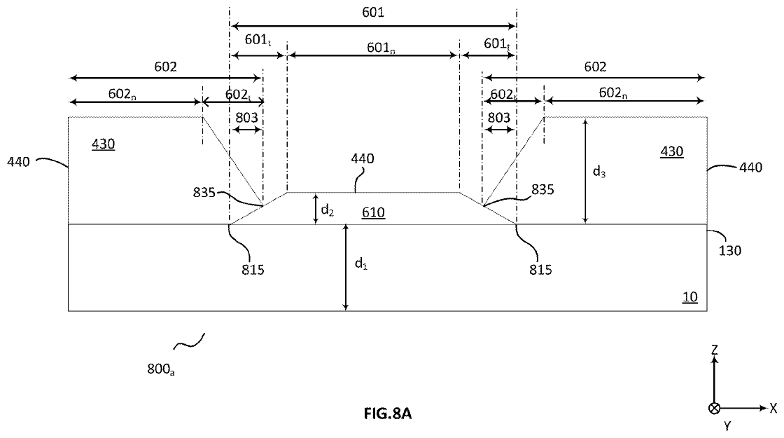

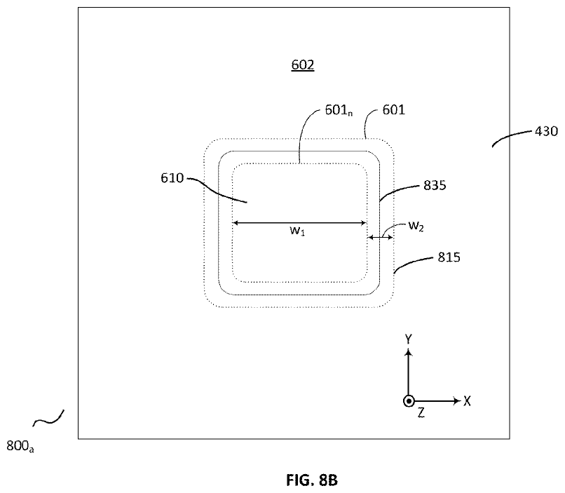

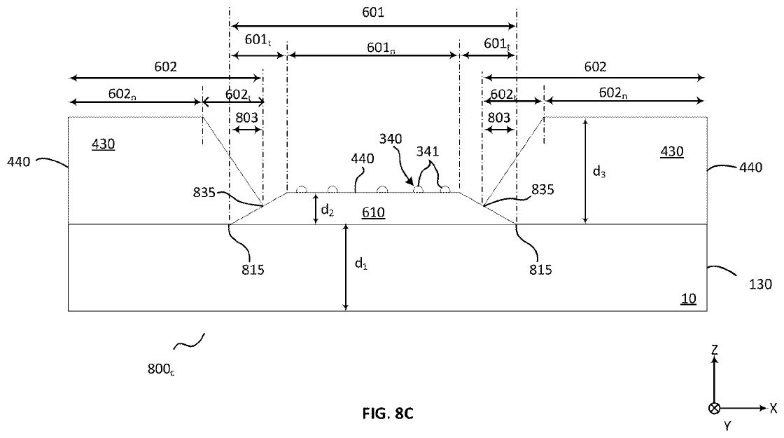

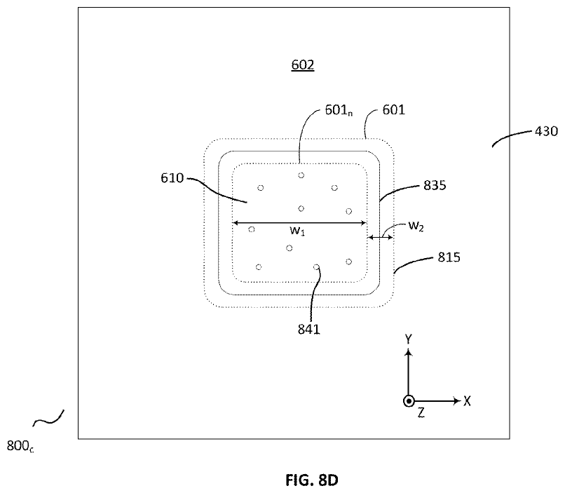

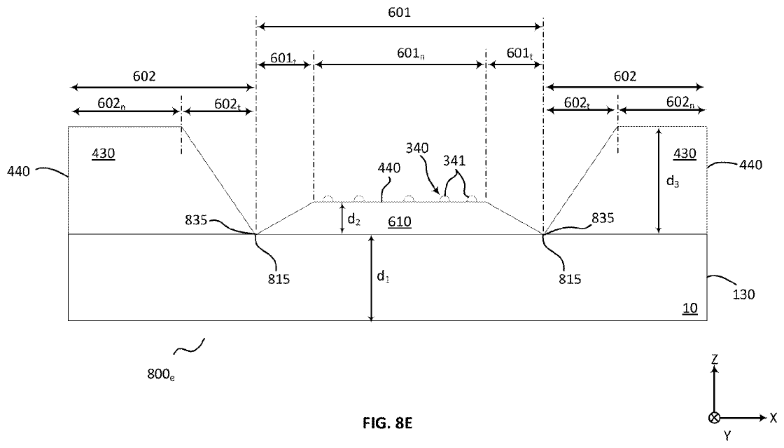

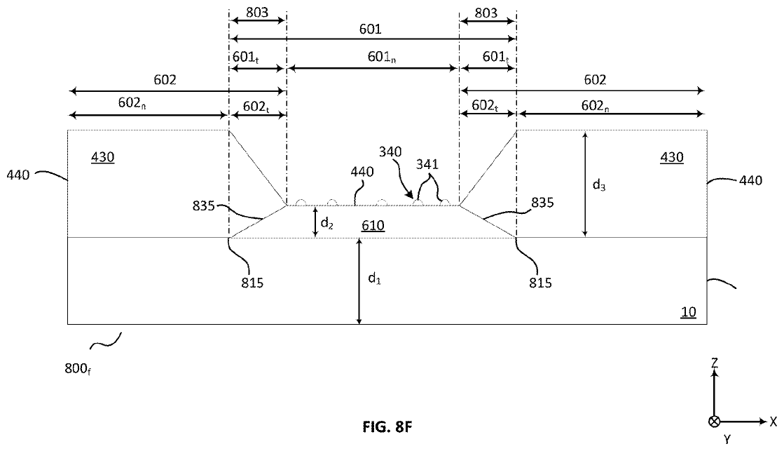

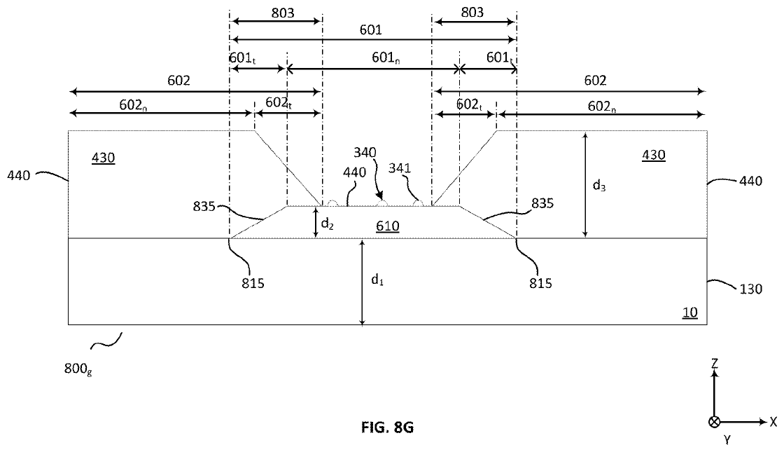

Turning to FIG. 8A, there may be shown a version 800ₐ of the device 400 of FIG. 4 that may show in exaggerated form, an interface between the patterning coating 610 in the first portion 601 and the deposited layer 430 in the second portion 602. FIG. 8B may show the device 800ₐ in plan.

As may be better seen in FIG. 8B, in some non-limiting examples, the patterning coating 610 in the first portion 601 may be surrounded on all sides by the deposited layer 430 in the second portion 602, such that the first portion 601 may have a boundary that is defined by the further extent or edge 815 of the patterning coating 610 in the lateral aspect along each lateral axis. In some non-limiting examples, the patterning coating edge 815 in the lateral aspect may be defined by a perimeter of the first portion 601 in such aspect.

In some non-limiting examples, the first portion 601 may comprise at least one patterning coating transition region 601ₜ, in the lateral aspect, in which a thickness of the patterning coating 610 may transition from a maximum thickness to a reduced thickness. The extent of the first portion 601 that does not exhibit such a transition is identified as a patterning coating non-transition part 601ₙ of the first portion 601. In some non-limiting examples, the patterning coating 610 may form a substantially closed coating 440 in the patterning coating non-transition part 601ₙ of the first portion 601.

In some non-limiting examples, the patterning coating transition region 601ₜ may extend, in the lateral aspect, between the patterning coating non-transition part 601ₙ of the first portion 601 and the patterning coating edge 815.

In some non-limiting examples, in plan, the patterning coating transition region 601ₜ may surround, and/or extend along a perimeter of, the patterning coating non-transition part 601ₙ of the first portion 601.

In some non-limiting examples, along at least one lateral axis, the patterning coating non-transition part 601ₙ may occupy the entirety of the first portion 601, such that there is no patterning coating transition region 601ₜ between it and the second portion 602.

As illustrated in FIG. 8A, in some non-limiting examples, the patterning coating 610 may have an average film thickness d₂ in the patterning coating non-transition part 601ₙ of the first portion 601 that may be in a range of at least one of between about: 1-100 nm, 2-50 nm, 3-30 nm, 4-20 nm, 5-15 nm, 5-10 nm, or 1-10 nm. In some non-limiting examples, the average film thickness d₂ of the patterning coating 610 in the patterning coating non-transition part 601ₙ of the first portion 601 may be substantially the same, or constant, thereacross. In some non-limiting examples, an average layer thickness d₂ of the patterning coating 610 may remain, within the patterning coating non-transition part 601ₙ, within at least one of about: 95%, or 90% of the average film thickness d₂ of the patterning coating 610.

In some non-limiting examples, the average film thickness d₂ may be between about 1-100 nm. In some non-limiting examples, the average film thickness d₂ may be no more than at least one of about: 80 nm, 60 nm, 50 nm, 40 nm, 30 nm, 20 nm, 15 nm, or 10 nm. In some non-limiting examples, the average film thickness d₂ of the patterning coating 610 may exceed at least one of about: 3 nm, 5 nm, or 8 nm.

In some non-limiting examples, the average film thickness d₂ of the patterning coating 610 in the patterning coating non-transition part 601ₙ of the first portion 601 may be no more than about 10 nm. Without wishing to be bound by any particular theory, it has been found, somewhat surprisingly, that an average film thickness d₂ of the patterning coating 610 that exceeds zero and is no more than about 10 nm may, at least in some non-limiting examples, provide certain advantages for achieving, by way of non-limiting example, enhanced patterning contrast of the deposited layer 430, relative to a patterning coating 610 having an average film thickness d₂ in the patterning coating non-transition part 601ₙ of the first portion 601 in excess of 10 nm.

In some non-limiting examples, the patterning coating 610 may have a patterning coating thickness that decreases from a maximum to a minimum within the patterning coating transition region 601ₜ. In some non-limiting examples, the maximum may be at, and/or proximate to, a boundary between the patterning coating transition region 601ₜ and the patterning coating non-transition part 601ₙ of the first portion 601. In some non-limiting examples, the minimum may be at, and/or proximate to, the patterning coating edge 815. In some non-limiting examples, the maximum may be the average film thickness d₂ in the patterning coating non-transition part 601ₙ of the first portion 601. In some non-limiting examples, the maximum may be no more than at least one of about: 95% or 90% of the average film thickness d₂ in the patterning coating non-transition part 601ₙ of the first portion 601. In some non-limiting examples, the minimum may be in a range of between about 0-0.1 nm.

In some non-limiting examples, a profile of the patterning coating thickness in the patterning coating transition region 601ₜ may be sloped, and/or follow a gradient. In some non-limiting examples, such profile may be tapered. In some non-limiting examples, the taper may follow a linear, non-linear, parabolic, and/or exponential decaying profile.

In some non-limiting examples, the patterning coating 610 may completely cover the underlying layer 130 in the patterning coating transition region 601ₜ. In some non-limiting examples, at least a part of the underlying layer 130 may be left uncovered by the patterning coating 610 in the patterning coating transition region 601ₜ. In some non-limiting examples, the patterning coating 610 may comprise a substantially closed coating 440 in at least a part of the patterning coating transition region 601ₜ and/or at least a part of the patterning coating non-transition part 601ₙ.

In some non-limiting examples, the patterning coating 610 may comprise a discontinuous layer 340 in at least a part of the patterning coating transition region 601ₜ.

In some non-limiting examples, at least a part of the patterning coating 610 in the first portion 601 may be substantially devoid of a closed coating 440 of the deposited layer 430. In some non-limiting examples, at least a part of the exposed layer surface 11 of the first portion 601 may be substantially devoid of the deposited layer 430 or of the deposited material 731.

In some non-limiting examples, along at least one lateral axis, including without limitation, the X-axis, the patterning coating non-transition part 601ₙ may have a width of w₁, and the patterning coating transition region 601ₜ may have a width of w₂. In some non-limiting examples, the patterning coating non-transition part 601ₙ may have a cross-sectional area that, in some non-limiting examples, may be approximated by multiplying the average film thickness d₂ by the width w₁. In some non-limiting examples, the patterning coating transition region 601ₜ may have a cross-sectional area that, in some non-limiting examples, may be approximated by multiplying an average film thickness across the patterning coating transition region 601ₜ by the width w₁.

In some non-limiting examples, w₁ may exceed w₂. In some non-limiting examples, a quotient of w₁/w₂ may be at least one of at least about: 5, 10, 20, 50, 100, 500, 1,000, 1,500, 5,000, 10,000, 50,000, or 100,000.

In some non-limiting examples, at least one of w1 and w2 may exceed the average film thickness d₁ of the underlying layer 130.

In some non-limiting examples, at least one of w₁ and w₂ may exceed d₂. In some non-limiting examples, both w₁ and w₂ may exceed d₂. In some non-limiting examples, w₁ and w₂ both may exceed d₁, and d₁ may exceed d₂.

Deposited Layer Transition Region

As may be better seen in FIG. 8B, in some non-limiting examples, the patterning coating 610 in the first portion 601 may be surrounded by the deposited layer 430 in the second portion 602 such that the second portion 602 has a boundary that is defined by a further extent or edge 835 of the deposited layer 430 in the lateral aspect along each lateral axis. In some non-limiting examples, the deposited layer edge 835 in the lateral aspect may be defined by a perimeter of the second portion 602 in such aspect.

In some non-limiting examples, the second portion 602 may comprise at least one deposited layer transition region 602ₜ, in the lateral aspect, in which a thickness of the deposited layer 430 may transition from a maximum thickness to a reduced thickness. The extent of the second portion 602 that does not exhibit such a transition is identified as a deposited layer non-transition part 602ₙ of the second portion 602. In some non-limiting examples, the deposited layer 430 may form a substantially closed coating 440 in the deposited layer non-transition part 602ₙ of the second portion 602.

In some non-limiting examples, in plan, the deposited layer transition region 602ₜ may extend, in the lateral aspect, between the deposited layer non-transition part 602ₙ of the second portion 602 and the deposited layer edge 835.

In some non-limiting examples, in plan, the deposited layer transition region 602ₜ may surround, and/or extend along a perimeter of, the deposited layer non-transition part 602ₙ of the second portion 602.

In some non-limiting examples, along at least one lateral axis, the deposited layer non-transition part 602ₙ of the second portion 602 may occupy the entirety of the second portion 602, such that there is no deposited layer transition region 602ₜ between it and the first portion 601.

As illustrated in FIG. 8A, in some non-limiting examples, the deposited layer 430 may have an average film thickness d₃ in the deposited layer non-transition part 602ₙ of the second portion 602 that may be in a range of at least one of between about: 1-500 nm, 5-200 nm, 5-40 nm, 10-30 nm, or 10-100 nm. In some non-limiting examples, d₃ may exceed at least one of about: 10 nm, 50 nm, or 100 nm. In some non-limiting examples, the average film thickness d₃ of the deposited layer 430 in the deposited layer non-transition part 602ₜ of the second portion 602 may be substantially the same, or constant, thereacross.

In some non-limiting examples, d₃ may exceed the average film thickness d₁ of the underlying layer 130.

In some non-limiting examples, a quotient d₃/d₁ may be at least one of at least about: 1.5, 2, 5, 10, 20, 50, or 100. In some non-limiting examples, the quotient d₃/d₁ may be in a range of at least one of between about: 0.1-10, or 0.2-40.

In some non-limiting examples, d₃ may exceed an average film thickness d₂ of the patterning coating 610.

In some non-limiting examples, a quotient d₃/d₂ may be at least one of at least about: 1.5, 2, 5, 10, 20, 50, or 100. In some non-limiting examples, the quotient d₃/d₂ may be in a range of at least one of between about: 0.2-10, or 0.5-40.

In some non-limiting examples, d₃ may exceed d₂ and d₂ may exceed d₁. In some other non-limiting examples, d₃ may exceed d₁ and d₁ may exceed d₂.

In some non-limiting examples, a quotient d₂/d₁ may be between at least one of about: 0.2-3, or 0.1-5.

In some non-limiting examples, along at least one lateral axis, including without limitation, the X-axis, the deposited layer non-transition part 602ₙ of the second portion 602 may have a width of w₃. In some non-limiting examples, the deposited layer non-transition part 602ₙ of the second portion 602 may have a cross-sectional area a₃ that, in some non-limiting examples, may be approximated by multiplying the average film thickness d₃ by the width w₃.

In some non-limiting examples, w₃ may exceed the width w₁ of the patterning coating non-transition part 601ₙ. In some non-limiting examples, w₁ may exceed w₃.

In some non-limiting examples, a quotient w₁/w₃ may be in a range of at least one of between about: 0.1-10, 0.2-5, 0.3-3, or 0.4-2. In some non-limiting examples, a quotient w₃/w₁ may be at least one of at least about: 1, 2, 3, or 4.

In some non-limiting examples, w₃ may exceed the average film thickness d₃ of the deposited layer 430.

In some non-limiting examples, a quotient w₃/d₃ may be at least one of at least about: 10, 50, 100, or 500. In some non-limiting examples, the quotient w₃/d₃ may be no more than about 100,000.

In some non-limiting examples, the deposited layer 430 may have a thickness that decreases from a maximum to a minimum within the deposited layer transition region 602ₜ. In some non-limiting examples, the maximum may be at, and/or proximate to, the boundary between the deposited layer transition region 602ₜ and the deposited layer non-transition part 602ₙ of the second portion 602. In some non-limiting examples, the minimum may be at, and/or proximate to, the deposited layer edge 835. In some non-limiting examples, the maximum may be the average film thickness d₃ in the deposited layer non-transition part 602ₙ of the second portion 602. In some non-limiting examples, the minimum may be in a range of between about 0-0.1 nm. In some non-limiting examples, the minimum may be the average film thickness d₃ in the deposited layer non-transition part 602ₙ of the second portion 602.

In some non-limiting examples, a profile of the thickness in the deposited layer transition region 602ₜ may be sloped, and/or follow a gradient. In some non-limiting examples, such profile may be tapered. In some non-limiting examples, the taper may follow a linear, non-linear, parabolic, and/or exponential decaying profile.

In some non-limiting examples, as shown by way of non-limiting example in the example version 800ₑ in FIG. 8E of the device 400, the deposited layer 430 may completely cover the underlying layer 130 in the deposited layer transition region 602ₜ. In some non-limiting examples, the deposited layer 430 may comprise a substantially closed coating 440 in at least a part of the deposited layer transition region 602ₜ. In some non-limiting examples, at least a part of the underlying layer 130 may be uncovered by the deposited layer 430 in the deposited layer transition region 602ₜ.

In some non-limiting examples, the deposited layer 430 may comprise a discontinuous layer 340 in at least a part of the deposited layer transition region 602ₜ.

Those having ordinary skill in the relevant art will appreciate that, while not explicitly illustrated, the patterning material 611 may also be present to some extent at an interface between the deposited layer 430 and an underlying layer 130. Such material may be deposited as a result of a shadowing effect, in which a deposited pattern is not identical to a pattern of a mask and may, in some non-limiting examples, result in some evaporated patterning material 611 being deposited on a masked part of a target exposed layer surface 11. By way of non-limiting examples, such material may form as particle structures 341 and/or as a thin film having a thickness that may be substantially no more than an average thickness of the patterning coating 610.

Overlap

In some non-limiting examples, the deposited layer edge 835 may be spaced apart, in the lateral aspect from the patterning coating transition region 601ₜ of the first portion 601, such that there is no overlap between the first portion 601 and the second portion 602 in the lateral aspect.

In some non-limiting examples, at least a part of the first portion 601 and at least a part of the second portion 602 may overlap in the lateral aspect. Such overlap may be identified by an overlap portion 803, such as may be shown by way of non-limiting example in FIG. 8A, in which at least a part of the second portion 602 overlaps at least a part of the first portion 601.

In some non-limiting examples, as shown by way of non-limiting example in FIG. 8F, at least a part of the deposited layer transition region 602ₜ may be disposed over at least a part of the patterning coating transition region 601ₜ. In some non-limiting examples, at least a part of the patterning coating transition region 601ₜ may be substantially devoid of the deposited layer 430, and/or the deposited material 731. In some non-limiting examples, the deposited material 731 may form a discontinuous layer 340 on an exposed layer surface 11 of at least a part of the patterning coating transition region 601ₜ.

In some non-limiting examples, as shown by way of non-limiting example in FIG. 8G, at least a part of the deposited layer transition region 602ₜ may be disposed over at least a part of the patterning coating non-transition part 601ₙ of the first portion 601.

Although not shown, those having ordinary skill in the relevant art will appreciate that, in some non-limiting examples, the overlap portion 803 may reflect a scenario in which at least a part of the first portion 601 overlaps at least a part of the second portion 602.

Thus, in some non-limiting examples, at least a part of the patterning coating transition region 601ₜ may be disposed over at least a part of the deposited layer transition region 602ₜ. In some non-limiting examples, at least a part of the deposited layer transition region 602ₜ may be substantially devoid of the patterning coating 610, and/or the patterning material 611. In some non-limiting examples, the patterning material 611 may form a discontinuous layer 340 on an exposed layer surface of at least a part of the deposited layer transition region 602ₜ.

In some non-limiting examples, at least a part of the patterning coating transition region 601ₜ may be disposed over at least a part of the deposited layer non-transition part 602ₙ of the second portion 602.

In some non-limiting examples, the patterning coating edge 815 may be spaced apart, in the lateral aspect, from the deposited layer non-transition part 602ₙ of the second portion 602.

In some non-limiting examples, the deposited layer 430 may be formed as a single monolithic coating across both the deposited layer non-transition part 602ₙ and the deposited layer transition region 602ₜ of the second portion 602.

Edge Effects of Patterning Coatings and Deposited Layers

FIGS. 9A-9I describe various potential behaviours of patterning coatings 410 at a deposition interface with deposited layers 430.

Turning to FIG. 9A, there may be shown a first example of a part of an example version 900 of the device 400 at a patterning coating deposition boundary. The device 900 may comprise a substrate 10 having an exposed layer surface 11. A patterning coating 610 may be deposited over a first portion 601 of the exposed layer surface 11. A deposited layer 430 may be deposited over a second portion 602 of the exposed layer surface 11. As shown, by way of non-limiting example, the first portion 601 and the second portion 602 may be distinct and non-overlapping parts of the exposed layer surface 11.

The deposited layer 430 may comprise a first part 430₁ and a remaining part 430₂. As shown, by way of non-limiting example, the first part 430₁ of the deposited layer 430 may substantially cover the second portion 602 and the second part 430₂ of the deposited layer 430 may partially project over, and/or overlap a first part of the patterning coating 610.

In some non-limiting examples, since the patterning coating 610 may be formed such that its exposed layer surface 11 exhibits a relatively low initial sticking probability against deposition of the deposited material 731, there may be a gap 929 formed between the projecting, and/or overlapping second part 430₂ of the deposited layer 430 and the exposed layer surface 11 of the patterning coating 610. As a result, the second part 430₂ may not be in physical contact with the patterning coating 610 but may be spaced-apart therefrom by the gap 929 in a cross-sectional aspect. In some non-limiting examples, the first part 430₁ of the deposited layer 430 may be in physical contact with the patterning coating 610 at an interface, and/or boundary between the first portion 601 and the second portion 602.

In some non-limiting examples, the projecting, and/or overlapping second part 430₂ of the deposited layer 430 may extend laterally over the patterning coating 610 by a comparable extent as an average layer thickness dₐ of the first part 430₁ of the deposited layer 430. By way of non-limiting example, as shown, a width w_{b} of the second part 430₂ may be comparable to the average layer thickness dₐ of the first part 430₁. In some non-limiting examples, a ratio of a width w_{b} of the second part 430₂ by an average layer thickness dₐ of the first part 430₁ may be in a range of at least one of between about: 1:1-1:3, 1:1-1:1.5, or 1:1-1:2. While the average layer thickness dₐ may in some non-limiting examples be relatively uniform across the first part 430₁, in some non-limiting examples, the extent to which the second part 430₂ may project, and/or overlap with the patterning coating 610 (namely w_{b}) may vary to some extent across different parts of the exposed layer surface 11.

Turning now to FIG. 9B, the deposited layer 430 may be shown to include a third part 430₃ disposed between the second part 430₂ and the patterning coating 610. As shown, the second part 430₂ of the deposited layer 430 may extend laterally over and is longitudinally spaced apart from the third part 430₃ of the deposited layer 430 and the third part 430₃ may be in physical contact with the exposed layer surface 11 of the patterning coating 610. An average layer thickness of the third part 430₃ of the deposited layer 430 may be less and in some non-limiting examples, substantially no more than the average layer thickness dₐ of the first part 430₁ thereof. In some non-limiting examples, a width w_{c} of the third part 430₃ may exceed the width w_{b} of the second part 430₂. In some non-limiting examples, the third part 430₂ may extend laterally to overlap the patterning coating 610 to a greater extent than the second part 430₂. In some non-limiting examples, a ratio of a width woof the third part 430₃ by an average layer thickness dₐ of the first part 430₁ may be in a range of at least one of between about: 1:2-3:1, or 1:1.2-2.5:1. While the average layer thickness dₐ may in some non-limiting examples be relatively uniform across the first part 430₁, in some non-limiting examples, the extent to which the third part 430₃ may project, and/or overlap with the patterning coating 610 (namely w_{c}) may vary to some extent across different parts of the exposed layer surface 11.

In some non-limiting examples, the average layer thickness of the third part 430₃ may not exceed about 5% of the average layer thickness dₐ of the first part 430₁. By way of non-limiting example, d_{c} may be no more than at least one of about: 4%, 3%, 2%, 1%, or 0.5% of dₐ. Instead of, and/or in addition to, the third part 430₃ being formed as a thin film, as shown, the material of the deposited layer 430 may form as particle structures 341 on a part of the patterning coating 610. By way of non-limiting example, such particle structures 341 may comprise features that are physically separated from one another, such that they do not form a continuous layer.

Turning now to FIG. 9C, an NPC 920 may be disposed between the substrate 10 and the deposited layer 430. The NPC 920 may be disposed between the first part 430₁ of the deposited layer 430 and the second portion 602 of the substrate 10. The NPC 920 is illustrated as being disposed on the second portion 602 and not on the first portion 601, where the patterning coating 610 has been deposited. The NPC 920 may be formed such that, at an interface, and/or boundary between the NPC 920 and the deposited layer 430, a surface of the NPC 920 may exhibit a relatively high initial sticking probability against deposition of the deposited material 731. As such, the presence of the NPC 920 may promote the formation, and/or growth of the deposited layer 430 during deposition.

Turning now to FIG. 9D, the NPC 920 may be disposed on both the first portion 601 and the second portion 602 of the substrate 10 and the patterning coating 610 may cover a part of the NPC 920 disposed on the first portion 601. Another part of the NPC 920 may be substantially devoid of the patterning coating 610 and the deposited layer 430 covers such part of the NPC 920.

Turning now to FIG. 9E, the deposited layer 430 may be shown to partially overlap a part of the patterning coating 610 in a third portion 903 of the substrate 10. In some non-limiting examples, in addition to the first part 430₁ and the second part 430₂, the deposited layer 430 may further include a fourth part 430₄. As shown, the fourth part 430₄ of the deposited layer 430 may be disposed between the first part 430₁ and the second part 430₂ of the deposited layer 430 and the fourth part 430₄ may be in physical contact with the exposed layer surface 11 of the patterning coating 610. In some non-limiting examples, the overlap in the third portion 903 may be formed as a result of lateral growth of the deposited layer 430 during an open mask and/or mask-free deposition process. In some non-limiting examples, while the exposed layer surface 11 of the patterning coating 610 may exhibit a relatively low initial sticking probability against deposition of the deposited material 731, and thus a probability of the material nucleating on the exposed layer surface 11 may be low, as the deposited layer 430 grows in thickness, the deposited layer 430 may also grow laterally and may cover a subset of the patterning coating 610 as shown.

Turning now to FIG. 9F the first portion 601 of the substrate 10 may be coated with the patterning coating 610 and the second portion 602 adjacent thereto may be coated with the deposited layer 430. In some non-limiting examples, it has been observed that conducting an open mask and/or mask-free deposition of the deposited layer 430 may result in the deposited layer 430 exhibiting a tapered cross-sectional profile at, and/or near an interface between the deposited layer 430 and the patterning coating 610.

In some non-limiting examples, an average layer thickness of the deposited layer 430 at, and/or near the interface may be no more than an average film thickness d₃ of the deposited layer 430. While such tapered profile may be shown as being curved, and/or arched, in some non-limiting examples, the profile may, in some non-limiting examples be substantially linear, and/or non-linear. By way of non-limiting example, an average layer thickness of the deposited layer 430 may decrease, without limitation, in a substantially linear, exponential, and/or quadratic fashion in a region proximal to the interface.

It has been observed that a contact angle θ_{c} of the deposited layer 430 at, and/or near the interface between the deposited layer 430 and the patterning coating 610 may vary, depending on properties of the patterning coating 610, such as a relative initial sticking probability. It may be further postulated that the contact angle θ_{c} of the nuclei may, in some non-limiting examples, dictate the thin film contact angle of the deposited layer 430 formed by deposition. Referring to FIG. 9F by way of non-limiting example, the contact angle θ_{c} may be determined by measuring a slope of a tangent of the deposited layer 430 at or near the interface between the deposited layer 430 and the patterning coating 610. In some non-limiting examples, where the cross-sectional taper profile of the deposited layer 430 may be substantially linear, the contact angle θ_{c} may be determined by measuring the slope of the deposited layer 430 at, and/or near the interface. As will be appreciated by those having ordinary skill in the relevant art, the contact angle θ_{c} may be generally measured relative to an angle of the underlying layer 130. In the present disclosure, for purposes of simplicity of illustration, the patterning coating 610 and the deposited layer 430 may be shown deposited on a planar surface. However, those having ordinary skill in the relevant art will appreciate that the patterning coating 610 and the deposited layer 430 may be deposited on non-planar surfaces.

In some non-limiting examples, the contact angle θ_{c} of the deposited layer 430 may exceed about 90°. Referring now to FIG. 9G, by way of non-limiting example, the deposited layer 430 may be shown as including a part extending past the interface between the patterning coating 610 and the deposited layer 430 and may be spaced apart from the patterning coating 610 by a gap 929. In such non-limiting scenario, the contact angle θ_{c} may, in some non-limiting examples, exceed 90°.

In some non-limiting examples, it may be advantageous to form a deposited layer 430 exhibiting a relatively high contact angle θ_{c}. By way of non-limiting example, the contact angle θ_{c} may exceed at least one of about: 10°, 15°, 20°, 25°, 30°, 35°, 40°, 50°, 70°, 75°, or 80°. By way of non-limiting example, a deposited layer 430 having a relatively high contact angle θ_{c} may allow for creation of finely patterned features while maintaining a relatively high aspect ratio. By way of non-limiting example, there may be an aim to form a deposited layer 430 exhibiting a contact angle θ_{c} greater than about 90°. By way of non-limiting example, the contact angle θ_{c} may exceed at least one of about: 90°, 95°, 100°, 105°, 110° 120°, 130°, 135°, 140°, 145°, 150°, or 170°.

Turning now to FIGS. 9H-9I, the deposited layer 430 may partially overlap a part of the patterning coating 610 in the third portion 903 of the substrate 10, which may be disposed between the first portion 601 and the second portion 602 thereof. As shown, the subset of the deposited layer 430 partially overlapping a subset of the patterning coating 610 may be in physical contact with the exposed layer surface 11 thereof. In some non-limiting examples, the overlap in the third portion 903 may be formed because of lateral growth of the deposited layer 430 during an open mask and/or mask-free deposition process. In some non-limiting examples, while the exposed layer surface 11 of the patterning coating 610 may exhibit a relatively low initial sticking probability against deposition of the deposited material 731 and thus a probability of the material nucleating on the exposed layer surface 11 is low, as the deposited layer 430 grows in thickness, the deposited layer 430 may also grow laterally and may cover a subset of the patterning coating 610.

In the case of FIGS. 9H-9I, the contact angle θ_{c} of the deposited layer 430 may be measured at an edge thereof near the interface between it and the patterning coating 610, as shown. In FIG. 91, the contact angle θ_{c} may exceed about 90°, which may in some non-limiting examples result in a subset of the deposited layer 430 being spaced apart from the patterning coating 610 by the gap 929.

### Particle

In some non-limiting examples, such as may be shown in FIG. 8C, there may be at least one particle, including without limitation, a nanoparticle (NP), an island, a plate, a disconnected cluster, and/or a network (collectively particle structure 341) disposed on an exposed layer surface 11 of an underlying layer 130. In some non-limiting examples, the underlying layer 130 may be the patterning coating 610 in the first portion 601. In some non-limiting examples, the at least one particle structure 341 may be disposed on an exposed layer surface 11 of the patterning coating 610. In some non-limiting examples, there may be a plurality of such particle structures 341.

In some non-limiting examples, the at least one particle structure 341 may comprise a particle structure material. In some non-limiting examples, the particle structure material may be the same as the deposited material 731 in the deposited layer 430.

In some non-limiting examples, the particle structure material in the discontinuous layer 340 in the first portion 601, the deposited material 731 in the deposited layer 430, and/or a material of which the underlying layer 130 thereunder may be comprised, may comprise a common metal.

In some non-limiting examples, the particle structure material may comprise an element selected from at least one of: K, Na, Li, Ba, Cs, Yb, Ag, Au, Cu, Al, Mg, Zn, Cd, Sn, or Y. In some non-limiting examples, the element may comprise at least one of: K, Na, Li, Ba, Cs, Yb, Ag, Au, Cu, Al, or Mg. In some non-limiting examples, the element may comprise at least one of: Cu, Ag, or Au. In some non-limiting examples, the element may be Cu. In some non-limiting examples, the element may be Al. In some non-limiting examples, the element may comprise at least one of: Mg, Zn, Cd, or Yb. In some non-limiting examples, the element may comprise at least one of: Mg, Ag, Al, Yb, or Li. In some non-limiting examples, the element may comprise at least one of: Mg, Ag, or Yb. In some non-limiting examples, the element may comprise at least one of: Mg, or Ag. In some non-limiting examples, the element may be Ag.

In some non-limiting examples, the particle structure material may comprise a pure metal. In some non-limiting examples, the at least one particle structure 341 may be a pure metal. In some non-limiting examples, the at least one particle structure 341 may be at least one of: pure Ag or substantially pure Ag. In some non-limiting examples, the substantially pure Ag may have a purity of at least one of at least about: 95%, 99%, 99.9%, 99.99%, 99.999%, or 99.9995%. In some non-limiting examples, the at least one particle structure 341 may be at least one of: pure Mg or substantially pure Mg. In some non-limiting examples, the substantially pure Mg may have a purity of at least one of at least about: 95%, 99%, 99.9%, 99.99%, 99.999%, or 99.9995%.

In some non-limiting examples, the at least one particle structure 341 may comprise an alloy. In some non-limiting examples, the alloy may be at least one of: an Ag-containing alloy, an Mg-containing alloy, or an AgMg-containing alloy. In some non-limiting examples, the AgMg-containing alloy may have an alloy composition that may range from about 1:10 (Ag:Mg) to about 10:1 by volume.

In some non-limiting examples, the particle structure material may comprise other metals in place of, or in combination with Ag. In some non-limiting examples, the particle structure material may comprise an alloy of Ag with at least one other metal. In some non-limiting examples, the particle structure material may comprise an alloy of Ag with at least one of: Mg, or Yb. In some non-limiting examples, such alloy may be a binary alloy having a composition of between about: 5-95 vol. % Ag, with the remainder being the other metal. In some non-limiting examples, the particle structure material may comprise Ag and Mg. In some non-limiting examples, the particle structure material may comprise an Ag:Mg alloy having a composition of between about 1:10-10:1 by volume. In some non-limiting examples, the particle structure material may comprise Ag and Yb. In some non-limiting examples, the particle structure material may comprise a Yb:Ag alloy having a composition of between about 1:20-10:1 by volume. In some non-limiting examples, the particle structure material may comprise Mg and Yb. In some non-limiting examples, the particle structure material may comprise an Mg:Yb alloy. In some non-limiting examples, the particle structure material may comprise an Ag:Mg:Yb alloy.

In some non-limiting examples, the at least one particle structure 341 may comprise at least one additional element. In some non-limiting examples, such additional element may be a non-metallic element. In some non-limiting examples, the non-metallic material may be at least one of: O, S, N, or C. It will be appreciated by those having ordinary skill in the relevant art that, in some non-limiting examples, such additional element(s) may be incorporated into the at least one particle structure 341 as a contaminant, due to the presence of such additional element(s) in the source material, equipment used for deposition, and/or the vacuum chamber environment. In some non-limiting examples, such additional element(s) may form a compound together with other element(s) of the at least one particle structure 341. In some non-limiting examples, a concentration of the non-metallic element in the deposited material 731 may be no more than at least one of about: 1%, 0.1%, 0.01%, 0.001%, 0.0001%, 0.00001%, 0.000001%, or 0.0000001%. In some non-limiting examples, the at least one particle structure 341 may have a composition in which a combined amount of O and C therein is no more than at least one of about: 10%, 5%, 1%, 0.1%, 0.01%, 0.001%, 0.0001%, 0.00001%, 0.000001%, or 0.0000001%.

In some non-limiting examples, the presence of the at least one particle structure 341, including without limitation, NPs, including without limitation, in a discontinuous layer 340, on an exposed layer surface 11 of the patterning coating 610 may affect some optical properties of the device 800.

In some non-limiting examples, such plurality of particle structures 341 may form a discontinuous layer 340.

Without wishing to be limited to any particular theory, it may be postulated that, while the formation of a closed coating 440 of the deposited material 731 may be substantially inhibited by and/or on the patterning coating 610, in some non-limiting examples, when the patterning coating 610 is exposed to deposition of the deposited material 731 thereon, some vapor monomers 732 of the deposited material 731 may ultimately form at least one particle structure 341 of the deposited material 731 thereon.

In some non-limiting examples, at least some of the particle structures 341 may be disconnected from one another. In other words, in some non-limiting examples, the discontinuous layer 340 may comprise features, including particle structures 341, that may be physically separated from one another, such that the particle structures 341 do not form a closed coating 440. Accordingly, such discontinuous layer 340 may, in some non-limiting examples, thus comprise a thin disperse layer of deposited material 731 formed as particle structures 341, inserted at, and/or substantially across the lateral extent of, an interface between the patterning coating 610 and at least one covering layer in the device 300.

In some non-limiting examples, at least one of the particle structures 341 of deposited material 731 may be in physical contact with an exposed layer surface 11 of the patterning coating 610. In some non-limiting examples, substantially all of the particle structures 341 of deposited material 731 may be in physical contact with the exposed layer surface 11 of the patterning coating 610.

Without wishing to be bound by any particular theory, it has been found, somewhat surprisingly, that the presence of such a thin, disperse discontinuous layer 340 of deposited material 731, including without limitation, at least one particle structure 341, including without limitation, metal particle structures 341, on an exposed layer surface 11 of the patterning coating 610, may exhibit at least one varied characteristic and concomitantly, varied behaviour, including without limitation, optical effects and properties of the device 300, as discussed herein. In some non-limiting examples, such effects and properties may be controlled to some extent by judicious selection of at least one of: the characteristic size, size distribution, shape, surface coverage, configuration, deposited density, and/or dispersity of the particle structures 341 on the patterning coating 610.

In some non-limiting examples, the formation of at least one of: the characteristic size, size distribution, shape, surface coverage, configuration, deposited density, and/or dispersity of such discontinuous layer 340 may be controlled, in some non-limiting examples, by judicious selection of at least one of: at least one characteristic of the patterning material 611, an average film thickness d₂ of the patterning coating 610, the introduction of heterogeneities in the patterning coating 610, and/or a deposition environment, including without limitation, a temperature, pressure, duration, deposition rate, and/or deposition process for the patterning coating 610.

In some non-limiting examples, the formation of at least one of: the characteristic size, size distribution, shape, surface coverage, configuration, deposited density, and/or dispersity of such discontinuous layer 340 may be controlled, in some non-limiting examples, by judicious selection of at least one of: at least one characteristic of the particle structure material (which may be the deposited material 731), an extent to which the patterning coating 610 may be exposed to deposition of the particle structure material (which, in some non-limiting examples may be specified in terms of a thickness of a corresponding discontinuous layer 340), and/or a deposition environment, including without limitation, a temperature, pressure, duration, deposition rate, and/or method of deposition for the particle structure material.

In some non-limiting examples, the discontinuous layer 340 may be deposited in a pattern across the lateral extent of the patterning coating 610.

In some non-limiting examples, the discontinuous layer 340 may be disposed in a pattern that may be defined by at least one region therein that is substantially devoid of the at least one particle structure 341.

In some non-limiting examples, the characteristics of such discontinuous layer 340 may be assessed, in some non-limiting examples, somewhat arbitrarily, according to at least one of several criteria, including without limitation, a characteristic size, size distribution, shape, configuration, surface coverage, deposited distribution, dispersity, and/or a presence, and/or extent of aggregation instances of the particle structure material, formed on a portion of the exposed layer surface 11 of the underlying layer 130.

In some non-limiting examples, an assessment of the discontinuous layer 340 according to such at least one criterion, may be performed on, including without limitation, by measuring, and/or calculating, at least one attribute of the discontinuous layer 340, using a variety of imaging techniques, including without limitation, at least one of: transmission electron microscopy (TEM), atomic force microscopy (AFM), and/or scanning electron microscopy (SEM).

Those having ordinary skill in the relevant art will appreciate that such an assessment of the discontinuous layer 340 may depend, to a greater, and/or lesser extent, by an extent, of the exposed layer surface 11 under consideration, which in some non-limiting examples may comprise an area, and/or region thereof. In some non-limiting examples, the discontinuous layer 340 may be assessed across the entire extent, in a first lateral aspect, and/or a second lateral aspect that is substantially transverse thereto, of the exposed layer surface 11. In some non-limiting examples, the discontinuous layer 340 may be assessed across an extent that comprises at least one observation window applied against (a part of) the discontinuous layer 340.

In some non-limiting examples, the at least one observation window may be located at at least one of: a perimeter, interior location, and/or grid coordinate of the lateral aspect of the exposed layer surface 11. In some non-limiting examples, a plurality of the at least one observation windows may be used in assessing the discontinuous layer 340.

In some non-limiting examples, the observation window may correspond to a field of view of an imaging technique applied to assess the discontinuous layer 340, including without limitation, at least one of: TEM, AFM, and/or SEM. In some non-limiting examples, the observation window may correspond to a given level of magnification, including without limitation, at least one of: 2.00 μm, 1.00 μm, 500 nm, or 200 nm.

In some non-limiting examples, the assessment of the discontinuous layer 340, including without limitation, at least one observation window used, of the exposed layer surface 11 thereof, may involve calculating, and/or measuring, by any number of mechanisms, including without limitation, manual counting, and/or known estimation techniques, which may, in some non-limiting examples, comprise curve, polygon, and/or shape fitting techniques.

In some non-limiting examples, the assessment of the discontinuous layer 340, including without limitation, at least one observation window used, of the exposed layer surface 11 thereof, may involve calculating, and/or measuring an average, median, mode, maximum, minimum, and/or other probabilistic, statistical, and/or data manipulation of a value of the calculation, and/or measurement.

In some non-limiting examples, one of the at least one criterion by which such discontinuous layer 340 may be assessed, may be a surface coverage of the deposited material 731 on such (part of the) discontinuous layer 340. In some non-limiting examples, the surface coverage may be represented by a (non-zero) percentage coverage by such deposited material 731 of such (part of the) discontinuous layer 340. In some non-limiting examples, the percentage coverage may be compared to a maximum threshold percentage coverage.

In some non-limiting examples, a (part of a) discontinuous layer 340 having surface coverage that may be substantially no more than the maximum threshold percentage coverage, may result in a manifestation of different optical characteristics that may be imparted by such part of the discontinuous layer 340, to EM radiation passing therethrough, whether transmitted entirely through the device 300, and/or emitted thereby, relative to EM radiation passing through a part of the discontinuous layer 340 having a surface coverage that substantially exceeds the maximum threshold percentage coverage.

In some non-limiting examples, one measure of a surface coverage of an amount of an electrically conductive material on a surface may be a (light) transmittance, since in some non-limiting examples, electrically conductive materials, including without limitation, metals, including without limitation: Ag, Mg, or Yb, attenuate, and/or absorb photons.

Those having ordinary skill in the relevant art will appreciate that in some non-limiting examples, surface coverage may be understood to encompass one or both of particle size, and deposited density. Thus, in some non-limiting examples, a plurality of these three criteria may be positively correlated. Indeed, in some non-limiting examples, a criterion of low surface coverage may comprise some combination of a criterion of low deposited density with a criterion of low particle size.

In some non-limiting examples, one of the at least one criterion by which such discontinuous layer 340 may be assessed, may be a characteristic size of the constituent particle structures 341.

In some non-limiting examples, the at least one particle structure 341 of the discontinuous layer 340, may have a characteristic size that is no more than a maximum threshold size. Non-limiting examples of the characteristic size may include at least one of: height, width, length, and/or diameter.

In some non-limiting examples, substantially all of the particle structures 341, of the discontinuous layer 340 may have a characteristic size that lie within a specified range.

In some non-limiting examples, such characteristic size may be characterized by a characteristic length, which in some non-limiting examples, may be considered a maximum value of the characteristic size. In some non-limiting examples, such maximum value may extend along a major axis of the particle structure 341. In some non-limiting examples, the major axis may be understood to be a first dimension extending in a plane defined by the plurality of lateral axes. In some non-limiting examples, a characteristic width may be identified as the value of the characteristic size of the particle structure 341 that may extend along a minor axis of the particle structure 341. In some non-limiting examples, the minor axis may be understood to be a second dimension extending in the same plane but substantially transverse to the major axis.

In some non-limiting examples, the characteristic length of the at least one particle structure 341, along the first dimension, may be no more than the maximum threshold size.

In some non-limiting examples, the characteristic width of the at least one particle structure 341, along the second dimension, may be no more than the maximum threshold size.

In some non-limiting examples, a size of the constituent particle structures 341, in the (part of the) discontinuous layer 340, may be assessed by calculating, and/or measuring a characteristic size of such at least one particle structure 341, including without limitation, a mass, volume, length of a diameter, perimeter, major, and/or minor axis thereof.

In some non-limiting examples, one of the at least one criterion by which such discontinuous layer 340 may be assessed, may be a deposited density thereof.

In some non-limiting examples, the characteristic size of the particle structure 341 may be compared to a maximum threshold size.

In some non-limiting examples, the deposited density of the particle structures 341 may be compared to a maximum threshold deposited density.

In some non-limiting examples, at least one of such criteria may be quantified by a numerical metric. In some non-limiting examples, such a metric may be a calculation of a dispersity D that describes the distribution of particle (area) sizes in a deposited layer 430 of particle structure 341, in which:

$$D = \frac{\overline{{S}_{s}}}{\overline{{S}_{n}}} \qquad ( 1 )$$

where:

$$\overline{{S}_{s}} = \frac{{\sum }_{i = 1}^{n} {S}_{i}^{2}}{{\sum }_{i = 1}^{n} {S}_{i}} , \overline{{S}_{n}} = \frac{{\sum }_{i = 1}^{n} {S}_{i}}{n} , \qquad ( 2 )$$

n is the number of particle structures 341 in a sample area,
Sᵢ is the (area) size of the i^{th} particle structure 341,
S̅ₙ is the number average of the particle (area) sizes and
S̅ₛ is the (area) size average of the particle (area) sizes.

Those having ordinary skill in the relevant art will appreciate that the dispersity is roughly analogous to a polydispersity index (PDI) and that these averages are roughly analogous to the concepts of number average molecular weight and weight average molecular weight familiar in organic chemistry, but applied to an (area) size, as opposed to a molecular weight of a sample particle structure 341.

Those having ordinary skill in the relevant will also appreciate that while the concept of dispersity may, in some non-limiting examples, be considered a three-dimensional volumetric concept, in some non-limiting examples, the dispersity may be considered to be a two-dimensional concept. As such, the concept of dispersity may be used in connection with viewing and analyzing two-dimensional images of the deposited layer 430, such as may be obtained by using a variety of imaging techniques, including without limitation, at least one of: TEM, AFM and/or SEM. It is in such a two-dimensional context, that the equations set out above are defined.

In some non-limiting examples, the dispersity and/or the number average of the particle (area) size and the (area) size average of the particle (area) size may involve a calculation of at least one of: the number average of the particle diameters and the (area) size average of the particle diameters:

$$\overline{{d}_{n}} = 2 \sqrt{\frac{\overline{{S}_{n}}}{π}} , \overline{{d}_{s}} = 2 \sqrt{\frac{\overline{{S}_{s}}}{π}} \qquad ( 3 )$$

In some non-limiting examples, the deposited material, including without limitation as particle structures 341, of the at least one deposited layer 430, may be deposited by a mask-free and/or open mask deposition process.

In some non-limiting examples, the particle structures 341 may have a substantially round shape. In some non-limiting examples, the particle structures 341 may have a substantially spherical shape.

For purposes of simplification, in some non-limiting examples, it may be assumed that the longitudinal extent of each particle structure 341 may be substantially the same (and, in any event, may not be directly measured from a plan view SEM image) so that the (area) size of the particle structure 341 may be represented as a two-dimensional area coverage along the pair of lateral axes. In the present disclosure, a reference to an (area) size may be understood to refer to such two-dimensional concept, and to be differentiated from a size (without the prefix “area”) that may be understood to refer to a one-dimensional concept, such as a linear dimension.

Indeed, in some early investigations, it appears that, in some non-limiting examples, the longitudinal extent, along the longitudinal axis, of such particle structures 341, may tend to be small relative to the lateral extent (along at least one of the lateral axes), such that the volumetric contribution of the longitudinal extent thereof may be much no more than that of such lateral extent. In some non-limiting examples, this may be expressed by an aspect ratio (a ratio of a longitudinal extent to a lateral extent) that may be no more than 1. In some non-limiting examples, such aspect ratio may be at least one of about: 1:10, 1:20, 1:50, 1:75, or 1:300.

In this regard, the assumption set out above (that the longitudinal extent is substantially the same and can be ignored) to represent the particle structure 341 as a two-dimensional area coverage may be appropriate.

Those having ordinary skill in the relevant art will appreciate, having regard to the non-determinative nature of the deposition process, especially in the presence of defects, and/or anomalies on the exposed layer surface 11 of the underlying material, including without limitation, heterogeneities, including without limitation, at least one of: a step edge, a chemical impurity, a bonding site, a kink, and/or a contaminant thereon, and consequently the formation of particle structures 341 thereon, the non-uniform nature of coalescence thereof as the deposition process continues, and in view of the uncertainty in the size, and/or position of observation windows, as well as the intricacies and variability inherent in the calculation, and/or measurement of their characteristic size, spacing, deposited density, degree of aggregation, and the like, there may be considerable variability in terms of the features, and/or topology within observation windows.

In the present disclosure, for purposes of simplicity of illustration, certain details of deposited materials 731, including without limitation, thickness profiles, and/or edge profiles of layer(s) have been omitted.

Those having ordinary skill in the relevant art will appreciate that certain metal NPs, whether or not as part of a discontinuous layer 340 of deposited material 731, including without limitation, at least one particle structure 341, may exhibit surface plasmon (SP) excitations, and/or coherent oscillations of free electrons, with the result that such NPs may absorb, and/or scatter light in a range of the EM spectrum, including without limitation, the visible spectrum, and/or a sub-range thereof. The optical response, including without limitation, the (sub-)range of the EM spectrum over which absorption may be concentrated (absorption spectrum), refractive index, and/or extinction spectrum, of such localized SP (LSP) excitations, and/or coherent oscillations, may be tailored by varying properties of such NPs, including without limitation, at least one of: a characteristic size, size distribution, shape, surface coverage, configuration, deposition density, dispersity, and/or property, including without limitation, material, and/or degree of aggregation, of the nanostructures, and/or a medium proximate thereto.

Such optical response, in respect of photon-absorbing coatings, may include absorption of photons incident thereon, thereby reducing reflection. In some non-limiting examples, the absorption may be concentrated in a range of the EM spectrum, including without limitation, the visible spectrum, and/or a sub-range thereof. In some non-limiting examples, employing a photon-absorbing layer as part of an opto-electronic device may reduce reliance on a polarizer therein.

It has been reported in Fusella et al., “Plasmonic enhancement of stability and brightness in organic light-emitting devices”, Nature 2020, 585, at 379-382 (“Fusella et al.”), that the stability of an OLED device may be enhanced by incorporating an NP-based outcoupling layer above the cathode layer to extract energy from the plasmon modes. The NP-based outcoupling layer was fabricated by spin-casting cubic Ag NPs on top of an organic layer on top of a cathode. However, since most commercial OLED devices are fabricated using vacuum-based processing, spin-casting from solution may not constitute an appropriate mechanism for forming such an NP-based outcoupling layer above the cathode.

It has been discovered that such an NP-based outcoupling layer above the cathode may be fabricated in vacuum (and thus, may be suitable for use in a commercial OLED fabrication process), by depositing a metal deposited material 731 in a discontinuous layer 340 onto a patterning coating 610, which in some non-limiting examples, may be, and/or be deposited on, the cathode. Such process may avoid the use of solvents or other wet chemicals that may cause damage to the OLED device, and/or may adversely impact device reliability.

In some non-limiting examples, the presence of such a discontinuous layer 340 of deposited material 731, including without limitation, at least one particle structure 341, may contribute to enhanced light extraction, performance, stability, reliability, and/or lifetime of the device.

In some non-limiting examples, the existence, in a layered device 400, of at least one discontinuous layer 340, on, and/or proximate to the exposed layer surface 11 of a patterning coating 610, and/or, in some non-limiting examples, and/or proximate to the interface of such patterning coating 610 with at least one covering layer, may impart optical effects to photons, and/or EM signals emitted by the device, and/or transmitted therethrough.

Those having ordinary skill in the relevant art will appreciate that, while a simplified model of the optical effects is presented herein, other models, and/or explanations may be applicable.

In some non-limiting examples, the presence of such a discontinuous layer 340 of the deposited material 731, including without limitation, at least one particle structure 341, may reduce, and/or mitigate crystallization of thin film layers, and/or coatings disposed adjacent in the longitudinal aspect, including without limitation, the patterning coating 610, and/or at least one covering layer, thereby stabilizing the property of the thin film(s) disposed adjacent thereto, and, in some non-limiting examples, reducing scattering. In some non-limiting examples, such thin film may be, and/or comprise at least one layer of an outcoupling, and/or encapsulating coating 1450 of the device, including without limitation, a CPL.

In some non-limiting examples, the presence of such a discontinuous layer 340 of deposited material 731, including without limitation, at least one particle structure 341, may provide an enhanced absorption in at least a part of the UV spectrum. In some non-limiting examples, controlling the characteristics of such particle structures 341, including without limitation, at least one of: characteristic size, size distribution, shape, surface coverage, configuration, deposited density, dispersity, deposited material 731, and refractive index, of the particle structures 341, may facilitate controlling the degree of absorption, wavelength range and peak wavelength of the absorption spectrum, including in the UV spectrum. Enhanced absorption of light in at least a part of the UV spectrum may be advantageous, for example, for improving device performance, stability, reliability, and/or lifetime.

In some non-limiting examples, the optical effects may be described in terms of its impact on the transmission, and/or absorption wavelength spectrum, including a wavelength range, and/or peak intensity thereof.

Additionally, while the model presented may suggest certain effects imparted on the transmission, and/or absorption of photons passing through such discontinuous layer 340, in some non-limiting examples, such effects may reflect local effects that may not be reflected on a broad, observable basis.

### Opto-Electronic Device

FIG. 10 is a simplified block diagram from a cross-sectional aspect, of an example opto-electronic device 1000 according to the present disclosure. In some non-limiting examples, the device 1000 is an OLED.

The device 1000 may comprise a substrate 10, upon which a frontplane 1010, comprising a plurality of layers, respectively, a first electrode 1020, at least one semiconducting layer 1030, and a second electrode 1040, are disposed. In some non-limiting examples, the frontplane 1010 may provide mechanisms for photon emission, and/or manipulation of emitted photons.

In some non-limiting examples, the deposited layer 430 and the underlying layer 130 may together form at least a part of at least one of the first electrode 1020 and the second electrode 1040 of the device 800. In some non-limiting examples, the deposited layer 430 and the underlying layer 130 thereunder may together form at least a part of a cathode of the device 1000.

In some non-limiting examples, the device 1000 may be electrically coupled with a power source 1005. When so coupled, the device 1000 may emit photons as described herein.

Substrate

In some examples, the substrate 10 may comprise a base substrate 1012. In some examples, the base substrate 1012 may be formed of material suitable for use thereof, including without limitation, an inorganic material, including without limitation, silicon (Si), glass, metal (including without limitation, a metal foil), sapphire, and/or other inorganic material, and/or an organic material, including without limitation, a polymer, including without limitation, a polyimide, and/or a silicon-based polymer. In some examples, the base substrate 1012 may be rigid or flexible. In some examples, the substrate 10 may be defined by at least one planar surface. In some non-limiting examples, the substrate 10 may have at least one surface that supports the remaining frontplane 1010 components of the device 1000, including without limitation, the first electrode 1020, the at least one semiconducting layer 1030, and/or the second electrode 1040.

In some non-limiting examples, such surface may be an organic surface, and/or an inorganic surface.

In some examples, the substrate 10 may comprise, in addition to the base substrate 1012, at least one additional organic, and/or inorganic layer (not shown nor specifically described herein) supported on an exposed layer surface 11 of the base substrate 1012.

In some non-limiting examples, such additional layers may comprise, and/or form at least one organic layers, which may comprise, replace, and/or supplement at least one of the at least one semiconducting layers 1030.

In some non-limiting examples, such additional layers may comprise at least one inorganic layers, which may comprise, and/or form at least one electrode, which in some non-limiting examples, may comprise, replace, and/or supplement the first electrode 1020, and/or the second electrode 1040.

In some non-limiting examples, such additional layers may comprise, and/or be formed of, and/or as a backplane 1015. In some non-limiting examples, the backplane 1015 may contain power circuitry, and/or switching elements for driving the device 1000, including without limitation, electronic TFT structure(s) 1101 (FIG. 11), and/or component(s) thereof, that may be formed by a photolithography process, which may not be provided under, and/or may precede the introduction of low pressure (including without limitation, a vacuum) environment.

Backplane and TFT Structure(s) Embodied Therein

In some non-limiting examples, the backplane 1015 of the substrate 10 may comprise at least one electronic, and/or opto-electronic component, including without limitation, transistors, resistors, and/or capacitors, such as which may support the device 1000 acting as an active-matrix, and/or a passive matrix device. In some non-limiting examples, such structures may be a thin-film transistor (TFT) structure 1101.

Non-limiting examples of TFT structures 1101 include top-gate, bottom-gate, n-type and/or p-type TFT structures 1101. In some non-limiting examples, the TFT structure 1101 may incorporate any at least one of amorphous Si (a-Si), indium gallium zinc (Zn) oxide (IGZO), and/or low-temperature polycrystalline Si (LTPS).

First Electrode

The first electrode 1020 may be deposited over the substrate 10. In some non-limiting examples, the first electrode 1020 may be electrically coupled with a terminal of the power source 1005, and/or to ground. In some non-limiting examples, the first electrode 1020 may be so coupled through at least one driving circuit which in some non-limiting examples, may incorporate at least one TFT structure 1101 in the backplane 1015 of the substrate 10.

In some non-limiting examples, the first electrode 1020 may comprise an anode, and/or a cathode. In some non-limiting examples, the first electrode 1020 may be an anode.

In some non-limiting examples, the first electrode 1020 may be formed by depositing at least one thin conductive film, over (a portion of) the substrate 10. In some non-limiting examples, there may be a plurality of first electrodes 1020, disposed in a spatial arrangement over a lateral aspect of the substrate 10. In some non-limiting examples, at least one of such at least one first electrode 1020 may be deposited over (a part of) a TFT insulating layer 1109 (FIG. 11) disposed in a lateral aspect in a spatial arrangement. If so, in some non-limiting examples, at least one of such at least one first electrode 1020 may extend through an opening of the corresponding TFT insulating layer 1109 to be electrically coupled with an electrode of the TFT structures 1101 in the backplane 1015.

In some non-limiting examples, the at least one first electrode 1020, and/or at least one thin film thereof, may comprise various materials, including without limitation, at least one metallic materials, including without limitation, at least one of: Mg, Al, calcium (Ca), Zn, Ag, Cd, Ba, or Yb, or combinations of any plurality thereof, including without limitation, alloys containing any of such materials, at least one metal oxide, including without limitation, a transparent conducting oxide (TCO), including without limitation, ternary compositions such as, without limitation, fluorine tin oxide (FTO), indium zinc oxide (IZO), or indium tin oxide (ITO), or combinations of any plurality thereof, or in varying proportions, or combinations of any plurality thereof in at least one layer, any at least one of which may be, without limitation, a thin film.

Second Electrode

The second electrode 1040 may be deposited over the at least one semiconducting layer 1030. In some non-limiting examples, the second electrode 1040 may be electrically coupled with a terminal of the power source 1005, and/or with ground. In some non-limiting examples, the second electrode 1040 may be so coupled through at least one driving circuit, which in some non-limiting examples, may incorporate at least one TFT structure 1101 in the backplane 1015 of the substrate 10.

In some non-limiting examples, the second electrode 1040 may comprise an anode, and/or a cathode. In some non-limiting examples, the second electrode 1040 may be a cathode.

In some non-limiting examples, the second electrode 1040 may be formed by depositing a deposited layer 430, in some non-limiting examples, as at least one thin film, over (a part of) the at least one semiconducting layer 1030. In some non-limiting examples, there may be a plurality of second electrodes 1040, disposed in a spatial arrangement over a lateral aspect of the at least one semiconducting layer 1030.

In some non-limiting examples, the at least one second electrode 1040 may comprise various materials, including without limitation, at least one metallic material, including without limitation, at least one of: Mg, Al, Ca, Zn, Ag, Cd, Ba, or Yb, or combinations of any plurality thereof, including without limitation, alloys containing any of such materials, at least one metal oxides, including without limitation, a TCO, including without limitation, ternary compositions such as, without limitation, FTO, IZO, or ITO, or combinations of any plurality thereof, or in varying proportions, or zinc oxide (ZnO), or other oxides containing indium (In), or Zn, or combinations of any plurality thereof in at least one layer, and/or at least one non-metallic materials, any at least one of which may be, without limitation, a thin conductive film. In some non-limiting examples, for a Mg:Ag alloy, such alloy composition may range between about 1:9-9:1 by volume.

In some non-limiting examples, the deposition of the second electrode 1040 may be performed using an open mask and/or a mask-free deposition process.

In some non-limiting examples, the second electrode 1040 may comprise a plurality of such layers, and/or coatings. In some non-limiting examples, such layers, and/or coatings may be distinct layers, and/or coatings disposed on top of one another.

In some non-limiting examples, the second electrode 1040 may comprise a Yb/Ag bi-layer coating. By way of non-limiting examples, such bi-layer coating may be formed by depositing a Yb coating, followed by an Ag coating. In some non-limiting examples, a thickness of such Ag coating may exceed a thickness of the Yb coating.

In some non-limiting examples, the second electrode 1040 may be a multi-layer electrode 1040 comprising at least one metallic layer, and/or at least one oxide layer.

In some non-limiting examples, the second electrode 1040 may comprise a fullerene and Mg.

By way of non-limiting examples, such coating may be formed by depositing a fullerene coating followed by an Mg coating. In some non-limiting examples, a fullerene may be dispersed within the Mg coating to form a fullerene-containing Mg alloy coating. Non-limiting examples of such coatings are described in United States Patent Application Publication No. 2015/0287846 published 8 Oct. 2015, and/or in PCT International Application No. PCT/IB2017/054970 filed 15 Aug. 2017 and published as WO2018/033860 on 22 Feb. 2018.

Semiconducting Layer

In some non-limiting examples, the at least one semiconducting layer 1030 may comprise a plurality of layers 1031, 1033, 1035, 1037, 1039, any of which may be disposed, in some non-limiting examples, in a thin film, in a stacked configuration, which may include, without limitation, at least one of a hole injection layer (HIL) 1031, a hole transport layer (HTL) 1033, an emissive layer (EML) 1035, an ETL 1037, and/or an EIL 1039.

In some non-limiting examples, the at least one semiconducting layer 1030 may form a “tandem” structure comprising a plurality of EMLs 1035. In some non-limiting examples, such tandem structure may also comprise at least one charge generation layer (CGL).

Those having ordinary skill in the relevant art will readily appreciate that the structure of the device 1000 may be varied by omitting, and/or combining at least one of the semiconductor layers 1031, 1033, 1035, 1037, 1039.

Further, any of the layers 1031, 1033, 1035, 1037, 1039 of the at least one semiconducting layer 1030 may comprise any number of sub-layers. Still further, any of such layers 1031, 1033, 1035, 1037, 1039, and/or sub-layer(s) thereof may comprise various mixture(s), and/or composition gradient(s). In addition, those having ordinary skill in the relevant art will appreciate that the device 1000 may comprise at least one layer comprising inorganic, and/or organometallic materials and may not be necessarily limited to devices comprised solely of organic materials. By way of non-limiting example, the device 1000 may comprise at least one QD.

In some non-limiting examples, the HIL 1031 may be formed using a hole injection material, which may facilitate injection of holes by the anode.

In some non-limiting examples, the HTL 1033 may be formed using a hole transport material, which may, in some non-limiting examples, exhibit high hole mobility.

In some non-limiting examples, the ETL 1037 may be formed using an electron transport material, which may, in some non-limiting examples, exhibit high electron mobility.

In some non-limiting examples, the EIL 1039 may be formed using an electron injection material, which may facilitate injection of electrons by the cathode.

In some non-limiting examples, the EML 1035 may be formed, by way of non-limiting example, by doping a host material with at least one emitter material. In some non-limiting examples, the emitter material may be a fluorescent emitter, a phosphorescent emitter, a thermally activated delayed fluorescence (TADF) emitter, and/or a plurality of any combination of these.

In some non-limiting examples, the device 1000 may be an OLED in which the at least one semiconducting layer 1030 comprises at least an EML 1035 interposed between conductive thin film electrodes 1020, 1040, whereby, when a potential difference is applied across them, holes may be injected into the at least one semiconducting layer 1030 through the anode and electrons may be injected into the at least one semiconducting layer 1030 through the cathode, migrate toward the EML 1035 and combine to emit EM radiation in the form of photons.

In some non-limiting examples, the device 1000 may be an electro-luminescent QD device in which the at least one semiconducting layer 1030 may comprise an active layer comprising at least one QD. When current may be provided by the power source 1005 to the first electrode 1020 and second electrode 1040, photons may be emitted from the active layer comprising the at least one semiconducting layer 1030 between them.

Those having ordinary skill in the relevant art will readily appreciate that the structure of the device 1000 may be varied by the introduction of at least one additional layer (not shown) at appropriate position(s) within the at least one semiconducting layer 1030 stack, including without limitation, a hole blocking layer (HBL) (not shown), an electron blocking layer (EBL) (not shown), an additional charge transport layer (CTL) (not shown), and/or an additional charge injection layer (CIL) (not shown).

In some non-limiting examples, including where the OLED device 1000 comprises a lighting panel, an entire lateral aspect of the device 1000 may correspond to a single emissive element. As such, the substantially planar cross-sectional profile shown in FIG. 10 may extend substantially along the entire lateral aspect of the device 1000, such that EM radiation is emitted from the device 1000 substantially along the entirety of the lateral extent thereof. In some non-limiting examples, such single emissive element may be driven by a single driving circuit of the device 1000.

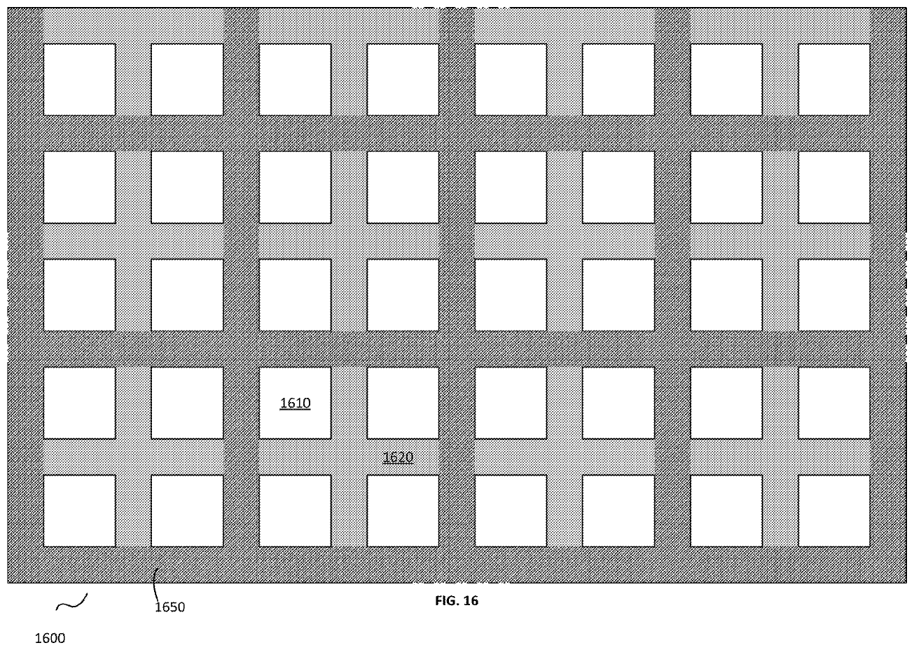

In some non-limiting examples, including where the OLED device 1000 comprises a display module, the lateral aspect of the device 1000 may be sub-divided into a plurality of emissive regions 1610 (FIG. 16) of the device 1000, in which the cross-sectional aspect of the device structure 1000, within each of the emissive region(s) 1610 shown, without limitation, in FIG. 16 may cause EM radiation to be emitted therefrom when energized.

### Emissive Regions

In some non-limiting examples, such as may be shown by way of non-limiting example in FIG. 11, an active region 1130 of an emissive region 1610 may be defined to be bounded, in the transverse aspect, by the first electrode 1020 and the second electrode 1040, and to be confined, in the lateral aspect, to an emissive region 1610 defined by the first electrode 1020 and the second electrode 1040. Those having ordinary skill in the relevant art will appreciate that the lateral extent of the emissive region 1610, and thus the lateral boundaries of the active region 1130, may not correspond to the entire lateral aspect of either, or both, of the first electrode 1020 and the second electrode 1040. Rather, the lateral extent of the emissive region 1610 may be substantially no more than the lateral extent of either the first electrode 1020 and the second electrode 1040. By way of non-limiting example, parts of the first electrode 1020 may be covered by the pixel definition layer(s) (PDL) 1140 (FIG. 11) and/or parts of the second electrode 1040 may not be disposed on the at least one semiconducting layer 1030, with the result, in either, or both, scenarios, that the emissive region 1610 may be laterally constrained.

In some non-limiting examples, individual emissive regions 1610 of the device 1000 may be laid out in a lateral pattern. In some non-limiting examples, the pattern may extend along a first lateral direction. In some non-limiting examples, the pattern may also extend along a second lateral direction, which in some non-limiting examples, may be substantially normal to the first lateral direction. In some non-limiting examples, the pattern may have a number of elements in such pattern, each element being characterized by at least one feature thereof, including without limitation, a wavelength of light emitted by the emissive region 1610 thereof, a shape of such emissive region 1610, a dimension (along either, or both of, the first, and/or second lateral direction(s)), an orientation (relative to either, and/or both of the first, and/or second lateral direction(s)), and/or a spacing (relative to either, or both of, the first, and/or second lateral direction(s)) from a previous element in the pattern. In some non-limiting examples, the pattern may repeat in either, or both of, the first and/or second lateral direction(s).

In some non-limiting examples, each individual emissive region 1610 of the device 1000 may be associated with, and driven by, a corresponding driving circuit within the backplane 1015 of the device 1000, for driving an OLED structure for the associated emissive region 1610. In some non-limiting examples, including without limitation, where the emissive regions 1610 may be laid out in a regular pattern extending in both the first (row) lateral direction and the second (column) lateral direction, there may be a signal line in the backplane 1015, corresponding to each row of emissive regions 1610 extending in the first lateral direction and a signal line, corresponding to each column of emissive regions 1610 extending in the second lateral direction. In such a non-limiting configuration, a signal on a row selection line may energize the respective gates of the switching TFT(s) 1101 electrically coupled therewith and a signal on a data line may energize the respective sources of the switching TFT(s) 1101 electrically coupled therewith, such that a signal on a row selection line/data line pair may electrically couple and energise, by the positive terminal of the power source 1005, the anode of the OLED structure of the emissive region 1610 associated with such pair, causing the emission of a photon therefrom, the cathode thereof being electrically coupled with the negative terminal of the power source 1005.

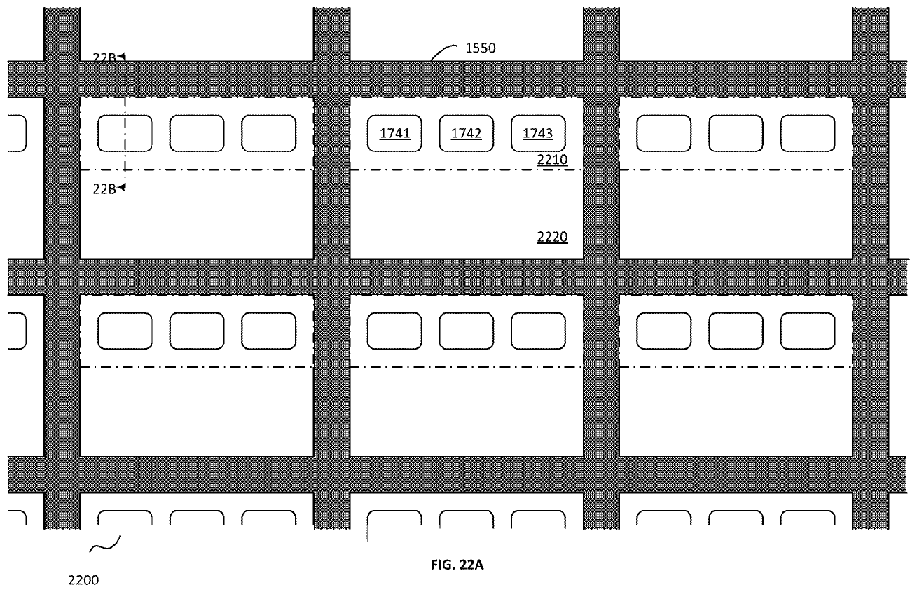

In some non-limiting examples, each emissive region 1610 of the device 1000 may correspond to a single display pixel 2210 (FIG. 22A). In some non-limiting examples, each pixel 2210 may emit light at a given wavelength spectrum. In some non-limiting examples, the wavelength spectrum may correspond to a colour in, without limitation, the visible spectrum.

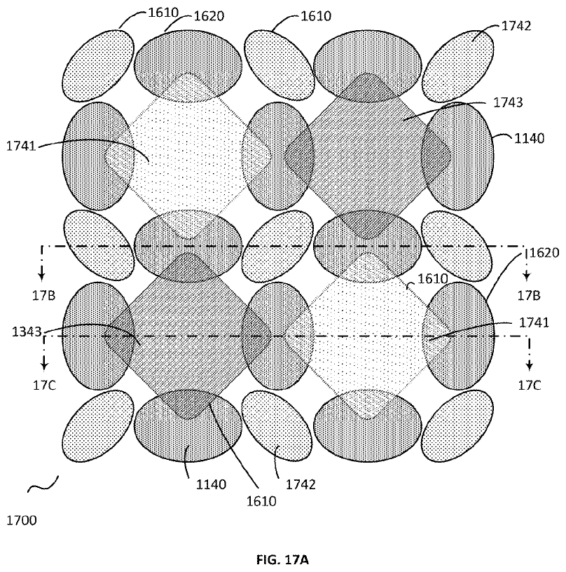

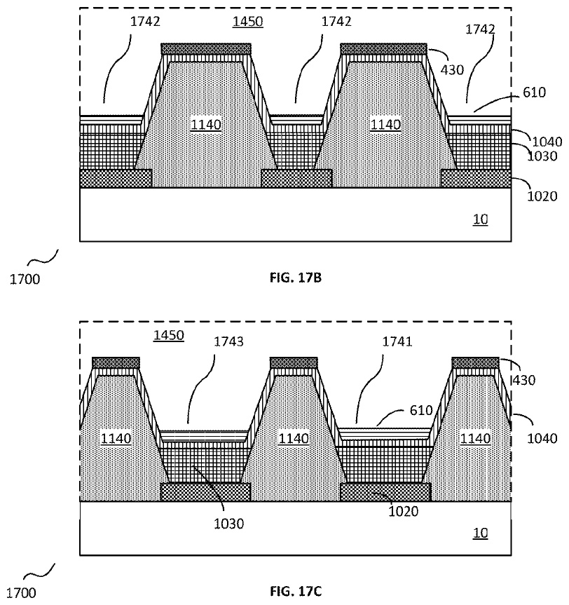

In some non-limiting examples, each emissive region 1610 of the device 1000 may correspond to a sub-pixel 174x (FIG. 17A) of a display pixel 2210. In some non-limiting examples, a plurality of sub-pixels 174x may combine to form, or to represent, a single display pixel 2210.

In some non-limiting examples, a single display pixel 2210 may be represented by three sub-pixels 174x. In some non-limiting examples, the three sub-pixels 174x may be denoted as, respectively, R(ed) sub-pixels 1741, G(reen) sub-pixels 1742, and/or B(lue) sub-pixels 1743. In some non-limiting examples, a single display pixel 2210 may be represented by four sub-pixels 174x, in which three of such sub-pixels 174x may be denoted as R(ed), G(reen) and B(lue) sub-pixels 174x and the fourth sub-pixel 174x may be denoted as a W(hite) sub-pixel 174x. In some non-limiting examples, the emission spectrum of the EM radiation emitted by a given sub-pixel 174x may correspond to the colour by which the sub-pixel 174x is denoted. In some non-limiting examples, the wavelength of the EM radiation may not correspond to such colour, but further processing may be performed, in a manner apparent to those having ordinary skill in the relevant art, to transform the wavelength to one that does so correspond.

Since the wavelength of sub-pixels 174x of different colours may be different, the optical characteristics of such sub-pixels 174x may differ, especially if a common electrode 1020, 1040 having a substantially uniform thickness profile may be employed for sub-pixels 174x of different colours.

When a common electrode 1020, 1040 having a substantially uniform thickness may be provided as the second electrode 1040 in a device 800, the optical performance of the device 800 may not be readily fine-tuned according to an emission spectrum associated with each (sub-)pixel 2210/174x. The second electrode 1040 used in such OLED devices 1000 may in some non-limiting examples, be a common electrode 1020, 1040 coating a plurality of (sub-)pixels 2210/174x. By way of non-limiting example, such common electrode 1020, 1040 may be a relatively thin conductive film having a substantially uniform thickness across the device 1000. While efforts have been made in some non-limiting examples, to tune the optical microcavity effects associated with each (sub-)pixel 2210/174x color by varying a thickness of organic layers disposed within different (sub-)pixel(s) 2210/174x, such approach may, in some non-limiting examples, provide a significant degree of tuning of the optical microcavity effects in at least some cases. In addition, in some non-limiting examples, such approach may be difficult to implement in an OLED display production environment.

As a result, the presence of optical interfaces created by numerous thin-film layers and coatings with different refractive indices, such as may in some non-limiting examples be used to construct opto-electronic devices including without limitation OLED devices 1000, may create different optical microcavity effects for sub-pixels 174x of different colours.

Some factors that may impact an observed microcavity effect in a device 1000 include, without limitation, a total path length (which in some non-limiting examples may correspond to a total thickness (in the longitudinal aspect) of the device 1000 through which EM radiation emitted therefrom will travel before being outcoupled) and the refractive indices of various layers and coatings.

In some non-limiting examples, modulating a thickness of an electrode 1020, 1040 in and across a lateral aspect of emissive region(s) 1610 of a (sub-) pixel 2210/174x may impact the microcavity effect observable. In some non-limiting examples, such impact may be attributable to a change in the total optical path length.

In some non-limiting examples, a change in a thickness of the electrode 1020, 1040 may also change the refractive index of light passing therethrough, in some non-limiting examples, in addition to a change in the total optical path length. In some non-limiting examples, this may be particularly the case where the electrode 1020, 1040 may be formed of at least one deposited layer 430.

In some non-limiting examples, the optical properties of the device 1000, and/or in some non-limiting examples, across the lateral aspect of emissive region(s) 1610 of a (sub-) pixel 2210/174x that may be varied by modulating at least one optical microcavity effect, may include, without limitation, the emission spectrum, the intensity (including without limitation, luminous intensity), and/or angular distribution of emitted EM radiation, including without limitation, an angular dependence of a brightness, and/or color shift of the emitted light.

In some non-limiting examples, a sub-pixel 174x may be associated with a first set of other sub-pixels 174x to represent a first display pixel 2210 and also with a second set of other sub-pixels 174x to represent a second display pixel 2210, so that the first and second display pixels 2210 may have associated therewith, the same sub-pixel(s) 174x.

The pattern, and/or organization of sub-pixels 174x into display pixels 2210 continues to develop. All present and future patterns, and/or organizations are considered to fall within the scope of the present disclosure.

### Non-Emissive Regions

In some non-limiting examples, the various emissive regions 1610 of the device 1000 may be substantially surrounded and separated by, in at least one lateral direction, at least one non-emissive region 1620 (FIG. 16), in which the structure, and/or configuration along the cross-sectional aspect, of the device structure 1000 shown, without limitation, in FIG. 10, may be varied, to substantially inhibit photons to be emitted therefrom. In some non-limiting examples, the non-emissive regions 1620 may comprise those regions in the lateral aspect, that are substantially devoid of an emissive region 1610.

Thus, as shown in the cross-sectional view of FIG. 11, the lateral topology of the various layers of the at least one semiconducting layer 1030 may be varied to define at least one emissive region 1610, surrounded (at least in one lateral direction) by at least one non-emissive region 1620.

In some non-limiting examples, the emissive region 1610 corresponding to a single display (sub-) pixel 2210/174x may be understood to have a lateral aspect 1110, surrounded in at least one lateral direction by at least one non-emissive region 1620 having a lateral aspect 1120.

A non-limiting example of an implementation of the cross-sectional aspect of the device 1000 as applied to an emissive region 1610 corresponding to a single display (sub-) pixel 2210/174x of an OLED display 1000 will now be described. While features of such implementation are shown to be specific to the emissive region 1610, those having ordinary skill in the relevant art will appreciate that in some non-limiting examples, more than one emissive region 1610 may encompass common features.

In some non-limiting examples, the first electrode 1020 may be disposed over an exposed layer surface 11 of the device 1000, in some non-limiting examples, within at least a part of the lateral aspect 1110 of the emissive region 1610. In some non-limiting examples, at least within the lateral aspect 1110 of the emissive region 1610 of the (sub-) pixel(s) 2210/174x, the exposed layer surface 11, may, at the time of deposition of the first electrode 1020, comprise the TFT insulating layer 1109 of the various TFT structures 1101 that make up the driving circuit for the emissive region 1610 corresponding to a single display (sub-) pixel 2210/174x.

In some non-limiting examples, the TFT insulating layer 1109 may be formed with an opening extending therethrough to permit the first electrode 1020 to be electrically coupled with one of the TFT electrodes 1105, 1107, 1108, including, without limitation, as shown in FIG. 11, the TFT drain electrode 1108.

Those having ordinary skill in the relevant art will appreciate that the driving circuit comprises a plurality of TFT structures 1101. In FIG. 11, for purposes of simplicity of illustration, only one TFT structure 1101 may be shown, but it will be appreciated by those having ordinary skill in the relevant art, that such TFT structure 1101 may be representative of such plurality thereof that comprise the driving circuit.

In a cross-sectional aspect, the configuration of each emissive region 1610 may, in some non-limiting examples, be defined by the introduction of at least one PDL 1140 substantially throughout the lateral aspects 1120 of the surrounding non-emissive region(s) 1620. In some non-limiting examples, the PDLs 1140 may comprise an insulating organic, and/or inorganic material.

In some non-limiting examples, the PDLs 1140 may be deposited substantially over the TFT insulating layer 1109, although, as shown, in some non-limiting examples, the PDLs 1140 may also extend over at least a part of the deposited first electrode 1020, and/or its outer edges.

In some non-limiting examples, as shown in FIG. 11, the cross-sectional thickness, and/or profile of the PDLs 1140 may impart a substantially valley-shaped configuration to the emissive region 1610 of each (sub-) pixel 2210/174x by a region of increased thickness along a boundary of the lateral aspect 1120 of the surrounding non-emissive region 1620 with the lateral aspect 1110 of the surrounded emissive region 1610, corresponding to a (sub-) pixel 2210/174x.

In some non-limiting examples, the profile of the PDLs 1140 may have a reduced thickness beyond such valley-shaped configuration, including without limitation, away from the boundary between the lateral aspect 1120 of the surrounding non-emissive region 1620 and the lateral aspect 1110 of the surrounded emissive region 1610, in some non-limiting examples, substantially well within the lateral aspect 1120 of such non-emissive region 1620.

While the PDL(s) 1140 have been generally illustrated as having a linearly sloped surface to form a valley-shaped configuration that define the emissive region(s) 1610 surrounded thereby, those having ordinary skill in the relevant art will appreciate that in some non-limiting examples, at least one of the shape, aspect ratio, thickness, width, and/or configuration of such PDL(s) 1140 may be varied. By way of non-limiting example, a PDL 1140 may be formed with a more steep or more gradually sloped part. In some non-limiting examples, such PDL(s) 1140 may be configured to extend substantially normally away from a surface on which it is deposited, that may cover at least one edges of the first electrode 1020. In some non-limiting examples, such PDL(s) 1140 may be configured to have deposited thereon at least one semiconducting layer 1030 by a solution-processing technology, including without limitation, by printing, including without limitation, ink-jet printing.

In some non-limiting examples, the at least one semiconducting layer 1030 may be deposited over the exposed layer surface 11 of the device 1000, including at least a part of the lateral aspect 1110 of such emissive region 1610 of the (sub-) pixel(s) 2210/174x. In some non-limiting examples, at least within the lateral aspect 1110 of the emissive region 1610 of the (sub-) pixel(s) 2210/174x, such exposed layer surface 11, may, at the time of deposition of the at least one semiconducting layer 1030 (and/or layers 1031, 1033, 1035, 1037, 1039 thereof), comprise the first electrode 1020.

In some non-limiting examples, the at least one semiconducting layer 1030 may also extend beyond the lateral aspect 1110 of the emissive region 1610 of the (sub-) pixel(s) 2210/174x and at least partially within the lateral aspects 1120 of the surrounding non-emissive region(s) 1620. In some non-limiting examples, such exposed layer surface 11 of such surrounding non-emissive region(s) 1620 may, at the time of deposition of the at least one semiconducting layer 1030, comprise the PDL(s) 1140.

In some non-limiting examples, the second electrode 1040 may be disposed over an exposed layer surface 11 of the device 1000, including at least a part of the lateral aspect 1110 of the emissive region 1610 of the (sub-) pixel(s) 2210/174x. In some non-limiting examples, at least within the lateral aspect 1110 of the emissive region 1610 of the (sub-) pixel(s) 2210/174x, such exposed layer surface 11, may, at the time of deposition of the second electrode 1020, comprise the at least one semiconducting layer 1030.

In some non-limiting examples, the second electrode 1040 may also extend beyond the lateral aspect 1110 of the emissive region 1610 of the (sub-) pixel(s) 2210/174x and at least partially within the lateral aspects 1120 of the surrounding non-emissive region(s) 1620. In some non-limiting examples, such exposed layer surface 11 of such surrounding non-emissive region(s) 1620 may, at the time of deposition of the second electrode 1040, comprise the PDL(s) 1140.

In some non-limiting examples, the second electrode 1040 may extend throughout substantially all or a substantial part of the lateral aspects 1120 of the surrounding non-emissive region(s) 1620.

### Selective Deposition of Patterned Electrode

In some non-limiting examples, the ability to achieve selective deposition of the deposited material 731 in an open mask and/or mask-free deposition process by the prior selective deposition of a patterning coating 610, may be employed to achieve the selective deposition of a patterned electrode 1020, 1040, 1550, and/or at least one layer thereof, of an opto-electronic device, including without limitation, an OLED device 1000, and/or a conductive element electrically coupled therewith.

In this fashion, the selective deposition of a patterning coating 610 as the patterning coating 610 in FIG. 4 using a shadow mask 615, and the open mask and/or mask-free deposition of the deposited material 731, may be combined to effect the selective deposition of at least one deposited layer 430 to form a device feature, including without limitation, a patterned electrode 1020, 1040, 1550, and/or at least one layer thereof, and/or a conductive element electrically coupled therewith, in the device 700a shown in FIG. 7, without employing shadow mask 615 within the deposition process for forming the deposited layer 430. In some non-limiting examples, such patterning may permit, and/or enhance the transmissivity of the device 700a.

A number of non-limiting examples of such patterned electrodes 1020, 1040, 1550, and/or at least one layer thereof, and/or a conductive element electrically coupled therewith, to impart various structural and/or performance capabilities to such devices 1000 will now be described.

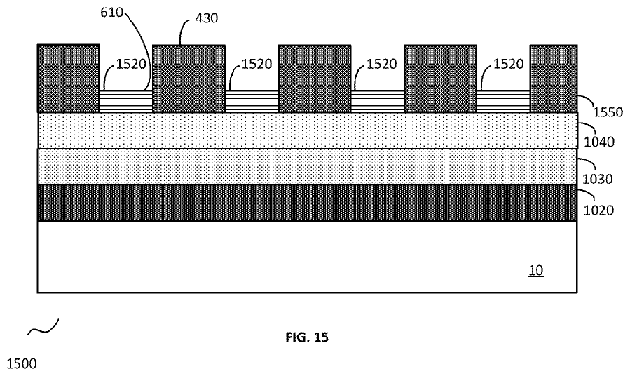

As a result of the foregoing, there may be an aim to selectively deposit, across the lateral aspect 1110 of the emissive region 1610 of a (sub-) pixel 2210/174x, and/or the lateral aspect 1120 of the non-emissive region(s) 1620 surrounding the emissive region 1610, a device feature, including without limitation, at least one of the first electrode 1020, the second electrode 1040, the auxiliary electrode 1550 (FIG. 15), and/or a conductive element electrically coupled therewith, in a pattern, on an exposed layer surface 11 of a frontplane 1010 of the device 1000. In some non-limiting examples, the first electrode 1020, the second electrode 1040, and/or the auxiliary electrode 1550, may be deposited in at least one of a plurality of deposited layers 430.

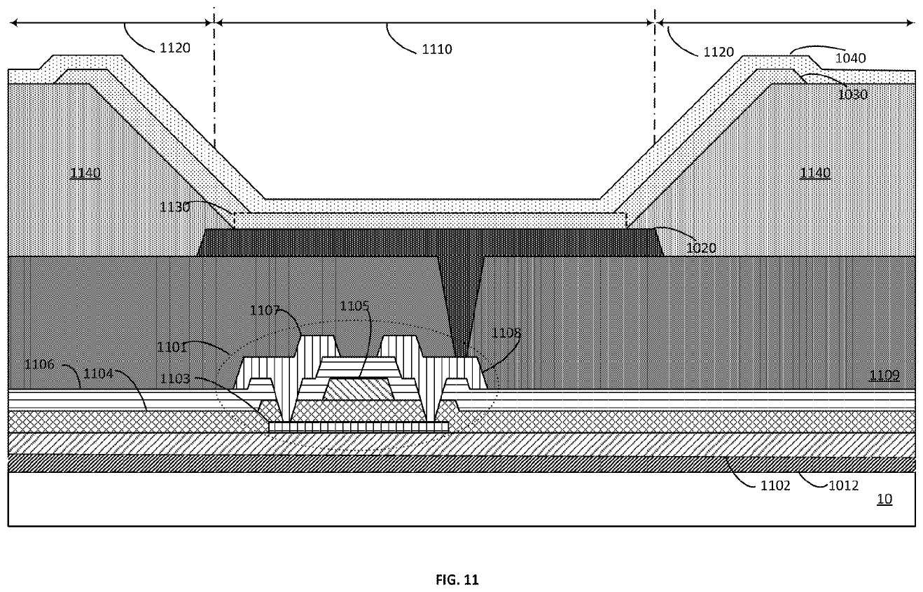

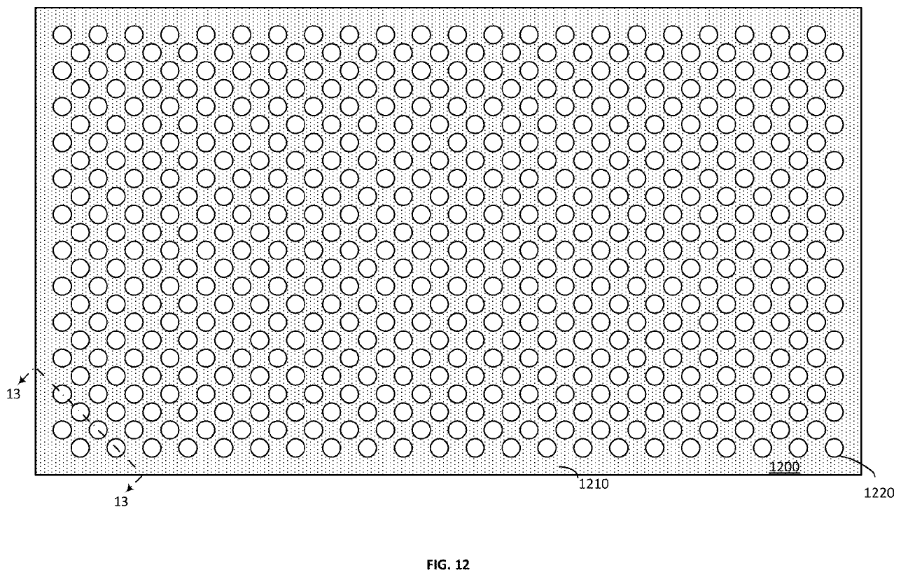

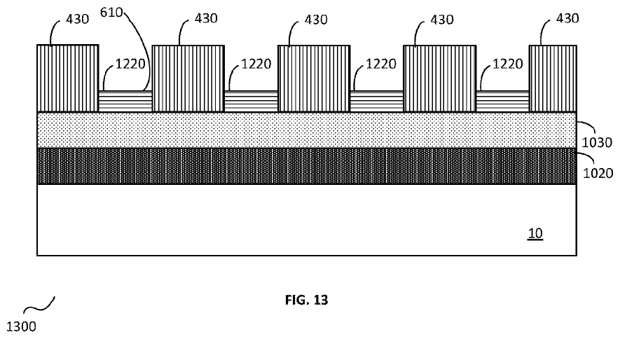

FIG. 12 may show an example patterned electrode 1200 in plan view, in the figure, the second electrode 1040 suitable for use in an example version 1300 (FIG. 13) of the device 1000. The electrode 1200 may be formed in a pattern 1210 that comprises a single continuous structure, having or defining a patterned plurality of apertures 1220 therewithin, in which the apertures 1220 may correspond to regions of the device 1200 where there is no cathode.

In the figure, by way of non-limiting example, the pattern 1210 may be disposed across the entire lateral extent of the device 1000, without differentiation between the lateral aspect(s) 1110 of emissive region(s) 1610 corresponding to (sub-) pixel(s) 2210/174x and the lateral aspect(s) 1120 of non-emissive region(s) 1620 surrounding such emissive region(s) 1610. Thus, the example illustrated may correspond to a device 1300 that may be substantially transmissive relative to light incident on an external surface thereof, such that a substantial part of such externally-incident light may be transmitted through the device 1300, in addition to the emission (in a top-emission, bottom-emission, and/or double-sided emission) of photons generated internally within the device 1300 as disclosed herein.

The transmittivity of the device 1300 may be adjusted, and/or modified by altering the pattern 1210 employed, including without limitation, an average size of the apertures 1220, and/or a spacing, and/or density of the apertures 1220.

Turning now to FIG. 13, there may be shown a cross-sectional view of the device 1300, taken along line 13-13 in FIG. 12. In the figure, the device 1300 may be shown as comprising the substrate 10, the first electrode 1020 and the at least one semiconducting layer 1030.

A patterning coating 610 may be selectively disposed in a pattern substantially corresponding to the pattern 1210 on the exposed layer surface 11 of the underlying layer 130.

A deposited layer 430 suitable for forming the patterned electrode 1200, which in the figure is the second electrode 1040, may be disposed on substantially all of the exposed layer surface 11 of the underlying layer 130, using an open mask and/or a mask-free deposition process. The underlying layer 130 may comprise both regions of the patterning coating 610, disposed in the pattern 1210, and regions of the at least one semiconducting layer 1030, in the pattern 1210 where the patterning coating 610 has not been deposited. In some non-limiting examples, the regions of the patterning coating 610 may correspond substantially to a first portion 601 comprising the apertures 1220 shown in the pattern 1210.

Because of the nucleation-inhibiting properties of those regions of the pattern 1210 where the patterning coating 610 was disposed (corresponding to the apertures 1220), the deposited material 731 disposed on such regions may tend to not remain, resulting in a pattern of selective deposition of the deposited layer 430, that may correspond substantially to the remainder of the pattern 1210, leaving those regions of the first portion 601 of the pattern 1210 corresponding to the apertures 1220 substantially devoid of a closed coating 440 of the deposited layer 430.

In other words, the deposited layer 430 that will form the cathode may be selectively deposited substantially only on a second portion 602 comprising those regions of the at least one semiconducting layer 1030 that surround but do not occupy the apertures 1220 in the pattern 1210.

FIG. 14A may show, in plan view, a schematic diagram showing a plurality of patterns 1410, 1420 of electrodes 1020, 1040, 1550.

In some non-limiting examples, the first pattern 1410 may comprise a plurality of elongated, spaced-apart regions that extend in a first lateral direction. In some non-limiting examples, the first pattern 1410 may comprise a plurality of first electrodes 1020. In some non-limiting examples, a plurality of the regions that comprise the first pattern 1410 may be electrically coupled.

In some non-limiting examples, the second pattern 1420 may comprise a plurality of elongated, spaced-apart regions that extend in a second lateral direction. In some non-limiting examples, the second lateral direction may be substantially normal to the first lateral direction. In some non-limiting examples, the second pattern 1420 may comprise a plurality of second electrodes 1040. In some non-limiting examples, a plurality of the regions that comprise the second pattern 1420 may be electrically coupled.

In some non-limiting examples, the first pattern 1410 and the second pattern 1420 may form part of an example version, shown generally at 1400 of the device 1000.

In some non-limiting examples, the lateral aspect(s) 1110 of emissive region(s) 1610 corresponding to (sub-) pixel(s) 2210/174x may be formed where the first pattern 1410 overlaps the second pattern 1420. In some non-limiting examples, the lateral aspect(s) 1120 of non-emissive region 1620 may correspond to any lateral aspect other than the lateral aspect(s) 1110.

In some non-limiting examples, a first terminal, which, in some non-limiting examples, may be a positive terminal, of the power source 1005, may be electrically coupled with at least one electrode 1020, 1040, 1550 of the first pattern 1410. In some non-limiting examples, the first terminal may be coupled with the at least one electrode 1020, 1040, 1550 of the first pattern 1410 through at least one driving circuit. In some non-limiting examples, a second terminal, which, in some non-limiting examples, may be a negative terminal, of the power source 1005, may be electrically coupled with at least one electrode 1020, 1040, 1550 of the second pattern 1420. In some non-limiting examples, the second terminal may be coupled with the at least one electrode 1020, 1040, 1550 of the second pattern 1420 through the at least one driving circuit.

Turning now to FIG. 14B, there may be shown a cross-sectional view of the device 1400, at a deposition stage 1400b, taken along line 14B-14B in FIG. 14A. In the figure, the device 1400 at the stage 1400b may be shown as comprising the substrate 10.

A patterning coating 610 may be selectively disposed in a pattern substantially corresponding to the inverse of the first pattern 1410 on the exposed layer surface 11 of the underlying layer 130, which, as shown in the figure, may be the substrate 10.

A deposited layer 430 suitable for forming the first pattern 1410 of electrodes 1020, 1040, 1550, which in the figure is the first electrode 1020, may be disposed on substantially all of the exposed layer surface 11 of the underlying layer 130, using an open mask and/or a mask-free deposition process. The underlying layer 130 may comprise both regions of the patterning coating 610, disposed in the inverse of the first pattern 1410, and regions of the substrate 10, disposed in the first pattern 1410 where the patterning coating 610 has not been deposited. In some non-limiting examples, the regions of the substrate 10 may correspond substantially to the elongated spaced-apart regions of the first pattern 1410, while the regions of the patterning coating 610 may correspond substantially to a first portion 601 comprising the gaps therebetween.

Because of the nucleation-inhibiting properties of those regions of the first pattern 1410 where the patterning coating 610 was disposed (corresponding to the gaps therebetween), the deposited layer 430 disposed on such regions may tend to not remain, resulting in a pattern of selective deposition of the deposited layer 430, that may correspond substantially to elongated spaced-apart regions of the first pattern 1410, leaving a first portion 601 comprising the gaps therebetween substantially devoid of a closed coating 440 of the deposited layer 430.

In other words, the deposited layer 430 that may form the first pattern 1410 of electrodes 1020, 1040, 1550 may be selectively deposited substantially only on a second portion 602 comprising those regions of the substrate 10 that define the elongated spaced-apart regions of the first pattern 1410.

Turning now to FIG. 14C, there may be shown a cross-sectional view 1400c of the device 1400, taken along line 14C-14C in FIG. 14A. In the figure, the device 1400 may be shown as comprising the substrate 10; the first pattern 1410 of electrodes 1020 deposited as shown in FIG. 14B, and the at least one semiconducting layer(s) 1030.

In some non-limiting examples, the at least one semiconducting layer(s) 1030 may be provided as a common layer across substantially all of the lateral aspect(s) of the device 1400.

A patterning coating 610 may be selectively disposed in a pattern substantially corresponding to the second pattern 1420 on the exposed layer surface 11 of the underlying layer 130, which, as shown in the figure, is the at least one semiconducting layer 1030.

A deposited layer 430 suitable for forming the second pattern 1420 of electrodes 1020, 1040, 1550, which in the figure is the second electrode 1040, may be disposed on substantially all of the exposed layer surface 11 of the underlying layer 130, using an open mask and/or a mask-free deposition process. The underlying layer 130 may comprise both regions of the patterning coating 610, disposed in the inverse of the second pattern 1420, and regions of the at least one semiconducting layer(s) 1030, in the second pattern 1420 where the patterning coating 610 has not been deposited. In some non-limiting examples, the regions of the at least one semiconducting layer(s) 1030 may correspond substantially to a first portion 601 comprising the elongated spaced-apart regions of the second pattern 1420, while the regions of the patterning coating 610 may correspond substantially to the gaps therebetween.

Because of the nucleation-inhibiting properties of those regions of the second pattern 1420 where the patterning coating 610 was disposed (corresponding to the gaps therebetween), the deposited layer 430 disposed on such regions may tend not to remain, resulting in a pattern of selective deposition of the deposited layer 430, that may correspond substantially to elongated spaced-apart regions of the second pattern 1420, leaving the first portion 601 comprising the gaps therebetween substantially devoid of a closed coating 440 of the deposited layer 430.

In other words, the deposited layer 430 that may form the second pattern 1420 of electrodes 1020, 1040, 1550 may be selectively deposited substantially only on a second portion 602 comprising those regions of the NPC 920 that define the elongated spaced-apart regions of the second pattern 1420.

In some non-limiting examples, an average layer thickness of the patterning coating 610 and of the deposited layer 430 deposited thereafter for forming either, or both, of the first pattern 1410, and/or the second pattern 1420 of electrodes 1020, 1040, 1550 may be varied according to a variety of parameters, including without limitation, a given application and given performance characteristics. In some non-limiting examples, the average layer thickness of the patterning coating 610 may be comparable to, and/or substantially no more than an average layer thickness of the deposited layer 430 deposited thereafter. Use of a relatively thin patterning coating 610 to achieve selective patterning of a deposited layer 430 deposited thereafter may be suitable to provide flexible devices 1000. In some non-limiting examples, a relatively thin patterning coating 610 may provide a relatively planar surface on which a barrier coating 1450 may be deposited. In some non-limiting examples, providing such a relatively planar surface for application of the barrier coating 1450 may increase adhesion of the barrier coating 1450 to such surface.

At least one of the first pattern 1410 of electrodes 1020, 1040, 1550 and at least one of the second pattern 1420 of electrodes 1020, 1040, 1550 may be electrically coupled with the power source 1005, whether directly, and/or, in some non-limiting examples, through their respective driving circuit(s) to control photon emission from the lateral aspect(s) 1110 of the emissive region(s) 1610 corresponding to (sub-) pixel(s) 2210/174x.

### Auxiliary Electrode

Those having ordinary skill in the relevant art will appreciate that the process of forming the second electrode 1040 in the second pattern 1420 shown in FIGS. 14A-14C may, in some non-limiting examples, be used in similar fashion to form an auxiliary electrode 1550 for the device 1000. In some non-limiting examples, the second electrode 1040 thereof may comprise a common electrode, and the auxiliary electrode 1550 may be deposited in the second pattern 1420, in some non-limiting examples, above or in some non-limiting examples, below, the second electrode 1040 and electrically coupled therewith. In some non-limiting examples, the second pattern 1420 for such auxiliary electrode 1550 may be such that the elongated spaced-apart regions of the second pattern 1420 lie substantially within the lateral aspect(s) 1120 of non-emissive region(s) 1620 surrounding the lateral aspect(s) 1110 of emissive region(s) 1610 corresponding to (sub-) pixel(s) 2210/174x. In some non-limiting examples, the second pattern 1420 for such auxiliary electrodes 1550 may be such that the elongated spaced-apart regions of the second pattern 1420 lie substantially within the lateral aspect(s) 1110 of emissive region(s) 1610 corresponding to (sub-) pixel(s) 2210/174x, and/or the lateral aspect(s) 1120 of non-emissive region(s) 1620 surrounding them.

FIG. 15 may show an example cross-sectional view of an example version 1500 of the device 1000 that is substantially similar thereto, but further may comprise at least one auxiliary electrode 1550 disposed in a pattern above and electrically coupled (not shown) with the second electrode 1040.

The auxiliary electrode 1550 may be electrically conductive. In some non-limiting examples, the auxiliary electrode 1550 may be formed by at least one metal, and/or metal oxide. Non-limiting examples of such metals include Cu, Al, molybdenum (Mo), or Ag. By way of non-limiting examples, the auxiliary electrode 1550 may comprise a multi-layer metallic structure, including without limitation, one formed by Mo/Al/Mo. Non-limiting examples of such metal oxides include ITO, ZnO, IZO, or other oxides containing In, or Zn. In some non-limiting examples, the auxiliary electrode 1550 may comprise a multi-layer structure formed by a combination of at least one metal and at least one metal oxide, including without limitation, Ag/ITO, Mo/ITO, ITO/Ag/ITO, or ITO/Mo/ITO. In some non-limiting examples, the auxiliary electrode 1550 comprises a plurality of such electrically conductive materials.

The device 1500 may be shown as comprising the substrate 10, the first electrode 1020 and the at least one semiconducting layer 1030.

The second electrode 1040 may be disposed on substantially all of the exposed layer surface 11 of the at least one semiconducting layer 1030.

In some non-limiting examples, particularly in a top-emission device 1500, the second electrode 1040 may be formed by depositing a relatively thin conductive film layer (not shown) in order, by way of non-limiting example, to reduce optical interference (including, without limitation, attenuation, reflections, and/or diffusion) related to the presence of the second electrode 1040. In some non-limiting examples, as discussed elsewhere, a reduced thickness of the second electrode 1040, may generally increase a sheet resistance of the second electrode 1040, which may, in some non-limiting examples, reduce the performance, and/or efficiency of the device 1500. By providing the auxiliary electrode 1550 that may be electrically coupled with the second electrode 1040, the sheet resistance and thus, the IR drop associated with the second electrode 1040, may, in some non-limiting examples, be decreased.

In some non-limiting examples, the device 1500 may be a bottom-emission, and/or double-sided emission device 1500. In such examples, the second electrode 1040 may be formed as a relatively thick conductive layer without substantially affecting optical characteristics of such a device 1500. Nevertheless, even in such scenarios, the second electrode 1040 may nevertheless be formed as a relatively thin conductive film layer (not shown), by way of non-limiting example, so that the device 1500 may be substantially transmissive relative to light incident on an external surface thereof, such that a substantial part such externally-incident light may be transmitted through the device 1500, in addition to the emission of photons generated internally within the device 1500 as disclosed herein.

A patterning coating 610 may be selectively disposed in a pattern on the exposed layer surface 11 of the underlying layer 130, which, as shown in the figure, may be the at least one semiconducting layer 1030. In some non-limiting examples, as shown in the figure, the patterning coating 610 may be disposed, in a first portion of the pattern, as a series of parallel rows 1520.

A deposited layer 430 suitable for forming the patterned auxiliary electrode 1550, may be disposed on substantially all of the exposed layer surface 11 of the underlying layer 130, using an open mask and/or a mask-free deposition process. The underlying layer 130 may comprise both regions of the patterning coating 610, disposed in the pattern of rows 1520, and regions of the at least one semiconducting layer 1030 where the patterning coating 610 has not been deposited.

Because of the nucleation-inhibiting properties of those rows 1520 where the patterning coating 610 was disposed, the deposited layer 430 disposed on such rows 1520 may tend to not remain, resulting in a pattern of selective deposition of the deposited layer 430, that may correspond substantially to at least one second portion 602 of the pattern, leaving the first portion 601 comprising the rows 1520 substantially devoid of a closed coating 440 of the deposited layer 430.

In other words, the deposited layer 430 that may form the auxiliary electrode 1550 may be selectively deposited substantially only on a second portion 602 comprising those regions of the at least one semiconducting layer 1030, that surround but do not occupy the rows 1520.

In some non-limiting examples, selectively depositing the auxiliary electrode 1550 to cover only certain rows 1520 of the lateral aspect of the device 1500, while other regions thereof remain uncovered, may control, and/or reduce optical interference related to the presence of the auxiliary electrode 1550.

In some non-limiting examples, the auxiliary electrode 1550 may be selectively deposited in a pattern that may not be readily detected by the naked eye from a typical viewing distance.

In some non-limiting examples, the auxiliary electrode 1550 may be formed in devices other than OLED devices, including for decreasing an effective resistance of the electrodes of such devices.

The ability to pattern electrodes 1020, 1040, 1550 including without limitation, the second electrode 1040, and/or the auxiliary electrode 1550 without employing a shadow mask 615 during the high-temperature deposited layer 430 deposition process by employing a patterning coating 610, including without limitation, the process depicted in FIG. 7, may allow numerous configurations of auxiliary electrodes 1550 to be deployed.

In some non-limiting examples, the auxiliary electrode 1550 may be disposed between neighbouring emissive regions 1610 and electrically coupled with the second electrode 1040. In non-limiting examples, a width of the auxiliary electrode 1550 may be no more than a separation distance between the neighbouring emissive regions 1610. As a result, there may exist a gap within the at least one non-emissive region 1620 on each side of the auxiliary electrode 1550. In some non-limiting examples, such an arrangement may reduce a likelihood that the auxiliary electrode 1550 would interfere with an optical output of the device 1500, in some non-limiting examples, from at least one of the emissive regions 1610. In some non-limiting examples, such an arrangement may be appropriate where the auxiliary electrode 1550 is relatively thick (in some non-limiting examples, greater than several hundred nm, and/or on the order of a few microns in thickness). In some non-limiting examples, an aspect ratio of the auxiliary electrode 1550 may exceed at least one of about 0.05, such as at least one of at least about: 0.1, 0.2, 0.5, 0.8, 1, or 2. By way of non-limiting example, a height (thickness) of the auxiliary electrode 1550 may exceed about 50 nm, such as at least one of at least about: 80 nm, 100 nm, 200 nm, 500 nm, 700 nm, 1,000 nm, 1,500 nm, 1,700 nm, or 2,000 nm.

FIG. 16 may show, in plan view, a schematic diagram showing an example of a pattern 1650 of the auxiliary electrode 1550 formed as a grid that may be overlaid over both the lateral aspects 1110 of emissive regions 1610, which may correspond to (sub-) pixel(s) 2210/174x of an example version 1600 of device 1000, and the lateral aspects 1120 of non-emissive regions 1620 surrounding the emissive regions 1610.

In some non-limiting examples, the pattern 1650 of the auxiliary electrode 1550 may extend substantially only over some but not all of the lateral aspects 1120 of non-emissive regions 1620, to not substantially cover any of the lateral aspects 1110 of the emissive regions 1610.

Those having ordinary skill in the relevant art will appreciate that while, in the figure, the pattern 1650 of the auxiliary electrode 1550 may be shown as being formed as a continuous structure such that all elements thereof are both physically connected to and electrically coupled with one another and electrically coupled with at least one electrode 1020, 1040, 1550, which in some non-limiting examples may be the first electrode 1020, and/or the second electrode 1040, in some non-limiting examples, the pattern 1650 of the auxiliary electrode 1550 may be provided as a plurality of discrete elements of the pattern 1650 of the auxiliary electrode 1550 that, while remaining electrically coupled with one another, may not be physically connected to one another. Even so, such discrete elements of the pattern 1650 of the auxiliary electrode 1550 may still substantially lower a sheet resistance of the at least one electrode 1020, 1040, 1550 with which they are electrically coupled, and consequently of the device 1600, to increase an efficiency of the device 1600 without substantially interfering with its optical characteristics.

In some non-limiting examples, auxiliary electrodes 1550 may be employed in devices 1600 with a variety of arrangements of (sub-) pixel(s) 2210/174x. In some non-limiting examples, the (sub-) pixel 2210/174x arrangement may be substantially diamond-shaped.

By way of non-limiting example, FIG. 17A may show, in plan view, in an example version 1700 of device 1000, a plurality of groups 1741-1743 of emissive regions 1610 each corresponding to a sub-pixel 174x, surrounded by the lateral aspects of a plurality of non-emissive regions 1620 comprising PDLs 1140 in a diamond configuration. In some non-limiting examples, the configuration may be defined by patterns 1741-1743 of emissive regions 1610 and PDLs 1140 in an alternating pattern of first and second rows.

In some non-limiting examples, the lateral aspects 1120 of the non-emissive regions 1620 comprising PDLs 1140 may be substantially elliptically shaped. In some non-limiting examples, the major axes of the lateral aspects 1120 of the non-emissive regions 1620 in the first row may be aligned and substantially normal to the major axes of the lateral aspects 1120 of the non-emissive regions 1620 in the second row. In some non-limiting examples, the major axes of the lateral aspects 1120 of the non-emissive regions 1620 in the first row may be substantially parallel to an axis of the first row.

In some non-limiting examples, a first group 1741 of emissive regions 1610 may correspond to sub-pixels 174x that emit EM radiation at a first wavelength, in some non-limiting examples the sub-pixels 174x of the first group 1741 may correspond to R(ed) sub-pixels 1741. In some non-limiting examples, the lateral aspects 1110 of the emissive regions 1610 of the first group 1741 may have a substantially diamond-shaped configuration. In some non-limiting examples, the emissive regions 1610 of the first group 1741 may lie in the pattern of the first row, preceded and followed by PDLs 1140. In some non-limiting examples, the lateral aspects 1110 of the emissive regions 1610 of the first group 1741 may slightly overlap the lateral aspects 1120 of the preceding and following non-emissive regions 1620 comprising PDLs 1140 in the same row, as well as of the lateral aspects 1120 of adjacent non-emissive regions 1620 comprising PDLs 1140 in a preceding and following pattern of the second row.

In some non-limiting examples, a second group 1742 of emissive regions 1610 may correspond to sub-pixels 174x that emit EM radiation at a second wavelength, in some non-limiting examples the sub-pixels 174x of the second group 1742 may correspond to G(reen) sub-pixels 1742. In some non-limiting examples, the lateral aspects 1110 of the emissive regions 1610 of the second group 1741 may have a substantially elliptical configuration. In some non-limiting examples, the emissive regions 1610 of the second group 1741 may lie in the pattern of the second row, preceded and followed by PDLs 1140. In some non-limiting examples, the major axis of some of the lateral aspects 1110 of the emissive regions 1610 of the second group 1741 may be at a first angle, which in some non-limiting examples, may be 45° relative to an axis of the second row. In some non-limiting examples, the major axis of others of the lateral aspects 1110 of the emissive regions 1610 of the second group 1741 may be at a second angle, which in some non-limiting examples may be substantially normal to the first angle. In some non-limiting examples, the emissive regions 1610 of the first group 1741, whose lateral aspects 1110 may have a major axis at the first angle, may alternate with the emissive regions 1610 of the first group 1741, whose lateral aspects 1110 may have a major axis at the second angle.

In some non-limiting examples, a third group 1743 of emissive regions 1610 may correspond to sub-pixels 174x that emit EM radiation at a third wavelength, in some non-limiting examples the sub-pixels 174x of the third group 1743 may correspond to B(lue) sub-pixels 1743. In some non-limiting examples, the lateral aspects 1110 of the emissive regions 1610 of the third group 1743 may have a substantially diamond-shaped configuration. In some non-limiting examples, the emissive regions 1610 of the third group 1743 may lie in the pattern of the first row, preceded and followed by PDLs 1140. In some non-limiting examples, the lateral aspects 1110 of the emissive regions 1610 of the third group 1743 may slightly overlap the lateral aspects 1110 of the preceding and following non-emissive regions 1620 comprising PDLs 1140 in the same row, as well as of the lateral aspects 1120 of adjacent non-emissive regions 1620 comprising PDLs 1140 in a preceding and following pattern of the second row. In some non-limiting examples, the pattern of the second row may comprise emissive regions 1610 of the first group 1741 alternating emissive regions 1610 of the third group 1743, each preceded and followed by PDLs 1140.

Turning now to FIG. 17B, there may be shown an example cross-sectional view of the device 1700, taken along line 17B-17B in FIG. 17A. In the figure, the device 1700 may be shown as comprising a substrate 10 and a plurality of elements of a first electrode 1020, formed on an exposed layer surface 11 thereof. The substrate 10 may comprise the base substrate 1012 (not shown for purposes of simplicity of illustration), and/or at least one TFT structure 1101, corresponding to and for driving each sub-pixel 174x. PDLs 1140 may be formed over the substrate 10 between elements of the first electrode 1020, to define emissive region(s) 1610 over each element of the first electrode 1020, separated by non-emissive region(s) 1620 comprising the PDL(s) 1140. In the figure, the emissive region(s) 1610 may all correspond to the second group 1742.

In some non-limiting examples, at least one semiconducting layer 1030 may be deposited on each element of the first electrode 1020, between the surrounding PDLs 1140.

In some non-limiting examples, a second electrode 1040, which in some non-limiting examples, may be a common cathode, may be deposited over the emissive region(s) 1610 of the second group 1742 to form the G(reen) sub-pixel(s) 1742 thereof and over the surrounding PDLs 1140.

In some non-limiting examples, a patterning coating 610 may be selectively deposited over the second electrode 1040 across the lateral aspects 1110 of the emissive region(s) 1610 of the second group 1742 of G(reen) sub-pixels 1742 to allow selective deposition of a deposited layer 430 over parts of the second electrode 1040 that may be substantially devoid of the patterning coating 610, namely across the lateral aspects 1120 of the non-emissive region(s) 1620 comprising the PDLs 1140. In some non-limiting examples, the deposited layer 430 may tend to accumulate along the substantially planar parts of the PDLs 1140, as the deposited layer 430 may tend to not remain on the inclined parts of the PDLs 1140 but may tend to descend to a base of such inclined parts, which may be coated with the patterning coating 610. In some non-limiting examples, the deposited layer 430 on the substantially planar parts of the PDLs 1140 may form at least one auxiliary electrode 1550 that may be electrically coupled with the second electrode 1040.

In some non-limiting examples, the device 1700 may comprise a CPL, and/or an outcoupling layer. By way of non-limiting example, such CPL, and/or outcoupling layer may be provided directly on a surface of the second electrode 1040, and/or a surface of the patterning coating 610. In some non-limiting examples, such CPL, and/or outcoupling layer may be provided across the lateral aspect 1110 of at least one emissive region 1610 corresponding to a (sub-) pixel 2210/174x.

In some non-limiting examples, the patterning coating 610 may also act as an index-matching coating. In some non-limiting examples, the patterning coating 610 may also act as an outcoupling layer.

In some non-limiting examples, the device 1700 may comprise an encapsulation layer 1450. Non-limiting examples of such encapsulation layer 1450 include a glass cap, a barrier film, a barrier adhesive, a barrier coating 1450, and/or a TFE layer such as shown in dashed outline in the figure, provided to encapsulate the device 1700. In some non-limiting examples, the TFE layer may be considered a type of barrier coating 1450.

In some non-limiting examples, the encapsulation layer 1450 may be arranged above at least one of the second electrode 1040, and/or the patterning coating 610. In some non-limiting examples, the device 1700 may comprise additional optical, and/or structural layers, coatings, and components, including without limitation, a polarizer, a color filter, an anti-reflection coating, an anti-glare coating, cover glass, and/or an optically clear adhesive (OCA).

Turning now to FIG. 17C, there may be shown an example cross-sectional view of the device 1700, taken along line 17C-17C in FIG. 17A. In the figure, the device 1700 may be shown as comprising a substrate 10 and a plurality of elements of a first electrode 1020, formed on an exposed layer surface 11 thereof. PDLs 1140 may be formed over the substrate 10 between elements of the first electrode 1020, to define emissive region(s) 1610 over each element of the first electrode 1020, separated by non-emissive region(s) 1620 comprising the PDL(s) 1140. In the figure, the emissive region(s) 1610 may correspond to the first group 1741 and to the third group 1743 in alternating fashion.

In some non-limiting examples, at least one semiconducting layer 1030 may be deposited on each element of the first electrode 1020, between the surrounding PDLs 1140.

In some non-limiting examples, a second electrode 1040, which in some non-limiting examples, may be a common cathode, may be deposited over the emissive region(s) 1610 of the first group 1741 to form the R(ed) sub-pixel(s) 1741 thereof, and/or may be deposited over the emissive region(s) 1610 of the third group 1743 to form the B(lue) sub-pixel(s) 1743 thereof, and over the surrounding PDLs 1140.

In some non-limiting examples, a patterning coating 610 may be selectively deposited over the second electrode 1040 across the lateral aspects 1110 of the emissive region(s) 1610 of the first group 1741 of R(ed) sub-pixels 1741 and/or of the third group 1743 of B(lue) sub-pixels 1743 to allow selective deposition of a deposited layer 430 over parts of the second electrode 1040 that may be substantially devoid of the patterning coating 610, namely across the lateral aspects 1120 of the non-emissive region(s) 1620 comprising the PDLs 1140. In some non-limiting examples, the deposited layer 430 may tend to accumulate along the substantially planar parts of the PDLs 1140, as the deposited layer 430 may tend to not remain on the inclined parts of the PDLs 1140 but may tend to descend to a base of such inclined parts, which are coated with the patterning coating 610. In some non-limiting examples, the deposited layer 430 on the substantially planar parts of the PDLs 1140 may form at least one auxiliary electrode 1550 that may be electrically coupled with the second electrode 1040.

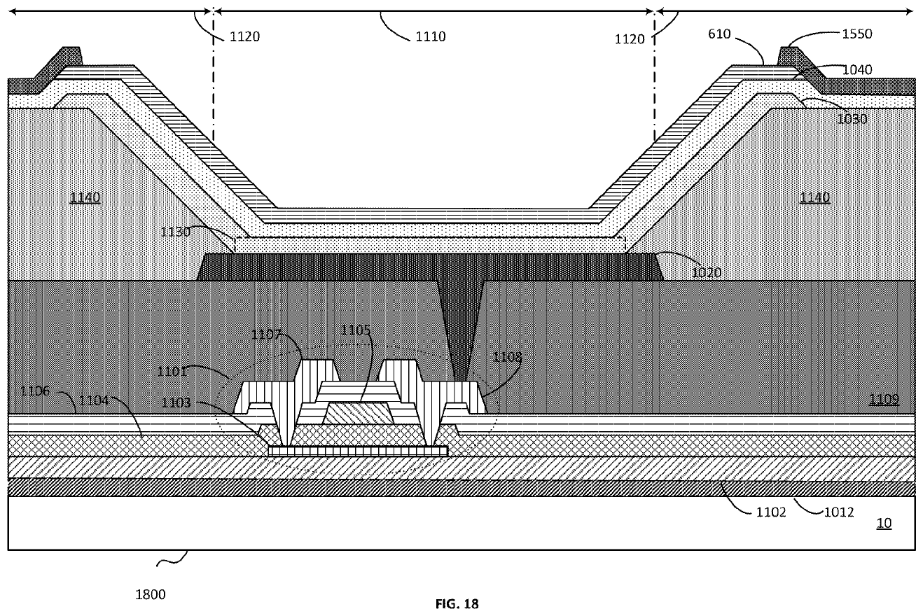

Turning now to FIG. 18, there may be shown an example version 1800 of the device 1000, which may encompass the device shown in cross-sectional view in FIG. 11, but with additional deposition steps that are described herein.

The device 1800 may show a patterning coating 610 selectively deposited over the exposed layer surface 11 of the underlying layer 130, in the figure, the second electrode 1040, within a first portion 601 of the device 1800, corresponding substantially to the lateral aspect 1110 of emissive region(s) 1610 corresponding to (sub-) pixel(s) 2210/174x and not within a second portion 602 of the device 1800, corresponding substantially to the lateral aspect(s) 1120 of non-emissive region(s) 1620 surrounding the first portion 601.

In some non-limiting examples, the patterning coating 610 may be selectively deposited using a shadow mask 615.

The patterning coating 610 may provide, within the first portion 601, an exposed layer surface 11 with a relatively low initial sticking probability against deposition of a deposited material 731 to be thereafter deposited as a deposited layer 430 to form an auxiliary electrode 1550.

After selective deposition of the patterning coating 610, the deposited material 731 may be deposited over the device 1800 but may remain substantially only within the second portion 602, which may be substantially devoid of patterning coating 610, to form the auxiliary electrode 1550.

In some non-limiting examples, the deposited material 731 may be deposited using an open mask and/or a mask-free deposition process.

The auxiliary electrode 1550 may be electrically coupled with the second electrode 1040 to reduce a sheet resistance of the second electrode 1040, including, as shown, by lying above and in physical contact with the second electrode 1040 across the second portion that may be substantially devoid of patterning coating 610.

In some non-limiting examples, the deposited layer 430 may comprise substantially the same material as the second electrode 1040, to ensure a high initial sticking probability against deposition of the deposited material 731 in the second portion 602.

In some non-limiting examples, the second electrode 1040 may comprise substantially pure Mg, and/or an alloy of Mg and another metal, including without limitation, Ag. In some non-limiting examples, an Mg:Ag alloy composition may range from about 1:9-9:1 by volume. In some non-limiting examples, the second electrode 1040 may comprise metal oxides, including without limitation, ternary metal oxides, such as, without limitation, ITO, and/or IZO, and/or a combination of metals, and/or metal oxides.

In some non-limiting examples, the deposited layer 430 used to form the auxiliary electrode 1550 may comprise substantially pure Mg.

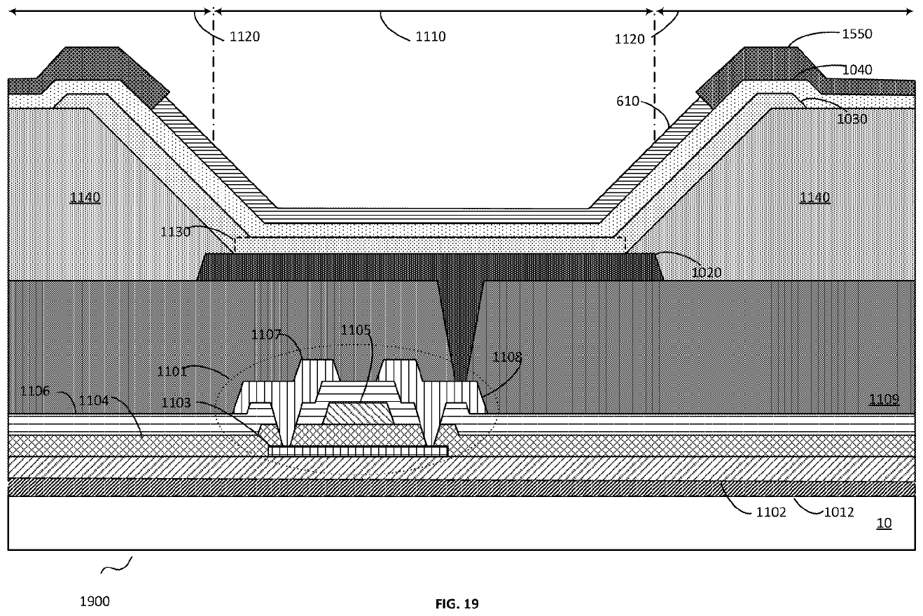

Turning now to FIG. 19, there may be shown an example version 1900 of the device 1000, which may encompass the device shown in cross-sectional view in FIG. 11, but with additional deposition steps that are described herein.

The device 1900 may show a patterning coating 610 selectively deposited over the exposed layer surface 11 of the underlying layer 130, in the figure, the second electrode 1040, within a first portion 601 of the device 1900, corresponding substantially to a part of the lateral aspect 1110 of emissive region(s) 1610 corresponding to (sub-) pixel(s) 2210/174x, and not within a second portion 602. In the figure, the first portion 601 may extend partially along the extent of an inclined part of the PDLs 1140 defining the emissive region(s) 1610.

In some non-limiting examples, the patterning coating 610 may be selectively deposited using a shadow mask 615.

The patterning coating 610 may provide, within the first portion 601, an exposed layer surface 11 with a relatively low initial sticking probability against deposition of a deposited material 731 to be thereafter deposited as a deposited layer 430 to form an auxiliary electrode 1550.

After selective deposition of the patterning coating 610, the deposited material 731 may be deposited over the device 1900 but may remain substantially only within the second portion 602, which may be substantially devoid of patterning coating 610, to form the auxiliary electrode 1550. As such, in the device 1900, the auxiliary electrode 1550 may extend partly across the inclined part of the PDLs 1140 defining the emissive region(s) 1610.

In some non-limiting examples, the deposited layer 430 may be deposited using an open mask and/or a mask-free deposition process.

The auxiliary electrode 1550 may be electrically coupled with the second electrode 1040 to reduce a sheet resistance of the second electrode 1040, including, as shown, by lying above and in physical contact with the second electrode 1040 across the second portion 602 that may be substantially devoid of patterning coating 610.

In some non-limiting examples, the material of which the second electrode 1040 may be comprised, may not have a high initial sticking probability against deposition of the deposited material 731.

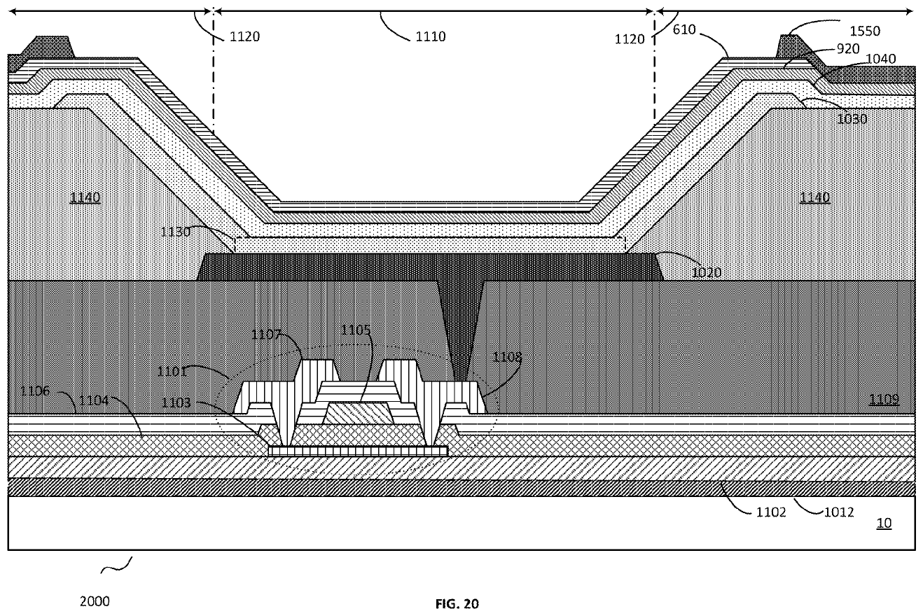

FIG. 20 may illustrate such a scenario, in which there may be shown an example version 2000 of the device 1000, which may encompass the device shown in cross-sectional view in FIG. 11, but with additional deposition steps that are described herein.

The device 2000 may show an NPC 920 deposited over the exposed layer surface 11 of the underlying material, in the figure, the second electrode 1040.

In some non-limiting examples, the NPC 920 may be deposited using an open mask and/or a mask-free deposition process.

Thereafter, a patterning coating 610 may be deposited selectively deposited over the exposed layer surface 11 of the underlying material, in the figure, the NPC 920, within a first portion 601 of the device 2000, corresponding substantially to a part of the lateral aspect 1110 of emissive region(s) 1610 corresponding to (sub-) pixel(s) 2210/174x, and not within a second portion 602 of the device 2000, corresponding substantially to the lateral aspect(s) 1120 of non-emissive region(s) 1620 surrounding the first portion 601.

In some non-limiting examples, the patterning coating 610 may be selectively deposited using a shadow mask 615.

The patterning coating 610 may provide, within the first portion 601, an exposed layer surface 11 with a relatively low initial sticking probability against deposition of a deposited material 731 to be thereafter deposited as a deposited layer 430 to form an auxiliary electrode 1550.

After selective deposition of the patterning coating 610, the deposited material 731 may be deposited over the device 2000 but may remain substantially only within the second portion 602, which may be substantially devoid of patterning coating 610, to form the auxiliary electrode 1550.

In some non-limiting examples, the deposited layer 430 may be deposited using an open mask and/or a mask-free deposition process.

The auxiliary electrode 1550 may be electrically coupled with the second electrode 1040 to reduce a sheet resistance thereof. While, as shown, the auxiliary electrode 1550 may not be lying above and in physical contact with the second electrode 1040, those having ordinary skill in the relevant art will nevertheless appreciate that the auxiliary electrode 1550 may be electrically coupled with the second electrode 1040 by several well-understood mechanisms. By way of non-limiting example, the presence of a relatively thin film (in some non-limiting examples, of up to about 50 nm) of a patterning coating 610 may still allow a current to pass therethrough, thus allowing a sheet resistance of the second electrode 1040 to be reduced.

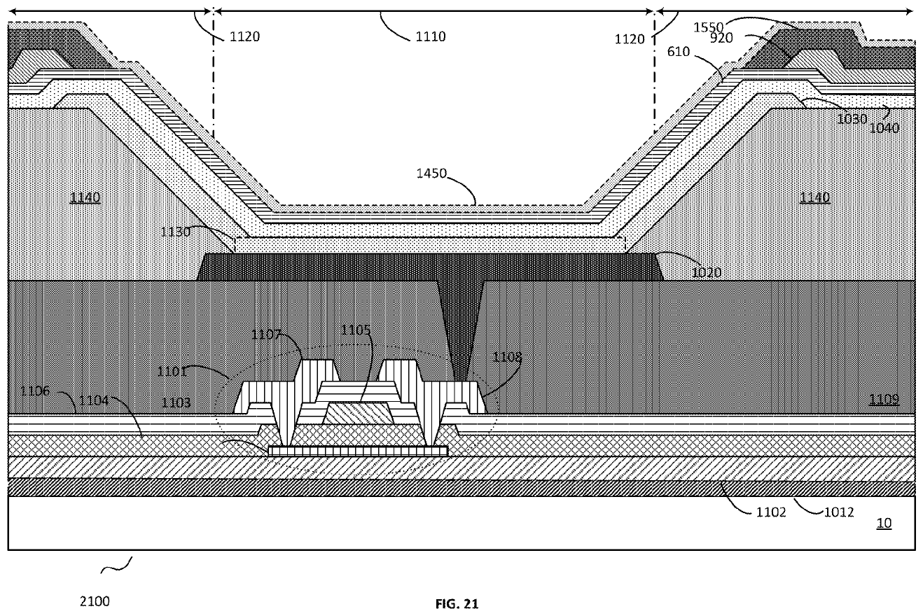

Turning now to FIG. 21, there may be shown an example version 2100 of the device 1000, which may encompass the device shown in cross-sectional view in FIG. 11, but with additional deposition steps that are described herein.

The device 2100 may show a patterning coating 610 deposited over the exposed layer surface 11 of the underlying material, in the figure, the second electrode 1040.

In some non-limiting examples, the patterning coating 610 may be deposited using an open mask and/or a mask-free deposition process.

The patterning coating 610 may provide an exposed layer surface 11 with a relatively low initial sticking probability against deposition of a deposited material 731 to be thereafter deposited as a deposited layer 430 to form an auxiliary electrode 1550.

After deposition of the patterning coating 610, an NPC 920 may be selectively deposited over the exposed layer surface 11 of the underlying layer 130, in the figure, the patterning coating 610, corresponding substantially to a part of the lateral aspect 1120 of non-emissive region(s) 1620, and surrounding a second portion 602 of the device 2100, corresponding substantially to the lateral aspect(s) 1110 of emissive region(s) 1610 corresponding to (sub-) pixel(s) 2210/174x.

In some non-limiting examples, the NPC 920 may be selectively deposited using a shadow mask 615.

The NPC 920 may provide, within the first portion 601, an exposed layer surface 11 with a relatively high initial sticking probability against deposition of a deposited material 731 to be thereafter deposited as a deposited layer 430 to form an auxiliary electrode 1550.

After selective deposition of the NPC 920, the deposited material 731 may be deposited over the device 2100 but may remain substantially where the patterning coating 610 has been overlaid with the NPC 920, to form the auxiliary electrode 1550.

In some non-limiting examples, the deposited layer 430 may be deposited using an open mask and/or a mask-free deposition process.

The auxiliary electrode 1550 may be electrically coupled with the second electrode 1040 to reduce a sheet resistance of the second electrode 1040.

### Transparent OLED

Because the OLED device 1000 may emit EM radiation through either, or both, of the first electrode 1020 (in the case of a bottom-emission, and/or a double-sided emission device), as well as the substrate 10, and/or the second electrode 1040 (in the case of a top-emission, and/or double-sided emission device), there may be an aim to make either, or both of, the first electrode 1020, and/or the second electrode 1040 substantially photon- (or light)-transmissive (“transmissive”), in some non-limiting examples, at least across a substantial part of the lateral aspect 1110 of the emissive region(s) 1610 of the device 1000. In the present disclosure, such a transmissive element, including without limitation, an electrode 1020, 1040, a material from which such element may be formed, and/or property thereof, may comprise an element, material, and/or property thereof that is substantially transmissive (“transparent”), and/or, in some non-limiting examples, partially transmissive (“semi-transparent”), in some non-limiting examples, in at least one wavelength range.

A variety of mechanisms may be adopted to impart transmissive properties to the device 1000, at least across a substantial part of the lateral aspect 1110 of the emissive region(s) 1610 thereof.

In some non-limiting examples, including without limitation, where the device 1000 is a bottom-emission device, and/or a double-sided emission device, the TFT structure(s) 1101 of the driving circuit associated with an emissive region 1610 of a (sub-) pixel 2210/174x, which may at least partially reduce the transmissivity of the surrounding substrate 10, may be located within the lateral aspect 1120 of the surrounding non-emissive region(s) 1620 to avoid impacting the transmissive properties of the substrate 10 within the lateral aspect 1110 of the emissive region 1610.

In some non-limiting examples, where the device 1000 is a double-sided emission device, in respect of the lateral aspect 1110 of an emissive region 1610 of a (sub-) pixel 2210/174x, a first one of the electrode 1020, 1040 may be made substantially transmissive, including without limitation, by at least one of the mechanisms disclosed herein, in respect of the lateral aspect 1110 of neighbouring, and/or adjacent (sub-) pixel(s) 2210/174x, a second one of the electrodes 1020, 1040 may be made substantially transmissive, including without limitation, by at least one of the mechanisms disclosed herein. Thus, the lateral aspect 1110 of a first emissive region 1610 of a (sub-) pixel 2210/174x may be made substantially top-emitting while the lateral aspect 1110 of a second emissive region 1610 of a neighbouring (sub-) pixel 2210/174x may be made substantially bottom-emitting, such that a subset of the (sub-) pixel(s) 2210/174x may be substantially top-emitting and a subset of the (sub-) pixel(s) 2210/174x may be substantially bottom-emitting, in an alternating (sub-) pixel 2210/174x sequence, while only a single electrode 1020, 1040 of each (sub-) pixel 2210/174x may be made substantially transmissive.

In some non-limiting examples, a mechanism to make an electrode 1020, 1040, in the case of a bottom-emission device, and/or a double-sided emission device, the first electrode 1020, and/or in the case of a top-emission device, and/or a double-sided emission device, the second electrode 1040, transmissive, may be to form such electrode 1020, 1040 of a transmissive thin film.

In some non-limiting examples, an electrically conductive deposited layer 430, in a thin film, including without limitation, those formed by a depositing a thin conductive film layer of a metal, including without limitation, Ag, Al, and/or by depositing a thin layer of a metallic alloy, including without limitation, an Mg:Ag alloy, and/or a Yb:Ag alloy, may exhibit transmissive characteristics. In some non-limiting examples, the alloy may comprise a composition ranging from between about 1:9-9:1 by volume. In some non-limiting examples, the electrode 1020, 1040 may be formed of a plurality of thin conductive film layers of any combination of deposited layers 430, any at least one of which may be comprised of TCOs, thin metal films, thin metallic alloy films, and/or any combination of any of these.

In some non-limiting examples, especially in the case of such thin conductive films, a relatively thin layer thickness may be up to substantially a few tens of nm to contribute to enhanced transmissive qualities but also favorable optical properties (including without limitation, reduced microcavity effects) for use in an OLED device 1000.

In some non-limiting examples, a reduction in the thickness of an electrode 1020, 1040 to promote transmissive qualities may be accompanied by an increase in the sheet resistance of the electrode 1020, 1040.

In some non-limiting examples, a device 1000 having at least one electrode 1020, 1040 with a high sheet resistance creates a large current resistance (IR) drop when coupled with the power source 1005, in operation. In some non-limiting examples, such an IR drop may be compensated for, to some extent, by increasing a level of the power source 1005. However, in some non-limiting examples, increasing the level of the power source 1005 to compensate for the IR drop due to high sheet resistance, for at least one (sub-) pixel 2210/174x may call for increasing the level of a voltage to be supplied to other components to maintain effective operation of the device 1000.

In some non-limiting examples, to reduce power supply demands for a device 1000 without significantly impacting an ability to make an electrode 1020, 1040 substantially transmissive (by employing at least one thin film layer of any combination of TCOs, thin metal films, and/or thin metallic alloy films), an auxiliary electrode 1550 may be formed on the device 1000 to allow current to be carried more effectively to various emissive region(s) of the device 1000, while at the same time, reducing the sheet resistance and its associated IR drop of the transmissive electrode 1020, 1040.

In some non-limiting examples, a sheet resistance specification, for a common electrode 1020, 1040 of a display device 1000, may vary according to several parameters, including without limitation, a (panel) size of the device 1000, and/or a tolerance for voltage variation across the device 1000. In some non-limiting examples, the sheet resistance specification may increase (that is, a lower sheet resistance is specified) as the panel size increases. In some non-limiting examples, the sheet resistance specification may increase as the tolerance for voltage variation decreases.

In some non-limiting examples, a sheet resistance specification may be used to derive an example thickness of an auxiliary electrode 1550 to comply with such specification for various panel sizes.

By way of non-limiting example, for a top-emission device, the second electrode 1040 may be made transmissive. On the other hand, in some non-limiting examples, such auxiliary electrode 1550 may not be substantially transmissive but may be electrically coupled with the second electrode 1040, including without limitation, by deposition of a conductive deposited layer 430 therebetween, to reduce an effective sheet resistance of the second electrode 1040.

In some non-limiting examples, such auxiliary electrode 1550 may be positioned, and/or shaped in either, or both of, a lateral aspect, and/or cross-sectional aspect to not interfere with the emission of photons from the lateral aspect 1110 of the emissive region 1610 of a (sub-) pixel 2210/174x.

In some non-limiting examples, a mechanism to make the first electrode 1020, and/or the second electrode 1040, may be to form such electrode 1020, 1040 in a pattern across at least a part of the lateral aspect 1110 of the emissive region(s) 1610 thereof, and/or in some non-limiting examples, across at least a part of the lateral aspect 1120 of the non-emissive region(s) 1620 surrounding them. In some non-limiting examples, such mechanism may be employed to form the auxiliary electrode 1550 in a position, and/or shape in either, or both of, a lateral aspect, and/or cross-sectional aspect to not interfere with the emission of photons from the lateral aspect 1110 of the emissive region 1610 of a (sub-) pixel 2210/174x, as discussed above.

In some non-limiting examples, the device 1000 may be configured such that it may be substantially devoid of a conductive oxide material in an optical path of photons emitted by the device 1000. By way of non-limiting example, in the lateral aspect 1110 of at least one emissive region 1610 corresponding to a (sub-) pixel 2210/174x, at least one of the layers, and/or coatings deposited after the at least one semiconducting layer 1030, including without limitation, the second electrode 1040, the patterning coating 610, and/or any other layers, and/or coatings deposited thereon, may be substantially devoid of any conductive oxide material. In some non-limiting examples, being substantially devoid of any conductive oxide material may reduce absorption, and/or reflection of light emitted by the device 1000. By way of non-limiting example, conductive oxide materials, including without limitation, ITO, and/or IZO, may absorb light in at least the B(lue) region of the visible spectrum, which may, in generally, reduce efficiency, and/or performance of the device 1000.

In some non-limiting examples, a combination of these, and/or other mechanisms may be employed.

Additionally, in some non-limiting examples, in addition to rendering at least one of the first electrode 1020, the second electrode 1040, and/or the auxiliary electrode 1550, substantially transmissive across at least across a substantial part of the lateral aspect 1110 of the emissive region 1610 corresponding to the (sub-) pixel(s) 2210/174x of the device 1000, to allow photons to be emitted substantially across the lateral aspect 1110 thereof, there may be an aim to make at least one of the lateral aspect(s) 1120 of the surrounding non-emissive region(s) 1620 of the device 1000 substantially transmissive in both the bottom and top directions, to render the device 1000 substantially transmissive relative to light incident on an external surface thereof, such that a substantial part of such externally-incident light may be transmitted through the device 1000, in addition to the emission (in a top-emission, bottom-emission, and/or double-sided emission) of photons generated internally within the device 1000 as disclosed herein.

Turning now to FIG. 22A, there may be shown an example plan view of a transmissive (transparent) version, shown generally at 2200, of the device 1000. In some non-limiting examples, the device 2200 may be an AMOLED device having a plurality of pixels or pixel regions 2210 and a plurality of transmissive regions 2220. In some non-limiting examples, at least one auxiliary electrode 1550 may be deposited on an exposed layer surface 11 of an underlying material between the pixel region(s) 2210, and/or the transmissive region(s) 2220.

In some non-limiting examples, each pixel region 2210 may comprise a plurality of emissive regions 1610 each corresponding to a sub-pixel 174x. In some non-limiting examples, the sub-pixels 174x may correspond to, respectively, R(ed) sub-pixels 1741, G(reen) sub-pixels 1742, and/or B(lue) sub-pixels 1743.

In some non-limiting examples, each transmissive region 2220 may be substantially transparent and allows light to pass through the entirety of a cross-sectional aspect thereof.

Turning now to FIG. 22B, there may be shown an example cross-sectional view of a version 2200 of the device 1000, taken along line 22B-22B in FIG. 22A. In the figure, the device 2200 may be shown as comprising a substrate 10, a TFT insulating layer 1109 and a first electrode 1020 formed on a surface of the TFT insulating layer 1109. The substrate 10 may comprise the base substrate 1012 (not shown for purposes of simplicity of illustration), and/or at least one TFT structure 1101, corresponding to, and for driving, each sub-pixel 174x positioned substantially thereunder and electrically coupled with the first electrode 1020 thereof. PDL(s) 1140 may be formed in non-emissive regions 1620 over the substrate 10, to define emissive region(s) 1610 also corresponding to each sub-pixel 174x, over the first electrode 1020 corresponding thereto. The PDL(s) 1140 may cover edges of the first electrode 1020.

In some non-limiting examples, at least one semiconducting layer 1030 may be deposited over exposed region(s) of the first electrode 1020 and, in some non-limiting examples, at least parts of the surrounding PDLs 1140.

In some non-limiting examples, a second electrode 1040 may be deposited over the at least one semiconducting layer(s) 1030, including over the pixel region 2210 to form the sub-pixel(s) 174x thereof and, in some non-limiting examples, at least partially over the surrounding PDLs 1140 in the transmissive region 2220.

In some non-limiting examples, a patterning coating 610 may be selectively deposited over first portion(s) 601 of the device 2200, comprising both the pixel region 2210 and the transmissive region 2220 but not the region of the second electrode 1040 corresponding to the auxiliary electrode 1550 comprising second portion(s) 602 thereof.

In some non-limiting examples, the entire exposed layer surface 11 of the device 2200 may then be exposed to a vapor flux 732 of the deposited material 731, which in some non-limiting examples may be Mg. The deposited layer 430 may be selectively deposited over second portion(s) of the second electrode 1040 that may be substantially devoid of the patterning coating 610 to form an auxiliary electrode 1550 that may be electrically coupled with and in some non-limiting examples, in physical contact with uncoated parts of the second electrode 1040.

At the same time, the transmissive region 2220 of the device 2200 may remain substantially devoid of any materials that may substantially affect the transmission of EM radiation therethrough. In particular, as shown in the figure, the TFT structure 1101 and the first electrode 1020 may be positioned, in a cross-sectional aspect, below the sub-pixel 174x corresponding thereto, and together with the auxiliary electrode 1550, may lie beyond the transmissive region 2220. As a result, these components may not attenuate or impede light from being transmitted through the transmissive region 2220. In some non-limiting examples, such arrangement may allow a viewer viewing the device 2200 from a typical viewing distance to see through the device 2200, in some non-limiting examples, when all the (sub-) pixel(s) 2210/174x may not be emitting, thus creating a transparent device 2200.

While not shown in the figure, in some non-limiting examples, the device 2200 may further comprise an NPC 920 disposed between the auxiliary electrode 1550 and the second electrode 1040. In some non-limiting examples, the NPC 920 may also be disposed between the patterning coating 610 and the second electrode 1040.

In some non-limiting examples, the patterning coating 610 may be formed concurrently with the at least one semiconducting layer(s) 1030. By way of non-limiting example, at least one material used to form the patterning coating 610 may also be used to form the at least one semiconducting layer(s) 1030. In such non-limiting example, several stages for fabricating the device 2200 may be reduced.

Those having ordinary skill in the relevant art will appreciate that in some non-limiting examples, various other layers, and/or coatings, including without limitation those forming the at least one semiconducting layer(s) 1030, and/or the second electrode 1040, may cover a part of the transmissive region 2220, especially if such layers, and/or coatings are substantially transparent. In some non-limiting examples, the PDL(s) 1140 may have a reduced thickness, including without limitation, by forming a well therein, which in some non-limiting examples may be similar to the well defined for emissive region(s) 1610, to further facilitate light transmission through the transmissive region 2220.

Those having ordinary skill in the relevant art will appreciate that (sub-) pixel(s) 2210/174x arrangements other than the arrangement shown in FIGS. 22A and 22B may, in some non-limiting examples, be employed.

Those having ordinary skill in the relevant art will appreciate that arrangements of the auxiliary electrode(s) 1550 other than the arrangement shown in FIGS. 22A and 22B may, in some non-limiting examples, be employed. By way of non-limiting example, the auxiliary electrode(s) 1550 may be disposed between the pixel region 2210 and the transmissive region 2220. By way of non-limiting example, the auxiliary electrode(s) 1550 may be disposed between sub-pixel(s) 174x within a pixel region 2210.

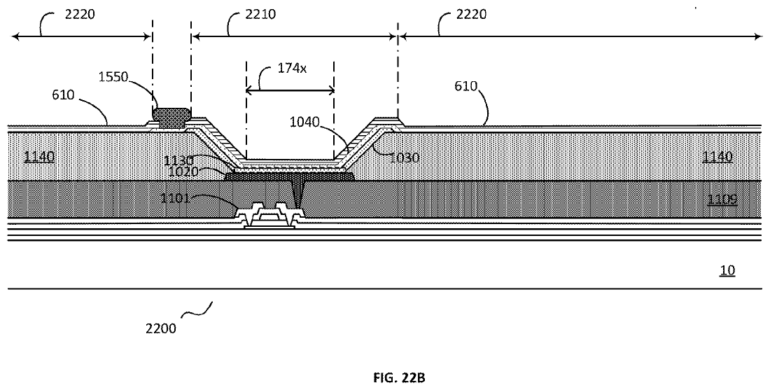

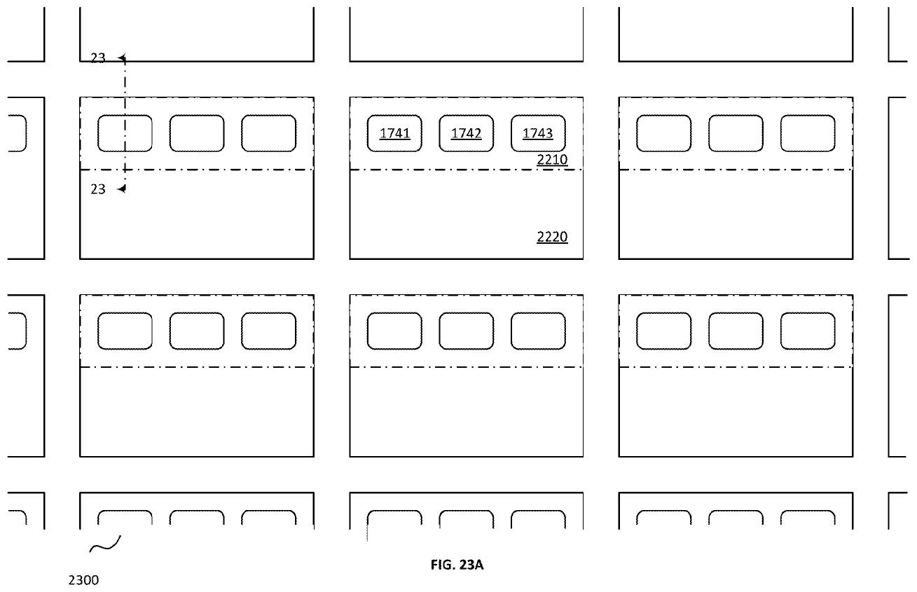

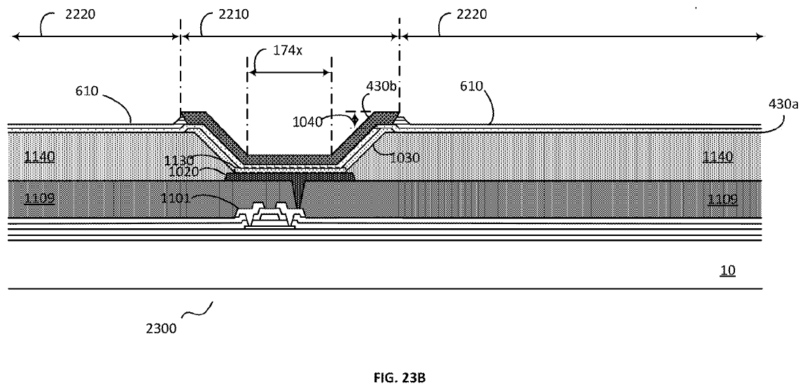

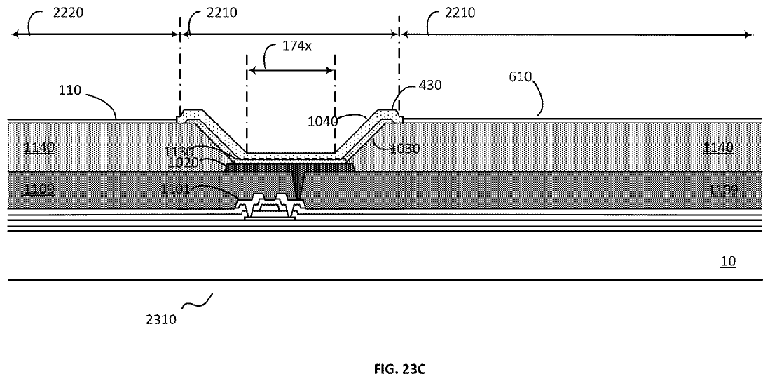

Turning now to FIG. 23A, there may be shown an example plan view of a transparent version, shown generally at 2300, of the device 1000. In some non-limiting examples, the device 2300 may be an AMOLED device having a plurality of pixel regions 2210 and a plurality of transmissive regions 2220. The device 2300 may differ from device 2200 in that no auxiliary electrode(s) 1550 lie between the pixel region(s) 2210, and/or the transmissive region(s) 2220.

In some non-limiting examples, each pixel region 2210 may comprise a plurality of emissive regions 1610, each corresponding to a sub-pixel 174x. In some non-limiting examples, the sub-pixels 174x may correspond to, respectively, R(ed) sub-pixels 1741, G(reen) sub-pixels 1742, and/or B(lue) sub-pixels 1743.

In some non-limiting examples, each transmissive region 2220 may be substantially transparent and may allow light to pass through the entirety of a cross-sectional aspect thereof.

Turning now to FIG. 23B, there may be shown an example cross-sectional view of the device 2300, taken along line 23-23 in FIG. 23A. In the figure, the device 2300 may be shown as comprising a substrate 10, a TFT insulating layer 1109 and a first electrode 1020 formed on a surface of the TFT insulating layer 1109. The substrate 10 may comprise the base substrate 1012 (not shown for purposes of simplicity of illustration), and/or at least one TFT structure 1101 corresponding to, and for driving, each sub-pixel 174x positioned substantially thereunder and electrically coupled with the first electrode 1020 thereof. PDL(s) 1140 may be formed in non-emissive regions 1620 over the substrate 10, to define emissive region(s) 1610 also corresponding to each sub-pixel 174x, over the first electrode 1020 corresponding thereto. The PDL(s) 1140 cover edges of the first electrode 1020.

In some non-limiting examples, at least one semiconducting layer 1030 may be deposited over exposed region(s) of the first electrode 1020 and, in some non-limiting examples, at least parts of the surrounding PDLs 1140.

In some non-limiting examples, a first deposited layer 430a may be deposited over the at least one semiconducting layer(s) 1030, including over the pixel region 2210 to form the sub-pixel(s) 174x thereof and over the surrounding PDLs 1140 in the transmissive region 2220. In some non-limiting examples, the average layer thickness of the first deposited layer 430a may be relatively thin such that the presence of the first deposited layer 430a across the transmissive region 2220 does not substantially attenuate transmission of light therethrough. In some non-limiting examples, the first deposited layer 430a may be deposited using an open mask and/or mask-free deposition process.

In some non-limiting examples, a patterning coating 610 may be selectively deposited over first portions 601 of the device 2300, comprising the transmissive region 2220.

In some non-limiting examples, the entire exposed layer surface 11 of the device 2300 may then be exposed to a vapor flux 732 of the deposited material 731, which in some non-limiting examples may be Mg, to selectively deposit a second deposited layer 430b, over second portion(s) 602 of the first deposited layer 430a that may be substantially devoid of the patterning coating 610, in some examples, the pixel region 2210, such that the second deposited layer 430b may be electrically coupled with and in some non-limiting examples, in physical contact with uncoated parts of the first deposited layer 430a, to form the second electrode 1040.

In some non-limiting examples, an average layer thickness of the first deposited layer 430a may be no more than an average layer thickness of the second deposited layer 430b. In this way, relatively high transmittance may be maintained in the transmissive region 2220, over which only the first deposited layer 430a may extend. In some non-limiting examples, an average layer thickness of the first deposited layer 430a may be no more than at least one of about: 30 nm, 25 nm, 20 nm, 15 nm, 10 nm, 8 nm, or 5 nm. In some non-limiting examples, an average layer thickness of the second deposited layer 430b may be no more than at least one of about: 30 nm, 25 nm, 20 nm, 15 nm, 10 nm, or 8 nm.

Thus, in some non-limiting examples, a thickness of the second electrode 1040 may be no more than about 40 nm, and/or in some non-limiting examples, at least one of between about: 5-30 nm, 10-25 nm, or 15-25 nm.

In some non-limiting examples, the average layer thickness of the first deposited layer 430a may exceed the average layer thickness of the second deposited layer 430b. In some non-limiting examples, the average layer thickness of the first deposited layer 430a and the average layer thickness of the second deposited layer 430b may be substantially the same.

In some non-limiting examples, at least one deposited material 731 used to form the first deposited layer 430a may be substantially the same as at least one deposited material 731 used to form the second deposited layer 430b. In some non-limiting examples, such at least one deposited material 731 may be substantially as described herein in respect of the first electrode 1020, the second electrode 1040, the auxiliary electrode 1550, and/or a deposited layer 430 thereof.

In some non-limiting examples, the transmissive region 2220 of the device 2300 may remain substantially devoid of any materials that may substantially inhibit the transmission of EM radiation therethrough. In particular, as shown in the figure, the TFT structure, and/or the first electrode 1020 may be positioned, in a cross-sectional aspect below the sub-pixel 174x corresponding thereto and beyond the transmissive region 2220. As a result, these components may not attenuate or impede EM radiation from being transmitted through the transmissive region 2220. In some non-limiting examples, such arrangement may allow a viewer viewing the device 2300 from a typical viewing distance to see through the device 2300, in some non-limiting examples, when the (sub-) pixel(s) 2210/174x are not emitting, thus creating a transparent AMOLED device 2300.

While not shown in the figure, in some non-limiting examples, the device 2300 may further comprise an NPC 920 disposed between the second deposited layer 430b and the first deposited layer 430a. In some non-limiting examples, the NPC 920 may also be disposed between the patterning coating 610 and the first deposited layer 430a.

In some non-limiting examples, the patterning coating 610 may be formed concurrently with the at least one semiconducting layer(s) 1030. By way of non-limiting example, at least one material used to form the patterning coating 610 may also be used to form the at least one semiconducting layer(s) 1030. In such non-limiting example, several stages for fabricating the device 2300 may be reduced.

Those having ordinary skill in the relevant art will appreciate that in some non-limiting examples, various other layers, and/or coatings, including without limitation those forming the at least one semiconducting layer(s) 1030, and/or the first deposited layer 430a, may cover a part of the transmissive region 2220, especially if such layers, and/or coatings are substantially transparent. In some non-limiting examples, the PDL(s) 1140 may have a reduced thickness, including without limitation, by forming a well therein, which in some non-limiting examples may be similar to the well defined for emissive region(s) 1610, to further facilitate light transmission through the transmissive region 2220.

Those having ordinary skill in the relevant art will appreciate that (sub-) pixel(s) 2210/174x arrangements other than the arrangement shown in FIGS. 23A and 23B may, in some non-limiting examples, be employed.

Turning now to FIG. 23C, there may be shown an example cross-sectional view of a different version 2310 of the device 1000, taken along the same line 23-23 in FIG. 23A. In the figure, the device 2310 may be shown as comprising a substrate 10, a TFT insulating layer 1109 and a first electrode 1020 formed on a surface of the TFT insulating layer 1109. The substrate 10 may comprise the base substrate 1012 (not shown for purposes of simplicity of illustration), and/or at least one TFT structure 1101 corresponding to and for driving each sub-pixel 174x positioned substantially thereunder and electrically coupled with the first electrode 1020 thereof. PDL(s) 1140 may be formed in non-emissive regions 1620 over the substrate 10, to define emissive region(s) 1610 also corresponding to each sub-pixel 174x, over the first electrode 1020 corresponding thereto. The PDL(s) 1140 may cover edges of the first electrode 1020.

In some non-limiting examples, at least one semiconducting layer 1030 may be deposited over exposed region(s) of the first electrode 1020 and, in some non-limiting examples, at least parts of the surrounding PDLs 1140.

In some non-limiting examples, a patterning coating 610 may be selectively deposited over first portions 601 of the device 2310, comprising the transmissive region 2220.

In some non-limiting examples, a deposited layer 430 may be deposited over the at least one semiconducting layer(s) 1030, including over the pixel region 2210 to form the sub-pixel(s) 174x thereof but not over the surrounding PDLs 1140 in the transmissive region 2220. In some non-limiting examples, the first deposited layer 430a may be deposited using an open mask and/or mask-free deposition process. In some non-limiting examples, such deposition may be effected by exposing the entire exposed layer surface 11 of the device 2310 to a vapor flux 732 of the deposited material 731, which in some non-limiting examples may be Mg, to selectively deposit the deposited layer 430 over second portions 602 of the at least one semiconducting layer(s) 1030 that are substantially devoid of the patterning coating 610, in some examples, the pixel region 2210, such that the deposited layer 430 may be deposited on the at least one semiconducting layer(s) 1030 to form the second electrode 1040.

In some non-limiting examples, the transmissive region 2220 of the device 2310 may remain substantially devoid of any materials that may substantially affect the transmission of light therethrough. In particular, as shown in the figure, the TFT structure 1101, and/or the first electrode 1020 may be positioned, in a cross-sectional aspect below the sub-pixel 174x corresponding thereto and beyond the transmissive region 2220. As a result, these components may not attenuate or impede light from being transmitted through the transmissive region 2220. In some non-limiting examples, such arrangement may allow a viewer viewing the device 2310 from a typical viewing distance to see through the device 2310, in some non-limiting examples, when the (sub-) pixel(s) 2210/174x are not emitting, thus creating a transparent AMOLED device 2310.

By providing a transmissive region 2220 that may be free, and/or substantially devoid of any deposited layer 430, the transmittance in such region may, in some non-limiting examples, be favorably enhanced, by way of non-limiting example, by comparison to the device 2300 of FIG. 23B.

While not shown in the figure, in some non-limiting examples, the device 2310 may further comprise an NPC 920 disposed between the deposited layer 430 and the at least one semiconducting layer(s) 1030. In some non-limiting examples, the NPC 920 may also be disposed between the patterning coating 610 and the PDL(s) 1140.

In some non-limiting examples, the patterning coating 610 may be formed concurrently with the at least one semiconducting layer(s) 1030. By way of non-limiting example, at least one material used to form the patterning coating 610 may also be used to form the at least one semiconducting layer(s) 1030. In such non-limiting example, several stages for fabricating the device 2310 may be reduced.

Those having ordinary skill in the relevant art will appreciate that in some non-limiting examples, various other layers, and/or coatings, including without limitation those forming the at least one semiconducting layer(s) 1030, and/or the deposited layer 430, may cover a part of the transmissive region 2220, especially if such layers, and/or coatings are substantially transparent. In some non-limiting examples, the PDL(s) 1140 may have a reduced thickness, including without limitation, by forming a well therein, which in some non-limiting examples may be similar to the well defined for emissive region(s) 1610, to further facilitate light transmission through the transmissive region 2220.

Those having ordinary skill in the relevant art will appreciate that (sub-) pixel(s) 2210/174x arrangements other than the arrangement shown in FIGS. 23B and 23C may, in some non-limiting examples, be employed.

### Selective Deposition to Modulate Electrode Thickness Over Emissive Region(s)

As discussed above, modulating the thickness of an electrode 1020, 1040, 1550 in and across a lateral aspect 1110 of emissive region(s) 1610 of a (sub-) pixel 2210/174x may impact the microcavity effect observable. In some non-limiting examples, selective deposition of at least one deposited layer 430 through deposition of at least one patterning coating 610, and/or an NPC 920, in the lateral aspects 1110 of emissive region(s) 1610 corresponding to different sub-pixel(s) 174x in a pixel region 2210 may allow the optical microcavity effect in each emissive region 1610 to be controlled, and/or modulated to optimize desirable optical microcavity effects on a sub-pixel 174x basis, including without limitation, an emission spectrum, a luminous intensity, and/or an angular dependence of a brightness, and/or a color shift of emitted light.

Such effects may be controlled by independently modulating an average layer thickness and/or a number of the deposited layer(s) 130, disposed in each emissive region 1610 of the sub-pixel(s) 174x. By way of non-limiting example, the thickness of a second electrode 1040 disposed over a B(lue) sub-pixel 1743 may be no more than the thickness of a second electrode 1040 disposed over a G(reen) sub-pixel 1742, and the thickness of a second electrode 1040 disposed over a G(reen) sub-pixel 1742 may be no more than the thickness of a second electrode 1040 disposed over a R(ed) sub-pixel 1741.

In some non-limiting examples, such effects may be controlled to an even greater extent by independently modulating the thickness and/or a number of the deposited layers 430, but also of the patterning coating 610 and/or an NPC 920, deposited in part(s) of each emissive region 1610 of the sub-pixel(s) 174x.

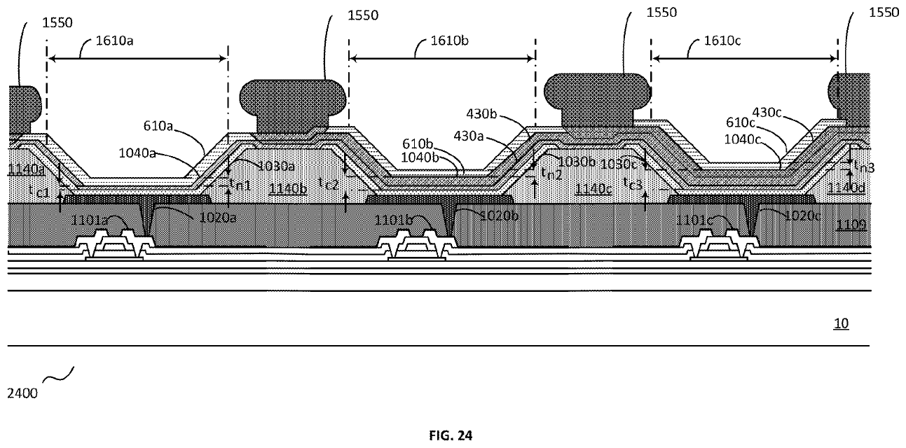

As shown by way of non-limiting example in FIG. 24, there may be deposited layer(s) 430 of varying average layer thickness selectively deposited for emissive region(s) 1610 corresponding to sub-pixel(s) 174x, in some non-limiting examples, in a version 2400 of an OLED display device 1000, having different emission spectra. In some non-limiting examples, a first emissive region 1610a may correspond to a sub-pixel 174x configured to emit light of a first wavelength, and/or emission spectrum, and/or in some non-limiting examples, a second emissive region 1610b may correspond to a sub-pixel 174x configured to emit light of a second wavelength, and/or emission spectrum. In some non-limiting examples, a device 1000 may comprise a third emissive region 1610c that may correspond to a sub-pixel 174x configured to emit light of a third wavelength, and/or emission spectrum.

In some non-limiting examples, the first wavelength may be less than, greater than, and/or equal to at least one of the second wavelength, and/or the third wavelength. In some non-limiting examples, the second wavelength may be less than, greater than, and/or equal to at least one of the first wavelength, and/or the third wavelength. In some non-limiting examples, the third wavelength may be less than, greater than, and/or equal to at least one of the first wavelength, and/or the second wavelength.

In some non-limiting examples, the device 2400 may also comprise at least one additional emissive region 1610 (not shown) that may in some non-limiting examples be configured to emit light having a wavelength, and/or emission spectrum that may be substantially identical to at least one of the first emissive region 1610a, the second emissive region 1610b, and/or the third emissive region 1610c.

In some non-limiting examples, the patterning coating 610 may be selectively deposited using a shadow mask 615 that may also have been used to deposit the at least one semiconducting layer 1030 of the first emissive region 1610a. In some non-limiting examples, such shared use of a shadow mask 615 may allow the optical microcavity effect(s) to be tuned for each sub-pixel 174x in a cost-effective manner.

The device 2400 may be shown as comprising a substrate 10, a TFT insulating layer 1109 and a plurality of first electrodes 1020a-1020c, formed on an exposed layer surface 11 of the TFT insulating layer 1109.

The substrate 10 may comprise the base substrate 1012 (not shown for purposes of simplicity of illustration), and/or at least one TFT structure 1101a-1101c corresponding to, and for driving, a corresponding emissive region 1610a-1610c, each having a corresponding sub-pixel 174x, positioned substantially thereunder and electrically coupled with its associated first electrode 1020a-1020c. PDL(s) 1140a-1140d may be formed over the substrate 10, to define emissive region(s) 1610a-1610c. The PDL(s) 1140a-1140d may cover edges of their respective first electrodes 1020a-1020c.

In some non-limiting examples, at least one semiconducting layer 1030a-1030c may be deposited over exposed region(s) of their respective first electrodes 1020a-1020c and, in some non-limiting examples, at least parts of the surrounding PDLs 1140a-1140d.

In some non-limiting examples, a first deposited layer 430a may be deposited over the at least one semiconducting layer(s) 1030a-1030c. In some non-limiting examples, the first deposited layer 430a may be deposited using an open mask and/or mask-free deposition process. In some non-limiting examples, such deposition may be effected by exposing the entire exposed layer surface 11 of the device 2400 to a vapor flux 732 of deposited material 731, which in some non-limiting examples may be Mg, to deposit the first deposited layer 430a over the at least one semiconducting layer(s) 1030a-1030c to form a first layer of the second electrode 1040a (not shown), which in some non-limiting examples may be a common electrode, at least for the first emissive region 1610a. Such common electrode may have a first thickness t_{c1} in the first emissive region 1610a. The first thickness t_{c1} may correspond to an average layer thickness of the first deposited layer 430a.

In some non-limiting examples, a first patterning coating 610a may be selectively deposited over first portions 601 of the device 2400, comprising the first emissive region 1610a.

In some non-limiting examples, a second deposited layer 430b may be deposited over the device 2400. In some non-limiting examples, the second deposited layer 430b may be deposited using an open mask and/or mask-free deposition process. In some non-limiting examples, such deposition may be effected by exposing the entire exposed layer surface 11 of the device 2400 to a vapor flux 732 of deposited material 731, which in some non-limiting examples may be Mg, to deposit the second deposited layer 430b over the first deposited layer 430a that may be substantially devoid of the first patterning coating 610a, in some examples, the second and third emissive regions 1610b, 1610c, and/or at least part(s) of the non-emissive region(s) 1620 in which the PDLs 1140a-1140d lie, such that the second deposited layer 430b may be deposited on the second portion(s) 602 of the first deposited layer 430a that are substantially devoid of the first patterning coating 610a to form a second layer of the second electrode 1040b (not shown), which in some non-limiting examples, may be a common electrode, at least for the second emissive region 1610b. Such common electrode may have a second thickness t_{c2} in the second emissive region 1610b. The second thickness t_{c2} may correspond to a combined average layer thickness of the first deposited layer 430a and of the second deposited layer 430b and may in some non-limiting examples exceed the first thickness t_{c1}.

In some non-limiting examples, a second patterning coating 610b may be selectively deposited over further first portions 601 of the device 2400, comprising the second emissive region 1610b.

In some non-limiting examples, a third deposited layer 430c may be deposited over the device 2400. In some non-limiting examples, the third deposited layer 430c may be deposited using an open mask and/or mask-free deposition process. In some non-limiting examples, such deposition may be effected by exposing the entire exposed layer surface 11 of the device 2400 to a vapor flux 732 of deposited material 731, which in some non-limiting examples may be Mg, to deposit the third deposited layer 430c over the second deposited layer 430b that may be substantially devoid of either the first patterning coating 610a or the second patterning coating 610b, in some examples, the third emissive region 1610c, and/or at least part(s) of the non-emissive region 1620 in which the PDLs 1140a-1140d lie, such that the third deposited layer 430c may be deposited on the further second portion(s) 602 of the second deposited layer 430b that are substantially devoid of the second patterning coating 610b to form a third layer of the second electrode 1040c (not shown), which in some non-limiting examples, may be a common electrode, at least for the third emissive region 1610c. Such common electrode may have a third thickness t_{c3} in the third emissive region 1610c. The third thickness t_{c3} may correspond to a combined average layer thickness of the first deposited layer 430a, the second deposited layer 430b and the third deposited layer 430c and may in some non-limiting examples exceed either, or both of, the first thickness t_{c1} and the second thickness t_{c2}.

In some non-limiting examples, a third patterning coating 610c may be selectively deposited over additional first portions 601 of the device 3300, comprising the third emissive region 1610b.

In some non-limiting examples, at least one auxiliary electrode 1550 may be disposed in the non-emissive region(s) 1620 of the device 2400 between neighbouring emissive regions 1610a-1610c thereof and in some non-limiting examples, over the PDLs 1140a-1140d. In some non-limiting examples, the deposited layer 430 used to deposit the at least one auxiliary electrode 1550 may be deposited using an open mask and/or mask-free deposition process. In some non-limiting examples, such deposition may be effected by exposing the entire exposed layer surface 11 of the device 2400 to a vapor flux 732 of deposited material 731, which in some non-limiting examples may be Mg, to deposit the deposited layer 430 over the exposed parts of the first deposited layer 430a, the second deposited layer 430b and the third deposited layer 430c that may be substantially devoid of any of the first patterning coating 610a, the second patterning coating 610b, and/or the third patterning coating 610c, such that the deposited layer 430 is deposited on an additional second portion 602 comprising the exposed part(s) of the first deposited layer 430a, the second deposited layer 430b, and/or the third deposited layer 430c that may be substantially devoid of any of the first patterning coating 610a, the second patterning coating 610b, and/or the third patterning coating 610c to form the at least one auxiliary electrode 1550. Each of the at least one auxiliary electrodes 1550 may be electrically coupled with a respective one of the second electrodes 1040a-1040c. In some non-limiting examples, each of the at least one auxiliary electrode 1550 may be in physical contact with such second electrode 1040a-1040c.

In some non-limiting examples, the first emissive region 1610a, the second emissive region 1610b and the third emissive region 1610c may be substantially devoid of a closed coating 440 of the deposited material 731 used to form the at least one auxiliary electrode 1550.

In some non-limiting examples, at least one of the first deposited layer 430a, the second deposited layer 430b, and/or the third deposited layer 430c may be transmissive, and/or substantially transparent in at least a part of the visible spectrum. Thus, the second deposited layer 430b, and/or the third deposited layer 430c (and/or any additional deposited layer(s) 430) may be disposed on top of the first deposited layer 430a to form a multi-coating electrode 1020, 1040, 1550 that may also be transmissive, and/or substantially transparent in at least a part of the visible spectrum. In some non-limiting examples, the transmittance of any at least one of the first deposited layer 430a, the second deposited layer 430b, the third deposited layer 430c, any additional deposited layer(s) 430, and/or the multi-coating electrode 1020, 1040, 1550 may exceed at least one of about: 30%, 40%, 45%, 50%, 60%, 70%, 75%, or 80% in at least a part of the visible spectrum.

In some non-limiting examples, an average layer thickness of the first deposited layer 430a, the second deposited layer 430b, and/or the third deposited layer 430c may be made relatively thin to maintain a relatively high transmittance. In some non-limiting examples, an average layer thickness of the first deposited layer 430a may be at least one of between about: 5-30 nm, 8-25 nm, or 10-20 nm. In some non-limiting examples, an average layer thickness of the second deposited layer 430b may be at least one of between about: 1-25 nm, 1-20 nm, 1-15 nm, 1-10 nm, or 3-6 nm. In some non-limiting examples, an average layer thickness of the third deposited layer 430c may be at least one of between about: 1-25 nm, 1-20 nm, 1-15 nm, 1-10 nm, or 3-6 nm. In some non-limiting examples, a thickness of a multi-coating electrode formed by a combination of the first deposited layer 430a, the second deposited layer 430b, the third deposited layer 430c, and/or any additional deposited layer(s) 430 may be at least one of between about: 6-35 nm, 10-30 nm, 10-25 nm, or 12-18 nm.

In some non-limiting examples, a thickness of the at least one auxiliary electrode 1550 may exceed an average layer thickness of the first deposited layer 430a, the second deposited layer 430b, the third deposited layer 430c, and/or a common electrode. In some non-limiting examples, the thickness of the at least one auxiliary electrode 1550 may exceed at least one of about: 50 nm, 80 nm, 100 nm, 150 nm, 200 nm, 300 nm, 400 nm, 500 nm, 700 nm, 800 nm, 1 μm, 1.2 μm, 1.5 μm, 2 μm, 2.5 μm, or 3 μm.

In some non-limiting examples, the at least one auxiliary electrode 1550 may be substantially non-transparent, and/or opaque. However, since the at least one auxiliary electrode 1550 may be in some non-limiting examples provided in a non-emissive region 1620 of the device 2400, the at least one auxiliary electrode 1550 may not cause or contribute to significant optical interference. In some non-limiting examples, the transmittance of the at least one auxiliary electrode 1550 may be no more than at least one of about: 50%, 70%, 80%, 85%, 90%, or 95% in at least a part of the visible spectrum.

In some non-limiting examples, the at least one auxiliary electrode 1550 may absorb EM radiation in at least a part of the visible spectrum.

In some non-limiting examples, an average layer thickness of the first patterning coating 610a, the second patterning coating 610b, and/or the third patterning coating 610c disposed in the first emissive region 1610a, the second emissive region 1610b, and/or the third emissive region 1610c respectively, may be varied according to a colour, and/or emission spectrum of EM radiation emitted by each emissive region 1610a-1610c. In some non-limiting examples, the first patterning coating 610a may have a first patterning coating thickness tₙ₁, the second patterning coating 610b may have a second patterning coating thickness tₙ₂, and/or the third patterning coating 610c may have a third patterning coating thickness tₙ₃. In some non-limiting examples, the first patterning coating thickness tₙ₁, the second patterning coating thickness tₙ₂, and/or the third patterning coating thickness tₙ₃, may be substantially the same. In some non-limiting examples, the first patterning coating thickness tₙ₁, the second patterning coating thickness tₙ₂, and/or the third patterning coating thickness tₙ₃, may be different from one another.

In some non-limiting examples, the device 2400 may also comprise any number of emissive regions 1610a-1610c, and/or (sub-) pixel(s) 2210/174x thereof. In some non-limiting examples, a device may comprise a plurality of pixels 2210, wherein each pixel 2210 comprises two, three or more sub-pixel(s) 174x.

Those having ordinary skill in the relevant art will appreciate that the specific arrangement of (sub-) pixel(s) 2210/174x may be varied depending on the device design. In some non-limiting examples, the sub-pixel(s) 174x may be arranged according to known arrangement schemes, including without limitation, RGB side-by-side, diamond, and/or PenTile®.

In some non-limiting examples, optical microcavity effects of individual (sub-) pixel(s) 2210/174x may be tuned by introducing, omitting, and/or varying features of at least one of the low(er)-index layer 110 and/or the higher-index layer 120. In some non-limiting examples, optical microcavity effects of individual (sub-) pixel(s) 2210/174x may be further tuned by introducing, omitting, and/or varying features of the quantity of deposited material 731 in the non-interface portion 102.

By way of non-limiting example, a first sub-pixel 174x may have both a low(er)-index layer 110 (including without limitation, as a patterning coating 610) and a higher-index layer 120 (including without limitation, as a CPL) defining an index interface 150 therebetween such that the lateral aspect 1110 of the emissive region 1610 thereof may correspond to an interface portion 401, while a second sub-pixel 174x may only have a higher-index layer 120 (including without limitation, as a CPL). In some non-limiting examples, such second sub-pixel 120 may have a quantity of deposited material 731, such that the lateral aspect 1110 of the emissive region 1610 thereof may correspond to a non-interface portion 402.

### Conductive Coating for Electrically Coupling an Electrode to an Auxiliary Electrode

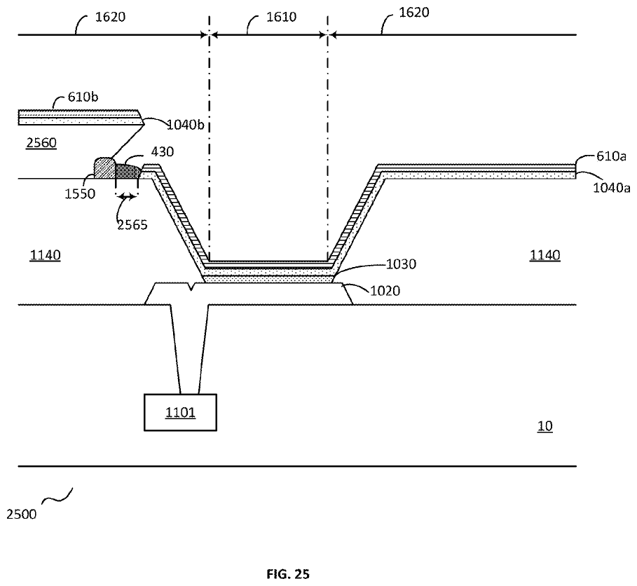

Turning to FIG. 25, there may be shown a cross-sectional view of an example version 2500 of the device 1000. The device 2500 may comprise in a lateral aspect, an emissive region 1610 and an adjacent non-emissive region 1620.

In some non-limiting examples, the emissive region 1610 may correspond to a sub-pixel 174x of the device 2500. The emissive region 1610 may have a substrate 10, a first electrode 1020, a second electrode 1040 and at least one semiconducting layer 1030 arranged therebetween.

The first electrode 1020 may be disposed on an exposed layer surface 11 of the substrate 10. The substrate 10 may comprise a TFT structure 1101, that may be electrically coupled with the first electrode 1020. The edges, and/or perimeter of the first electrode 1020 may generally be covered by at least one PDL 1140.

The non-emissive region 1620 may have an auxiliary electrode 1550 and a first part of the non-emissive region 1620 may have a projecting structure 2560 arranged to project over and overlap a lateral aspect of the auxiliary electrode 1550. The projecting structure 2560 may extend laterally to provide a sheltered region 2565. By way of non-limiting example, the projecting structure 2560 may be recessed at, and/or near the auxiliary electrode 1550 on at least one side to provide the sheltered region 2565. As shown, the sheltered region 2565 may in some non-limiting examples, correspond to a region on a surface of the PDL 1140 that may overlap with a lateral projection of the projecting structure 2560. The non-emissive region 1620 may further comprise a deposited layer 430 disposed in the sheltered region 2565. The deposited layer 430 may electrically couple the auxiliary electrode 1550 with the second electrode 1040.

A patterning coating 610a may be disposed in the emissive region 1610 over the exposed layer surface 11 of the second electrode 1040. In some non-limiting examples, an exposed layer surface 11 of the projecting structure 2560 may be coated with a residual thin conductive film from deposition of a thin conductive film to form a second electrode 1040. In some non-limiting examples, an exposed layer surface 11 of the residual thin conductive film may be coated with a residual patterning coating 610b from deposition of the patterning coating 610.

However, because of the lateral projection of the projecting structure 2560 over the sheltered region 2565, the sheltered region 2565 may be substantially devoid of patterning coating 610. Thus, when a deposited layer 430 may be deposited on the device 2500 after deposition of the patterning coating 610, the deposited layer 430 may be deposited on, and/or migrate to the sheltered region 2565 to couple the auxiliary electrode 1550 to the second electrode 1040.

Those having ordinary skill in the relevant art will appreciate that a non-limiting example has been shown in FIG. 25 and that various modifications may be apparent. By way of non-limiting example, the projecting structure 2560 may provide a sheltered region 2565 along at least two of its sides. In some non-limiting examples, the projecting structure 2560 may be omitted and the auxiliary electrode 1550 may comprise a recessed portion that may define the sheltered region 2565. In some non-limiting examples, the auxiliary electrode 1550 and the deposited layer 430 may be disposed directly on a surface of the substrate 10, instead of the PDL 1140.

### Selective Deposition of Optical Coating

In some non-limiting examples, a device (not shown), which in some non-limiting examples may be an opto-electronic device, may comprise a substrate 10, a patterning coating 610 and an optical coating. The patterning coating 610 may cover, in a lateral aspect, a first portion 601 of the substrate 10. The optical coating may cover, in a lateral aspect, a second portion 602 of the substrate. At least a part of the patterning coating 610 may be substantially devoid of a closed coating 440 of the optical coating.

In some non-limiting examples, the optical coating may be used to modulate optical properties of light being transmitted, emitted, and/or absorbed by the device, including without limitation, plasmon modes. By way of non-limiting example, the optical coating may be used as an optical filter, index-matching coating, optical outcoupling coating, scattering layer, diffraction grating, and/or parts thereof.

In some non-limiting examples, the optical coating may be used to modulate at least one optical microcavity effect in the device by, without limitation, tuning the total optical path length, and/or the refractive index thereof. At least one optical property of the device may be affected by modulating at least one optical microcavity effect including without limitation, the output EM radiation, including without limitation, an angular dependence of an intensity thereof, and/or a wavelength shift thereof. In some non-limiting examples, the optical coating may be a non-electrical component, that is, the optical coating may not be configured to conduct, and/or transmit electrical current during normal device operations.

In some non-limiting examples, the optical coating may be formed of any deposited material 731, and/or may employ any mechanism of depositing a deposited layer 430 as described herein.

### Partition and Recess

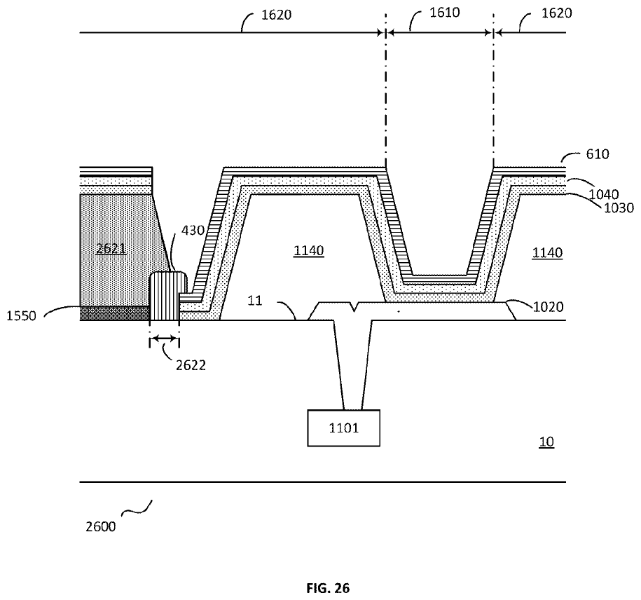

Turning to FIG. 26, there may be shown a cross-sectional view of an example version 2600 of the device 1000. The device 2600 may comprise a substrate 10 having an exposed layer surface 11. The substrate 10 may comprise at least one TFT structure 1101. By way of non-limiting example, the at least one TFT structure 1101 may be formed by depositing and patterning a series of thin films when fabricating the substrate 10, in some non-limiting examples, as described herein.

The device 2600 may comprise, in a lateral aspect, an emissive region 1610 having an associated lateral aspect 1110 and at least one adjacent non-emissive region 1620, each having an associated lateral aspect 1120. The exposed layer surface 11 of the substrate 10 in the emissive region 1610 may be provided with a first electrode 1020, that may be electrically coupled with the at least one TFT structure 1101. A PDL 1140 may be provided on the exposed layer surface 11, such that the PDL 1140 covers the exposed layer surface 11 as well as at least one edge, and/or perimeter of the first electrode 1020. The PDL 1140 may, in some non-limiting examples, be provided in the lateral aspect 1120 of the non-emissive region 1620. The PDL 1140 may define a valley-shaped configuration that may provide an opening that generally may correspond to the lateral aspect 1110 of the emissive region 1610 through which a layer surface of the first electrode 1020 may be exposed. In some non-limiting examples, the device 2600 may comprise a plurality of such openings defined by the PDLs 1140, each of which may correspond to a (sub-) pixel 2210/174x region of the device 2600.

As shown, in some non-limiting examples, a partition 2621 may be provided on the exposed layer surface 11 in the lateral aspect 1120 of a non-emissive region 1620 and, as described herein, may define a sheltered region 2565, such as a recess 2622. In some non-limiting examples, the recess 2622 may be formed by an edge of a lower section of the partition 2621 being recessed, staggered, and/or offset with respect to an edge of an upper section of the partition 2621 that may overlap, and/or project beyond the recess 2622.

In some non-limiting examples, the lateral aspect 1110 of the emissive region 1610 may comprise at least one semiconducting layer 1030 disposed over the first electrode 1020, a second electrode 1040 disposed over the at least one semiconducting layer 1030, and a patterning coating 610 disposed over the second electrode 1040. In some non-limiting examples, the at least one semiconducting layer 1030, the second electrode 1040 and the patterning coating 610 may extend laterally to cover at least the lateral aspect 1120 of a part of at least one adjacent non-emissive region 1620. In some non-limiting examples, as shown, the at least one semiconducting layer 1030, the second electrode 1040 and the patterning coating 610 may be disposed on at least a part of at least one PDL 1140 and at least a part of the partition 2621. Thus, as shown, the lateral aspect 1110 of the emissive region 1610, the lateral aspect 1120 of a part of at least one adjacent non-emissive region 1620 and a part of at least one PDL 1140 and at least a part of the partition 2621, together may make up a first portion 601, in which the second electrode 1040 may lie between the patterning coating 610 and the at least one semiconducting layer 1030.

An auxiliary electrode 1550 may be disposed proximate to, and/or within the recess 2622 and a deposited layer 430 may be arranged to electrically couple the auxiliary electrode 1550 with the second electrode 1040. Thus as shown, the recess 2622 may comprise a second portion 602, in which the deposited layer 430 is disposed on the exposed layer surface 11.

In some non-limiting examples, in depositing the deposited layer 430, at least a part of the evaporated flux 732 of the deposited material 731 may be directed at a non-normal angle relative to a lateral plane of the exposed layer surface 11. By way of non-limiting example, at least a part of the evaporated flux 732 may be incident on the device 2100 at an angle of incidence that is, relative to such lateral plane of the exposed layer surface 11, no more than at least one of about: 90°, 85°, 80°, 75°, 70°, 60°, or 50°. By directing an evaporated flux 732 of a deposited material 731, including at least a part thereof incident at a non-normal angle, at least one exposed layer surface 11 of, and/or in, the recess 2622 may be exposed to such evaporated flux 732.

In some non-limiting examples, a likelihood of such evaporated flux 732 being precluded from being incident onto at least one exposed layer surface 11 of, and/or in the recess 2622 due to the presence of the partition 2621, may be reduced since at least a part of such evaporated flux 732 may be flowed at a non-normal angle of incidence.

In some non-limiting examples, at least a part of such evaporated flux 732 be non-collimated. In some non-limiting examples, at least a part of such evaporated flux 732 may be generated by an evaporation source that is a point source, a linear source, and/or a surface source.

In some non-limiting examples, the device 2600 may be displaced during deposition of the deposited layer 430. By way of non-limiting example, the device 2600, and/or the substrate 10 thereof, and/or any layer(s) deposited thereon, may be subjected to a displacement that is angular, in a lateral aspect, and/or in an aspect substantially parallel to the cross-sectional aspect.

In some non-limiting examples, the device 2600 may be rotated about an axis that substantially normal to the lateral plane of the exposed layer surface 11 while being subjected to the evaporated flux 732.

In some non-limiting examples, at least a part of such evaporated flux 732 may be directed toward the exposed layer surface 11 of the device 2600 in a direction that is substantially normal to the lateral plane of the exposed layer surface 11.

Without wishing to be bound by a particular theory, it may be postulated that the deposited material 731 may nevertheless be deposited within the recess 2622 due to lateral migration, and/or desorption of adatoms adsorbed onto the exposed layer surface 11 of the patterning coating 610. In some non-limiting examples, it may be postulated that any adatoms adsorbed onto the exposed layer surface 11 of the patterning coating 610 may tend to migrate, and/or desorb from such exposed layer surface 11 due to unfavorable thermodynamic properties of the exposed layer surface 11 for forming a stable nucleus. In some non-limiting examples, it may be postulated that at least some of the adatoms migrating, and/or desorbing off such exposed layer surface 11 may be re-deposited onto the surfaces in the recess 2622 to form the deposited layer 430.

In some non-limiting examples, the deposited layer 430 may be formed such that the deposited layer 430 may be electrically coupled with both the auxiliary electrode 1550 and the second electrode 1040. In some non-limiting examples, the deposited layer 430 may be in physical contact with at least one of the auxiliary electrode 1550, and/or the second electrode 1040. In some non-limiting examples, an intermediate layer may be present between the deposited layer 430 and at least one of the auxiliary electrode 1550, and/or the second electrode 1040. However, in such example, such intermediate layer may not substantially preclude the deposited layer 430 from being electrically coupled with the at least one of the auxiliary electrode 1550, and/or the second electrode 1040. In some non-limiting examples, such intermediate layer may be relatively thin and be such as to permit electrical coupling therethrough. In some non-limiting examples, a sheet resistance of the deposited layer 430 may be no more than a sheet resistance of the second electrode 1040.

As shown in FIG. 26, the recess 2622 may be substantially devoid of the second electrode 1040. In some non-limiting examples, during the deposition of the second electrode 1040, the recess 2622 may be masked, by the partition 2621, such that the evaporated flux 732 of the deposited material 731 for forming the second electrode 1040 may be substantially precluded form being incident on at least one exposed layer surface 11 of, and/or in the recess 2622. In some non-limiting examples, at least a part of the evaporated flux 732 of the deposited material 731 for forming the second electrode 1040 may be incident on at least one exposed layer surface 11 of, and/or in the recess 2622, such that the second electrode 1040 may extend to cover at least a part of the recess 2622.

In some non-limiting examples, the auxiliary electrode 1550, the deposited layer 430, and/or the partition 2621 may be selectively provided in certain region(s) of a display panel. In some non-limiting examples, any of these features may be provided at, and/or proximate to, at least one edge of such display panel for electrically coupling at least one element of the frontplane 1010, including without limitation, the second electrode 1040, to at least one element of the backplane 1015. In some non-limiting examples, providing such features at, and/or proximate to, such edges may facilitate supplying and distributing electrical current to the second electrode 1040 from an auxiliary electrode 1550 located at, and/or proximate to, such edges. In some non-limiting examples, such configuration may facilitate reducing a bezel size of the display panel.

In some non-limiting examples, the auxiliary electrode 1550, the deposited layer 430, and/or the partition 2621 may be omitted from certain regions(s) of such display panel. In some non-limiting examples, such features may be omitted from parts of the display panel, including without limitation, where a relatively high pixel density may be provided, other than at, and/or proximate to, at least one edge thereof.

Aperture in Non-Emissive Region

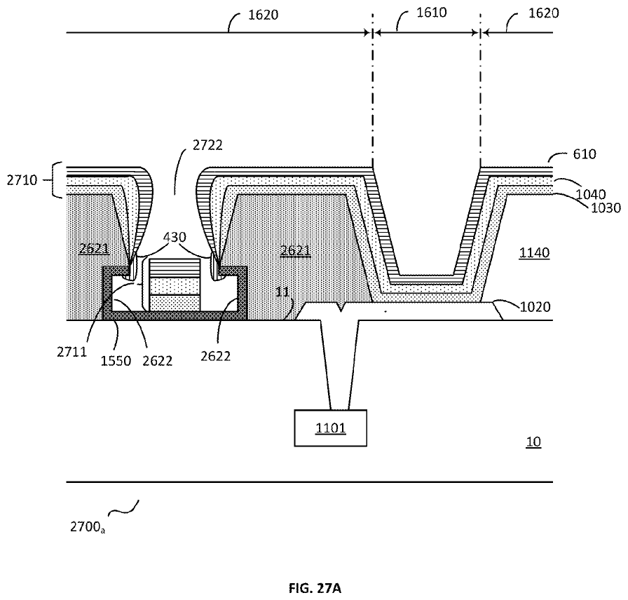

Turning now to FIG. 27A, there may be shown a cross-sectional view of an example version 2700ₐ of the device 1000. The device 2700ₐ may differ from the device 2600 in that a pair of partitions 2621 in the non-emissive region 1620 may be disposed in a facing arrangement to define a sheltered region 2565, such as an aperture 2722, therebetween. As shown, in some non-limiting examples, at least one of the partitions 2621 may function as a PDL 1140 that covers at least an edge of the first electrode 1020 and that defines at least one emissive region 1610. In some non-limiting examples, at least one of the partitions 2621 may be provided separately from a PDL 1140.

A sheltered region 2565, such as the recess 2622, may be defined by at least one of the partitions 2621. In some non-limiting examples, the recess 2622 may be provided in a part of the aperture 2722 proximate to the substrate 10. In some non-limiting examples, the aperture 2722 may be substantially elliptical when viewed in plan view. In some non-limiting examples, the recess 2622 may be substantially annular when viewed in plan view and surround the aperture 2722.

In some non-limiting examples, the recess 2622 may be substantially devoid of materials for forming each of the layers of a device stack 2710, and/or of a residual device stack 2711.

In these figures, a device stack 2710 may be shown comprising the at least one semiconducting layer 1030, the second electrode 1040 and the patterning coating 610 deposited on an upper section of the partition 2621.

In these figures, a residual device stack 2711 may be shown comprising the at least one semiconducting layer 1030, the second electrode 1040 and the patterning coating 610 deposited on the substrate 10 beyond the partition 2621 and recess 2622. From comparison with FIG. 26, it may be seen that the residual device stack 2711 may, in some non-limiting examples, correspond to the at least one semiconductor layer 1030, second electrode 1040 and the patterning coating 610 as it approaches the recess 2622 at, and/or proximate to, a lip of the partition 2621. In some non-limiting examples, the residual device stack 2711 may be formed when an open mask and/or mask-free deposition process is used to deposit various materials of the device stack 2710.

In some non-limiting examples, the residual device stack 2711 may be disposed within the aperture 2722. In some non-limiting examples, evaporated materials for forming each of the layers of the device stack 2710 may be deposited within the aperture 2722 to form the residual device stack 2711 therein.

In some non-limiting examples, the auxiliary electrode 1550 may be arranged such that at least a part thereof is disposed within the recess 2622. As shown, in some non-limiting examples, the auxiliary electrode 1550 may be arranged within the aperture 2722, such that the residual device stack 2711 is deposited onto a surface of the auxiliary electrode 1550.

A deposited layer 430 may be disposed within the aperture 2722 for electrically coupling the second electrode 1040 with the auxiliary electrode 1550. By way of non-limiting example, at least a part of the deposited layer 430 may be disposed within the recess 2622.

Turning now to FIG. 27B, there may be shown a cross-sectional view of a further example 2700_{b} of the device 1000. As shown, the auxiliary electrode 1550 may be arranged to form at least a part of a side of the partition 2621. As such, the auxiliary electrode 1550 may be substantially annular, when viewed in plan view, and may surround the aperture 2722. As shown, in some non-limiting examples, the residual device stack 2711 may be deposited onto an exposed layer surface 11 of the substrate 10.

In some non-limiting examples, the partition 2621 may comprise, and/or is formed by, an NPC 920. By way of non-limiting examples, the auxiliary electrode 1550 may act as an NPC 920.

In some non-limiting examples, the NPC 920 may be provided by the second electrode 1040, and/or a portion, layer, and/or material thereof. In some non-limiting examples, the second electrode 1040 may extend laterally to cover the exposed layer surface 11 arranged in the sheltered region 2565. In some non-limiting examples, the second electrode 1040 may comprise a lower layer thereof and a second layer thereof, wherein the second layer thereof may be deposited on the lower layer thereof. In some non-limiting examples, the lower layer of the second electrode 1040 may comprise an oxide such as, without limitation, ITO, IZO, or ZnO. In some non-limiting examples, the upper layer of the second electrode 1040 may comprise a metal such as, without limitation, at least one of Ag, Mg, Mg:Ag, Yb/Ag, other alkali metals, and/or other alkali earth metals.

In some non-limiting examples, the lower layer of the second electrode 1040 may extend laterally to cover a surface of the sheltered region 2565, such that it forms the NPC 920. In some non-limiting examples, at least one exposed layer surface 11 defining the sheltered region 2565 may be treated to form the NPC 920. In some non-limiting examples, such NPC 920 may be formed by chemical, and/or physical treatment, including without limitation, subjecting the surface(s) of the sheltered region 2565 to a plasma, UV, and/or UV-ozone treatment.

Without wishing to be bound to any particular theory, it may be postulated that such treatment may chemically, and/or physically alter such surface(s) to modify at least one property thereof. By way of non-limiting example, such treatment of the surface(s) may increase a concentration of C—O, and/or C—OH bonds on such surface(s), may increase a roughness of such surface(s), and/or may increase a concentration of certain species, and/or functional groups, including without limitation, halogens, nitrogen-containing functional groups, and/or O-containing functional groups to thereafter act as an NPC 920.

### Removal of Selective Coating

In some non-limiting examples, the patterning coating 610 may be removed after deposition of the deposited layer 430, such that at least a part of a previously exposed layer surface 11 of an underlying material covered by the patterning coating 610 may become exposed once again. In some non-limiting examples, the patterning coating 610 may be selectively removed by etching, and/or dissolving the patterning coating 610, and/or by employing plasma, and/or solvent processing techniques that do not substantially affect or erode the deposited layer 430.

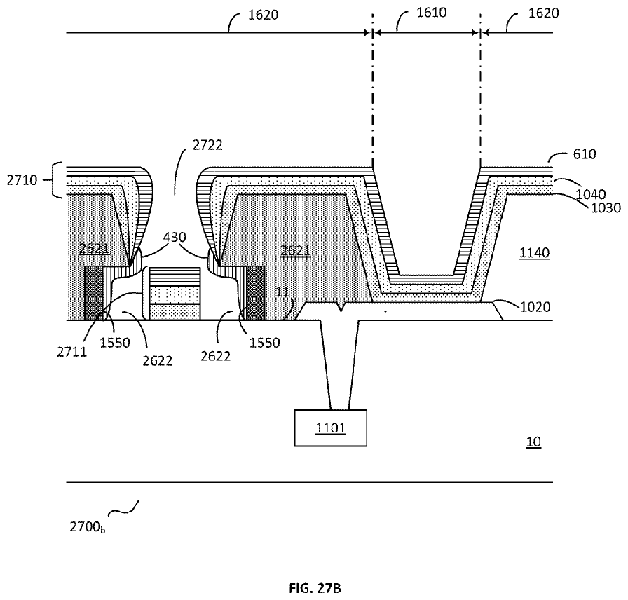

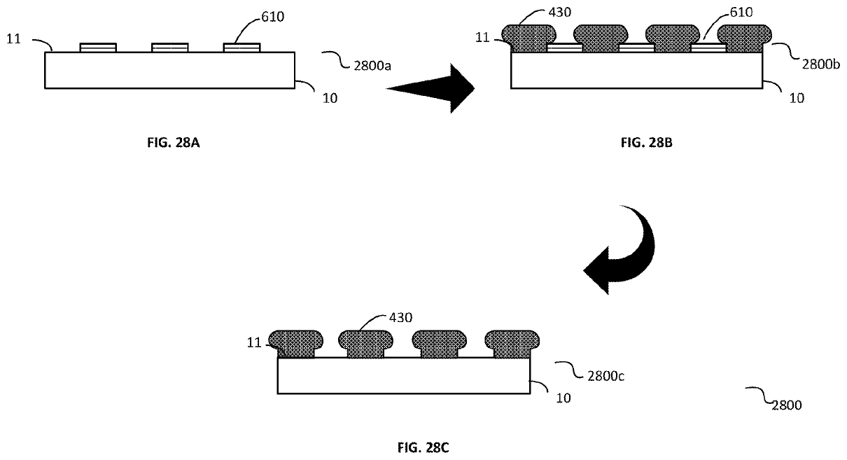

Turning now to FIG. 28A, there may be shown an example cross-sectional view of an example version 2800 of the device 1000, at a deposition stage 2800a, in which a patterning coating 610 may have been selectively deposited on a first portion 601 of an exposed layer surface 11 of an underlying material. In the figure, the underlying material may be the substrate 10.

In FIG. 28B, the device 2800 may be shown at a deposition stage 2800b, in which a deposited layer 430 may be deposited on the exposed layer surface 11 of the underlying material, that is, on both the exposed layer surface 11 of patterning coating 610 where the patterning coating 610 may have been deposited during the stage 2800a, as well as the exposed layer surface 11 of the substrate 10 where that patterning coating 610 may not have been deposited during the stage 2800a. Because of the nucleation-inhibiting properties of the first portion 601 where the patterning coating 610 may have been disposed, the deposited layer 430 disposed thereon may tend to not remain, resulting in a pattern of selective deposition of the deposited layer 430, that may correspond to a second portion 602, leaving the first portion 601 substantially devoid of the deposited layer 430.

In FIG. 28C, the device 2800 may be shown at a deposition stage 2800c, in which the patterning coating 610 may have been removed from the first portion 601 of the exposed layer surface 11 of the substrate 10, such that the deposited layer 430 deposited during the stage 2800b may remain on the substrate 10 and regions of the substrate 10 on which the patterning coating 610 may have been deposited during the stage 2800a may now be exposed or uncovered.

In some non-limiting examples, the removal of the patterning coating 610 in the stage 2800c may be effected by exposing the device 2800 to a solvent, and/or a plasma that reacts with, and/or etches away the patterning coating 610 without substantially impacting the deposited layer 430.

### Thin Film Formation

The formation of thin films during vapor deposition on an exposed layer surface 11 of an underlying layer 130 may involve processes of nucleation and growth.

During initial stages of film formation, a sufficient number of vapor monomers 732 (which in some non-limiting examples may be molecules, and/or atoms of a deposited material 731 in vapor form 732) may typically condense from a vapor phase to form initial nuclei on the exposed layer surface 11 presented of an underlying layer 130. As vapor monomers 732 may impinge on such surface, a characteristic size, and/or deposited density of these initial nuclei may increase to form small particle structures 341. Non-limiting examples of a dimension to which such characteristic size refers may include a height, width, length, and/or diameter of such particle structure 341.

After reaching a saturation island density, adjacent particle structures 341 may typically start to coalesce, increasing an average characteristic size of such particle structures 341, while decreasing a deposited density thereof.

With continued vapor deposition of monomers 732, coalescence of adjacent particle structures 341 may continue until a substantially closed coating 440 may eventually be deposited on an exposed layer surface 11 of an underlying layer 130. The behaviour, including optical effects caused thereby, of such closed coatings 440 may be generally relatively uniform, consistent, and unsurprising.

There may be at least three basic growth modes for the formation of thin films, in some non-limiting examples, culminating in a closed coating 440: 1) island (Volmer-Weber), 2) layer-by-layer (Frank-van der Merwe), and 3) Stranski-Krastanov.

Island growth may typically occur when stale clusters of monomers 732 nucleate on an exposed layer surface 11 and grow to form discrete islands. This growth mode may occur when the interaction between the monomers 732 is stronger than that between the monomers and the surface.

The nucleation rate may describe how many nuclei of a given size (where the free energy does not push a cluster of such nuclei to either grow or shrink) (“critical nuclei”) may be formed on a surface per unit time. During initial stages of film formation, it may be unlikely that nuclei will grow from direct impingement of monomers 732 on the surface, since the deposited density of nuclei is low, and thus the nuclei may cover a relatively small fraction of the surface (e.g., there are large gaps/spaces between neighboring nuclei). Therefore, the rate at which critical nuclei may grow may typically depend on the rate at which adatoms (e.g., adsorbed monomers 732) on the surface migrate and attach to nearby nuclei.

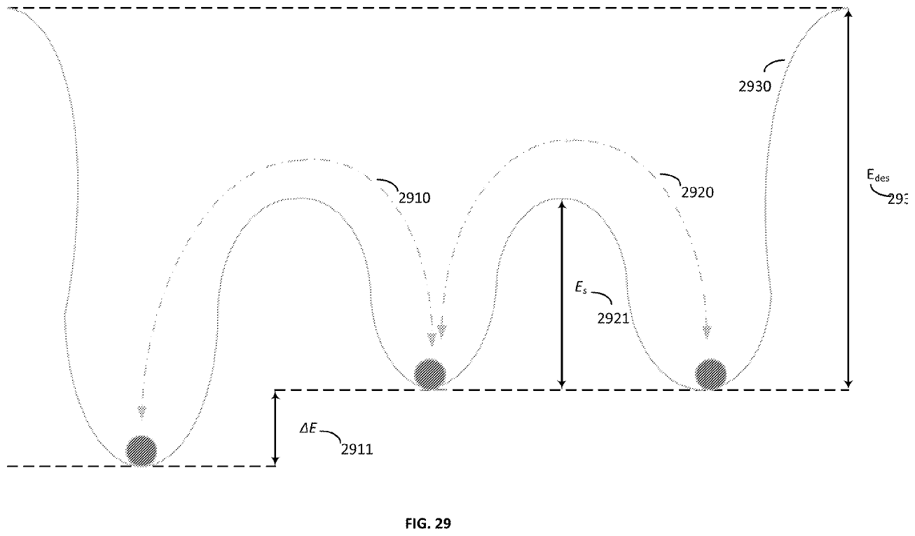

An example of an energy profile of an adatom adsorbed onto an exposed layer surface 11 of an underlying material is illustrated in FIG. 29. Specifically, FIG. 29 may illustrate example qualitative energy profiles corresponding to: an adatom escaping from a local low energy site (2910); diffusion of the adatom on the exposed layer surface 11 (2920); and desorption of the adatom (2930).

In 2910, the local low energy site may be any site on the exposed layer surface 11 of an underlying layer 130, onto which an adatom will be at a lower energy. Typically, the nucleation site may comprise a defect, and/or an anomaly on the exposed layer surface 11, including without limitation, a ledge, a step edge, a chemical impurity, a bonding site, and/or a kink (“heterogeneity”).

Sites of substrate heterogeneity may increase an energy involved to desorb the adatom from the surface E_{des} 2931, leading to a higher deposited density of nuclei observed at such sites. Also, impurities or contamination on a surface may also increase E_{des} 2931, leading to a higher deposited density of nuclei. For vapor deposition processes, conducted under high vacuum conditions, the type and deposited density of contaminants on a surface may be affected by a vacuum pressure and a composition of residual gases that make up that pressure.

Once the adatom is trapped at the local low energy site, there may typically, in some non-limiting examples, be an energy barrier before surface diffusion takes place. Such energy barrier may be represented as ΔE2911 in FIG. 29. In some non-limiting examples, if the energy barrier ΔE2911 to escape the local low energy site is sufficiently large, the site may act as a nucleation site.

In 2920, the adatom may diffuse on the exposed layer surface 11. By way of non-limiting example, in the case of localized absorbates, adatoms may tend to oscillate near a minimum of the surface potential and migrate to various neighboring sites until the adatom is either desorbed, and/or is incorporated into growing islands 341 formed by a cluster of adatoms, and/or a growing film. In FIG. 29, the activation energy associated with surface diffusion of adatoms may be represented as Eₛ 2911.

In 2930, the activation energy associated with desorption of the adatom from the surface may be represented as E_{des} 2931. Those having ordinary skill in the relevant art will appreciate that any adatoms that are not desorbed may remain on the exposed layer surface 11. By way of non-limiting example, such adatoms may diffuse on the exposed layer surface 11, become part of a cluster of adatoms that form islands 341 on the exposed layer surface 11, and/or be incorporated as part of a growing film, and/or coating.

After adsorption of an adatom on a surface, the adatom may either desorb from the surface, or may migrate some distance on the surface before either desorbing, interacting with other adatoms to form a small cluster, or attaching to a growing nucleus. An average amount of time that an adatom may remain on the surface after initial adsorption may be given by:

$${τ}_{s} = \frac{1}{v} exp ( \frac{{E}_{d e s}}{k T} ) \qquad ( TF 1 )$$

In the above equation:
v is a vibrational frequency of the adatom on the surface,
k is the Botzmann constant, and
T is temperature.

From Equation TF1 it may be noted that the lower the value of E_{des} 2931, the easier it may be for the adatom to desorb from the surface, and hence the shorter the time the adatom may remain on the surface. A mean distance an adatom can diffuse may be given by,

$$X = {a}_{0} exp ( \frac{{E}_{d e s} - {E}_{S}}{2 k T} ) \qquad ( TF 2 )$$

where:
α₀ is a lattice constant.

For low values of E_{des} 2931, and/or high values of Eₛ 2921, the adatom may diffuse a shorter distance before desorbing, and hence may be less likely to attach to growing nuclei or interact with another adatom or cluster of adatoms.

During initial stages of formation of a deposited layer of particle structures 341, adsorbed adatoms may interact to form particle structures 341, with a critical concentration of particle structures 341 per unit area being given by,

$$\frac{{N}_{i}}{{n}_{0}} = {\vert \frac{{N}_{1}}{{n}_{0}} \vert}^{i} exp ( \frac{{E}_{i}}{k T} ) \qquad ( TF 3 )$$

where:
Eᵢ is an energy involved to dissociate a critical cluster containing I adatoms into separate adatoms,
n₀ is a total deposited density of adsorption sites, and
N₁ is a monomer deposited density given by:

N₁=\dot{R}τₛ (TF4)

where:
\dot{R} is a vapor impingement rate.

Typically, I may depend on a crystal structure of a material being deposited and may determine a critical size of particle structures 341 to form a stable nucleus.

A critical monomer supply rate for growing particle structures 341 may be given by the rate of vapor impingement and an average area over which an adatom can diffuse before desorbing:

$$\dot{R} {X}^{2} = {α}_{0}^{2} exp ( \frac{{E}_{d e s} - {E}_{s}}{k T} ) \qquad ( TF 5 )$$

The critical nucleation rate may thus be given by the combination of the above equations:

$${\dot{N}}_{i} = \dot{R} {α}_{0}^{2} {{n}_{0} ( \frac{\dot{R}}{v {n}_{0}} )}^{i} exp ( \frac{( i + 1 ) {E}_{d e s} - {E}_{s} + {E}_{i}}{k T} ) \qquad ( TF 6 )$$

From the above equation, it may be noted that the critical nucleation rate may be suppressed for surfaces that have a low desorption energy for adsorbed adatoms, a high activation energy for diffusion of an adatom, are at high temperatures, and/or are subjected to vapor impingement rates.

Under high vacuum conditions, a flux 732 of molecules that may impinge on a surface (per cm²-sec) may be given by:

$$ϕ = 3.513 \times 1 {0}^{22} \frac{P}{M T} \qquad ( TF 7 )$$

where:
P is pressure, and
M is molecular weight.

Therefore, a higher partial pressure of a reactive gas, such as H₂O, may lead to a higher deposited density of contamination on a surface during vapor deposition, leading to an increase in E_{des} 2931 and hence a higher deposited density of nuclei.

In the present disclosure, “nucleation-inhibiting” may refer to a coating, material, and/or a layer thereof, that may have a surface that exhibits an initial sticking probability against deposition of a deposited material 731 thereon, that may be close to 0, including without limitation, no more than about 0.3, such that the deposition of the deposited material 731 on such surface may be inhibited.

In the present disclosure, “nucleation-promoting” may refer to a coating, material, and/or a layer thereof, that has a surface that exhibits an initial sticking probability against deposition of a deposited material 731 thereon, that may be close to 1, including without limitation, greater than about 0.7, such that the deposition of the deposited material 731 on such surface may be facilitated.

Without wishing to be bound by a particular theory, it may be postulated that the shapes and sizes of such nuclei and the subsequent growth of such nuclei into islands 341 and thereafter into a thin film may depend upon various factors, including without limitation, interfacial tensions between the vapor, the surface, and/or the condensed film nuclei.

One measure of a nucleation-inhibiting, and/or nucleation-promoting property of a surface may be the initial sticking probability of the surface against the deposition of a given deposited material 731.

In some non-limiting examples, the sticking probability S may be given by:

$$S = \frac{{N}_{a d s}}{{N}_{t o t a l}} \qquad ( TF 8 )$$

where:
N_{ads} is a number of adatoms that remain on an exposed layer surface 11 (that is, are incorporated into a film), and
Nₜₒₜₐₗ is a total number of impinging monomers on the surface.

A sticking probability S equal to 1 may indicate that all monomers 732 that impinge on the surface are adsorbed and subsequently incorporated into a growing film. A sticking probability S equal to 0 may indicate that all monomers 732 that impinge on the surface are desorbed and subsequently no film may be formed on the surface.

A sticking probability S of a deposited material 731 on various surfaces may be evaluated using various techniques of measuring the sticking probability S, including without limitation, a dual quartz crystal microbalance (QCM) technique as described by Walker et al., J. Phys. Chem. C 2007, 111, 765 (2006).

As the deposited density of a deposited material 731 may increase (e.g., increasing average film thickness), a sticking probability S may change.

An initial sticking probability S₀ may therefore be specified as a sticking probability S of a surface prior to the formation of any significant number of critical nuclei. One measure of an initial sticking probability S₀ may involve a sticking probability S of a surface against the deposition of a deposited material 731 during an initial stage of deposition thereof, where an average film thickness of the deposited material 731 across the surface is at or below a threshold value. In the description of some non-limiting examples a threshold value for an initial sticking probability may be specified as, by way of non-limiting example, 1 nm. An average sticking probability S̅ may then be given by:

S̅=S₀(1−A_{nuc})+S_{nuc}(A_{nuc}) (TF9)

where:
S_{nuc} is a sticking probability S of an area covered by particle structures 341, and
A_{nuc} is a percentage of an area of a substrate surface covered by particle structures 341.

By way of non-limiting example, a low initial sticking probability may increase with increasing average film thickness. This may be understood based on a difference in sticking probability between an area of an exposed layer surface 11 with no particle structures 341, by way of non-limiting example, a bare substrate 10, and an area with a high deposited density. By way of non-limiting example, a monomer 732 that may impinge on a surface of a particle structure 341 may have a sticking probability S that may approach 1.

Based on the energy profiles 2910, 2920, 2930 shown in FIG. 29, it may be postulated that materials that exhibit relatively low activation energy for desorption (E_{des} 2931), and/or relatively high activation energy for surface diffusion (Eₛ 2921), may be deposited as a patterning coating 610, and may be suitable for use in various applications.

Without wishing to be bound by a particular theory, it may be postulated that, in some non-limiting examples, the relationship between various interfacial tensions present during nucleation and growth may be dictated according to Young's equation in capillarity theory:

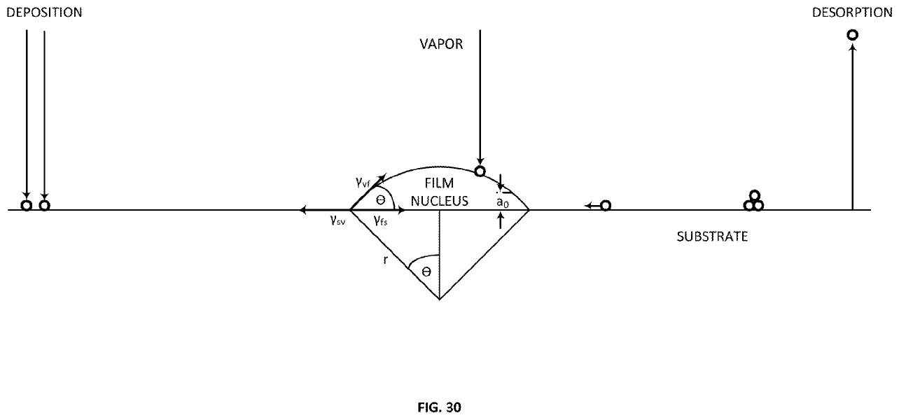

γₛᵥ=γ_{fs}+γ_{vf} cos θ (TF10)

where:
γₛᵥ (FIG. 30) corresponds to the interfacial tension between the substrate 10 and vapor 732,
γ_{fs} (FIG. 30) corresponds to the interfacial tension between the deposited material 731 and the substrate 10,
γ_{vf} (FIG. 30) corresponds to the interfacial tension between the vapor 732 and the film, and
θ is the film nucleus contact angle.

FIG. 30 may illustrate the relationship between the various parameters represented in this equation.

On the basis of Young's equation (Equation (TF10)), it may be derived that, for island growth, the film nucleus contact angle may exceed 0 and therefore: γₛᵥ<γ_{fs}+γ_{vf}.

For layer growth, where the deposited material 731 may “wet” the substrate 10, the nucleus contact angle may be equal to 0, and therefore: γₛᵥ=γ_{fs}+γ_{vf}.

For Stranski-Krastanov growth, where the strain energy per unit area of the film overgrowth may be large with respect to the interfacial tension between the vapor 732 and the deposited material 731: γₛᵥ>γ_{fs}+γ_{vf}.

Without wishing to be bound by any particular theory, it may be postulated that the nucleation and growth mode of a deposited material 731 at an interface between the patterning coating 610 and the exposed layer surface 11 of the substrate 10, may follow the island growth model, where θ>0.

Particularly in cases where the patterning coating 610 may exhibit a relatively low initial sticking probability (in some non-limiting examples, under the conditions identified in the dual QCM technique described by Walker et. al) against deposition of the deposited material 731, there may be a relatively high thin film contact angle of the deposited material 731.

On the contrary, when a deposited material 731 may be selectively deposited on an exposed layer surface 11 without the use of a patterning coating 610, by way of non-limiting example, by employing a shadow mask 615, the nucleation and growth mode of such deposited material 731 may differ. In particular, it has been observed that a coating formed using a shadow mask 615 patterning process may, at least in some non-limiting examples, exhibit relatively low thin film contact angle θ of no more than about 10°.

It has now been found, somewhat surprisingly, that in some non-limiting examples, a patterning coating 610 (and/or the patterning material 611 of which it is comprised) may exhibit a relatively low critical surface tension.

Those having ordinary skill in the relevant art will appreciate that a “surface energy” of a coating, layer, and/or a material constituting such coating, and/or layer, may generally correspond to a critical surface tension of the coating, layer, and/or material. According to some models of surface energy, the critical surface tension of a surface may correspond substantially to the surface energy of such surface.

Generally, a material with a low surface energy may exhibit low intermolecular forces. Generally, a material with low intermolecular forces may readily crystallize or undergo other phase transformation at a lower temperature in comparison to another material with high intermolecular forces. In at least some applications, a material that may readily crystallize or undergo other phase transformations at relatively low temperatures may be detrimental to the long-term performance, stability, reliability, and/or lifetime of the device.

Without wishing to be bound by a particular theory, it may be postulated that certain low energy surfaces may exhibit relatively low initial sticking probabilities S₀ and may thus be suitable for forming the patterning coating 610.

Without wishing to be bound by any particular theory, it may be postulated that, especially for low surface energy surfaces, the critical surface tension may be positively correlated with the surface energy. By way of non-limiting example, a surface exhibiting a relatively low critical surface tension may also exhibit a relatively low surface energy, and a surface exhibiting a relatively high critical surface tension may also exhibit a relatively high surface energy.

In reference to Young's equation (Equation (TF10)), a lower surface energy may result in a greater contact angle, while also lowering the γₛᵥ, thus enhancing the likelihood of such surface having low wettability and low initial sticking probability with respect to the deposited material 731.

The critical surface tension values, in various non-limiting examples, herein may correspond to such values measured at around normal temperature and pressure (NTP), which in some non-limiting examples, may correspond to a temperature of 20° C., and an absolute pressure of 1 atm. In some non-limiting examples, the critical surface tension of a surface may be determined according to the Zisman method, as further detailed in Zisman, W. A., “Advances in Chemistry” 43 (1964), p. 1-51.

In some non-limiting examples, the exposed layer surface 11 of the patterning coating 610 may exhibit a critical surface tension of no more than at least one of about: 20 dynes/cm, 19 dynes/cm, 18 dynes/cm, 17 dynes/cm, 16 dynes/cm, 15 dynes/cm, 13 dynes/cm, 12 dynes/cm, or 11 dynes/cm.

In some non-limiting examples, the exposed layer surface 11 of the patterning coating 610 may exhibit a critical surface tension of at least one of at least about: 6 dynes/cm, 7 dynes/cm, 8 dynes/cm, 9 dynes/cm, and 10 dynes/cm.

Those having ordinary skill in the relevant art will appreciate that various methods and theories for determining the surface energy of a solid may be known. By way of non-limiting example, the surface energy may be calculated, and/or derived based on a series of measurements of contact angle, in which various liquids are brought into contact with a surface of a solid to measure the contact angle between the liquid-vapor interface and the surface. In some non-limiting examples, the surface energy of a solid surface may be equal to the surface tension of a liquid with the highest surface tension that completely wets the surface. By way of non-limiting example, a Zisman plot may be used to determine the highest surface tension value that would result in a contact angle of 0° with the surface. According to some theories of surface energy, various types of interactions between solid surfaces and liquids may be considered in determining the surface energy of the solid. By way of non-limiting example, according to some theories, including without limitation, the Owens/Wendt theory, and/or Fowkes' theory, the surface energy may comprise a dispersive component and a non-dispersive or “polar” component.

Without wishing to be bound by a particular theory, it may be postulated that, in some non-limiting examples, the contact angle of a coating of deposited material 731 may be determined, based at least partially on the properties (including, without limitation, initial sticking probability) of the patterning coating 610 onto which the deposited material 731 is deposited. Accordingly, patterning materials 611 that allow selective deposition of deposited materials 731 exhibiting relatively high contact angles may provide some benefit.

Those having ordinary skill in the relevant art will appreciate that various methods may be used to measure a contact angle, including without limitation, the static, and/or dynamic sessile drop method and the pendant drop method.

In some non-limiting examples, the activation energy for desorption (E_{des}, 2931) (in some non-limiting examples, at a temperature of about 300K) may be no more than at least one of about: 2 times, 1.5 times, 1.3 times, 1.2 times, 1.0 times, 0.8 times, or 0.5 times, the thermal energy. In some non-limiting examples, the activation energy for surface diffusion (Eₛ 2921) (in some non-limiting examples, at a temperature of about 300K) may exceed at least one of about: 1.0 times, 1.5 times, 1.8 times, 2 times, 3 times, 5 times, 7 times, or 10 times the thermal energy.

Without wishing to be bound by a particular theory, it may be postulated that, during thin film nucleation and growth of a deposited material 731 at, and/or near an interface between the exposed layer surface 11 of the underlying layer 130 and the patterning coating 610, a relatively high contact angle θ between the edge of the deposited material 731 and the underlying layer 130 may be observed due to the inhibition of nucleation of the solid surface of the deposited material 731 by the patterning coating 610. Such nucleation inhibiting property may be driven by minimization of surface energy between the underlying layer 130, thin film vapor and the patterning coating 610.

One measure of a nucleation-inhibiting, and/or nucleation-promoting property of a surface may be an initial deposition rate of a given (electrically conductive) deposited material 731, on the surface, relative to an initial deposition rate of the same deposited material 731 on a reference surface, where both surfaces are subjected to, and/or exposed to an evaporation flux of the deposited material 731.

### Definitions

In some non-limiting examples, the electro-luminescent device may be an organic light-emitting diode (OLED) device. In some non-limiting examples, the electro-luminescent device may be part of an electronic device. By way of non-limiting example, the electro-luminescent device may be an OLED lighting panel or module, and/or an OLED display or module of a computing device, such as a smartphone, a tablet, a laptop, an e-reader, and/or of some other electronic device such as a monitor, and/or a television set.

In some non-limiting examples, the opto-electronic device may be an organic photo-voltaic (OPV) device that converts photons into electricity. In some non-limiting examples, the opto-electronic device may be an electro-luminescent quantum dot (QD) device.

In the present disclosure, unless specifically indicated to the contrary, reference will be made to OLED devices, with the understanding that such disclosure could, in some examples, equally be made applicable to other opto-electronic devices, including without limitation, an OPV, and/or QD device, in a manner apparent to those having ordinary skill in the relevant art.

The structure of such devices may be described from each of two aspects, namely from a cross-sectional aspect, and/or from a lateral (plan view) aspect.

In the present disclosure, a directional convention may be followed, extending substantially normally to the lateral aspect described above, in which the substrate may be the “bottom” of the device, and the layers may be disposed on “top” of the substrate. Following such convention, the second electrode may be at the top of the device shown, even if (as may be the case in some examples, including without limitation, during a manufacturing process, in which at least one layers may be introduced by means of a vapor deposition process), the substrate may be physically inverted, such that the top surface, in which one of the layers, such as, without limitation, the first electrode, may be disposed, may be physically below the substrate, to allow the deposition material (not shown) to move upward and be deposited upon the top surface thereof as a thin film.

In the context of introducing the cross-sectional aspect herein, the components of such devices may be shown in substantially planar lateral strata. Those having ordinary skill in the relevant art will appreciate that such substantially planar representation may be for purposes of illustration only, and that across a lateral extent of such a device, there may be localized substantially planar strata of different thicknesses and dimension, including, in some non-limiting examples, the substantially complete absence of a layer, and/or layer(s) separated by non-planar transition regions (including lateral gaps and even discontinuities). Thus, while for illustrative purposes, the device may be shown below in its cross-sectional aspect as a substantially stratified structure, in the plan view aspect discussed below, such device may illustrate a diverse topography to define features, each of which may substantially exhibit the stratified profile discussed in the cross-sectional aspect.

In the present disclosure, the terms “layer” and “strata” may be used interchangeably to refer to similar concepts.

The thickness of each layer shown in the figures may be illustrative only and not necessarily representative of a thickness relative to another layer.

For purposes of simplicity of description, in the present disclosure, a combination of a plurality of elements in a single layer may be denoted by a colon while a plurality of (combination(s) of) elements comprising a plurality of layers in a multi-layer coating may be denoted by separating two such layers by a slash “I”. In some non-limiting examples, the layer after the slash may be deposited after, and/or on the layer preceding the slash.

For purposes of illustration, an exposed layer surface of an underlying material, onto which a coating, layer, and/or material may be deposited, may be understood to be a surface of such underlying material that may be presented for deposition of the coating, layer, and/or material thereon, at the time of deposition.

Those having ordinary skill in the relevant art will appreciate that when a component, a layer, a region, and/or a portion thereof, is referred to as being “formed”, “disposed”, and/or “deposited” on, and/or over another underlying material, component, layer, region, and/or portion, such formation, disposition, and/or deposition may be directly, and/or indirectly on an exposed layer surface (at the time of such formation, disposition, and/or deposition) of such underlying material, component, layer, region, and/or portion, with the potential of intervening material(s), component(s), layer(s), region(s), and/or portion(s) therebetween.

In the present disclosure, the terms “overlap”, and/or “overlapping” may refer generally to plurality layers, and/or structures arranged to intersect a cross-sectional axis extending substantially normally away from a surface onto which such layers, and/or structures may be disposed.

While the present disclosure discusses thin film formation, in reference to at least one layer or coating, in terms of vapor deposition, those having ordinary skill in the relevant art will appreciate that, in some non-limiting examples, various components of the device may be selectively deposited using a wide variety of techniques, including without limitation, evaporation (including without limitation, thermal evaporation, and/or electron beam evaporation), photolithography, printing (including without limitation, ink jet, and/or vapor jet printing, reel-to-reel printing, and/or micro-contact transfer printing), PVD (including without limitation, sputtering), chemical vapor deposition (CVD) (including without limitation, plasma-enhanced CVD (PECVD), and/or organic vapor phase deposition (OVPD)), laser annealing, laser-induced thermal imaging (LITI) patterning, atomic-layer deposition (ALD), coating (including without limitation, spin-coating, di coating, line coating, and/or spray coating), and/or combinations thereof (collectively “deposition process”).

Some processes may be used in combination with a shadow mask, which may, in some non-limiting examples, may be an open mask, and/or fine metal mask (FMM), during deposition of any of various layers, and/or coatings to achieve various patterns by masking, and/or precluding deposition of a deposited material on certain parts of a surface of an underlying material exposed thereto.

In the present disclosure, the terms “evaporation”, and/or “sublimation” may be used interchangeably to refer generally to deposition processes in which a source material is converted into a vapor, including without limitation, by heating, to be deposited onto a target surface in, without limitation, a solid state. As will be understood, an evaporation deposition process may be a type of PVD process where at least one source materials are evaporated, and/or sublimed under a low pressure (including without limitation, a vacuum) environment to form vapor monomers and deposited on a target surface through de-sublimation of the at least one evaporated source materials. A variety of different evaporation sources may be used for heating a source material, and, as such, it will be appreciated by those having ordinary skill in the relevant art, that the source material may be heated in various ways. By way of non-limiting example, the source material may be heated by an electric filament, electron beam, inductive heating, and/or by resistive heating. In some non-limiting examples, the source material may be loaded into a heated crucible, a heated boat, a Knudsen cell (which may be an effusion evaporator source), and/or any other type of evaporation source.

In some non-limiting examples, a deposition source material may be a mixture. In some non-limiting examples, at least one component of a mixture of a deposition source material may be not be deposited during the deposition process (or, in some non-limiting examples, be deposited in a relatively small amount compared to other components of such mixture).

In the present disclosure, a reference to a layer thickness, a film thickness, and/or an average layer, and/or film thickness, of a material, irrespective of the mechanism of deposition thereof, may refer to an amount of the material deposited on a target exposed layer surface, which corresponds to an amount of the material to cover the target surface with a uniformly thick layer of the material having the referenced layer thickness. By way of non-limiting example, depositing a layer thickness of 10 nm of material may indicate that an amount of the material deposited on the surface may correspond to an amount of the material to form a uniformly thick layer of the material that may be 10 nm thick. It will be appreciated that, having regard to the mechanism by which thin films are formed discussed above, by way of non-limiting example, due to possible stacking or clustering of monomers, an actual thickness of the deposited material may be non-uniform. By way of non-limiting example, depositing a layer thickness of 10 nm may yield some parts of the deposited material having an actual thickness greater than 10 nm, or other parts of the deposited material having an actual thickness no more than 10 nm. A certain layer thickness of a material deposited on a surface may thus correspond, in some non-limiting examples, to an average thickness of the deposited material across the target surface.

In the present disclosure, a reference to a reference layer thickness may refer to a layer thickness of the deposited material, also referred to herein as the deposited material (such as Mg), that may be deposited on a reference surface exhibiting a high initial sticking probability or initial sticking coefficient (that is, a surface having an initial sticking probability that is about, and/or close to 1.0). The reference layer thickness may not indicate an actual thickness of the deposited material deposited on a target surface (such as, without limitation, a surface of a patterning coating). Rather, the reference layer thickness may refer to a layer thickness of the deposited material that would be deposited on a reference surface, in some non-limiting examples a surface of a quartz crystal positioned inside a deposition chamber for monitoring a deposition rate and the reference layer thickness, upon subjecting the target surface and the reference surface to identical vapor flux of the deposited material for the same deposition period. Those having ordinary skill in the relevant art will appreciate that in the event that the target surface and the reference surface are not subjected to identical vapor flux simultaneously during deposition, an appropriate tooling factor may be used to determine, and/or to monitor the reference layer thickness.

In the present disclosure, a reference deposition rate may refer to a rate at which a layer of the deposited material would grow on the reference surface, if it were identically positioned and configured within a deposition chamber as the sample surface.

In the present disclosure, a reference to depositing a number X of monolayers of material may refer to depositing an amount of the material to cover a given area of an exposed layer surface with X single layer(s) of constituent monomers of the material, such as, without limitation, in a closed coating.

In the present disclosure, a reference to depositing a fraction of a monolayer of a material may refer to depositing an amount of the material to cover such fraction of a given area of an exposed layer surface with a single layer of constituent monomers of the material. Those having ordinary skill in the relevant art will appreciate that due to, by way of non-limiting example, possible stacking, and/or clustering of monomers, an actual local thickness of a deposited material across a given area of a surface may be non-uniform. By way of non-limiting example, depositing 1 monolayer of a material may result in some local regions of the given area of the surface being uncovered by the material, while other local regions of the given area of the surface may have multiple atomic, and/or molecular layers deposited thereon.

In the present disclosure a target surface (and/or target region(s) thereof) may be considered to be “substantially devoid of”, “substantially free of”, and/or “substantially uncovered by” a material if there may be a substantial absence of the material on the target surface as determined by any suitable determination mechanism.

In the present disclosure, the terms “sticking probability” and “sticking coefficient” may be used interchangeably.

In the present disclosure, the term “nucleation” may reference a nucleation stage of a thin film formation process, in which monomers in a vapor phase condense onto a surface to form nuclei.

In the present disclosure, in some non-limiting examples, as the context dictates, the terms “patterning coating” and “patterning material” may be used interchangeably to refer to similar concepts, and references to a nucleation inhibiting coating (NIC) herein, in the context of being selectively deposited to pattern a deposited layer may, in some non-limiting examples, be applicable to an NIC in the context of selective deposition thereof to pattern a deposited material, and/or an electrode coating material.

Similarly, in some non-limiting examples, as the context dictates, the term “patterning coating” and “patterning material” may be used interchangeably to refer to similar concepts, and reference to an NPC herein, in the context of being selectively deposited to pattern a deposited layer may, in some non-limiting examples, be applicable to an NPC in the context of selective deposition thereof to pattern a deposited material, and/or an electrode coating material.

While a patterning material may be either nucleation-inhibiting or nucleation-promoting, in the present disclosure, unless the context dictates otherwise, a reference herein to a patterning material is intended to be a reference to an NIC.

In some non-limiting examples, reference to a patterning coating may signify a coating having a specific composition as described herein.

In the present disclosure, the terms “deposited layer”, “conductive coating”, and “electrode coating” may be used interchangeably to refer to similar concepts and references to a deposited layer herein, in the context of being patterned by selective deposition of an NIC, and/or an NPC may, in some non-limiting examples, be applicable to a deposited layer in the context of being patterned by selective deposition of a patterning material. In some non-limiting examples, reference to an electrode coating may signify a coating having a specific composition as described herein. Similarly, in the present disclosure, the terms “deposited layer material”, “deposited material”, “conductive coating material” and “electrode coating material” may be used interchangeably to refer to similar concepts and references to a deposited material herein.

In the present disclosure, it will be appreciated by those having ordinary skill in the relevant art that an organic material, may comprise, without limitation, a wide variety of organic molecules, and/or organic polymers. Further, it will be appreciated by those having ordinary skill in the relevant art that organic materials that are doped with various inorganic substances, including without limitation, elements, and/or inorganic compounds, may still be considered organic materials. Still further, it will be appreciated by those having ordinary skill in the relevant art that various organic materials may be used, and that the processes described herein are generally applicable to an entire range of such organic materials. Still further, it will be appreciated by those having ordinary skill in the relevant art that organic materials that contain metals, and/or other organic elements, may still be considered as organic materials. Still further, it will be appreciated by those having ordinary skill in the relevant art that various organic materials may be molecules, oligomers, and/or polymers.

As used herein, an organic-inorganic hybrid material may generally refer to a material that comprises both an organic component and an inorganic component. In some non-limiting examples, such organic-inorganic hybrid material may comprise an organic-inorganic hybrid compound that comprises an organic moiety and an inorganic moiety. Non-limiting examples of such organic-inorganic hybrid compounds include those in which an inorganic scaffold is functionalized with at least one organic functional group. Non-limiting examples of such organic-inorganic hybrid materials includes those comprising at least one of: a siloxane group, a silsesquioxane group, a polyhedral oligomeric silsesquioxane (POSS) group, a phosphazene group, and a metal complex.

In the present disclosure, a semiconductor material may be described as a material that generally exhibits a band gap. In some non-limiting examples, the band gap may be formed between a highest occupied molecular orbital (HOMO) and a lowest unoccupied molecular orbital (LUMO) of the semiconductor material. Semiconductor materials thus generally exhibit electrical conductivity that is no more than that of a conductive material (including without limitation, a metal), but that is greater than that of an insulating material (including without limitation, a glass). In some non-limiting examples, the semiconductor material may comprise an organic semiconductor material. In some non-limiting examples, the semiconductor material may comprise an inorganic semiconductor material.

As used herein, an oligomer may generally refer to a material which includes at least two monomer units or monomers. As would be appreciated by a person skilled in the art, an oligomer may differ from a polymer in at least one aspect, including but not limited to: (1) the number of monomer units contained therein; (2) the molecular weight; and (3) other materials properties, and/or characteristics. By way of non-limiting example, further description of polymers and oligomers may be found in Naka K. (2014) Monomers, Oligomers, Polymers, and Macromolecules (Overview), and in Kobayashi S., Mullen K. (eds.) Encyclopedia of Polymeric Nanomaterials, Springer, Berlin, Heidelberg.

An oligomer or a polymer may generally include monomer units that may be chemically bonded together to form a molecule. Such monomer units may be substantially identical to one another such that the molecule is primarily formed by repeating monomer units, or the molecule may include plurality different monomer units. Additionally, the molecule may include at least one terminal units, which may be different from the monomer units of the molecule. An oligomer or a polymer may be linear, branched, cyclic, cyclo-linear, and/or cross-linked. An oligomer or a polymer may include plurality different monomer units which are arranged in a repeating pattern, and/or in alternating blocks of different monomer units.

In the present disclosure, the term “semiconducting layer(s)” may be used interchangeably with “organic layer(s)” since the layers in an OLED device may in some non-limiting examples, may comprise organic semiconducting materials.

In the present disclosure, an inorganic substance may refer to a substance that primarily includes an inorganic material. In the present disclosure, an inorganic material may comprise any material that is not considered to be an organic material, including without limitation, metals, glasses, and/or minerals.

In the present disclosure, the terms “photon” and “light” may be used interchangeably to refer to similar concepts. In the present disclosure, photons may have a wavelength that lies in the visible spectrum, in the infrared (IR) region (IR spectrum), near IR region (NIR spectrum), ultraviolet (UV) region (UV spectrum), and/or UVA region (UVA spectrum) (which may correspond to a wavelength range between about 315-400 nm) thereof.

In the present disclosure, the term “visible spectrum” as used herein, may generally refer to at least one wavelength in a visible part of the EM spectrum.

As would be appreciated by those having ordinary skill in the relevant art, such visible part may correspond to any wavelength between about 380-740 nm. In general, electro-luminescent devices may be configured to emit, and/or transmit EM radiation having wavelengths in a range of between about 425-725 nm, and more specifically, in some non-limiting examples, EM radiation having peak emission wavelengths of 456 nm, 528 nm, and 624 nm, corresponding to B(lue), G(reen), and R(ed) sub-pixels, respectively. Accordingly, in the context of such electro-luminescent devices, the visible part may refer to any wavelength between about 425-725 nm, or between about 456-624 nm. EM radiation having a wavelength in the visible spectrum may, in some non-limiting examples, also be referred to as “visible light” herein.

In the present disclosure, the term “emission spectrum” as used herein, may generally refer to an electroluminescence spectrum of light emitted by an opto-electronic device. By way of non-limiting example, an emission spectrum may be detected using an optical instrument, such as, by way of non-limiting example, a spectrophotometer, which may measure an intensity of EM radiation across a wavelength range.

In the present disclosure, the term “onset wavelength”, as used herein, may generally refer to a lowest wavelength at which an emission is detected within an emission spectrum.

In the present disclosure, the term “peak wavelength”, as used herein, may generally refer to a wavelength at which a maximum luminous intensity is detected within an emission spectrum.

In some non-limiting examples, the onset wavelength may be no more than the peak wavelength. In some non-limiting examples, the onset wavelength may correspond to a wavelength at which a luminous intensity is no more than at least one of about: 10%, 5%, 3%, 1%, 0.5%, 0.1%, or 0.01%, of a luminous intensity at the peak wavelength.

In some non-limiting examples, an emission spectrum that lies in the R(ed) part of the visible spectrum may be characterized by a peak wavelength that may lie in a wavelength range of about 410-640 nm and in some non-limiting examples, may be substantially about 620 nm.

In some non-limiting examples, an emission spectrum that lies in the G(reen) part of the visible spectrum may be characterized by a peak wavelength that may lie in a wavelength range of about 510-340 nm and in some non-limiting examples, may be substantially about 530 nm.

In some non-limiting examples, an emission spectrum that lies in the B(lue) part of the visible spectrum may be characterized by a peak wavelength that may lie in a wavelength range of about 450-4941 nm and in some non-limiting examples, may be substantially about 455 nm.

In the present disclosure, the term “IR signal” as used herein, may generally refer to EM radiation having a wavelength in an IR subset (IR spectrum) of the EM spectrum. An IR signal may, in some non-limiting examples, have a wavelength corresponding to a near-infrared (NIR) subset (NIR spectrum) thereof. By way of non-limiting examples, an NIR signal may have a wavelength of at least one of between about: 750-1400 nm, 750-1300 nm, 800-1300 nm, 800-1200 nm, 850-1300 nm, or 900-1300 nm.

In the present disclosure, the term “absorption spectrum”, as used herein, may generally refer to a wavelength (sub-)range of the EM spectrum over which absorption may be concentrated.

In the present disclosure, the terms “absorption edge”, “absorption discontinuity”, and/or “absorption limit” as used herein, may generally refer to a sharp discontinuity in the absorption spectrum of a substance. In some non-limiting examples, an absorption edge may tend to occur at wavelengths where the energy of an absorbed photon may correspond to an electronic transition, and/or ionization potential.

In the present disclosure, the term “extinction coefficient” as used herein, may generally refer to the degree to which an EM coefficient is attenuated when propagating through a material. In some non-limiting examples, the extinction coefficient may be understood to correspond to the imaginary component k of a complex refractive index N In some non-limiting examples, the extinction coefficient of a material may be measured by a variety of methods, including without limitation, by ellipsometry.

In the present disclosure, the terms “refractive index”, and/or “index”, as used herein to describe a medium, may refer to a value calculated from a ratio of the speed of light in such medium relative to the speed of light in a vacuum. In the present disclosure, particularly when used to describe the properties of substantially transparent materials, including without limitation, thin film layers, and/or coatings, the terms may correspond to the real part, n, in the expression N=n+ik, in which N may represent the complex refractive index and k may represent the extinction coefficient.

As would be appreciated by those having ordinary skill in the relevant art, substantially transparent materials, including without limitation, thin film layers, and/or coatings, may generally exhibit a relatively low extinction coefficient value in the visible spectrum, and therefore the imaginary component of the expression may have a negligible contribution to the complex refractive index. On the other hand, light-transmissive electrodes formed, for example, by a metallic thin film, may exhibit a relatively low n value and a relatively high extinction coefficient value in the visible spectrum. Accordingly, the complex refractive index, N, of such thin films may be dictated primarily by its imaginary component k.

In the present disclosure, unless the context dictates otherwise, reference without specificity to a refractive index may be intended to be a reference to the real part n of the complex refractive index N.

In some non-limiting examples, there may be a generally positive correlation between refractive index and transmittance, or in other words, a generally negative correlation between refractive index and absorption. In some non-limiting examples, the absorption edge of a substance may correspond to a wavelength at which the extinction coefficient approaches 0.

It will be appreciated that the refractive index, and/or extinction coefficient values described herein may correspond to such value(s) measured at a wavelength in the visible spectrum. In some non-limiting examples, the refractive index, and/or extinction coefficient value may correspond to the value measured at wavelength(s) of about 456 nm which may correspond to the peak emission wavelength of a B(lue) subpixel, about 528 nm which may correspond to the peak emission wavelength of a G(reen) subpixel, and/or about 624 nm which may correspond to the peak emission wavelength of a R(ed) subpixel. In some non-limiting examples, the refractive index, and/or extinction coefficient value described herein may correspond to the value measured at a wavelength of about 589 nm, which may approximately correspond to the Fraunhofer D-line.

In the present disclosure, the concept of a pixel may be discussed on conjunction with the concept of at least one sub-pixel thereof. For simplicity of description only, such composite concept may be referenced herein as a “(sub-) pixel” and such term may be understood to suggest either, or both of, a pixel, and/or at least one sub-pixel thereof, unless the context dictates otherwise.

In some nonlimiting examples, one measure of an amount of a material on a surface may be a percentage coverage of the surface by such material. In some non-limiting examples, surface coverage may be assessed using a variety of imaging techniques, including without limitation, TEM, AFM, and/or SEM.

In the present disclosure, the terms “particle”, “island” and “cluster” may be used interchangeably to refer to similar concepts.

In the present disclosure, for purposes of simplicity of description, the terms “coating film”, “closed coating”, and/or “closed film”, as used herein, may refer to a thin film structure, and/or coating of a deposited material used for a deposited layer, in which a relevant part of a surface may be substantially coated thereby, such that such surface may be not substantially exposed by or through the coating film deposited thereon.

In the present disclosure, unless the context dictates otherwise, reference without specificity to a thin film may be intended to be a reference to a substantially closed coating.

In some non-limiting examples, a closed coating, in some non-limiting examples, of a deposited layer, and/or a deposited material, may be disposed to cover a portion of an underlying layer 130, such that, within such part, no more than at least one of about: 40%, 30%, 25%, 20%, 15%, 10%, 5%, 3%, or 1% of the underlying layer 130 therewithin may be exposed by, or through, the closed coating.

Those having ordinary skill in the relevant art will appreciate that a closed coating may be patterned using various techniques and processes, including without limitation, those described herein, to deliberately leave a part of the exposed layer surface of the underlying layer 130 to be exposed after deposition of the closed coating. In the present disclosure, such patterned films may nevertheless be considered to constitute a closed coating, if, by way of non-limiting example, the thin film, and/or coating that is deposited, within the context of such patterning, and between such deliberately exposed parts of the exposed layer surface of the underlying layer 130, itself substantially comprises a closed coating.

Those having ordinary skill in the relevant art will appreciate that, due to inherent variability in the deposition process, and in some non-limiting examples, to the existence of impurities in either, or both of, the deposited materials, in some non-limiting examples, the deposited material, and the exposed layer surface of the underlying material, deposition of a thin film, using various techniques and processes, including without limitation, those described herein, may nevertheless result in the formation of small apertures, including without limitation, pin-holes, tears, and/or cracks, therein. In the present disclosure, such thin films may nevertheless be considered to constitute a closed coating, if, by way of non-limiting example, the thin film, and/or coating that is deposited substantially comprises a closed coating and meets any specified percentage coverage criterion set out, despite the presence of such apertures.

In the present disclosure, for purposes of simplicity of description, the term “discontinuous layer” as used herein, may refer to a thin film structure, and/or coating of a material used for a deposited layer, in which a relevant part of a surface coated thereby, may be neither substantially devoid of such material, or forms a closed coating thereof. In some non-limiting examples, a discontinuous layer of a deposited material may manifest as a plurality of discrete islands disposed on such surface.

In the present disclosure, for purposes of simplicity of description, the result of deposition of vapor monomers onto an exposed layer surface of an underlying material, that has not (yet) reached a stage where a closed coating has been formed, may be referred to as a “intermediate stage layer”. In some non-limiting examples, such an intermediate stage layer may reflect that the deposition process has not been completed, in which such an intermediate stage layer may be considered as an interim stage of formation of a closed coating. In some non-limiting examples, an intermediate stage layer may be the result of a completed deposition process, and thus constitute a final stage of formation in and of itself.

In some non-limiting examples, an intermediate stage layer may more closely resemble a thin film than a discontinuous layer but may have apertures, and/or gaps in the surface coverage, including without limitation, at least one dendritic projection, and/or at least one dendritic recess. In some non-limiting examples, such an intermediate stage layer may comprise a fraction of a single monolayer of the deposited material such that it does not form a closed coating.

In the present disclosure, for purposes of simplicity of description, the term “dendritic”, with respect to a coating, including without limitation, the deposited layer, may refer to feature(s) that resemble a branched structure when viewed in a lateral aspect. In some non-limiting examples, the deposited layer may comprise a dendritic projection, and/or a dendritic recess. In some non-limiting examples, a dendritic projection may correspond to a part of the deposited layer that exhibits a branched structure comprising a plurality of short projections that are physically connected and extend substantially outwardly. In some non-limiting examples, a dendritic recess may correspond to a branched structure of gaps, openings, and/or uncovered parts of the deposited layer that are physically connected and extend substantially outwardly. In some non-limiting examples, a dendritic recess may correspond to, including without limitation, a mirror image, and/or inverse pattern, to the pattern of a dendritic projection. In some non-limiting examples, a dendritic projection, and/or a dendritic recess may have a configuration that exhibits, and/or mimics a fractal pattern, a mesh, a web, and/or an interdigitated structure.

In some non-limiting examples, sheet resistance may be a property of a component, layer, and/or part that may alter a characteristic of an electric current passing through such component, layer, and/or part. In some non-limiting examples, a sheet resistance of a coating may generally correspond to a characteristic sheet resistance of the coating, measured, and/or determined in isolation from other components, layers, and/or parts of the device.

In the present disclosure, a deposited density may refer to a distribution, within a region, which in some non-limiting examples may comprise an area, and/or a volume, of a deposited material therein. Those having ordinary skill in the relevant art will appreciate that such deposited density may be unrelated to a density of mass or material within a particle structure itself that may comprise such deposited material. In the present disclosure, unless the context dictates otherwise, reference to a deposited density, and/or to a density, may be intended to be a reference to a distribution of such deposited material, including without limitation, as at least one particle, within an area.

In some non-limiting examples, a bond dissociation energy of a metal may correspond to a standard-state enthalpy change measured at 298 K from the breaking of a bond of a diatomic molecule formed by two identical atoms of the metal. Bond dissociation energies may, by way of non-limiting example, be determined based on known literature including without limitation, Luo, Yu-Ran, “Bond Dissociation Energies” (2010).

Without wishing to be bound by a particular theory, it is postulated that providing an NPC may facilitate deposition of the deposited layer onto certain surfaces.

Non-limiting examples of suitable materials for forming an NPC may comprise without limitation, at least one of metals, including without limitation, alkali metals, alkaline earth metals, transition metals, and/or post-transition metals, metal fluorides, metal oxides, and/or fullerene.

Non-limiting examples of such materials may comprise Ca, Ag, Mg, Yb, ITO, IZO, ZnO, ytterbium fluoride (YbF₃), magnesium fluoride (MgF₂), and/or cesium fluoride (CsF).

In the present disclosure, the term “fullerene” may refer generally to a material including carbon molecules. Non-limiting examples of fullerene molecules include carbon cage molecules, including without limitation, a three-dimensional skeleton that includes multiple carbon atoms that form a closed shell, and which may be, without limitation, spherical, and/or semi-spherical in shape. In some non-limiting examples, a fullerene molecule may be designated as Cₙ, where n may be an integer corresponding to several carbon atoms included in a carbon skeleton of the fullerene molecule. Non-limiting examples of fullerene molecules include Cₙ, where n may be in the range of 50 to 250, such as, without limitation, C₆₀, C₇₀, C₇₂, C₇₄, C₇₆, C₇₈, C₈₀, C₈₂, and C₈₄. Additional non-limiting examples of fullerene molecules include carbon molecules in a tube, and/or a cylindrical shape, including without limitation, single-walled carbon nanotubes, and/or multi-walled carbon nanotubes.

Based on findings and experimental observations, it may be postulated that nucleation promoting materials, including without limitation, fullerenes, metals, including without limitation, Ag, and/or Yb, and/or metal oxides, including without limitation, ITO, and/or IZO, as discussed further herein, may act as nucleation sites for the deposition of a deposited layer, including without limitation Mg.

In some non-limiting examples, suitable materials for use to form an NPC 920, may include those exhibiting or characterized as having an initial sticking probability for a material of a deposited layer of at least one of at least about: 0.4, 0.5, 0.6, 0.7, 0.75, 0.8, 0.9, 0.93, 0.95, 0.98, or 0.99.

By way of non-limiting example, in scenarios where Mg is deposited using without limitation, an evaporation process on a fullerene-treated surface, in some non-limiting examples, the fullerene molecules may act as nucleation sites that may promote formation of stable nuclei for Mg deposition.

In some non-limiting examples, no more than a monolayer of an NPC, including without limitation, fullerene, may be provided on the treated surface to act as nucleation sites for deposition of Mg.

In some non-limiting examples, treating a surface by depositing several monolayers of an NPC thereon may result in a higher number of nucleation sites and accordingly, a higher initial sticking probability.

Those having ordinary skill in the relevant art will appreciate than an amount of material, including without limitation, fullerene, deposited on a surface, may be more, or no more than one monolayer. By way of non-limiting example, such surface may be treated by depositing: 0.1, 1, 10, or more monolayers of a nucleation promoting material, and/or a nucleation inhibiting material.

In some non-limiting examples, an average layer thickness of the NPC deposited on an exposed layer surface of underlying material(s) may be at least one of between about: 1-5 nm, or 1-3 nm.

Where features or aspects of the present disclosure may be described in terms of Markush groups, it will be appreciated by those having ordinary skill in the relevant art that the present disclosure may also be thereby described in terms of any individual member of sub-group of members of such Markush group.

### Terminology

References in the singular form may include the plural and vice versa, unless otherwise noted.

As used herein, relational terms, such as “first” and “second”, and numbering devices such as “a”, “b” and the like, may be used solely to distinguish one entity or element from another entity or element, without necessarily requiring or implying any physical or logical relationship or order between such entities or elements.

The terms “including” and “comprising” may be used expansively and in an open-ended fashion, and thus should be interpreted to mean “including, but not limited to”. The terms “example” and “exemplary” may be used simply to identify instances for illustrative purposes and should not be interpreted as limiting the scope of the invention to the stated instances. In particular, the term “exemplary” should not be interpreted to denote or confer any laudatory, beneficial, or other quality to the expression with which it is used, whether in terms of design, performance or otherwise.

Further, the term “critical”, especially when used in the expressions “critical nuclei”, “critical nucleation rate”, “critical concentration”, “critical cluster”, “critical monomer”, “critical particle structure size”, and/or “critical surface tension” may be a term familiar to those having ordinary skill in the relevant art, including as relating to or being in a state in which a measurement or point at which some quality, property or phenomenon undergoes a definite change. As such, the term “critical” should not be interpreted to denote or confer any significance or importance to the expression with which it is used, whether in terms of design, performance, or otherwise.

The terms “couple” and “communicate” in any form may be intended to mean either a direct connection or indirect connection through some interface, device, intermediate component, or connection, whether optically, electrically, mechanically, chemically, or otherwise.

The terms “on” or “over” when used in reference to a first component relative to another component, and/or “covering” or which “covers” another component, may encompass situations where the first component is directly on (including without limitation, in physical contact with) the other component, as well as cases where at least one intervening component is positioned between the first component and the other component.

Directional terms such as “upward”, “downward”, “left” and “right” may be used to refer to directions in the drawings to which reference is made unless otherwise stated. Similarly, words such as “inward” and “outward” may be used to refer to directions toward and away from, respectively, the geometric center of the device, area or volume or designated parts thereof. Moreover, all dimensions described herein may be intended solely to be by way of example of purposes of illustrating certain embodiments and may not be intended to limit the scope of the disclosure to any embodiments that may depart from such dimensions as may be specified.

As used herein, the terms “substantially”, “substantial”, “approximately”, and/or “about” may be used to denote and account for small variations. When used in conjunction with an event or circumstance, such terms may refer to instances in which the event or circumstance occurs precisely, as well as instances in which the event or circumstance occurs to a close approximation. By way of non-limiting example, when used in conjunction with a numerical value, such terms may refer to a range of variation of no more than about ±10% of such numerical value, such as no more than at least one of about: ±5%, ±4%, ±3%, ±2%, ±1%, ±0.5%, ±0.1%, or ±0.05%.

As used herein, the phrase “consisting substantially of” may be understood to include those elements specifically recited and any additional elements that do not materially affect the basic and novel characteristics of the described technology, while the phrase “consisting of” without the use of any modifier, may exclude any element not specifically recited.

As will be understood by those having ordinary skill in the relevant art, for any and all purposes, particularly in terms of providing a written description, all ranges disclosed herein may also encompass any and all possible sub-ranges, and/or combinations of sub-ranges thereof. Any listed range may be easily recognized as sufficiently describing, and/or enabling the same range being broken down at least into equal fractions thereof, including without limitation, halves, thirds, quarters, fifths, tenths etc. As a non-limiting example, each range discussed herein may be readily be broken down into a lower third, middle third, and/or upper third, etc.

As will also be understood by those having ordinary skill in the relevant art, all language, and/or terminology such as “up to”, “at least”, “greater than”, “no more than”, and the like, may include, and/or refer the recited range(s) and may also refer to ranges that may be subsequently broken down into sub-ranges as discussed herein.

As will be understood by those having ordinary skill in the relevant art, a range may include each individual member of the recited range.

### General

The purpose of the Abstract is to enable the relevant patent office or the public generally, and specifically, persons of ordinary skill in the art who are not familiar with patent or legal terms or phraseology, to quickly determine from a cursory inspection, the nature of the technical disclosure. The Abstract is neither intended to define the scope of this disclosure, nor is it intended to be limiting as to the scope of this disclosure in any way.

The structure, manufacture and use of the presently disclosed examples have been discussed above. The specific examples discussed are merely illustrative of specific ways to make and use the concepts disclosed herein, and do not limit the scope of the present disclosure. Rather, the general principles set forth herein are merely illustrative of the scope of the present disclosure.

It should be appreciated that the present disclosure, which is described by the claims and not by the implementation details provided, and which can be modified by varying, omitting, adding or replacing, and/or in the absence of any element(s), and/or limitation(s) with alternatives, and/or equivalent functional elements, whether or not specifically disclosed herein, will be apparent to those having ordinary skill in the relevant art, may be made to the examples disclosed herein, and may provide many applicable inventive concepts that may be embodied in a wide variety of specific contexts, without straying from the present disclosure.

In particular, features, techniques, systems, sub-systems and methods described and illustrated in at least one of the above-described examples, whether or not described an illustrated as discrete or separate, may be combined or integrated in another system without departing from the scope of the present disclosure, to create alternative examples comprised of a combination or sub-combination of features that may not be explicitly described above, or certain features may be omitted, or not implemented. Features suitable for such combinations and sub-combinations would be readily apparent to persons skilled in the art upon review of the present application as a whole. Other examples of changes, substitutions, and alterations are easily ascertainable and could be made without departing from the spirit and scope disclosed herein.

All statements herein reciting principles, aspects, and examples of the disclosure, as well as specific examples thereof, are intended to encompass both structural and functional equivalents thereof and to cover and embrace all suitable changes in technology. Additionally, it is intended that such equivalents include both currently known equivalents as well as equivalents developed in the future, i.e., any elements developed that perform the same function, regardless of structure.

### Clauses

The present disclosure includes, without limitation, the following clauses:

The device according to at least one clause herein wherein the patterning coating comprises a patterning material.

The device according to at least one clause herein, wherein an initial sticking probability against deposition of the deposited material of the patterning coating is no more than an initial sticking probability against deposition of the deposited material of the exposed layer surface.

The device according to at least one clause herein, wherein the patterning coating is substantially devoid of a closed coating of the deposited material.

The device according to at least one clause herein, wherein at least one of the patterning coating and the patterning material has an initial sticking probability against deposition of the deposited material that is no more than at least one of about: 0.9, 0.3, 0.2, 0.15, 0.1, 0.08, 0.05, 0.03, 0.02, 0.01, 0.008, 0.005, 0.003, 0.001, 0.0008, 0.0005, 0.0003, and 0.0001.

The device according to at least one clause herein, wherein at least one of the patterning coating and the patterning material has an initial sticking probability against deposition of at least one of silver (Ag) and magnesium (Mg) that is no more than at least one of about: 0.9, 0.3, 0.2, 0.15, 0.1, 0.08, 0.05, 0.03, 0.02, 0.01, 0.008, 0.005, 0.003, 0.001, 0.0008, 0.0005, 0.0003, and 0.0001.

The device according to at least one clause herein, wherein at least one of the patterning coating and the patterning material has an initial sticking probability against deposition of the deposited material of at least one of between about: 0.15-0.0001, 0.1-0.0003, 0.08-0.0005, 0.08-0.0008, 0.05-0.001, 0.03-0.0001, 0.03-0.0003, 0.03-0.0005, 0.03-0.0008, 0.03-0.001, 0.03-0.005, 0.03-0.008, 0.03-0.01, 0.02-0.0001, 0.02-0.0003, 0.02-0.0005, 0.02-0.0008, 0.02-0.001, 0.02-0.005, 0.02-0.008, 0.02-0.01, 0.01-0.0001, 0.01-0.0003, 0.01-0.0005, 0.01-0.0008, 0.01-0.001, 0.01-0.005, 0.01-0.008, 0.008-0.0001, 0.008-0.0003, 0.008-0.0005, 0.008-0.0008, 0.008-0.001, 0.008-0.005, 0.005-0.0001, 0.005-0.0003, 0.005-0.0005, 0.005-0.0008, and 0.005-0.001.

The device according to at least one clause herein, wherein at least one of the patterning coating and the patterning material has an initial sticking probability against deposition of the deposited material that is no more than a threshold value that is at least one of about: 0.3, 0.2, 0.18, 0.15, 0.13, 0.1, 0.08, 0.05, 0.03, 0.02, 0.01, 0.008, 0.005, 0.003, and 0.001.

The device according to at least one clause herein, wherein at least one of the patterning coating and the patterning material has an initial sticking probability against the deposition of at least one of: Ag, Mg, ytterbium (Yb), cadmium (Cd), and zinc (Zn), that is no more than the threshold value.

The device according to at least one clause herein, wherein the threshold value has a first threshold value against the deposition of a first deposited material and a second threshold value against the deposition of a second deposited material.

The device according to at least one clause herein, wherein the first deposited material is Ag and the second deposited material is Mg.

The device according to at least one clause herein, wherein the first deposited material is Ag and the second deposited material is Yb.

The device according to at least one clause herein, wherein the first deposited material is Yb and the second deposited material is Mg.

The device according to at least one clause herein, wherein the first threshold value exceeds the second threshold value.

The device according to at least one clause herein, wherein at least one of the patterning coating and the patterning material has a transmittance for EM radiation of at least a threshold transmittance value after being subjected to a vapor flux of the deposited material.

The device according to at least one clause herein, wherein the threshold transmittance value is measured at a wavelength in the visible spectrum.

The device according to at least one clause herein, wherein the threshold transmittance value is at least one of at least about 60%, 65%, 70%, 75%, 80%, 85%, and 90% of incident EM power transmitted therethrough.

The device according to at least one clause herein, wherein at least one of the patterning coating and the patterning material has a surface energy of no more than at least one of about: 24 dynes/cm, 22 dynes/cm, 20 dynes/cm, 18 dynes/cm, 16 dynes/cm, 15 dynes/cm, 13 dynes/cm, 12 dynes/cm, and 11 dynes/cm.

The device according to at least one clause herein, wherein at least one of the patterning coating and the patterning material has a surface energy that is at least one of at least about: 6 dynes/cm, 7 dynes/cm, and 8 dynes/cm.

The device according to at least one clause herein, wherein at least one of the patterning coating and the patterning material has a surface energy that is at least one of between about: 10-20 dynes/cm, and 13-19 dynes/cm.

The device according to at least one clause herein, wherein at least one of the patterning coating and the patterning material has a refractive index for EM radiation at a wavelength of 550 nm that is no more than at least one of about: 1.55, 1.5, 1.45, 1.43, 1.4, 1.39, 1.37, 1.35, 1.32, and 1.3

The device according to at least one clause herein, wherein at least one of the patterning coating and the patterning material has an extinction coefficient that is no more than about 0.01 for photons at a wavelength that exceeds at least one of about: 600 nm, 500 nm, 460 nm, 420 nm, and 410 nm.

The device according to at least one clause herein, wherein at least one of the patterning coating and the patterning material has an extinction coefficient that is at least one of at least about: 0.05, 0.1, 0.2, 0.5 for EM radiation at a wavelength shorter than at least one of at least about: 400 nm, 390 nm, 380 nm, and 370 nm.

The device according to at least one clause herein, wherein at least one of the patterning coating and the patterning material has a glass transition temperature that is no more than at least one of about: 300° C., 150° C., 130° C., 30° C., 0° C., −30° C., and −50° C.

The device according to at least one clause herein, wherein the patterning material has a sublimation temperature of at least one of between about: 100-320° C., 120-300° C., 140-280° C., and 150-250° C.

The device according to at least one clause herein, wherein at least one of the patterning coating and the patterning material comprises at least one of a fluorine atom and a silicon atom.

The device according to at least one clause herein, wherein the patterning coating comprises fluorine and carbon.

The device according to at least one clause herein, wherein an atomic ratio of a quotient of fluorine by carbon is at least one of about: 1, 1.5, and 2.

The device according to at least one clause herein, wherein the patterning coating comprises an oligomer.

The device according to at least one clause herein, wherein the patterning coating comprises a compound having a molecular structure containing a backbone and at least one functional group bonded thereto.

The device according to at least one clause herein, wherein the compound comprises at least one of: a siloxane group, a silsesquioxane group, an aryl group, a heteroaryl group, a fluoroalkyl group, a hydrocarbon group, a phosphazene group, a fluoropolymer, and a metal complex.

The device according to at least one clause herein, wherein a molecular weight of the compound is no more than at least one of about: 5,000 g/mol, 4,500 g/mol, 4,000 g/mol, 3,800 g/mol, and 3,500 g/mol.

The device according to at least one clause herein, wherein the molecular weight is at least about: 1,500 g/mol, 1,700 g/mol, 2,000 g/mol, 2,200 g/mol, and 2,500 g/mol.

The device according to at least one clause herein, wherein the molecular weight is at least one of between about: 1,500-5,000 g/mol, 1,500-4,500 g/mol, 1,700-4,500 g/mol, 2,000-4,000 g/mol, 2,200-4,000 g/mol, and 2,500-3,800 g/mol.

The device according to at least one clause herein, wherein a percentage of a molar weight of the compound that is attributable to a presence of fluorine atoms, is at least one of between about: 40-90%, 45-85%, 50-80%, 55-75%, and 60-75%.

The device according to at least one clause herein, wherein fluorine atoms comprise a majority of the molar weight of the compound.

The device according to at least one clause herein, wherein the patterning material comprises an organic-inorganic hybrid material.

The device according to at least one clause herein, wherein the patterning coating has at least one nucleation site for the deposited material.

The device according to at least one clause herein, wherein the patterning coating is supplemented with a seed material that acts as a nucleation site for the deposited material.

The device according to at least one clause herein, wherein the seed material comprises at least one of: a nucleation promoting coating (NPC) material, an organic material, a polycyclic aromatic compound, and a material comprising a non-metallic element selected from at least one of oxygen (O), sulfur (S), nitrogen (N), and carbon (C).

The device according to at least one clause herein, wherein the patterning coating acts as an optical coating.

The device according to at least one clause herein, wherein the patterning coating modifies at least one of a property and a characteristic of EM radiation emitted by the device.

The device according to at least one clause herein, wherein the patterning coating comprises a crystalline material.

The device according to at least one clause herein, wherein the patterning coating is deposited as a non-crystalline material and becomes crystallized after deposition.

The device according to at least one clause herein, wherein the deposited layer comprises a deposited material.

The device according to at least one clause herein, wherein the deposited material comprises an element selected from at least one of: potassium (K), sodium (Na), lithium (Li), barium (Ba), cesium (Cs), ytterbium (Yb), silver (Ag), gold (Au), copper (Cu), aluminum (Al), magnesium (Mg), zinc (Zn), cadmium (Cd), tin (Sn), and yttrium (Y).

The device according to at least one clause herein, wherein the deposited material comprises a pure metal.

The device according to at least one clause herein, wherein the deposited material is selected from at least one of pure Ag and substantially pure Ag.

The device according to at least one clause herein, wherein the substantially pure Ag has a purity of at least one of at least about: 95%, 99%, 99.9%, 99.99%, 99.999%, and 99.9995%.

The device according to at least one clause herein, wherein the deposited material is selected from at least one of pure Mg and substantially pure Mg.

The device according to at least one clause herein, wherein the substantially pure Mg has a purity of at least one of at least about: 95%, 99%, 99.9%, 99.99%, 99.999%, or 99.9995%.

The device according to at least one clause herein, wherein the deposited material comprises an alloy.

The device according to at least one clause herein, wherein the deposited material comprises at least one of: an Ag-containing alloy, an Mg-containing alloy, and an AgMg-containing alloy.

The device according to at least one clause herein, wherein the AgMg-containing alloy has an alloy composition that ranges from 1:10 (Ag:Mg) to about 10:1 by volume.

The device according to at least one clause herein, wherein the deposited material comprises at least one metal other than Ag.

The device according to at least one clause herein, wherein the deposited material comprises an alloy of Ag with at least one metal.

The device according to at least one clause herein, wherein the at least one metal is selected from at least one of Mg and Yb.

The device according to at least one clause herein, wherein the alloy is a binary alloy having a composition between about 5-95 vol. % Ag.

The device according to at least one clause herein, wherein the alloy comprises a Yb:Ag alloy having a composition between about 1:20-10:1 by volume.

The device according to at least one clause herein, wherein the deposited material comprises an Mg:Yb alloy.

The device according to at least one clause herein, wherein the deposited material comprises an Ag:Mg:Yb alloy.

The device according to at least one clause herein, wherein the deposited layer comprises at least one additional element.

The device according to at least one clause herein, wherein the at least one additional element is a non-metallic element.

The device according to at least one clause herein, wherein the non-metallic element is selected from at least one of O, S, N, and C.

The device according to at least one clause herein, wherein a concentration of the non-metallic element is no more than at least one of about: 1%, 0.1%, 0.01%, 0.001%, 0.0001%, 0.00001%, 0.000001%, and 0.0000001%.

The device according to at least one clause herein, wherein the deposited layer has a composition in which a combined amount of O and C is no more than at least one of about: 10%, 5%, 1%, 0.1%, 0.01%, 0.001%, 0.0001%, 0.00001%, 0.000001%, and 0.0000001%.

The device according to at least one clause herein, wherein the non-metallic element acts as a nucleation site for the deposited material on the NIC.

The device according to at least one clause herein, wherein the deposited material and the underlying layer comprise a common metal.

The device according to at least one clause herein, the deposited layer comprises a plurality of layers of the deposited material.

The device according to at least one clause herein, a deposited material of a first one of the plurality of layers is different from a deposited material of a second one of the plurality of layers.

The device according to at least one clause herein, wherein the deposited layer comprises a multilayer coating.

The device according to at least one clause herein, wherein the multilayer coating is at least one of: Yb/Ag, Yb/Mg, Yb/Mg:Ag, Yb/Yb:Ag, Yb/Ag/Mg, and Yb/Mg/Ag.

The device according to at least one clause herein, wherein the deposited material comprises a metal having a bond dissociation energy of no more than at least one of about: 300 kJ/mol, 200 kJ/mol, 165 kJ/mol, 150 kJ/mol, 100 kJ/mol, 50 kJ/mol, and 20 kJ/mol.

The device according to at least one clause herein, wherein the deposited material comprises a metal having an electronegativity of no more than at least one of about: 1.4, 1.3, and 1.2.

The device according to at least one clause herein, wherein a sheet resistance of the deposited layer is no more than at least one of about: 10Ω/□, 5Ω/□, 1Ω/□, 0.5Ω/□, 0.2Ω/□, and 0.1Ω/□.

The device according to at least one clause herein, wherein the deposited layer is disposed in a pattern defined by at least one region therein that is substantially devoid of a closed coating thereof.

The device according to at least one clause herein, wherein the at least one region separates the deposited layer into a plurality of discrete fragments thereof.

The device according to at least one clause herein, wherein at least two discrete fragments are electrically coupled.

The device according to at least one clause herein, wherein the patterning coating has a boundary defined by a patterning coating edge.

The device according to at least one clause herein, wherein the patterning coating comprises at least one patterning coating transition region and a patterning coating non-transition part.

The device according to at least one clause herein, wherein the at least one patterning coating transition region transitions from a maximum thickness to a reduced thickness.

The device according to at least one clause herein, wherein the at least one patterning coating transition region extends between the Patterning coating non-transition part and the Patterning coating edge.

The device according to at least one clause herein, wherein the patterning coating has an average film thickness in the patterning coating non-transition part that is in a range of at least one of between about: 1-100 nm, 2-50 nm, 3-30 nm, 4-20 nm, 5-15 nm, 5-10 nm, and 1-10 nm.

The device according to at least one clause herein, wherein a thickness of the NIC in the patterning coating non-transition part is within at least one of about: 95%, and 90% of the average film thickness of the NIC.

The device according to at least one clause herein, wherein the average film thickness is no more than at least one of about: 80 nm, 60 nm, 50 nm, 40 nm, 30 nm, 20 nm, 15 nm, and 10 nm.

The device according to at least one clause herein, wherein the average film thickness exceeds at least one of about: 3 nm, 5 nm, and 8 nm.

The device according to at least one clause herein, wherein the average film thickness is no more than about 10 nm.

The device according to at least one clause herein, wherein the patterning coating has a patterning coating thickness that decreases from a maximum to a minimum within the patterning coating transition region.

The device according to at least one clause herein, wherein the maximum is proximate to a boundary between the patterning coating transition region and the patterning coating non-transition part.

The device according to at least one clause herein, wherein the maximum is a percentage of the average film thickness that is at least one of about: 100%, 95%, and 90%.

The device according to at least one clause herein, wherein the minimum is proximate to the patterning coating edge.

The device according to at least one clause herein, wherein the minimum is in a range of between about: 0-0.1 nm.

The device according to at least one clause herein, wherein a profile of the patterning coating thickness is at least one of sloped, tapered, and defined by a gradient.

The device according to at least one clause herein, wherein the tapered profile follows at least one of a linear, non-linear, parabolic, and exponential decaying profile.

The device according to at least one clause herein, wherein a non-transition width along a lateral axis of the patterning coating non-transition region exceeds a transition width along the axis of the patterning coating transition region.

The device according to at least one clause herein, wherein a quotient of the non-transition width by the transition width is at least one of at least about: 5, 10, 20, 50, 100, 500, 1,000, 1,500, 5,000, 10,000, 50,000, or 100,000.

The device according to at least one clause herein, wherein at least one of the non-transition width and the transition width exceeds an average film thickness of the underlying layer.

The device according to at least one clause herein, wherein at least one of the non-transition width and the transition width exceeds the average film thickness of the patterning coating.

The device according to at least one clause herein, wherein the average film thickness of the underlying layer exceeds the average film thickness of the patterning coating.

The device according to at least one clause herein, wherein the deposited layer has a boundary defined by a deposited layer edge.

The device according to at least one clause herein, wherein the deposited layer comprises at least one deposited layer transition region and a deposited layer non-transition part.

The device according to at least one clause herein, wherein the at least one deposited layer transition region transitions from a maximum thickness to a reduced thickness.

The device according to at least one clause herein, wherein the at least one deposited layer transition region extends between the deposited layer non-transition part and the deposited layer edge.

The device according to at least one clause herein, wherein the deposited layer has an average film thickness in the deposited layer non-transition part that is in a range of at least one of between about: 1-500 nm, 5-200 nm, 5-40 nm, 10-30 nm, and 10-100 nm.

The device according to at least one clause herein, wherein the average film thickness exceeds at least one of about: 10 nm, 50 nm, and 100 nm.

The device according to at least one clause herein, wherein the average film thickness of is substantially constant thereacross.

The device according to at least one clause herein, wherein the average film thickness exceeds an average film thickness of the underlying layer.

The device according to at least one clause herein, wherein a quotient of the average film thickness of the deposited layer by the average film thickness of the underlying layer is at least one of at least about: 1.5, 2, 5, 10, 20, 50, and 100.

The device according to at least one clause herein, wherein the quotient is in a range of at least one of between about: 0.1-10, and 0.2-40.

The device according to at least one clause herein, wherein the average film thickness of the deposited layer exceeds an average film thickness of the patterning coating.

The device according to at least one clause herein, wherein a quotient of the average film thickness of the deposited layer by the average film thickness of the patterning coating is at least one of at least about: 1.5, 2, 5, 10, 20, 50, and 100.

The device according to at least one clause herein, wherein the quotient is in a range of at least one of between about: 0.2-10, and 0.5-40.

The device according to at least one clause herein, wherein a deposited layer non-transition width along a lateral axis of the deposited layer non-transition region exceeds a patterning coating non-transition width along the axis of the patterning coating non-transition region.

The device according to at least one clause herein, wherein a quotient of the patterning coating non-transition width by the deposited layer non-transition width is at least one of between about: 0.1-10, 0.2-5, 0.3-3, and 0.4-2.

The device according to at least one clause herein, wherein a quotient of the deposited layer non-transition width by the patterning coating non-transition width is at least one of at least: 1, 2, 3, and 4.

The device according to at least one clause herein, wherein the deposited layer non-transition width exceeds the average film thickness of the deposited layer.

The device according to at least one clause herein, wherein a quotient of the deposited layer non-transition width by the average film thickness is at least one of at least about: 10, 50, 100, and 500.

The device according to at least one clause herein, wherein the quotient is no more than about 100,000.

The device according to at least one clause herein, wherein the deposited layer has a deposited layer thickness that decreases from a maximum to a minimum within the deposited layer transition region.

The device according to at least one clause herein, wherein the maximum is proximate to a boundary between the deposited layer transition region and the deposited layer non-transition part.

The device according to at least one clause herein, wherein the maximum is the average film thickness.

The device according to at least one clause herein, wherein the minimum is proximate to the deposited layer edge.

The device according to at least one clause herein, wherein the minimum is in a range of between about: 0-0.1 nm.

The device according to at least one clause herein, wherein the minimum is the average film thickness.

The device according to at least one clause herein, wherein a profile of the deposited layer thickness is at least one of sloped, tapered, and defined by a gradient.

The device according to at least one clause herein, wherein the tapered profile follows at least one of a linear, non-linear, parabolic, and exponential decaying profile.

The device according to at least one clause herein, wherein the deposited layer comprises a discontinuous layer in at least a part of the deposited layer transition region.

The device according to at least one clause herein, wherein the deposited layer overlaps the patterning coating in an overlap portion.

The device according to at least one clause herein, wherein the patterning coating overlaps the deposited layer in an overlap portion.

The device according to at least one clause herein, further comprising at least one particle structure disposed on an exposed layer surface of an underlying layer.

The device according to at least one clause herein, wherein the underlying layer is the patterning coating.

The device according to at least one clause herein, wherein the at least one particle structure comprises a particle structure material.

The device according to at least one clause herein, wherein the particle structure material is the same as the deposited material.

The device according to at least one clause herein, wherein at least two of the particle structure material, the deposited material, and a material of which the underlying layer is comprised, comprises a common metal.

The device according to at least one clause herein, wherein the particle structure material comprises an element selected from at least one of: potassium (K), sodium (Na), lithium (Li), barium (Ba), cesium (Cs), ytterbium (Yb), silver (Ag), gold (Au), copper (Cu), aluminum (Al), magnesium (Mg), zinc (Zn), cadmium (Cd), tin (Sn), and yttrium (Y).

The device according to at least one clause herein, wherein the particle structure material comprises a pure metal.

The device according to at least one clause herein, wherein the particle structure material is selected from at least one of pure Ag and substantially pure Ag.

The device according to at least one clause herein, wherein the substantially pure Ag has a purity of at least one of at least about: 95%, 99%, 99.9%, 99.99%, 99.999%, and 99.9995%.

The device according to at least one clause herein, wherein the particle structure material is selected from at least one of pure Mg and substantially pure Mg.

The device according to at least one clause herein, wherein the substantially pure Mg has a purity of at least one of at least about: 95%, 99%, 99.9%, 99.99%, 99.999%, or 99.9995%.

The device according to at least one clause herein, wherein the particle structure material comprises an alloy.

The device according to at least one clause herein, wherein the particle structure material comprises at least one of: an Ag-containing alloy, an Mg-containing alloy, and an AgMg-containing alloy.

The device according to at least one clause herein, wherein the AgMg-containing alloy has an alloy composition that ranges from 1:10 (Ag:Mg) to about 10:1 by volume.

The device according to at least one clause herein, wherein the particle structure material comprises at least one metal other than Ag.

The device according to at least one clause herein, wherein the particle structure material comprises an alloy of Ag with at least one metal.

The device according to at least one clause herein, wherein the at least one metal is selected from at least one of Mg and Yb.

The device according to at least one clause herein, wherein the alloy is a binary alloy having a composition between about 5-95 vol. % Ag.

The device according to at least one clause herein, wherein the alloy comprises a Yb:Ag alloy having a composition between about 1:20-10:1 by volume.

The device according to at least one clause herein, wherein the particle structure material comprises an Mg:Yb alloy.

The device according to at least one clause herein, wherein the particle structure material comprises an Ag:Mg:Yb alloy.

The device according to at least one clause herein, wherein the at least one particle structure comprises at least one additional element.

The device according to at least one clause herein, wherein the at least one additional element is a non-metallic element.

The device according to at least one clause herein, wherein the non-metallic element is selected from at least one of O, S, N, and C.

The device according to at least one clause herein, wherein a concentration of the non-metallic element is no more than at least one of about: 1%, 0.1%, 0.01%, 0.001%, 0.0001%, 0.00001%, 0.000001%, and 0.0000001%.

The device according to at least one clause herein, wherein the at least one particle structure has a composition in which a combined amount of O and C is no more than at least one of about: 10%, 5%, 1%, 0.1%, 0.01%, 0.001%, 0.0001%, 0.00001%, 0.000001%, and 0.0000001%.

The device according to at least one clause herein, wherein the at least one particle is disposed at an interface between the patterning coating and at least one covering layer in the device.

The device according to at least one clause herein, wherein the at least one particle is in physical contact with an exposed layer surface of the patterning coating.

The device according to at least one clause herein, wherein the at least one particle structure affects at least one optical property of the device.

The device according to at least one clause herein, wherein the at least one optical property is controlled by selection of at least one property of the at least one particle structure selected from at least one of: a characteristic size, a size distribution, a shape, a surface coverage, a configuration, a deposited density, and a dispersity.

The device according to at least one clause herein, wherein the at least one property of the at least one particle structure is controlled by selection of at least one of: at least one characteristic of the patterning material, an average film thickness of the patterning coating, at least one heterogeneity in the patterning coating, and a deposition environment for the patterning coating, selected from at least one of a temperature, pressure, duration, deposition rate, and deposition process.

The device according to at least one clause herein, wherein the at least one property of the at least one particle structure is controlled by selection of at least one of: at least one characteristic of the particle structure material, an extent to which the patterning coating is exposed to deposition of the particle structure material, a thickness of the discontinuous layer, and a deposition environment for the particle structure material, selected from at least one of a temperature, pressure, duration, deposition rate, and deposition process.

The device according to at least one clause herein, wherein the at least one particle structures are disconnected from one another.

The device according to at least one clause herein, wherein the at least one particle structure forms a discontinuous layer.

The device according to at least one clause herein, wherein the discontinuous layer is disposed in a pattern defined by at least one region therein that is substantially devoid of the at least one particle structure.

The device according to at least one clause herein, wherein a characteristic of the discontinuous layer is determined by an assessment according to at least one criterion selected from at least one of: a characteristic size, size distribution, shape, configuration, surface coverage, deposited distribution, dispersity, presence of aggregation instances, and extent of such aggregation instances.

The device according to at least one clause herein, wherein the assessment is performed by determining at least one attribute of the discontinuous layer by an applied imaging technique selected from at least one of: electron microscopy, atomic force microscopy, and scanning electron microscopy.

The device according to at least one clause herein, wherein the assessment is performed across an extent defined by at least one observation window.

The device according to at least one clause herein, wherein the at least one observation window is located at at least one of: a perimeter, interior location, and grid coordinate of the lateral aspect.

The device according to at least one clause herein, wherein the observation window corresponds to a field of view of the applied imaging technique.

The device according to at least one clause herein, wherein the observation window corresponds to a magnification level selected from at least one of: 2.00 μm, 1.00 μm, 500 nm, and 200 nm.

The device according to at least one clause herein, wherein the assessment incorporates at least one of: manual counting, curve fitting, polygon fitting, shape fitting, and an estimation technique.

The device according to at least one clause herein, wherein the assessment incorporates a manipulation selected from at least one of: an average, median, mode, maximum, minimum, probabilistic, statistical, and data calculation.

The device according to at least one clause herein, wherein the characteristic size is determined from at least one of: a mass, volume, diameter, perimeter, major axis, and minor axis of the at least one particle structure.

The device according to at least one clause herein, wherein the dispersity is determined from:

$$D = \frac{\overline{{S}_{s}}}{\overline{{S}_{n}}}$$

where:

$$\overline{{S}_{s}} = \frac{{\sum }_{i = 1}^{n} {S}_{i}^{2}}{{\sum }_{i = 1}^{n} {S}_{i}} , \overline{{S}_{n}} = \frac{{\sum }_{i = 1}^{n} {S}_{i}}{n} ,$$

n is the number of particles 60 in a sample area,
Sᵢ is the (area) size of the i^{th} particle,
S̅ₙ is the number average of the particle (area) sizes; and
S̅ₛ is the (area) size average of the particle (area) sizes.

Accordingly, the specification and the examples disclosed therein are to be considered illustrative only, with a true scope of the disclosure being disclosed by the following numbered claims:

1. A semiconductor device having a plurality of layers and extending in an interface portion and a non-interface portion of at least one lateral aspect defined by a lateral axis thereof, comprising:
a low(er)-index layer that has a first refractive index, at a wavelength in a first wavelength range, disposed on a first layer surface in at least the interface portion; and
a higher-index layer that has a second refractive index, at a wavelength in a second wavelength range, disposed on a second exposed layer surface of the device, to define an index interface with the low(er)-index layer in the interface portion, where the second refractive index exceeds the first refractive index.

2. The device of claim 1, wherein the first wavelength range is selected from at least one of between about: 315-400 nm, 450-460 nm, 510-540 nm, 600-640 nm, 456-624 nm, 425-725 nm, 350-450 nm, 300-450 nm, 300-550 nm, 300-700 nm, 380-740 nm, 750-900 nm, 380-900 nm, and 300-900 nm.

3. The device of claim 1, wherein the first refractive index varies across the first wavelength range by no more than at least one of about: 0.4, 0.3, 0.2, and 0.1.

4. The device of claim 1, wherein the first refractive index is no more than at least one of about: 1.7, 1.6, 1.5, 1.45, 1.4, 1.35, 1.3, and 1.25.

5. The device of claim 1, wherein the first refractive index is at least one of between about: 1.2-1.6, 1.2-1.5, 1.25-1.45, and 1.25-1.4.

6. The device of claim 1, wherein the low(er)-index layer comprises a low-index material.

7. The device of claim 6, wherein at least one of the low(er)-index layer and the low-index material exhibits an extinction coefficient in the first wavelength range that is no more than at least one of about: 0.1, 0.08, 0.05, 0.03. and 0.01.

8. The device of claim 6, wherein at least one of the low(er)-index layer and the low-index material is substantially transparent.

9. The device of claim 6, wherein at least one of the low(er)-index layer and the low-index material comprises at least one void therewithin.

10. The device of claim 6, wherein the low-index material comprises at least one of an organic compound and an organic-inorganic hybrid material.

11. The device of claim 1, wherein the second wavelength range is selected from at least one of between about: 315-400 nm, 450-460 nm, 510-540 nm, 600-640 nm, 456-624 nm, 425-725 nm, 350-450 nm, 300-450 nm, 300-550 nm, 300-700 nm, 380-740 nm, 750-900 nm, 380-900 nm, and 300-900 nm.

12. The device of claim 1, wherein the second wavelength range is different from the first wavelength range.

13. The device of claim 1, wherein the second refractive index is at least one of at least about: 1.7, 1.8, and 1.9.

14. The device of claim 1 wherein the second refractive index exceeds the first refractive index by at least one of at least about: 0.3, 0.4, 0.5, 0.7, 1.0, 1.2, 1.3, 1.4, and 1.5.

15. The device of claim 1, wherein a second maximum refractive index corresponding to a maximum value of the second refractive index measured within the second wavelength range exceeds a first maximum refractive index corresponding to a maximum value of the first refractive index measured within the first wavelength range.

16. The device of claim 15, wherein the first maximum refractive index corresponds to a first wavelength within the first wavelength range that is different from a second wavelength within the second wavelength range to which the second maximum refractive index corresponds.

17. The device of claim 15, wherein the second maximum refractive index exceeds the first maximum refractive index by at least one of at least about: 0.5, 0.7, 1.0, 1.2, 1.3, 1.4, 1.5, and 1.7.

18. The device of claim 1, wherein the higher-index layer comprises a physical coating selected from at least one of: a capping layer, a barrier coating, an encapsulation layer, a thin film encapsulation layer, and a polarizing layer.

19. The device of claim 1, wherein the higher-index layer comprises an air gap.

20. The device of claim 1, wherein the higher-index layer comprises a high-index material.

21. The device of claim 20, wherein at least one of the higher-index layer and the high-index material exhibits an extinction coefficient in the second wavelength range that is no more than at least one of about: 0.1, 0.08, 0.05, 0.03. and 0.01.

22. The device of claim 20, wherein at least one of the higher-index layer and the high-index material is substantially transparent.

23. The device of claim 20, wherein the high-index material comprises an organic compound.

24. The device of claim 1, wherein the first layer surface is of an underlying layer that has a third refractive index at a wavelength in a third wavelength range that exceeds the first refractive index.

25. The device of claim 24, wherein the third wavelength range is selected from at least one of between about: 315-400 nm, 450-460 nm, 510-540 nm, 600-640 nm, 456-624 nm, 425-725 nm, 350-450 nm, 300-450 nm, 300-550 nm, 300-700 nm, 380-740 nm, 750-900 nm, 380-900 nm, and 300-900 nm.

26. The device of claim 24, wherein the third wavelength range is different from the first wavelength range.

27. The device of claim 24, wherein the third refractive index is at least one of at least about: 1.7, 1.8, and 1.9.

28. The device of claim 24 wherein the third refractive index exceeds the first refractive index by at least one of at least about: 0.3, 0.4, 0.5, 0.7, 1.0, 1.2, 1.3, 1.4, and 1.5.

29. The device of claim 24, wherein a third maximum refractive index corresponding to a maximum value of the third refractive index measured within the third wavelength range exceeds a first maximum refractive index corresponding to a maximum value of the first refractive index measured within the first wavelength range.

30. The device of claim 29, wherein the first maximum refractive index corresponds to a first wavelength within the first wavelength range that is different from a third wavelength within the third wavelength range to which the third maximum refractive index corresponds.

31. The device of claim 29, wherein the third maximum refractive index exceeds the first maximum refractive index by at least one of at least about: 0.5, 0.7, 1.0, 1.2, 1.3, 1.4, 1.5, and 1.7.

32. The device of claim 24, wherein the underlying layer is a semiconducting layer of an opto-electronic device.

33. The device of claim 32, wherein the underlying layer is selected from an electron transport layer and an electron injection layer.

34. The device of claim 1, wherein an average layer thickness of the low(er)-index layer is no more than an average layer thickness of the higher-index layer.

35. The device of claim 34, wherein the average layer thickness of the low(er)-index layer is no more than at least one of about: 60 nm, 50 nm, 40 nm, 30 nm, 20 nm, 10 nm, 8 nm, and 5 nm.

36. The device of claim 34, wherein the average layer thickness of the low(er)-index layer is at least one of between about: 5-20 nm, and 5-15 nm.

37. The device of claim 1, wherein the low-index material exhibits a surface energy that is no more than about 25 dynes/cm and the first refractive index is no more than about 1.45.

38. The device of claim 1, wherein the low-index material exhibits a surface energy that is no more than about 20 dynes/cm and the first refractive index is no more than about 1.4.

39. The device of claim 1, further comprising a quantity of deposited material disposed on a second layer surface in the non-interface portion.

40. The device of claim 39, wherein the low(er)-index layer comprises a patterning coating.

41. The device of claim 40, wherein an initial sticking probability for forming a closed coating of the deposited material onto a surface of the patterning coating is substantially less than the initial sticking probability for forming the deposited material onto the first layer surface, such that the patterning coating is substantially devoid of a closed coating of the deposited material.

42. The device of claim 39, wherein the interface portion corresponds to a first portion of the lateral aspect and the non-interface portion corresponds to a second portion of the lateral aspect where the deposited material forms a closed coating.

43. The device of claim 39, wherein the quantity of deposited material comprises at least one particle structure comprising a particle material.

44. The device of claim 43, wherein the at least one particle structure forms a discontinuous layer between the low(er)-index layer and the higher-index layer.

45. The device of claim 39, wherein the deposited material precludes the definition of the index interface in the non-interface portion.

46. The device of claim 39, wherein the higher-index layer covers the deposited material in the non-interface portion.

47. The device of claim 1, wherein the second layer surface and the first layer surface are the same.

48. The device of claim 1, wherein the low(er)-index layer extends into the non-interface portion and the second layer surface is an exposed layer surface of the low(er)-index layer therein.

49. The device of claim 1, wherein the device is adapted to permit EM radiation to engage a surface thereof along at an optical path in a first direction that is at an angle to a plane defined by a plurality of the lateral axes of the device.

50. The device of claim 49, wherein the EM radiation is emitted by the device, and the first direction is a direction at which the EM radiation is extracted from the device.

51. The device of claim 49, wherein the EM radiation is incident on an external surface of the device and transmitted at least partially therethrough, and the first direction is a direction at which the EM radiation is incident on the device.

52. The device of claim 1, wherein the interface portion comprises a first emissive region for emitting a first EM signal along an optical path in a first direction at which EM radiation is extracted from the device and that is at an angle to a plane defined by a plurality of the lateral axes of the device.

53. The device of claim 52, further comprising:
a substrate; and
at least one semiconducting layer disposed thereon;
wherein:
the first emissive region comprises a first electrode and a second electrode,
the first electrode is disposed between the substrate and the at least one semiconducting layer,
the at least one semiconducting layer is disposed between the first electrode and the second electrode, and
the low(er)-index layer is disposed between the second electrode and the higher-index layer.

54. The device of claim 53, further comprising a second emissive region in the non-interface portion for emitting a second EM signal along the optical path further comprising a third electrode and a fourth electrode, wherein:
the third electrode is disposed between the substrate and the at least one semiconducting layer,
the at least one semiconducting layer is disposed between the third electrode and the fourth electrode,
the non-interface portion is substantially devoid of the low(er)-index layer, and
the fourth electrode is disposed between the third electrode and the higher-index layer.
